(19) United States
(12) Patent Application Publication
(10) Pub. No.: US 2021/0200088 A1
(43) Pub. Date: Jul. 1, 2021

(54) RESIST COMPOSITION AND METHOD OF FORMING RESIST PATTERN

(71) Applicant: TOKYO OHKA KOGYO CO., LTD., Kawasaki-shi (JP)

(72) Inventors: Toshiaki YATSUNAMI, Kawasaki-shi (JP); Takaya MAEHASHI, Kawasaki-shi (JP); Masahiro SHIOSAKI, Kawasaki-shi (JP); Hiroshi GOHARA, Kawasaki-shi (JP); Seiji TODOROKI, Kawasaki-shi (JP); Koshi ONISHI, Kawasaki-shi (JP); KhanhTin NGUYEN, Kawasaki-shi (JP); Nobuhiro MICHIBAYASHI, Kawasaki-shi (JP); Takuya IKEDA, Kawasaki-shi (JP)

(21) Appl. No.: 17/129,218

(22) Filed: Dec. 21, 2020

(30) Foreign Application Priority Data
Dec. 25, 2019 (JP) 2019-234479
Dec. 25, 2019 (JP) 2019-234510
Dec. 25, 2019 (JP) 2019-234511

(51) Int. Cl. G03F 7/038; G03F 7/004; G03F 7/20; C08L 33/06

(52) U.S. Cl. CPC G03F 7/0382; C08L 33/064; G03F 7/2004; G03F 7/0045

(57) ABSTRACT

A resist composition which generates acid upon exposure and exhibits changed solubility in a developing solution under action of acid, a total amount of a basic component including a compound represented by general formula (d0) and an acid-generator component is 25 to 60 parts by weight relative to 100 parts by weight of a base material component. In formula (d0), Rd⁰ represents a monovalent organic group; Xd⁰ represents —O—, —C(═O)—, —O—C(═O)—, —C(═O)—O—, —S— or —SO₂—; Yd⁰ represents a single bond or a divalent hydrocarbon group which may have a substituent; M^{m+} represents a m-valent organic cation; and m represents an integer of 1 or more

Rd⁰-Xd⁰-Yd⁰-COO^{⊖}(M^{m⊕})_{1/m} (d0).

### TECHNICAL FIELD

The present invention relates to a resist composition and a method of forming a resist pattern.

Priority is claimed on Japanese Patent Application Nos. 2019-234511, 2019-234479 and 2019-234510, all of which were filed Dec. 25, 2019, the entire contents of which are incorporated herein by reference.

### DESCRIPTION OF RELATED ART

In recent years, in the production of semiconductor elements and liquid crystal display elements, advances in lithography techniques have led to rapid progress in the field of pattern miniaturization. Typically, these miniaturization techniques involve shortening the wavelength (increasing the energy) of the exposure light source.

Resist materials for use with these types of exposure light sources require lithographic properties such as a high resolution capable of reproducing patterns of minute dimensions, and a high level of sensitivity to these types of exposure light sources.

As a resist material that satisfies these conditions, a chemically amplified composition is used, which includes a base material component that exhibits a changed solubility in a developing solution under the action of acid and an acid-generator component that generates acid upon exposure.

In the formation of a resist pattern, it is considered that the behavior of the acid generated from the acid-generator component upon exposure is one of the factors that has a large influence on the lithography properties.

In consideration of the above, there has been proposed a chemically amplified resist composition which uses, in combination with an acid generator component, an acid diffusion control agent which controls the diffusion of acid generated from the acid generator component upon exposure.

For example, Patent Literature 1 describes a radiation-sensitive resin containing a resin component whose solubility in a developing solution changes due to the action of an acid, an acid generator component, and an acid diffusion control agent having an anion moiety having a specific structure.

This acid diffusion control agent is considered to be a component that exerts an ion exchange reaction with the acid generated from the acid generator component to exert a quenching effect. By blending such an acid diffusion control agent, diffusion of the acid generated from the acid generator component from the exposed portion of the resist film to the unexposed portion is controlled, and the lithography characteristics are improved.

### DOCUMENTS OF RELATED ART

### Patent Literature

[Patent Literature 1] WO2014/188762

### SUMMARY OF THE INVENTION

Recently, advances in lithography techniques and expansion in the application fields have led to rapid progress in the field of pattern miniaturization. As a consequence, in the production of a semiconductor device or the like, there is a demand for a technique which enable formation of a fine resist pattern having a pattern width of no more than 100 nm with good shape.

However, in the conventional resist composition as described in Patent Literature 1 described above, when an attempt is made to increase the sensitivity to an exposure light source such as EUV, there was a problem that a resist pattern shape having desired lithography characteristics such as reduction of roughness may not be obtained, and it was difficult to satisfy all of such lithography characteristics. On the other hand, by increasing the blending amount of the acid generating agent component, the lithography characteristics can be improved, but on the other hand, there is a problem that the film thickness loss of the pattern is likely to occur.

The present invention takes the above circumstances into consideration, with an object of providing a resist composition which exhibits high sensitivity, improved lithography properties such as reduction of roughness, and is unlikely to cause film thickness loss of the pattern; and a method of forming a resist pattern using the resist composition.

For solving the above-mentioned problems, the present invention employs the following aspects.

A first aspect of the present invention is a resist composition which generates acid upon exposure and exhibits changed solubility in a developing solution under action of acid, and which includes a base material component (A) which exhibits changed solubility in a developing solution under action of acid, an acid-generator component (B) which generates acid upon exposure, and a basic component (D) which controls diffusion of the acid generated from the acid-generator component (B) upon exposure, the basic component (D) including a compound (D0) represented by general formula (d0) shown below, and a total amount of the acid-generator component (B) and the basic component (D) being 25 to 60 parts by weight, relative to 100 parts by weight of the base material component (A).

[Chemical Formula 1]

Rd⁰-Xd⁰-Yd⁰-COO^{⊖}(M^{m⊕})_{1/m} (d0)

In the formula, Rd⁰ represents a monovalent organic group; Xd⁰ represents —O—, —C(═O)—, —O—C(═O)—, —C(═O)—O—, —S— or —SO₂—; Yd⁰ represents a single bond or a divalent hydrocarbon group which may have a substituent; M^{m+} represents a m-valent organic cation; and m represents an integer of 1 or more.

A second aspect of the present invention is a method of forming a resist pattern, including: using a resist composition according to the first aspect to form a resist film, exposing the resist film, and developing the exposed resist film to form a resist pattern.

According to the present invention, there are provided a resist composition which exhibits high sensitivity, improved lithography properties such as reduction of roughness, and is unlikely to cause film thickness loss of the pattern; and a method of forming a resist pattern using the resist composition.

### BRIEF DESCRIPTION OF THE DRAWING

FIG. 1 is a graph showing the change in the film retention ratio relative to the total amount of the components (B) and (D) in a resist composition.

### DETAILED DESCRIPTION OF THE INVENTION

In the present description and claims, the term “aliphatic” is a relative concept used in relation to the term “aromatic”, and defines a group or compound that has no aromaticity.

The term “alkyl group” includes linear, branched or cyclic, monovalent saturated hydrocarbon, unless otherwise specified. The same applies for the alkyl group within an alkoxy group.

The term “alkylene group” includes linear, branched or cyclic, divalent saturated hydrocarbon, unless otherwise specified.

Examples of the halogen atom include a fluorine atom, a chlorine atom, a bromine atom and an iodine atom. The term “structural unit” refers to a monomer unit that contributes to the formation of a polymeric compound (resin, polymer, copolymer).

The case of describing “may have a substituent” includes both of the case where the hydrogen atom (—H) is substituted with a monovalent group and the case where a methylene group (—CH₂—) is substituted with a divalent group.

The term “exposure” is used as a general concept that includes irradiation with any form of radiation.

The term “acid decomposable group” refers to a group in which at least a part of the bond within the structure thereof is cleaved by the action of an acid.

Examples of acid decomposable groups which exhibit increased polarity by the action of an acid include groups which are decomposed by the action of an acid to form a polar group.

Examples of the polar group include a carboxy group, a hydroxy group, an amino group and a sulfo group (—SO₃H).

More specifically, as an example of an acid decomposable group, a group in which the aforementioned polar group has been protected with an acid dissociable group (such as a group in which the hydrogen atom of the OH-containing polar group has been protected with an acid dissociable group) can be given.

The “acid dissociable group” refers to both (i) a group in which the bond between the acid dissociable group and the adjacent atom is cleaved by the action of acid; and (ii) a group in which one of the bonds is cleaved by the action of acid, and then a decarboxylation reaction occurs, thereby cleaving the bond between the acid dissociable group and the adjacent atom.

It is necessary that the acid dissociable group that constitutes the acid decomposable group is a group which exhibits a lower polarity than the polar group generated by the dissociation of the acid dissociable group. Thus, when the acid dissociable group is dissociated by the action of acid, a polar group exhibiting a higher polarity than that of the acid dissociable group is generated, thereby increasing the polarity. As a result, the polarity of the entire component (A1) is increased. By the increase in the polarity, the solubility in an alkali developing solution changes, and the solubility in an alkali developing solution is relatively increased, whereas the solubility in an organic developing solution is relatively decreased.

The term “base component” refers to an organic compound capable of forming a film. The organic compound used as the base component is broadly classified into non-polymers and polymers. In general, as a non-polymer, any of those which have a molecular weight in the range of 500 to less than 4,000 is used. Hereafter, a “low molecular weight compound” refers to a non-polymer having a molecular weight in the range of 500 to less than 4,000. As a polymer, any of those which have a molecular weight of 1,000 or more is generally used. Hereafter, a “resin” or a “polymer” refers to a polymer having a molecular weight of 1,000 or more. As the molecular weight of the polymer, the weight average molecular weight in terms of the polystyrene equivalent value determined by gel permeation chromatography (GPC) is used.

The expression “structural unit derived from” refers to a structural unit which is formed by cleavage of a multiple bond between carbon atoms, e.g., an ethylenic double bond.

The acrylate ester may have the hydrogen atom bonded to the carbon atom on the α-position substituted with a substituent. The substituent (R^{αx}) that substitutes the hydrogen atom bonded to the carbon atom on the α-position is an atom other than hydrogen or a group. Further, an acrylate ester having the hydrogen atom bonded to the carbon atom on the α-position substituted with a substituent (R^{αx}) in which the substituent has been substituted with a substituent containing an ester bond (e.g., an itaconic acid diester), or an acrylic acid having the hydrogen atom bonded to the carbon atom on the α-position substituted with a substituent (R^{αx}) in which the substituent has been substituted with a hydroxyalkyl group or a group in which the hydroxy group within a hydroxyalkyl group has been modified (e.g., α-hydroxyalkyl acrylate ester) may be mentioned as an acrylate ester having the hydrogen atom bonded to the carbon atom on the α-position substituted with a substituent. A carbon atom on the α-position of an acrylate ester refers to the carbon atom bonded to the carbonyl group, unless specified otherwise.

Hereafter, an acrylate ester having the hydrogen atom bonded to the carbon atom on the α-position substituted with a substituent is sometimes referred to as “α-substituted acrylate ester”.

The term “derivative” is a concept including a compound in which a hydrogen atom at the α-position of the subject compound has been substituted with another substituent such as an alkyl group or a halogenated alkyl group, and derivatives thereof. Examples of the derivatives include a compound in which the hydrogen atom at the α-position of the subject compound may be substituted with a substituent, and the hydrogen atom of the hydroxy group of the target compound has been substituted with an organic group; and a compound in which the hydrogen atom at the α-position of the subject compound may be substituted with a substituent, and a substituent other than a hydroxy group has been bonded to the subject compound. The α-position refers to the first carbon atom adjacent to a functional group, unless otherwise specified.

As the substituent which substitutes the hydrogen atom on the α-position of hydroxystyrene, the same substituents as those described above for R^{αx} may be mentioned.

In the present specification and claims, some structures represented by chemical formulae may have an asymmetric carbon, such that an enantiomer or a diastereomer may be present. In such a case, the one formula represents all isomers. The isomers may be used individually, or in the form of a mixture.

(Resist Composition)

The resist composition of the present embodiment generates acid upon exposure and exhibits changed solubility in a developing solution under action of acid.

The resist composition includes a base material component (A) (hereafter, sometimes referred to as “component (A)”) which exhibits changed solubility in a developing solution under action of acid, an acid-generator component (B) (hereafter, sometimes referred to as “component (B)”) which generates acid upon exposure, and a basic component (D) (hereafter, sometimes referred to as “component (D)”) which controls diffusion of the acid generated from the component (B) upon exposure.

When a resist film is formed using the resist composition according to the present embodiment and the formed resist film is subjected to a selective exposure, acid is generated at exposed portions, and the generated acid acts on the component (A) to change the solubility of the component (A) in a developing solution, whereas the solubility of the component (A) in a developing solution is not changed at unexposed portions, thereby generating difference in solubility in a developing solution between exposed portions and unexposed portions. Therefore, by subjecting the resist film to development, the exposed portions of the resist film are dissolved and removed to form a positive-tone resist pattern in the case of a positive resist, whereas the unexposed portions of the resist film are dissolved and removed to form a negative-tone resist pattern in the case of a negative resist.

In the present specification, a resist composition which forms a positive resist pattern by dissolving and removing the exposed portions of the resist film is called a positive resist composition, and a resist composition which forms a negative resist pattern by dissolving and removing the unexposed portions of the resist film is called a negative resist composition. The resist composition of the present embodiment may be either a positive resist composition or a negative resist composition. Further, in the present embodiment, the resist composition may be applied to an alkali developing process using an alkali developing solution in the developing treatment, or a solvent developing process using a developing solution containing an organic solvent (organic developing solution) in the developing treatment, and preferably a solvent developing process.

<Component (A)>

In the resist composition of the present embodiment, the component (A) is a base component which exhibits changed solubility in a developing solution under action of acid.

The component (A) preferably contains a resin component (A1) (hereafter, referred to as “component (A1)”) which exhibits changed solubility in a developing solution by the action of acid. By using the component (A1), the polarity of the base component before and after exposure is changed. Therefore, a good development contrast may be achieved not only in an alkali developing process, but also in a solvent developing process.

As the component (A), at least the component (A1) is used, and a polymeric compound and/or a low molecular weight compound may be used in combination with the component (A1).

More specifically, in the case of applying an alkali developing process, the base component containing the component (A1) is hardly soluble in an alkali developing solution prior to exposure, but when acid is generated from the component (B) upon exposure, the action of this acid causes an increase in the polarity of the base component, thereby increasing the solubility of the component (A1) in an alkali developing solution. Therefore, in the formation of a resist pattern, by conducting selective exposure of a resist film formed by applying the resist composition to a substrate, the exposed portions of the resist film change from an insoluble state to a soluble state in an alkali developing solution, whereas the unexposed portions of the resist film remain insoluble in an alkali developing solution, and hence, a positive-tone resist pattern is formed by alkali developing.

On the other hand, in the case of a solvent developing process, the base component containing the component (A1) exhibits high solubility in an organic developing solution prior to exposure, and when acid is generated from the component (B) upon exposure, the polarity of the component (A1) is increased by the action of the generated acid, thereby decreasing the solubility of the component (A1) in an organic developing solution. Therefore, in the formation of a resist pattern, by conducting selective exposure of a resist film formed by applying the resist composition to a substrate, the exposed portions of the resist film changes from an soluble state to an insoluble state in an organic developing solution, whereas the unexposed portions of the resist film remain soluble in an organic developing solution. As a result, by conducting development using an organic developing solution, a contrast can be made between the exposed portions and unexposed portions, thereby forming a negative resist pattern.

In the resist composition of the present embodiment, as the component (A), one kind of compound may be used, or two or more kinds of compounds may be used in combination.

Component (A1)

The component (A1) is a resin component which exhibits changed solubility in a developing solution under action of acid. The component (A1) is preferably a resin component which has a structural unit (a1) containing an acid decomposable group that exhibits increased polarity by the action of acid.

If desired, the component (A1) may include, in addition to the structural unit (a1), other structural unit.

<<Structural Unit (a1)>>

The structural unit (a1) is a structural unit containing an acid decomposable group that exhibits increased polarity by the action of acid.

Examples of the acid dissociable group include groups which have been proposed as acid dissociable groups for the base resin of a conventional chemically amplified resist composition.

Specific examples of acid dissociable groups for the base resin of a conventional chemically amplified resist composition include “acetal-type acid dissociable group”, “tertiary alkyl ester-type acid dissociable group” and “tertiary alkyloxycarbonyl acid dissociable group” described below.

Acetal-Type Acid Dissociable Group

Examples of the acid dissociable group for protecting the carboxy group or hydroxy group as a polar group include the acid dissociable group represented by general formula (a1-r-1) shown below (hereafter, referred to as “acetal-type acid dissociable group”).

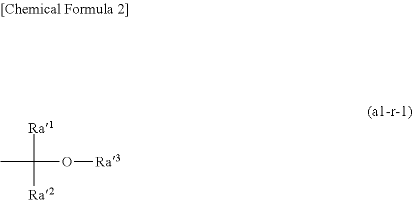

In the formula, Ra′¹ and Ra′² each independently represents a hydrogen atom or an alkyl group; Ra′³ represents a hydrocarbon group, provided that Ra′³ may be bonded to Ra′¹ or Ra′² to form a ring.

In the formula (a1-r-1), it is preferable that at least one of Ra′¹ and Ra′² represents a hydrogen atom, and it is more preferable that both of Ra′¹ and Ra′² represent a hydrogen atom.

In the case where Ra′¹ or Ra′² is an alkyl group, the alkyl group is preferably an alkyl group having 1 to 5 carbon atoms. Specific examples include linear or branched alkyl groups. Specific examples of the alkyl group include a methyl group, an ethyl group, a propyl group, an isopropyl group, an n-butyl group, an isobutyl group, a tert-butyl group, a pentyl group, an isopentyl group and a neopentyl group. Of these, a methyl group or an ethyl group is preferable, and a methyl group is particularly preferable.

In formula (a1-r-1), examples of the hydrocarbon group for Ra′³ include a linear or branched alkyl group and a cyclic hydrocarbon group.

The linear alkyl group preferably has 1 to 5 carbon atoms, more preferably 1 to 4 carbon atoms, and still more preferably 1 or 2 carbon atoms. Specific examples include a methyl group, an ethyl group, an n-propyl group, an n-butyl group and an n-pentyl group. Among these, a methyl group, an ethyl group or an n-butyl group is preferable, and a methyl group or an ethyl group is more preferable.

The branched alkyl group preferably has 3 to 10 carbon atoms, and more preferably 3 to 5 carbon atoms. Specific examples include an isopropyl group, an isobutyl group, a tert-butyl group, an isopentyl group, a neopentyl group a 1,1-diethylpropyl group and a 2,2-dimethylbutyl group. Among these, an isopropyl group is preferable.

In the case where Ra′³ represents a cyclic hydrocarbon group, the cyclic hydrocarbon group may be an aliphatic hydrocarbon group or an aromatic hydrocarbon group, and may be polycyclic or monocyclic.

As the monocyclic aliphatic hydrocarbon group, a group in which 1 hydrogen atom has been removed from a monocycloalkane is preferable. The monocycloalkane preferably has 3 to 6 carbon atoms, and specific examples thereof include cyclopentane and cyclohexane.

As the polycyclic aliphatic hydrocarbon group, a group in which 1 hydrogen atom has been removed from a polycycloalkane is preferable, and the polycyclic group preferably has 7 to 12 carbon atoms. Examples of the polycycloalkane include adamantane, norbornane, isobornane, tricyclodecane and tetracyclododecane.

When the monovalent hydrocarbon group for Ra′³ is an aromatic hydrocarbon group, the aromatic hydrocarbon group is a hydrocarbon group having at least one aromatic ring.

The aromatic ring is not particularly limited, as long as it is a cyclic conjugated compound having (4n+2)π electrons, and may be either monocyclic or polycyclic. The aromatic ring preferably has 5 to 30 carbon atoms, more preferably 5 to 20 carbon atoms, and still more preferably 6 to 15 carbon atoms, and most preferably 6 to 12 carbon atoms. Examples of the aromatic ring include aromatic hydrocarbon rings, such as benzene, naphthalene, anthracene and phenanthrene; and aromatic hetero rings in which part of the carbon atoms constituting the aforementioned aromatic hydrocarbon rings has been substituted with a hetero atom. Examples of the hetero atom within the aromatic hetero rings include an oxygen atom, a sulfur atom and a nitrogen atom. Specific examples of the aromatic hetero ring include a pyridine ring and a thiophene ring.

Specific examples of the aromatic hydrocarbon group for Ra′³ include a group in which one hydrogen atom has been removed from the aforementioned aromatic hydrocarbon ring or aromatic hetero ring (aryl group or heteroaryl group); a group in which one hydrogen atom has been removed from an aromatic compound having two or more aromatic rings (biphenyl, fluorene or the like); and a group in which one hydrogen atom of the aforementioned aromatic hydrocarbon ring or aromatic hetero ring has been substituted with an alkylene group (an arylalkyl group such as a benzyl group, a phenethyl group, a 1-naphthylmethyl group, a 2-naphthylmethyl group, a 1-naphthylethyl group, or a 2-naphthylethyl group). The alkylene group bonded to the aforementioned aromatic hydrocarbon ring or the aromatic hetero ring preferably has 1 to 4 carbon atoms, more preferably 1 or 2 carbon atoms, and most preferably 1 carbon atom.

The cyclic hydrocarbon group for Ra′³ may have a substituent. Examples of the substituent include —R^{P1}, —R^{P2}—O—R^{P1}, —R^{P2}—CO—R^{P1}, —R^{P2}—CO—OR^{P1}, —R^{P2}—O—CO—R^{P1}, —R^{P2}—OH, —R^{P2}—CN and —R^{P2}—COOH (hereafter, these substituents are sometimes collectively referred to as “Ra^{x5}”). R^{P1} represents a monovalent saturated chain hydrocarbon group of 1 to 10 carbon atoms, a monovalent saturated cyclic aliphatic hydrocarbon group of 3 to 20 carbon atoms or a monovalent aromatic hydrocarbon group of 6 to 30 carbon atoms. R^{P2} represents a single bond, monovalent saturated chain hydrocarbon group of 1 to 10 carbon atoms, a monovalent saturated aliphatic cyclic hydrocarbon group of 3 to 20 carbon atoms or a monovalent aromatic hydrocarbon group of 6 to 30 carbon atoms. The saturated chain hydrocarbon group, the saturated cyclic aliphatic hydrocarbon group and the aromatic hydrocarbon group for R^{P1} and R^{P2} may have part or all of the hydrogen atoms substituted with fluorine. The aliphatic cyclic hydrocarbon group may have 1 or more substituents of 1 kind, or 1 or more substituents of a plurality of kinds.

Examples of the monovalent chain saturated hydrocarbon group having 1 to 10 carbon atoms include a methyl group, an ethyl group, a propyl group, a butyl group, a pentyl group, a hexyl group, a heptyl group, an octyl group, and a decyl group.

Examples of the monovalent aliphatic cyclic saturated hydrocarbon group having 3 to 20 carbon atoms include a monocyclic aliphatic saturated hydrocarbon group such as a cyclopropyl group, a cyclobutyl group, a cyclopentyl group, a cyclohexyl group, a cycloheptyl group, a cyclooctyl group, a cyclodecyl group, and a cyclododecyl group; and a polycyclic aliphatic saturated hydrocarbon group such as a bicyclo[2.2.2]octanyl group, a tricyclo[5.2.1.02,6]decanyl group, a tricyclo[3.3.1.13,7]decanyl group, a tetracyclo[6.2.1.13,6.02,7]dodecanyl group, and an adamantyl group.

Examples of the monovalent aromatic hydrocarbon group having 6 to 30 carbon atoms include a group obtained by removing one hydrogen atom from the aromatic hydrocarbon ring such as benzene, biphenyl, fluorene, naphthalene, anthracene, and phenanthrene.

In the case where Ra′³ is bonded to Ra′¹ or Ra′² to form a ring, the cyclic group is preferably a 4 to 7-membered ring, and more preferably a 4 to 6-membered ring. Specific examples of the cyclic group include tetrahydropyranyl group and tetrahydrofuranyl group.

Tertiary Alkyl Ester-Type Acid Dissociable Group

Examples of the acid dissociable group for protecting the carboxy group as a polar group include the acid dissociable group represented by general formula (a1-r-2) shown below.

Among the acid dissociable groups represented by general formula (a1-r-2), for convenience, a group which is constituted of alkyl groups is referred to as “tertiary ester-type acid dissociable group”.

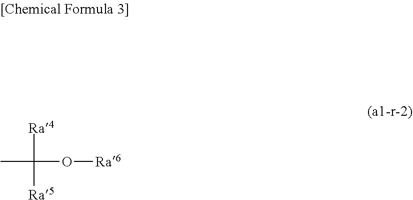

In the formula, Ra′⁴ to Ra′⁶ each independently represents a hydrocarbon group, provided that Ra′⁵ and Ra′⁶ may be mutually bonded to form a ring.

Examples of the hydrocarbon group for Ra′⁴ include a linear or branched alkyl group, a chain or cyclic alkenyl group, and a cyclic hydrocarbon group.

The linear or branched alkyl group and the cyclic hydrocarbon group (monocyclic aliphatic hydrocarbon group, polycyclic aliphatic hydrocarbon group or aromatic hydrocarbon group) for Ra′⁴ are the same as defined for Ra′³.

The chain or cyclic alkenyl group for Ra′⁴ is preferably an alkenyl group having 2 to 10 carbon atoms.

The hydrocarbon group for Ra′⁵ and Ra′⁶ is the same as defined for Ra′³.

In the case where Ra′⁵ and Ra′⁶ are mutually bonded to form a ring, a group represented by general formula (a1-r2-1) shown below, a group represented by general formula (a1-r2-2) shown below, and a group represented by general formula (a1-r2-3) shown below may be given as preferable examples.

On the other hand, in the case where Ra′⁴ to Ra′⁶ are not mutually bonded and independently represent a hydrocarbon group, the group represented by general formula (a1-r2-4) shown below may be given as a preferable example.

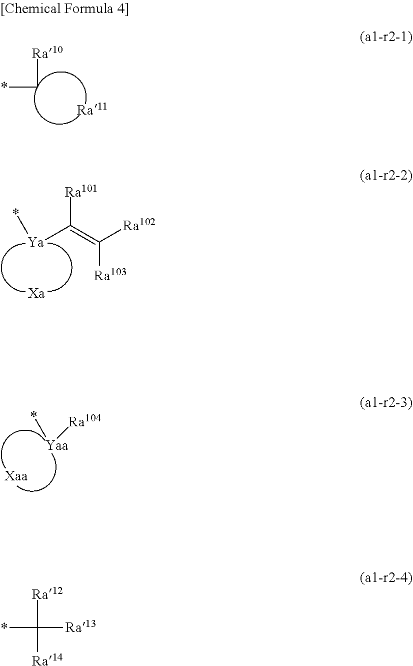

In formula (a1-r2-1), Ra′¹⁰ represents a linear or branched alkyl group having 1 to 12 carbon atoms optionally having part thereof substituted with a halogen atom or a hetero atom-containing group; Ra′¹¹ is a group which forms an aliphatic cyclic group together with a carbon atom having Ra′¹⁰ bonded thereto. In formula (a1-r2-2), Ya represents a carbon atom; Xa represents a group which forms a cyclic hydrocarbon group together with Ya, provided that part or all of the hydrogen atoms of the cyclic hydrocarbon group may be substituted; Ra¹⁰¹ to Ra¹⁰³ each independently represents a hydrogen atom, a monovalent saturated chain hydrocarbon group of 1 to 10 carbon atoms or a monovalent saturated aliphatic cyclic hydrocarbon group of 3 to 20 carbon atoms, provided that part or all of the hydrogen atoms of the saturated chain hydrocarbon or the saturated aliphatic cyclic hydrocarbon may be substituted; two or more of Ra¹⁰¹ to Ra¹⁰³ may be mutually bonded to form a cyclic structure. In formula (a1-r2-3), Yaa represents a carbon atom; Xaa represents a group which forms an aliphatic cyclic group together with Yaa; Ra¹⁰⁴ represents an aromatic hydrocarbon group which may have a substituent. In formula (a1-r2-4), Ra′¹² and Ra′¹³ each independently represents a hydrogen atom or a monovalent saturated hydrocarbon group of 1 to 10 carbon atoms, provided that part or all of the hydrogen atoms of the saturated hydrocarbon group may be substituted; Ra′¹⁴ represents a hydrocarbon group which may have a substituent; and * represents a bonding site.

In formula (a1-r2-1), Ra′¹⁰ represents a linear or branched alkyl group having 1 to 12 carbon atoms optionally having part thereof substituted with a halogen atom or a hetero atom-containing group.

The linear alkyl group for Ra′¹⁰ has 1 to 12 carbon atoms, preferably 1 to 10 carbon atoms, and more preferably 1 to 5 carbon atoms.

The branched alkyl group for Ra′¹⁰ is the same as defined for Ra′³.

The alkyl group for Ra′¹⁰ may have part thereof substituted with a halogen atom or a hetero atom-containing group. For example, part of the hydrogen atoms constituting the alkyl group may be substituted with a halogen atom or a hetero atom-containing group. Further, for example, part of the carbon atoms constituting the alkyl group (e.g., a methylene group) may be substituted with a hetero atom-containing group.

Examples of the hetero atom include an oxygen atom, a sulfur atom and a nitrogen atom. Examples of the hetero atom-containing group include (—O—), —C(═O)—O—, —O—C(═O)—, —C(═O)—, —O—C(═O)—O—, —C(═O)—NH—, —NH—, —S—, —S(═O)₂— and —S(═O)₂—O—.

In formula (a1-r2-1), the aliphatic cyclic group which is formed by Ra′¹¹ together with the carbon atom bonded to Ra′¹⁰, the same groups as those described above for the monocyclic or polycyclic aliphatic hydrocarbon group (alicyclic hydrocarbon group) for Ra′³ in formula (a1-r-1) are preferable. Among the above examples, a monocyclic alicyclic hydrocarbon group is preferable, a cyclopentyl group or a cyclohexyl group is more preferable, and a cyclopentyl group is still more preferable.

In formula (a1-r2-2), as the cyclic hydrocarbon group formed by Xa together with Ya, a group in which 1 or more hydrogen atoms have been removed from the monovalent cyclic hydrocarbon group (aliphatic hydrocarbon group) for Ra′³ in the aforementioned formula (a1-r-1) may be mentioned.

The cyclic hydrocarbon group which Xa forms with Ya may have a substituent. Examples of substituents include the same substituents as those which the cyclic hydrocarbon group for Ra′³ may have.

In formula (a1-r2-2), examples of the monovalent saturated chain hydrocarbon group of 1 to 10 carbon atoms for Ra¹⁰¹ to Ra¹⁰³ include a methyl group, an ethyl group, a propyl group, a butyl group, a pentyl group, a hexyl group, a heptyl group, an octyl group, and a decyl group.

Examples of the monovalent aliphatic cyclic saturated hydrocarbon group having 3 to 20 carbon atoms for Ra¹⁰¹ to Ra¹⁰³ include a monocyclic aliphatic saturated hydrocarbon group such as a cyclopropyl group, a cyclobutyl group, a cyclopentyl group, a cyclohexyl group, a cycloheptyl group, a cyclooctyl group, a cyclodecyl group, and a cyclododecyl group; and a polycyclic aliphatic saturated hydrocarbon group such as a bicyclo[2.2.2]octanyl group, a tricyclo[5.2.1.02,6]decanyl group, a tricyclo[3.3.1.13,7]decanyl group, a tetracyclo[6.2.1.13,6.02,7]dodecanyl group, and an adamantyl group.

Among these examples, in terms of ease in synthesis, Ra¹⁰¹ to Ra¹⁰³ is preferably a hydrogen atom or a monovalent saturated hydrocarbon group having 1 to 10 carbon atoms, more preferably a hydrogen atom, a methyl group or an ethyl group, and most preferably a hydrogen atom.

As the substituent for the saturated chain hydrocarbon group or saturated cyclic aliphatic hydrocarbon group represented by Ra¹⁰¹ to Ra¹⁰³, for example, the same substituents as those described above for Ra^{x5} may be mentioned.

Examples of the group containing a carbon-carbon double bond which is generated by forming a cyclic structure in which two or more of Ra¹⁰¹ to Ra¹⁰³ are bonded to each other include a cyclopentenyl group, a cyclohexenyl group, a methyl cyclopentenyl group, a methyl cyclohexenyl group, a cyclopentylideneethenyl group, and a cyclohexylidenethenyl group. Among these examples, in terms of ease in synthesis, a cyclopentenyl group, a cyclohexenyl group or a cyclopentylideneethenyl group is preferable.

In formula (a1-r2-3), an aliphatic cyclic group which is formed of Xaa together with Yaa is preferably a group exemplified as an aliphatic hydrocarbon group which is a monocyclic group or a polycyclic group of Ra′³ in general formula (a1-r-1).

In general formula (a1-r2-3), examples of the aromatic hydrocarbon group for Ra¹⁰⁴ include a group obtained by removing one or more hydrogen atoms from an aromatic hydrocarbon ring having 5 to 30 carbon atoms. Among these examples, Ra¹⁰⁴ is preferably a group obtained by removing one or more hydrogen atoms from an aromatic hydrocarbon ring having 6 to 15 carbon atoms, a group obtained by removing one or more hydrogen atoms from benzene, naphthalene, anthracene, or phenanthrene is further preferable, a group obtained by removing one or more hydrogen atoms from benzene, naphthalene, or anthracene is still further preferable, a group obtained by removing one or more hydrogen atoms from benzene and naphthalene is particularly preferable, and a group obtained by removing one or more hydrogen atoms from benzene is most preferable.

Examples of the substituent that Ra¹⁰⁴ in general formula (a1-r2-3) may have include a methyl group, an ethyl group, a propyl group, a hydroxyl group, a carboxyl group, a halogen atom, an alkoxy group (a methoxy group, an ethoxy group, a propoxy group, a butoxy group, or the like), and an alkyloxycarbonyl group.

In general formula (a1-r2-4), Ra′¹² and Ra′¹³ each independently represent a monovalent chain saturated hydrocarbon group having 1 to 10 carbon atoms or a hydrogen atom. With respect to Ra′¹² and Ra′¹³, examples of the monovalent chain saturated hydrocarbon group having 1 to 10 carbon atoms include the same monovalent chain saturated hydrocarbon group having 1 to 10 carbon atoms as that for Ra¹⁰¹ to Ra¹⁰³, provided that part or all of the hydrogen atoms of the saturated hydrocarbon group may be substituted; Among these examples, as Ra′¹² and Ra′¹³, a hydrogen atom and an alkyl group having 1 to 5 carbon atoms are preferable, an alkyl group having 1 to 5 carbon atoms is further preferable, a methyl group and an ethyl group are still further preferable, and a methyl group is particularly preferable.

In the case where the chain saturated hydrocarbon group represented by Ra′¹² and Ra′¹³ is substituted, examples of the substituent include the same group as that of Ra^{x5}.

In general formula (a1-r2-4), Ra′¹⁴ is a hydrocarbon group which may have a substituent. Examples of the hydrocarbon group for Ra′¹⁴ include a linear or branched alkyl group and a cyclic hydrocarbon group.

The linear alkyl group for Ra′¹⁴ preferably has 1 to 5 carbon atoms, more preferably 1 to 4 carbon atoms, and still more preferably 1 or 2 carbon atoms. Specific examples include a methyl group, an ethyl group, an n-propyl group, an n-butyl group and an n-pentyl group. Among these, a methyl group, an ethyl group or an n-butyl group is preferable, and a methyl group or an ethyl group is more preferable.

The branched alkyl group for Ra′¹⁴ preferably has 3 to 10 carbon atoms, and more preferably 3 to 5 carbon atoms. Specific examples include an isopropyl group, an isobutyl group, a tert-butyl group, an isopentyl group, a neopentyl group a 1,1-diethylpropyl group and a 2,2-dimethylbutyl group. Among these, an isopropyl group is preferable.

In the case where Ra′¹⁴ represents a cyclic hydrocarbon group, the cyclic hydrocarbon group may be an aliphatic hydrocarbon group or an aromatic hydrocarbon group, and may be polycyclic or monocyclic.

As the monocyclic aliphatic hydrocarbon group, a group in which 1 hydrogen atom has been removed from a monocycloalkane is preferable. The monocycloalkane preferably has 3 to 6 carbon atoms, and specific examples thereof include cyclopentane and cyclohexane.

As the polycyclic aliphatic hydrocarbon group, a group in which 1 hydrogen atom has been removed from a polycycloalkane is preferable, and the polycyclic group preferably has 7 to 12 carbon atoms. Examples of the polycycloalkane include adamantane, norbornane, isobornane, tricyclodecane and tetracyclododecane.

Examples of the aromatic hydrocarbon group for Ra′¹⁴ include the same aromatic hydrocarbon groups as those described above for Ra¹⁰⁴. Among these examples, Ra′¹⁴ is preferably a group formed by removing one or more hydrogen atoms from an aromatic hydrocarbon ring having 6 to 15 carbon atoms, more preferably a group formed by removing one or more hydrogen atoms from benzene, naphthalene, anthracene, or phenanthrene, still more preferably a group formed by removing one or more hydrogen atoms from benzene, naphthalene, or anthracene, still more preferably a group formed by removing one or more hydrogen atoms from naphthalene or anthracene, and most preferably a group formed by removing one or more hydrogen atoms from naphthalene.

Examples of the substituent that Ra′¹⁴ may have include the same group as the substituent that Ra¹⁰⁴ may have.

In the case where Ra′¹⁴ in general formula (a1-r2-4) is a naphthyl group, a position which is bonded to a tertiary carbon atom in general formula (a1-r2-4) may be 1-position and 2-position of the naphthyl group.

In the case where Ra′¹⁴ in general formula (a1-r2-4) is an anthryl group, a position which is bonded to a tertiary carbon atom in general formula (a1-r2-4) may be any one of 1-position, 2-position, and 9-position of the anthryl group.

Specific examples of the group represented by the aforementioned formula (a1-r2-1) are shown below.

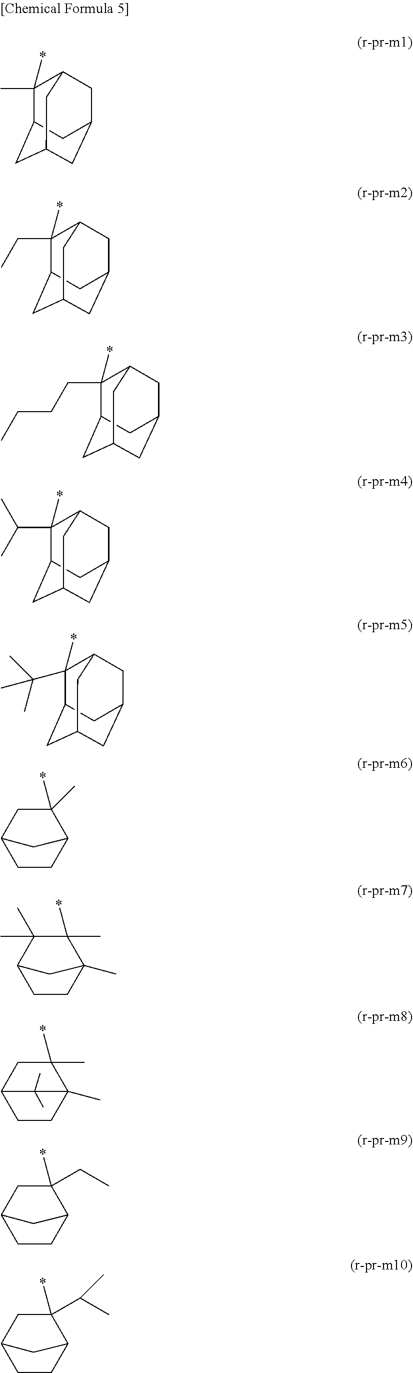

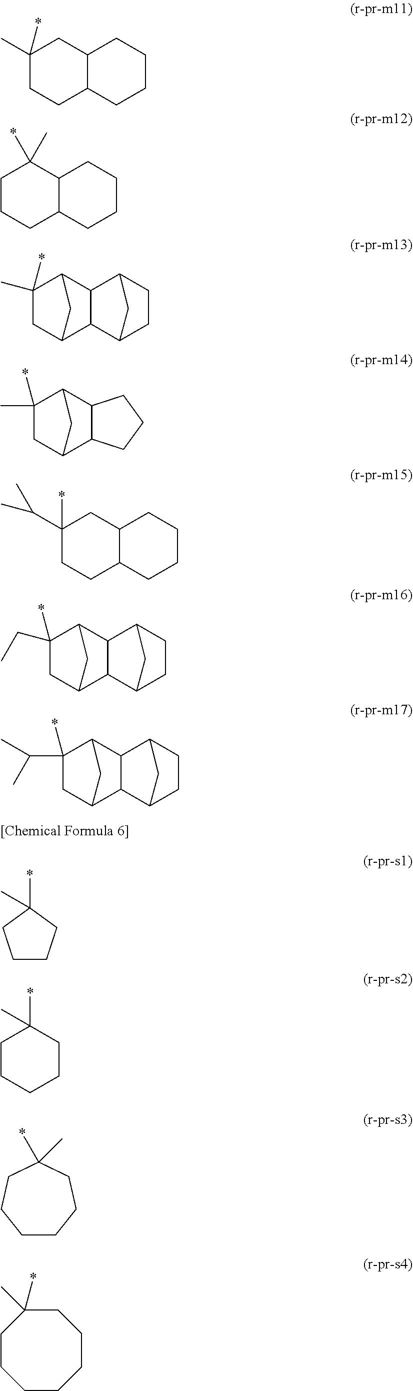

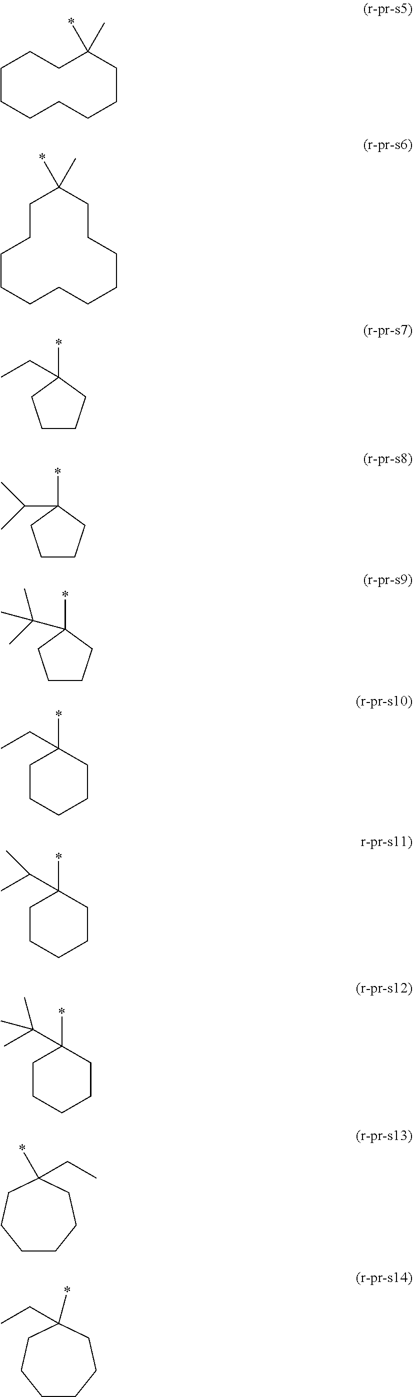

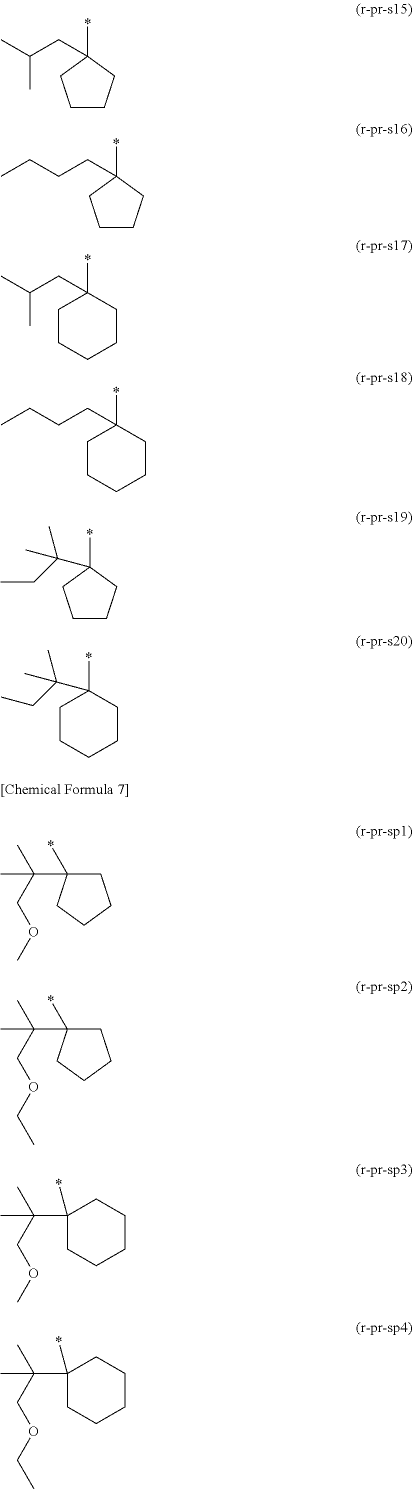

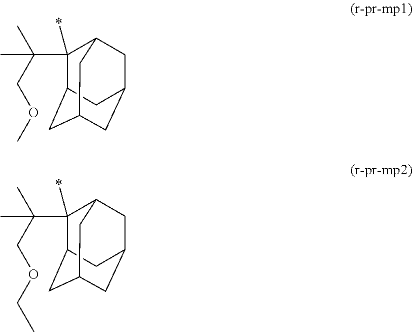

Specific examples of the group represented by the aforementioned formula (a1-r2-2) are shown below.

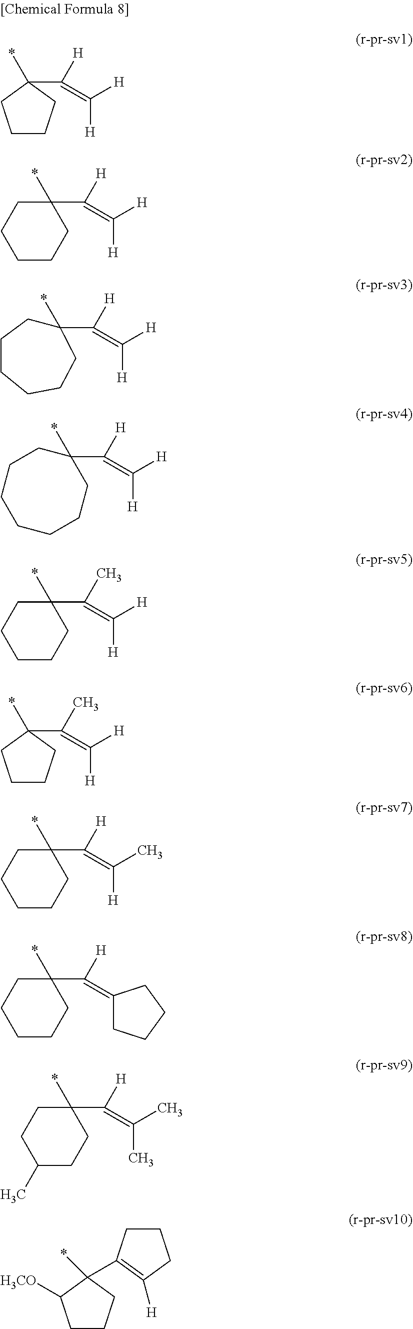

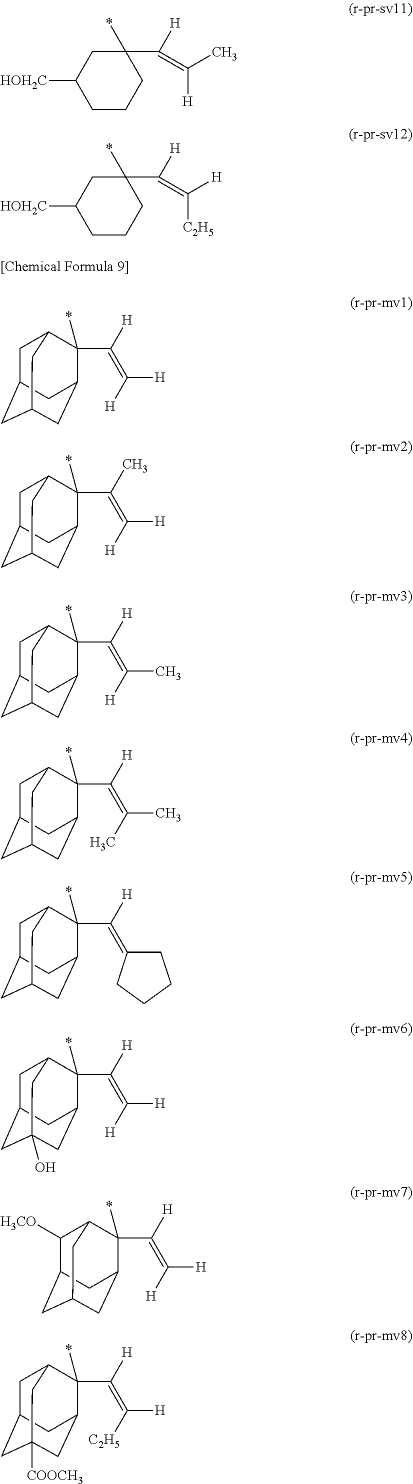

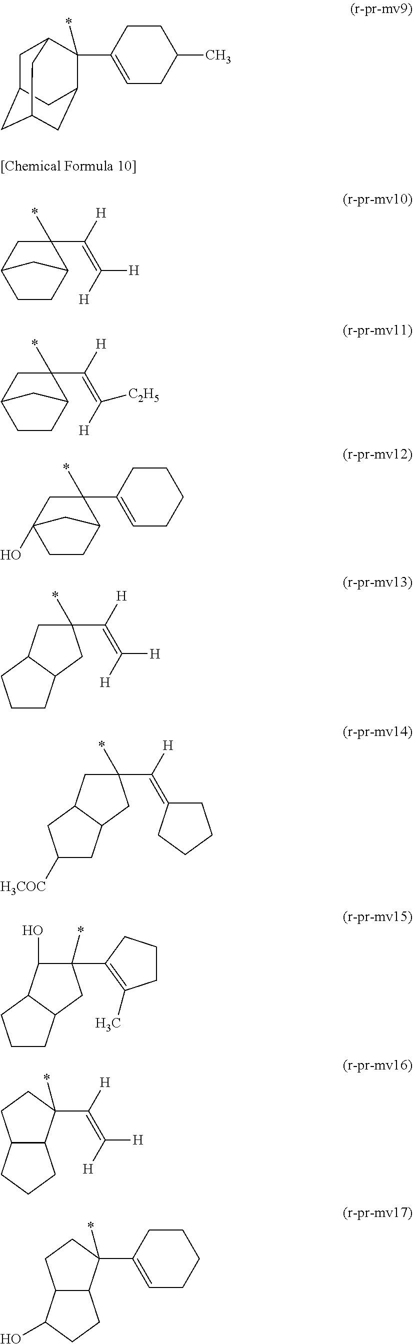

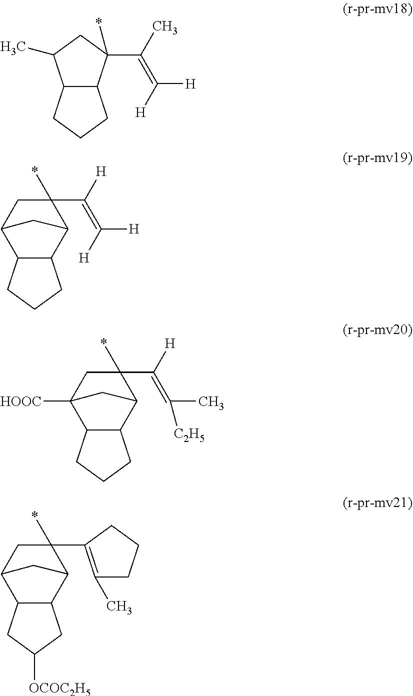

Specific examples of the group represented by the aforementioned formula (a1-r2-3) are shown below.

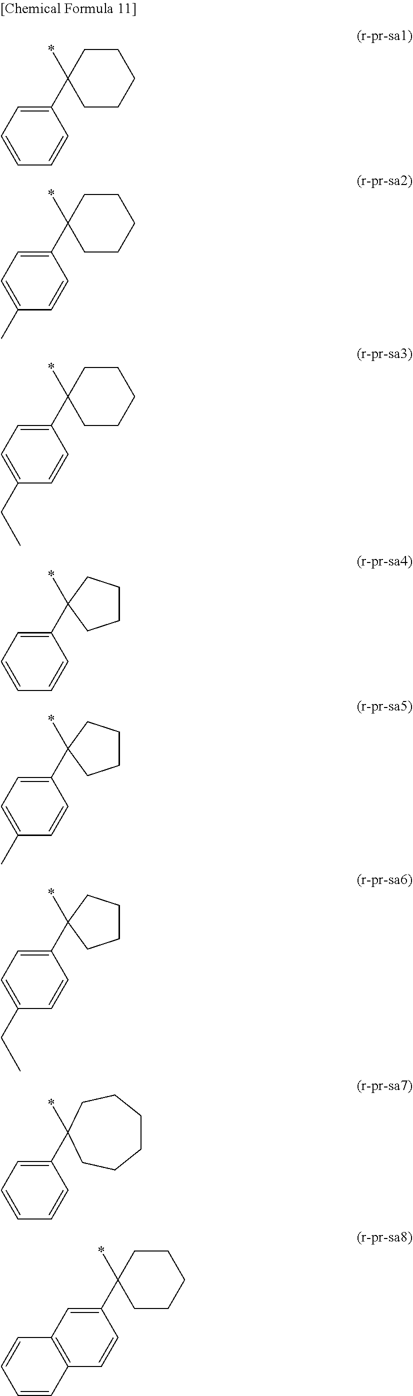

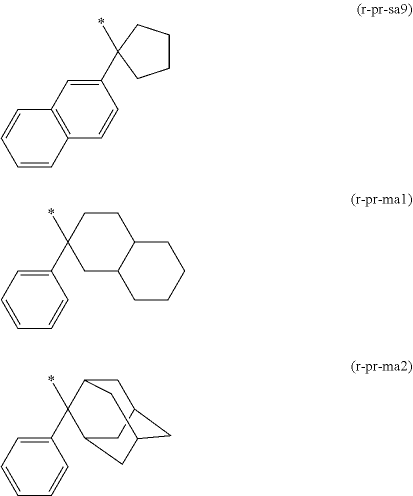

Specific examples of the group represented by the aforementioned formula (a1-r2-4) are shown below.

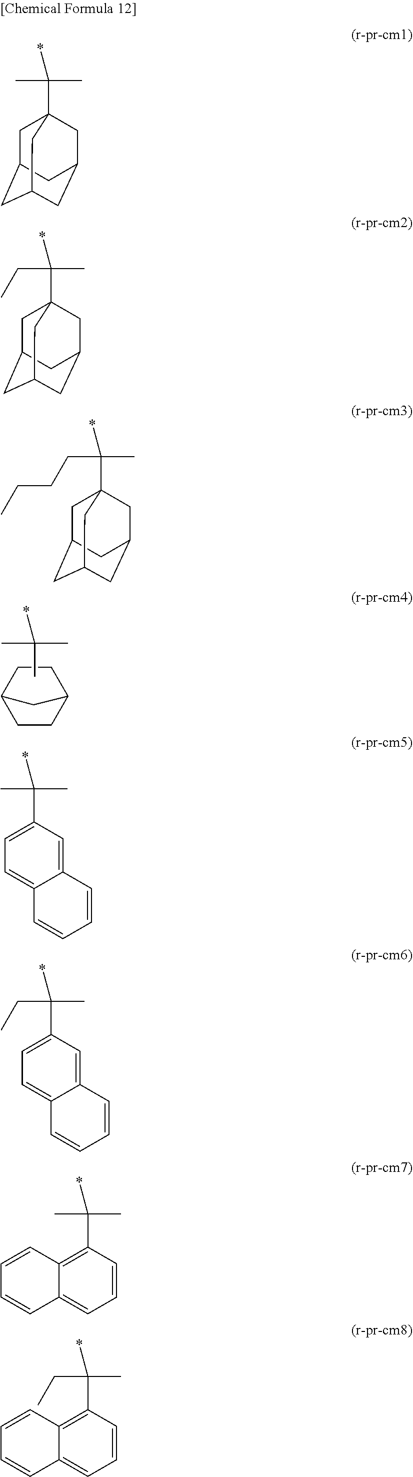

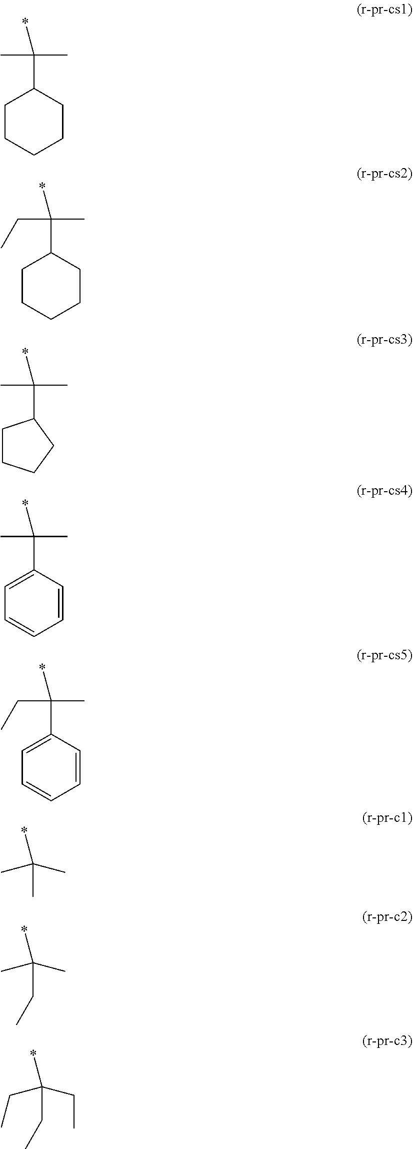

Tertiary Alkyloxycarbonyl Acid Dissociable Group

Examples of the acid dissociable group for protecting a hydroxy group as a polar group include the acid dissociable group represented by general formula (a1-r-3) shown below (hereafter, for convenience, referred to as “tertiary alkyloxycarbonyl-type acid dissociable group”).

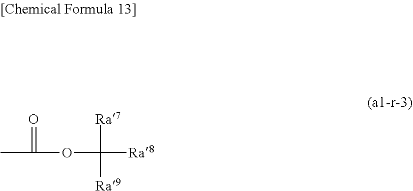

In the formula, Ra′⁷ to Ra′⁹ each independently represents an alkyl group.

In formula (a1-r-3), each of Ra′⁷ to Ra′⁹ is preferably an alkyl group having 1 to carbon atoms, and more preferably an alkyl group having 1 to 3 carbon atoms.

Further, the total number of carbon atoms in the alkyl groups is preferably 3 to 7, more preferably 3 to 5, and still more preferably 3 or 4.

Examples of the structural unit (a1) include a structural unit derived from an acrylate ester which may have the hydrogen atom bonded to the carbon atom on the ex-position substituted with a substituent; a structural unit derived from an acrylamide; a structural unit derived from hydroxystyrene or a hydroxystyrene derivative in which at least a part of the hydrogen atom of the hydroxy group is protected with a substituent containing an acid decomposable group; and a structural unit derived from vinylbenzoic acid or a vinylbenzoic acid derivative in which at least a part of the hydrogen atom within —C(═O)—OH is protected with a substituent containing an acid decomposable group.

As the structural unit (a1), a structural unit derived from an acrylate ester which may have the hydrogen atom bonded to the carbon atom on the α-position substituted with a substituent is preferable. Specific examples of preferable structural units for the structural unit (a1) include structural units represented by general formula (a1-1) or (a1-2) shown below.

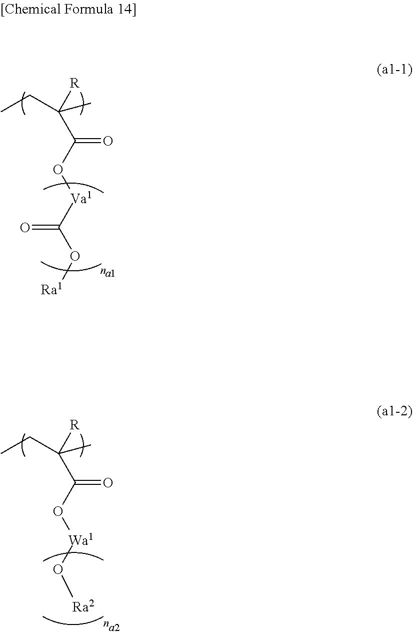

In the formula, R represents a hydrogen atom, an alkyl group of 1 to 5 carbon atoms or a halogenated alkyl group of 1 to 5 carbon atoms; Va¹ represents a divalent hydrocarbon group optionally having an ether bond; nₐ₁ represents an integer of 0 to 2; Ra¹ represents an acid dissociable group represented by the aforementioned formula (a1-r-1) or (a1-r-2); Wa¹ represents a hydrocarbon group having a valency of nₐ₂+1; nₐ₂ represents an integer of 1 to 3; and Ra² represents an acid dissociable group represented by the aforementioned general formula (a1-r-1) or (a1-r-3).

In the aforementioned formula (a1-1), as the alkyl group of 1 to 5 carbon atoms for R, a linear or branched alkyl group of 1 to 5 carbon atoms is preferable, and specific examples thereof include a methyl group, an ethyl group, a propyl group, an isopropyl group, an n-butyl group, an isobutyl group, a tert-butyl group, a pentyl group, an isopentyl group and a neopentyl group. The halogenated alkyl group of 1 to 5 carbon atoms represented by R is a group in which part or all of the hydrogen atoms of the aforementioned alkyl group of 1 to 5 carbon atoms have been substituted with halogen atoms. As the halogen atom, a fluorine atom is most preferable.

As R, a hydrogen atom, an alkyl group of 1 to 5 carbon atoms or a fluorinated alkyl group of 1 to 5 carbon atoms is preferable, and a hydrogen atom or a methyl group is particularly desirable in terms of industrial availability.

In formula (a1-1), the divalent hydrocarbon group for V¹ may be either an aliphatic hydrocarbon group or an aromatic hydrocarbon group.

The aliphatic hydrocarbon group as the divalent hydrocarbon group for Va¹ may be either saturated or unsaturated. In general, the aliphatic hydrocarbon group is preferably saturated.

As specific examples of the aliphatic hydrocarbon group, a linear or branched aliphatic hydrocarbon group, and an aliphatic hydrocarbon group containing a ring in the structure thereof can be given.

The linear aliphatic hydrocarbon group preferably has 1 to 10 carbon atoms, more preferably 1 to 6 carbon atoms, still more preferably 1 to 4 carbon atoms, and most preferably 1 to 3 carbon atoms. As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅—].

The branched aliphatic hydrocarbon group preferably has 2 to 10 carbon atoms, more preferably 3 to 6, still more preferably 3 or 4, and most preferably 3. As the branched aliphatic hydrocarbon group, branched alkylene groups are preferred, and specific examples include various alkylalkylene groups, including alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group within the alkylalkylene group, a linear alkyl group of 1 to 5 carbon atoms is preferable.

As examples of the hydrocarbon group containing a ring in the structure thereof, an alicyclic hydrocarbon group (a group in which two hydrogen atoms have been removed from an aliphatic hydrocarbon ring), a group in which the alicyclic hydrocarbon group is bonded to the terminal of the aforementioned chain-like aliphatic hydrocarbon group, and a group in which the alicyclic group is interposed within the aforementioned linear or branched aliphatic hydrocarbon group, can be given. The linear or branched aliphatic hydrocarbon group is the same as defined for the aforementioned linear aliphatic hydrocarbon group or the aforementioned branched aliphatic hydrocarbon group.

The alicyclic hydrocarbon group preferably has 3 to 20 carbon atoms, and more preferably 3 to 12 carbon atoms.

The alicyclic hydrocarbon group may be either a monocyclic group or a polycyclic group. As the monocyclic aliphatic hydrocarbon group, a group in which 2 hydrogen atoms have been removed from a monocycloalkane is preferable. The monocycloalkane preferably has 3 to 6 carbon atoms, and specific examples thereof include cyclopentane and cyclohexane. As the polycyclic group, a group in which two hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane.

The aromatic hydrocarbon group as the divalent hydrocarbon group for Va¹ is a hydrocarbon group having an aromatic ring.

The aromatic hydrocarbon group preferably has 3 to 30 carbon atoms, more preferably 5 to 30, still more preferably 5 to 20, still more preferably 6 to 15, and most preferably 6 to 12. Here, the number of carbon atoms within a substituent(s) is not included in the number of carbon atoms of the aromatic hydrocarbon group. Examples of the aromatic ring contained in the aromatic hydrocarbon group include aromatic hydrocarbon rings, such as benzene, biphenyl, fluorene, naphthalene, anthracene and phenanthrene; and aromatic hetero rings in which part of the carbon atoms constituting the aforementioned aromatic hydrocarbon rings has been substituted with a hetero atom. Examples of the hetero atom within the aromatic hetero rings include an oxygen atom, a sulfur atom and a nitrogen atom.

Specific examples of the aromatic hydrocarbon group include a group in which two hydrogen atoms have been removed from the aforementioned aromatic hydrocarbon ring (arylene group); and a group in which one hydrogen atom has been removed from the aforementioned aromatic hydrocarbon ring (aryl group) and one hydrogen atom has been substituted with an alkylene group (such as a benzyl group, a phenethyl group, a 1-naphthylmethyl group, a 2-naphthylmethyl group, a 1-naphthylethyl group, or a 2-naphthylethyl group). The alkylene group (alkyl chain within the arylalkyl group) preferably has 1 to 4 carbon atom, more preferably 1 or 2, and most preferably 1.

In formula (a1-1), Ra¹ represents an acid dissociable group represented by the aforementioned formula (a1-r-1) or (a1-r-2).

In the aforementioned formula (a1-2), the hydrocarbon group for Wa¹ having a valency of nₐ₂+1 may be either an aliphatic hydrocarbon group or an aromatic hydrocarbon group. The aliphatic cyclic group refers to a hydrocarbon group that has no aromaticity, and may be either saturated or unsaturated, but is preferably saturated. Examples of the aliphatic hydrocarbon group include a linear or branched aliphatic hydrocarbon group, an aliphatic hydrocarbon group containing a ring in the structure thereof, and a combination of the linear or branched aliphatic hydrocarbon group and the aliphatic hydrocarbon group containing a ring in the structure thereof. The valency of nₐ₂+1 is preferably divalent, trivalent or tetravalent, and divalent or trivalent is more preferable.

In formula (a1-2), Ra² represents an acid dissociable group represented by the aforementioned formula (a1-r-1) or (a1-r-3).

Specific examples of structural unit represented by formula (a1-1) are shown below. In the formulae shown below, R^{α} represents a hydrogen atom, a methyl group or a trifluoromethyl group.

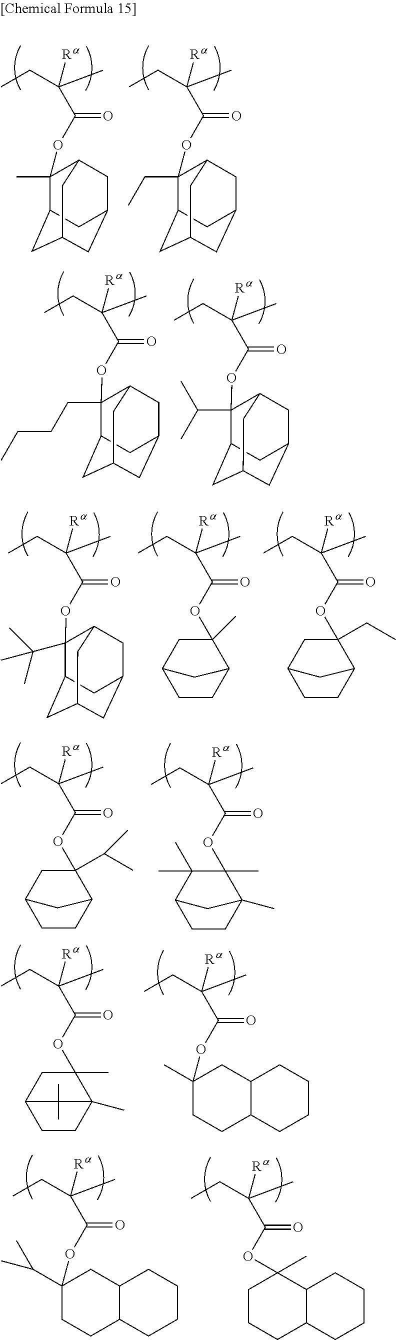

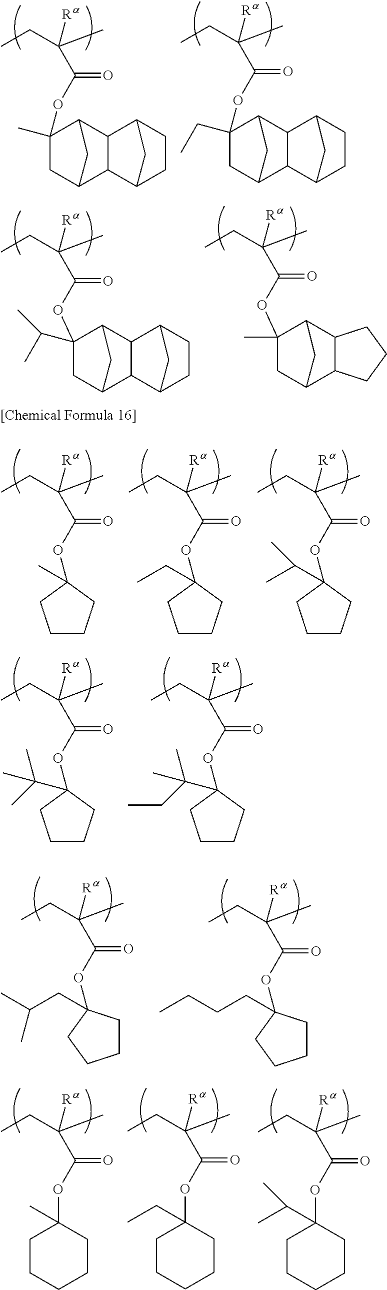

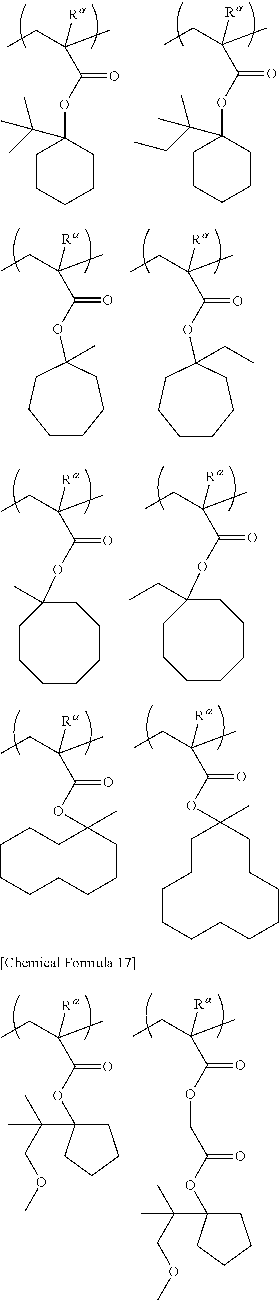

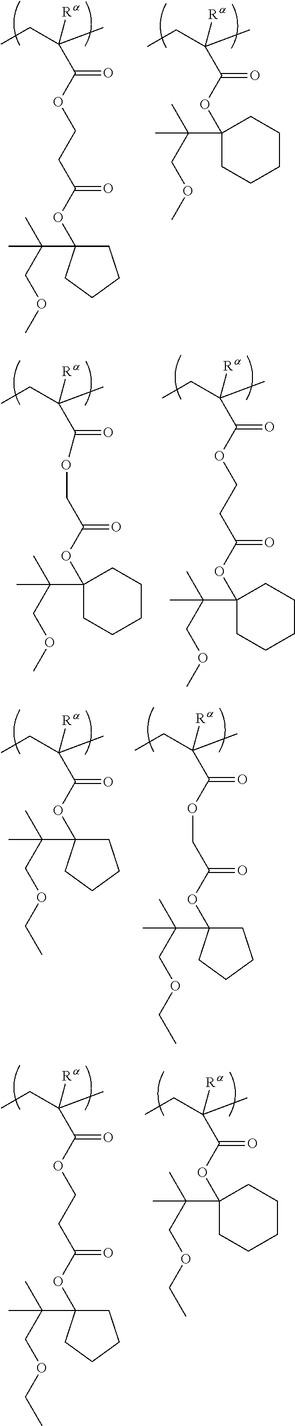

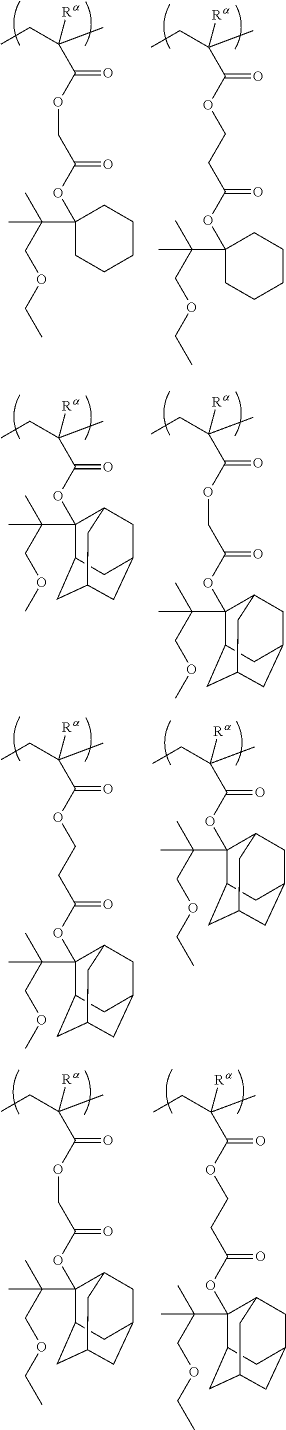

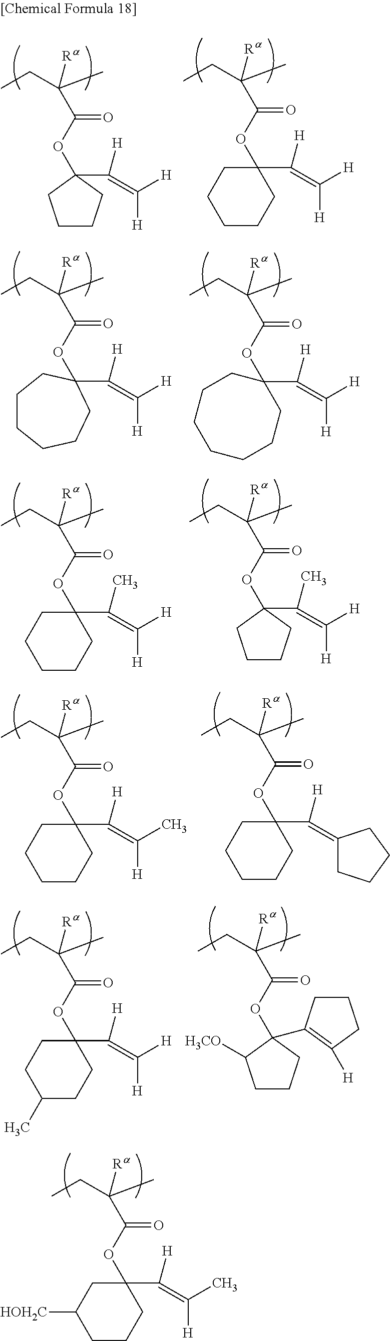

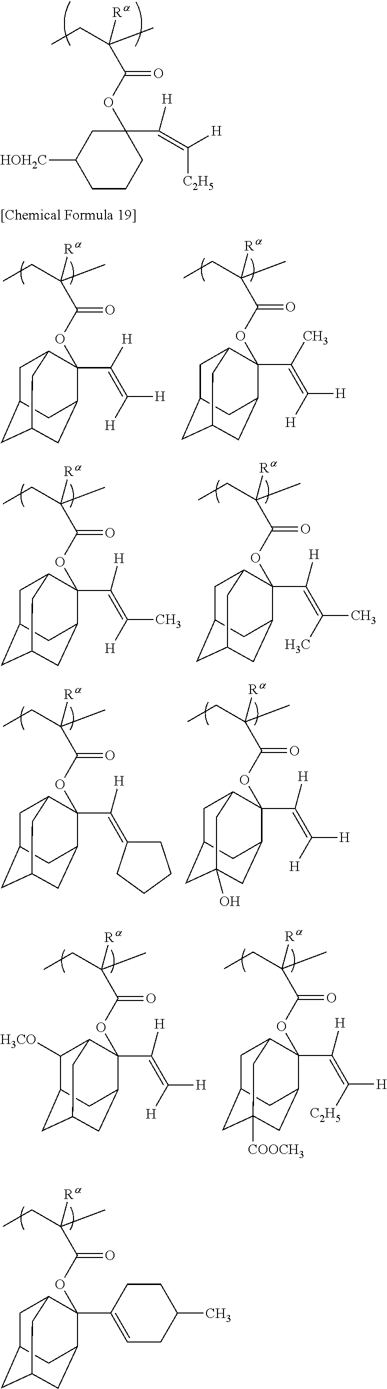

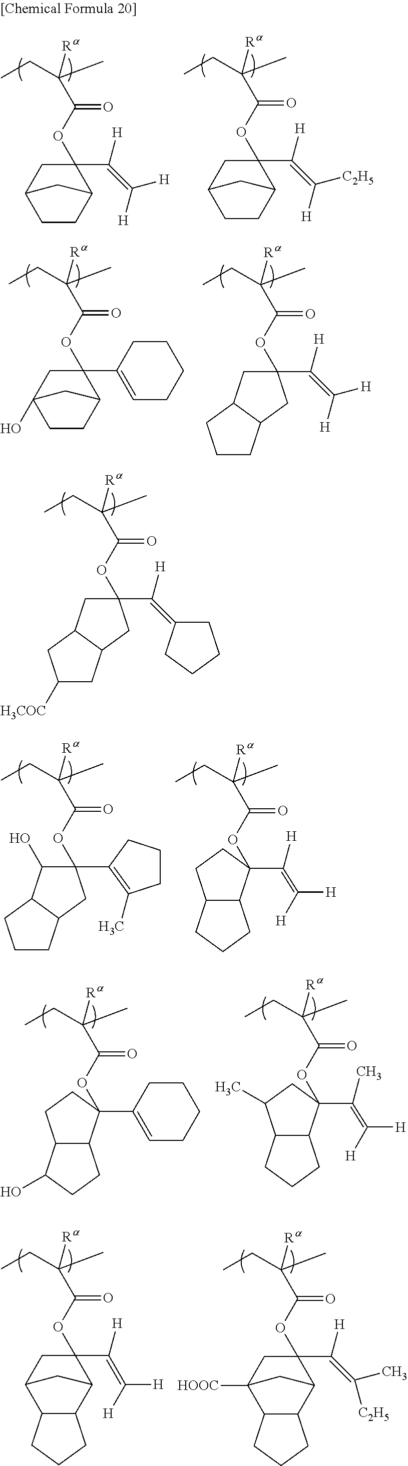

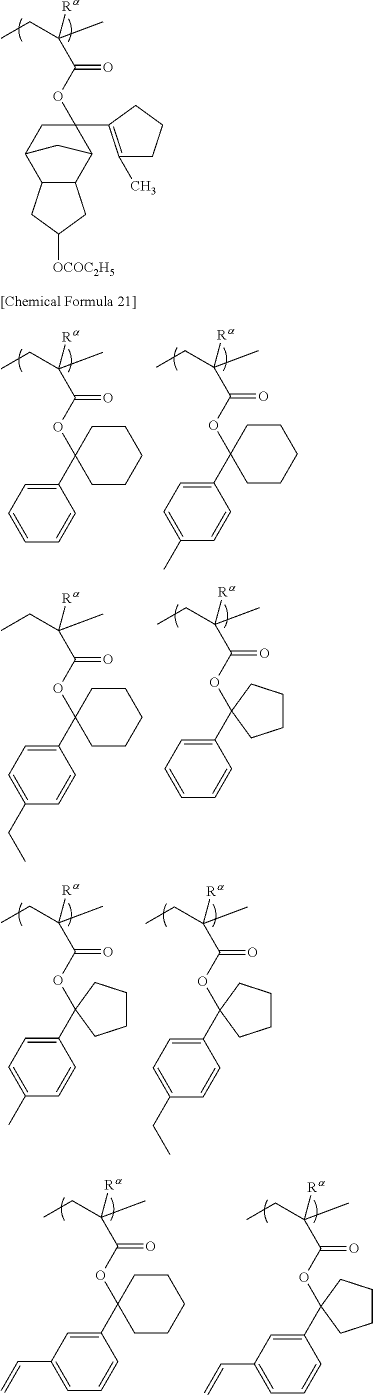

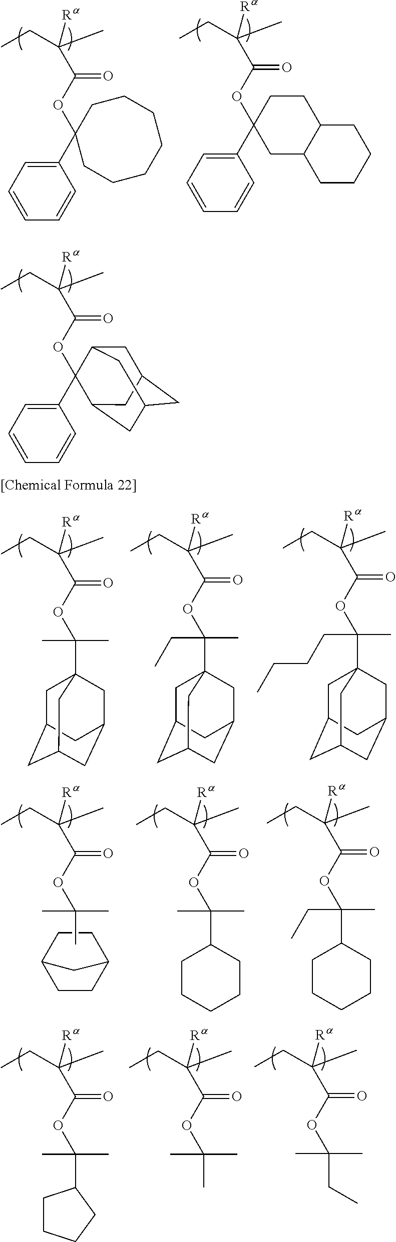

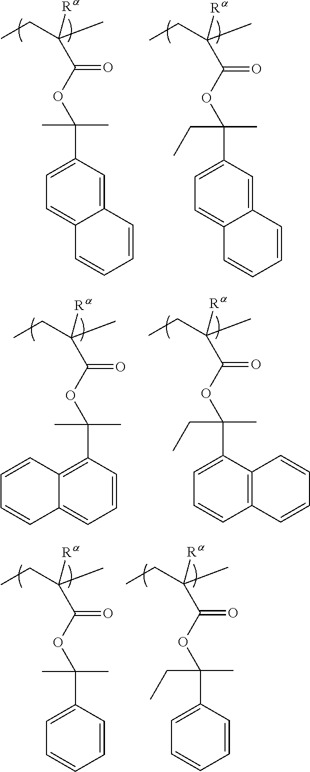

As the structural unit (a1) contained in the component (A1), 1 type of structural unit may be used, or 2 or more types may be used.

From the viewpoint that the properties of the lithography (sensitivity, shape, and the like) by electron beam and EUV are more likely to be enhanced, the structural unit (a1) is further preferably a structural unit represented by general formula (a1-1).

Among these examples, as the structural unit (a1), a structural unit represented by general formula (a1-1-1) is particularly preferable.

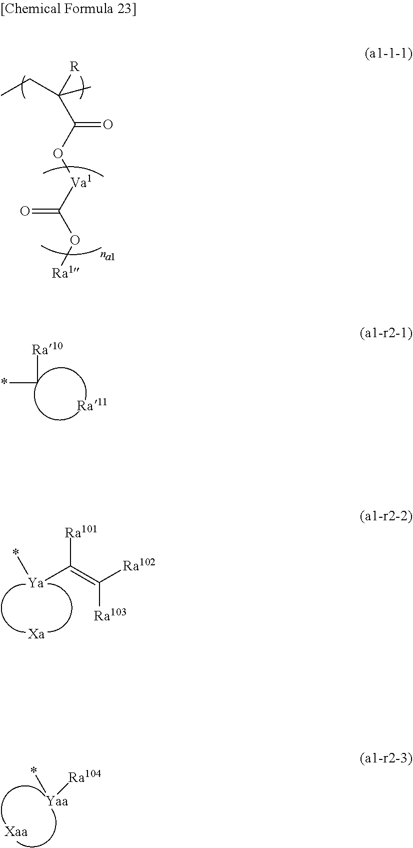

In the formula, Ra¹″ is an acid dissociable group represented by general formula (a1-r2-1), (a1-r2-2), or (a1-r2-3).

In general formula (a1-1-1), R, Va¹ and nₐ₁ are the same as defined for R, Va¹ and nₐ₁ in general formula (a1-1).

The description of the acid dissociable group represented by general formula (a1-r2-1), (a1-r2-2), or (a1-r2-3) is the same as described above.

Among the above examples, as Ra¹″, in terms of enhancing the reactivity in EB or EUV lithography, an acid dissociable group represented by general formula (a1-r2-2) or (a1-r2-3) is preferable.

In the component (A1), the amount of the structural unit (a1) based on the combined total of all structural units constituting the component (A1) is preferably 5 to 80 mol %, more preferably 10 to 75 mol %, still more preferably 30 to 70 mol %, and most preferably 40 to 60 mol %.

When the amount of the structural unit (a1) is within the above-mentioned preferable range, efficiency of the deprotection reaction and solubility in a developing solution may be reliably assured, and the effects of the present invention may be more reliably achieved.

<<Other Structural Units>>

If desired, the component (A1) may include, in addition to the structural unit (a1), any other structural unit.

Examples of other structural units include a structural unit (a10) represented by general formula (a10-1) described later; a structural unit (a8) represented by general formula (a8-1) described later; a structural unit (a2) containing a lactone-containing cyclic group, an —SO₂— containing cyclic group or a carbonate-containing cyclic group; a structural unit (a3) containing a polar group-containing aliphatic hydrocarbon group; a structural unit (a4) containing an acid non-dissociable aliphatic cyclic group; and a structural unit (st) derived from styrene or a derivative thereof.

Structural Unit (a10):

The structural unit (a10) is a structural unit represented by general formula (a10-1) shown below.

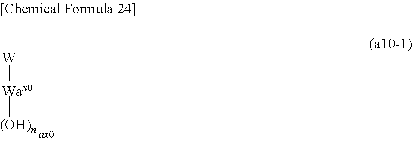

In the formula, W represents a polymerizable group-containing group; Wa^{x0} represents a (nₐₓ₀+1)-valent cyclic group having aromaticity and optionally having a substituent; Wa^{x0} may form a condensed ring together with W; and nₐₓ₀ represents an integer of 1 to 3.

In formula (a10-1), W represents a polymerizable group-containing group.

The “polymerizable group” for W refers to a group that renders a compound containing the group polymerizable by a radical polymerization or the like, for example, a group having a carbon-carbon multiple bond such as an ethylenic double bond.

Examples of the polymerizable group include a vinyl group, an allyl group, an acryloyl group, a methacryloyl group, a fluorovinyl group, a difluorovinyl group, a trifluorovinyl group, a difluorotrifluoromethylvinyl group, a trifluoroallyl group, a perfluoroallyl group, a trifluoromethylacryloyl group, a nonylfluorobutylacryloyl group, a vinyl ether group, a fluorine-containing vinyl ether group, an allyl ether group, an fluorine-containing allyl ether group, a styryl group, a vinylnaphthyl group, a fluorine-containing styryl group, a fluorine-containing vinylnaphthyl group, a norbornyl group, a fluorine-containing norbornyl group, and a silyl group.

The “polymerizable group-containing group” for W may be a group constituted of only a polymerizable group, or a group constituted of a polymerizable group and a group other than the polymerizable group. Examples of the group other than a polymerizable group include a divalent hydrocarbon group which may have a substituent, and a divalent linking group containing a hetero atom.

Divalent Hydrocarbon Group which May have a Substituent:

In the case where the group other than the polymerizable group is a divalent linking group which may have a substituent, the hydrocarbon group may be either an aliphatic hydrocarbon group or an aromatic hydrocarbon group.

Aliphatic Hydrocarbon Group for Group Other than the Polymerizable Group

The “aliphatic hydrocarbon group” refers to a hydrocarbon group that has no aromaticity. The aliphatic hydrocarbon group may be saturated or unsaturated. In general, the aliphatic hydrocarbon group is preferably saturated. Examples of the aliphatic hydrocarbon group include a linear or branched aliphatic hydrocarbon group, and an aliphatic hydrocarbon group containing a ring in the structure thereof can be given.

Linear or Branched Aliphatic Hydrocarbon Group

The linear aliphatic hydrocarbon group preferably has 1 to 10 carbon atoms, more preferably 1 to 6, still more preferably 1 to 4, and most preferably 1 to 3.

As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅—].

The branched aliphatic hydrocarbon group preferably has 2 to 10 carbon atoms, more preferably 3 to 6, still more preferably 3 or 4, and most preferably 3.

As the branched aliphatic hydrocarbon group, branched alkylene groups are preferred, and specific examples include various alkylalkylene groups, including alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group within the alkylalkylene group, a linear alkyl group of 1 to 5 carbon atoms is preferable.

The linear or branched aliphatic hydrocarbon group may or may not have a substituent. Examples of the substituent include a fluorine atom, a fluorinated alkyl group of 1 to 5 carbon atoms, and a carbonyl group.

Aliphatic Hydrocarbon Group Containing a Ring in the Structure Thereof

As examples of the hydrocarbon group containing a ring in the structure thereof, a cyclic aliphatic hydrocarbon group containing a hetero atom in the ring structure thereof and may have a substituent (a group in which two hydrogen atoms have been removed from an aliphatic hydrocarbon ring), a group in which the cyclic aliphatic hydrocarbon group is bonded to the terminal of the aforementioned chain-like aliphatic hydrocarbon group, and a group in which the cyclic aliphatic group is interposed within the aforementioned linear or branched aliphatic hydrocarbon group, can be given. As the linear or branched aliphatic hydrocarbon group, the same groups as those described above can be used.

The cyclic aliphatic hydrocarbon group preferably has 3 to 20 carbon atoms, and more preferably 3 to 12 carbon atoms.

The cyclic aliphatic hydrocarbon group may be either a polycyclic group or a monocyclic group. As the monocyclic aliphatic hydrocarbon group, a group in which 2 hydrogen atoms have been removed from a monocycloalkane is preferable. The monocycloalkane preferably has 3 to 6 carbon atoms, and specific examples thereof include cyclopentane and cyclohexane. As the polycyclic group, a group in which 2 hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane.

The cyclic aliphatic hydrocarbon group may or may not have a substituent. Examples of the substituent include an alkyl group, an alkoxy group, a halogen atom, a halogenated alkyl group, a hydroxyl group and a carbonyl group.

The alkyl group as the substituent is preferably an alkyl group of 1 to 5 carbon atoms, and a methyl group, an ethyl group, a propyl group, an n-butyl group or a tert-butyl group is particularly desirable.

The alkoxy group as the substituent is preferably an alkoxy group having 1 to 5 carbon atoms, more preferably a methoxy group, ethoxy group, n-propoxy group, iso-propoxy group, n-butoxy group or tert-butoxy group, and most preferably a methoxy group or an ethoxy group.

Examples of the halogen atom for the substituent include a fluorine atom, a chlorine atom, a bromine atom and an iodine atom, and a fluorine atom is preferable.

Examples of the halogenated alkyl group for the substituent include groups in which part or all of the hydrogen atoms within the aforementioned alkyl groups has been substituted with the aforementioned halogen atoms.

The cyclic aliphatic hydrocarbon group may have part of the carbon atoms constituting the ring structure thereof substituted with a substituent containing a hetero atom. As the substituent containing a hetero atom, —O—, —C(═O)—O—, —S—, —S(═O)₂— or —S(═O)₂—O— is preferable.

Aromatic Hydrocarbon Group for Group Other than the Polymerizable Group

The aromatic hydrocarbon group is a hydrocarbon group having at least one aromatic ring.

The aromatic ring is not particularly limited, as long as it is a cyclic conjugated compound having (4n+2)π electrons, and may be either monocyclic or polycyclic. The aromatic ring preferably has 5 to 30 carbon atoms, more preferably 5 to 20 carbon atoms, and still more preferably 6 to 15 carbon atoms, and most preferably 6 to 12 carbon atoms. Here, the number of carbon atoms within a substituent(s) is not included in the number of carbon atoms of the aromatic hydrocarbon group. Examples of the aromatic ring include aromatic hydrocarbon rings, such as benzene, naphthalene, anthracene and phenanthrene; and aromatic hetero rings in which part of the carbon atoms constituting the aforementioned aromatic hydrocarbon rings has been substituted with a hetero atom. Examples of the hetero atom within the aromatic hetero rings include an oxygen atom, a sulfur atom and a nitrogen atom. Specific examples of the aromatic hetero ring include a pyridine ring and a thiophene ring.

Specific examples of the aromatic hydrocarbon group include a group in which two hydrogen atoms have been removed from the aforementioned aromatic hydrocarbon ring or aromatic hetero ring (arylene group or heteroarylene group); a group in which two hydrogen atoms have been removed from an aromatic compound having two or more aromatic rings (biphenyl, fluorene or the like); and a group in which one hydrogen atom of the aforementioned aromatic hydrocarbon ring or aromatic hetero ring has been substituted with an alkylene group (a group in which one hydrogen atom has been removed from the aryl group within the aforementioned arylalkyl group such as a benzyl group, a phenethyl group, a 1-naphthylmethyl group, a 2-naphthylmethyl group, a 1-naphthylethyl group, or a 2-naphthylethyl group, or a heteroarylalkyl group). The alkylene group which is bonded to the aforementioned aryl group or heteroaryl group preferably has 1 to 4 carbon atoms, more preferably 1 or 2 carbon atoms, and most preferably 1 carbon atom.

With respect to the aromatic hydrocarbon group, the hydrogen atom within the aromatic hydrocarbon group may be substituted with a substituent. For example, the hydrogen atom bonded to the aromatic ring within the aromatic hydrocarbon group may be substituted with a substituent. Examples of substituents include an alkyl group, an alkoxy group, a halogen atom, a halogenated alkyl group, and a hydroxyl group.

The alkyl group as the substituent is preferably an alkyl group of 1 to 5 carbon atoms, and a methyl group, an ethyl group, a propyl group, an n-butyl group or a tert-butyl group is particularly desirable.

As the alkoxy group, the halogen atom and the halogenated alkyl group for the substituent, the same groups as the aforementioned substituent groups for substituting a hydrogen atom within the cyclic aliphatic hydrocarbon group can be used.

Divalent Linking Group Containing a Hetero Atom

In the case where the group other than the polymerizable group is a divalent linking group containing a hetero atom, preferable examples of the linking group include —O—, —C(═O)—O—, —C(═O)—, —O—C(═O)—O—, —C(═O)—NH—, —NH—, —NH—C(═NH)—(H may be substituted with an alkyl group, an acyl group, or the like), —S—, —S(═O)₂—, —S(═O)₂—O—, and a group represented by general formula —Y²¹—O—Y²²—, —Y²¹—O—, —Y²¹—C(═O)—O—, —C(═O)—O—Y²¹—, —[Y²¹—C(═O)—O]_{m″}—Y²²—, —Y²¹—O—C(═O)—Y²²— or —Y²¹—S(═O)₂—O—Y²²— (in the formulae, Y²¹ and Y²² each independently represents a divalent hydrocarbon group which may have a substituent, O represents an oxygen atom, and m″ represents an integer of 0 to 3).

In the case where the divalent linking group containing a hetero atom is —C(═O)—NH—, —C(═O)—NH—C(═O)—, —NH— or —NH—C(═NH)—, H may be substituted with a substituent such as an alkyl group, an acyl group or the like. The substituent (an alkyl group, an acyl group or the like) preferably has 1 to 10 carbon atoms, more preferably 1 to 8, and most preferably 1 to 5.

In general formulae —Y²¹—O—Y²²-, —Y²¹—O—, —Y²¹—C(═O)—O—, —C(═O)—O—Y²¹—, —[Y²¹—C(═O)—O]_{m″}—Y²²—, —Y²¹—O—C(═O)—Y²²— or —Y²¹—S(═O)₂—O—Y²²—, Y²¹ and Y²² each independently represents a divalent hydrocarbon group which may have a substituent. Examples of the divalent hydrocarbon group include the same groups as those described above as the “divalent hydrocarbon group which may have a substituent” in the explanation of the aforementioned divalent linking group.

As Y²¹, a linear aliphatic hydrocarbon group is preferable, more preferably a linear alkylene group, still more preferably a linear alkylene group of 1 to 5 carbon atoms, and a methylene group or an ethylene group is particularly desirable.

As Y²², a linear or branched aliphatic hydrocarbon group is preferable, and a methylene group, an ethylene group or an alkylmethylene group is more preferable. The alkyl group within the alkylmethylene group is preferably a linear alkyl group of 1 to 5 carbon atoms, more preferably a linear alkyl group of 1 to 3 carbon atoms, and most preferably a methyl group.

In the group represented by the formula —[Y²¹—C(═O)—O]ₘ″—Y²²—, m″ represents an integer of 0 to 3, preferably an integer of 0 to 2, more preferably 0 or 1, and most preferably 1. Namely, it is particularly desirable that the group represented by the formula —[Y²¹—C(═O)—O]ₘ″—Y²²— is a group represented by the formula —Y²¹—C(═O)—O—Y²²—. Among these, a group represented by the formula —(CH₂)_{a′}—C(═O)—O—(CH₂)_{b′}— is preferable. In the formula, a′ is an integer of 1 to 10, preferably an integer of 1 to 8, more preferably an integer of 1 to 5, still more preferably 1 or 2, and most preferably 1. b′ is an integer of 1 to 10, preferably an integer of 1 to 8, more preferably an integer of 1 to 5, still more preferably 1 or 2, and most preferably 1.

Preferable examples of W include a group represented by a chemical formula C(R^{X11})(R^{X12})═C(R^{X13})—Ya^{x0}-.

In the chemical formula, R^{X11}, R^{X12} and R^{X13} independently represents a hydrogen atom, an alkyl group having 1 to 5 carbon atoms or a halogenated alkyl group having 1 to carbon atoms, and Ya^{x0} represents a single bond or a divalent linking group.

As the alkyl group of 1 to 5 carbon atoms for R^{X11}, R^{X12} and R^{X13}, a linear or branched alkyl group of 1 to 5 carbon atoms is preferable, and specific examples thereof include a methyl group, an ethyl group, a propyl group, an isopropyl group, an n-butyl group, an isobutyl group, a tert-butyl group, a pentyl group, an isopentyl group and a neopentyl group. The halogenated alkyl group of 1 to 5 carbon atoms represented by R is a group in which part or all of the hydrogen atoms of the aforementioned alkyl group of 1 to 5 carbon atoms have been substituted with halogen atoms. As the halogen atom, a fluorine atom is most preferable.

Among these examples, as R^{X11} and R^{X12} a hydrogen atom, an alkyl group of 1 to carbon atoms or a fluorinated alkyl group of 1 to 5 carbon atoms is preferable, and in terms of industrial availability, a hydrogen atom or a methyl group is more preferable, and a hydrogen atom is still more preferable.

As R^{X13}, a hydrogen atom, an alkyl group of 1 to 5 carbon atoms or a fluorinated alkyl group of 1 to 5 carbon atoms is preferable, and in terms of industrial availability, a hydrogen atom or a methyl group is more preferable.

The divalent linking group for Ya^{x0} is not particularly limited, and preferable examples thereof include a divalent hydrocarbon group which may have a substituent and a divalent linking group containing a hetero atom, and are the same as defined above.

Among these examples, as Ya^{x0}, an ester bond [—C(═O)—O—, —O—C(═O)—], an ether bond (—O—), a linear or branched alkylene group, an aromatic hydrocarbon group, or a combination thereof, or a single bond is preferable. Among the above examples, as Ya^{x0}, an ester bond [—C(═O)—O—, —O—C(═O)—] or a single bond is preferable.

In formula (a10-1), Wa^{x0} represents a (nₐₓ₀+1)-valent cyclic group having aromaticity and optionally having a substituent.

Regarding Wa^{x0}, examples of the cyclic group having aromaticity include a group in which (nₐₓ₀+1) hydrogen atoms have been removed from an aromatic ring. The aromatic ring is not particularly limited, as long as it is a cyclic conjugated compound having (4n+2)π electrons, and may be either monocyclic or polycyclic. The aromatic ring preferably has 5 to 30 carbon atoms, more preferably 5 to 20 carbon atoms, and still more preferably 6 to 15 carbon atoms, and most preferably 6 to 12 carbon atoms. Examples of the aromatic ring include aromatic hydrocarbon rings, such as benzene, naphthalene, anthracene and phenanthrene; and aromatic hetero rings in which part of the carbon atoms constituting the aforementioned aromatic hydrocarbon rings has been substituted with a hetero atom. Examples of the hetero atom within the aromatic hetero rings include an oxygen atom, a sulfur atom and a nitrogen atom. Specific examples of the aromatic hetero ring include a pyridine ring and a thiophene ring.

Examples of the aromatic hydrocarbon group for Wa^{x0} include a group obtained by removing (nₐₓ₀+1) hydrogen atoms from an aromatic compound having two or more aromatic rings which may have a substituent (e.g., biphenyl or fluorene).

The aromatic hydrocarbon group for Wa^{x0} may be a group in which 1 hydrogen atom has been removed from an aromatic hydrocarbon ring or an aromatic hetero ring and has nₐₓ₀ or less hydrogen atom(s) substituted with an alkylene group or a halogenated alkylene group.

Examples of the substituent for Wa^{x0} a carboxy group, a halogen atom (such as a fluorine atom, a chlorine atom or a chlorine atom), an alkoxy group (such as a methoxy group, an ethoxy group, a propoxy group or a butoxy group), and an alkyloxycarbonyl group.

In formula (a10-1), Wa^{x0} may form a condensed ring together with W.

In the case where W and Wa^{x0} form a condensed ring, examples of the ring structure include a condensed ring of an alicyclic hydrocarbon group and an aromatic hydrocarbon group. The condensed ring formed by Wa^{x0} and W may contain a hetero atom.

In the condensed ring formed by W and Wa^{x0}, the alicyclic hydrocarbon portion may be monocyclic or polycyclic.

Examples of the condensed ring formed by W and Wa^{x0} include a condensed ring formed by the polymerizable group of the W portion and Wa^{x0}, and a condensed ring formed by the group other than the polymerizable group of the W portion and Wa^{x0}.

The condensed ring formed by W and Wa^{x0} may have a substituent.

Examples of the substituent include a methyl group, an ethyl group, a propyl group, a hydroxy group, a hydroxyalkyl group, a carboxy group, a halogen atom (such as a fluorine atom, a chlorine atom or bromine atom), an alkoxy group (such as a methoxy group, an ethoxy group, a propoxy group or a butoxy group), an acyl group, an alkyloxycarbonyl group, and an alkylcarbonyloxy group.

Specific examples of the condensed ring formed by W and Wa^{x0} are shown below. W^{α} represents a polymerizable group. ** represents a bonding site with a hydroxy group.

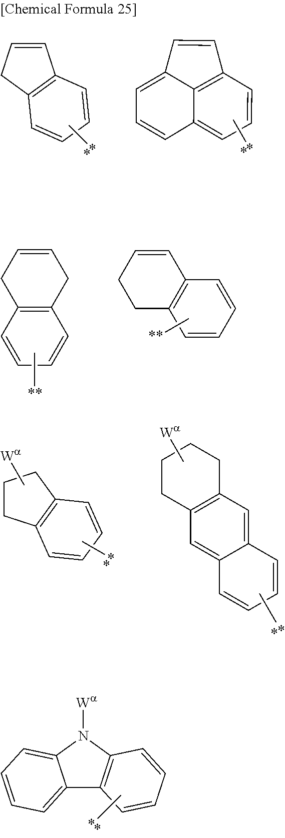

In formula (a10-1), nₐₓ₀ is an integer of 1 to 3, preferably 1 or 2, and more preferably 1.

Preferable examples of the structural unit (a10) include a structural unit represented by general formula (a10-1-1) shown below.

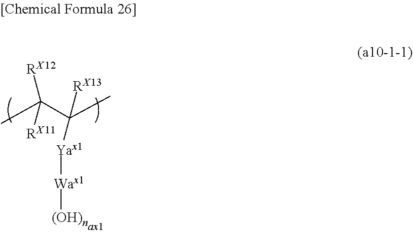

In the formula, R^{X11}, R^{X12} and R^{X13} each independently represents a hydrogen atom, an alkyl group of 1 to 5 carbon atoms or a halogenated alkyl group of 1 to 5 carbon atoms; Ya^{x1} represents a single bond or a divalent linking group; Wa^{x1} represents a (nₐₓ₁+1)-valent cyclic group having aromaticity and optionally having a substituent; provided that Ya^{x1} and Wa^{x1} may form a condensed ring, or R^{X11}, Ya^{x1} and Wa^{x1} may form a condensed ring; and nₐₓ₁ represents an integer of 1 to 3.

In formula (a10-1-1), R^{X11}, R^{X12} and R^{X13} each independently represents a hydrogen atom, an alkyl group of 1 to 5 carbon atoms or a halogenated alkyl group of 1 to 5 carbon atoms. The alkyl group of 1 to 5 carbon atoms for R^{X11}, R^{X12} and R^{X13} is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group.

The halogenated alkyl group of 1 to 5 carbon atoms represented by R^{X11}, R^{X12} or R^{X13} is a group in which part or all of the hydrogen atoms of the aforementioned alkyl group of 1 to 5 carbon atoms have been substituted with halogen atom(s). As the halogen atom, a fluorine atom is most preferable.

As R^{X11} and R^{X12}, a hydrogen atom, an alkyl group of 1 to 5 carbon atoms or a fluorinated alkyl group of 1 to 5 carbon atoms is preferable, and in terms of industrial availability, a hydrogen atom or a methyl group is more preferable, and a hydrogen atom is still more preferable.

As R^{X13}, a hydrogen atom, an alkyl group of 1 to 5 carbon atoms or a fluorinated alkyl group of 1 to 5 carbon atoms is preferable, and in terms of industrial availability, a hydrogen atom or a methyl group is more preferable.

In formula (a10-1-1), Ya^{x1} represents a single bond or a divalent linking group.

Preferable examples of the divalent linking group for Ya^{x1} include a divalent hydrocarbon group which may have a substituent, and a divalent linking group containing a hetero atom.

As the divalent linking group which may have a substituent or the divalent linking group containing a hetero atom for Ya^{x1} the same divalent linking groups (divalent linking group which may have a substituent or divalent linking group containing a hetero atom) described above for W in formula (a10-1) may be mentioned. Among the above examples, as Ya^{x1}, a single bond, an ester bond [—C(═O)—O—, —O—C(═O)—], an ether bond (—O—), —C(═O)—NH—, a linear or branched alkylene group, or a combination of any of the above groups is preferable, a single bond, an ester bond [—C(═O)—O—, —O—C(═O)—], a linear or branched alkylene group, or a combination of these groups is more preferable, and a single bond or an ester bond [—C(═O)—O—, —O—C(═O)—] is still more preferable.

In formula (a10-1-1), Wa^{x1} represents a (nₐₓ₁+1)-valent cyclic group having aromaticity and optionally having a substituent. The cyclic group having aromaticity for Wa^{x1} is the same as defined for Wa^{x0} in the aforementioned formula (a10-1).

In formula (a10-1-1), Ya^{x1} and Wa^{x1} may form a condensed ring, or R^{X11}, Ya^{x1} and Wa^{x1} may form a condensed ring.

The condensed ring is the same as described above for the condensed ring formed by W and Wa^{x0} (the condensed ring formed by the polymerizable group of the W portion and Wa^{x0}, and the condensed ring formed by the group other than the polymerizable group of the W portion and Wa^{x0}).

Specific examples of the case where R^{X11}, Ya^{x1} and Wa^{x1} together form a condensed ring in the aforementioned formula (a10-1-1) are shown below. ** represents a bonding site with a hydroxy group.

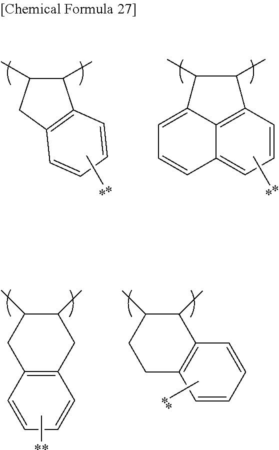

Specific examples of the case where Ya^{x1} and Wa^{x1} together form a condensed ring in the aforementioned formula (a10-1-1) are shown below. * indicates a bonding site where a carbon atom which constitutes the main chain and is bonded to R^{X13} is bonded. ** represents a bonding site with a hydroxy group.

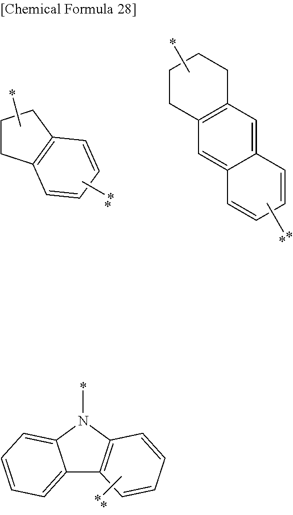

In formula (a10-1-1), nₐₓ₁ is an integer of 1 to 3, preferably 1 or 2, and more preferably 1.

Specific examples of the structural unit (a10) are shown below.

In the following formulae, R^{α} represents a hydrogen atom, a methyl group or a trifluoromethyl group.

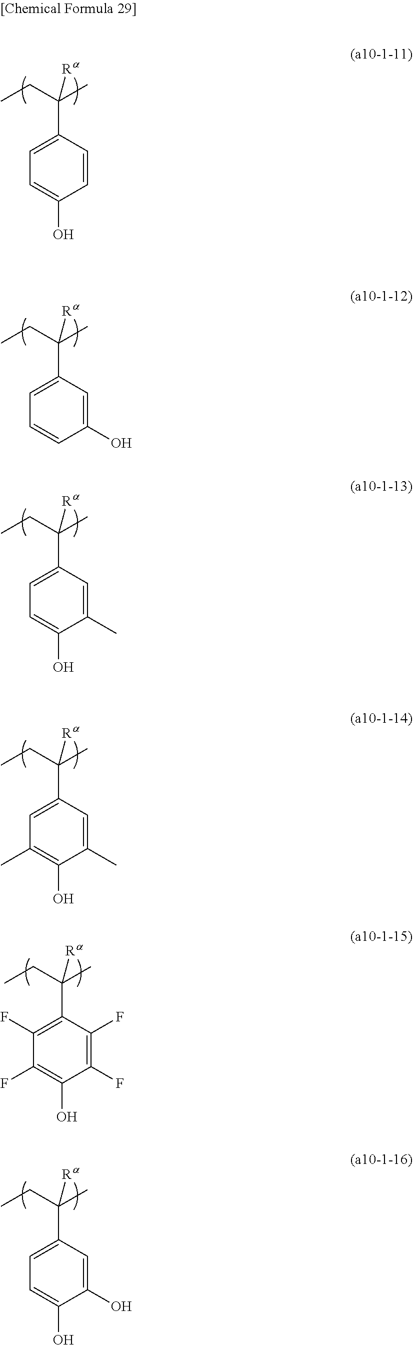

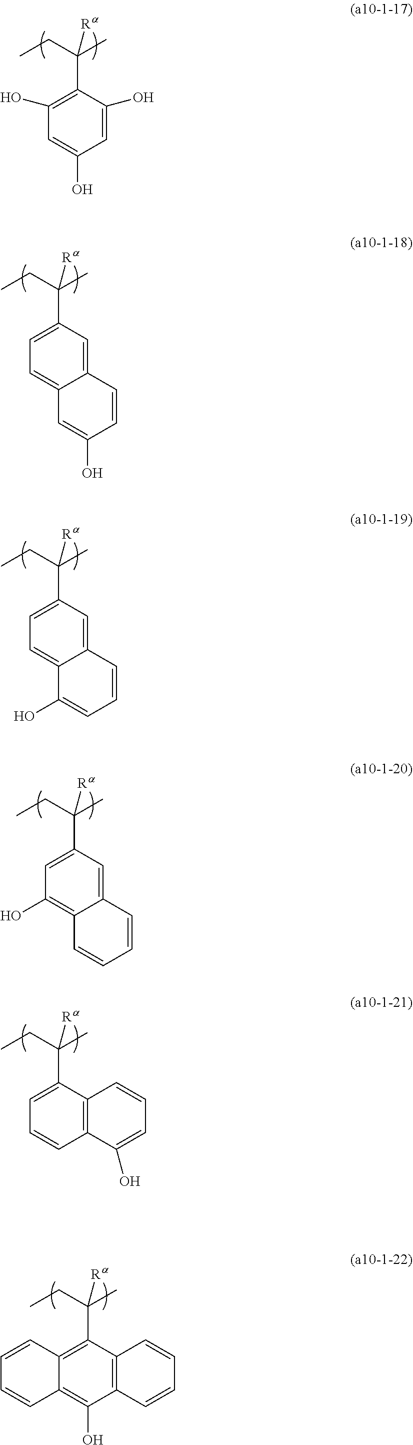

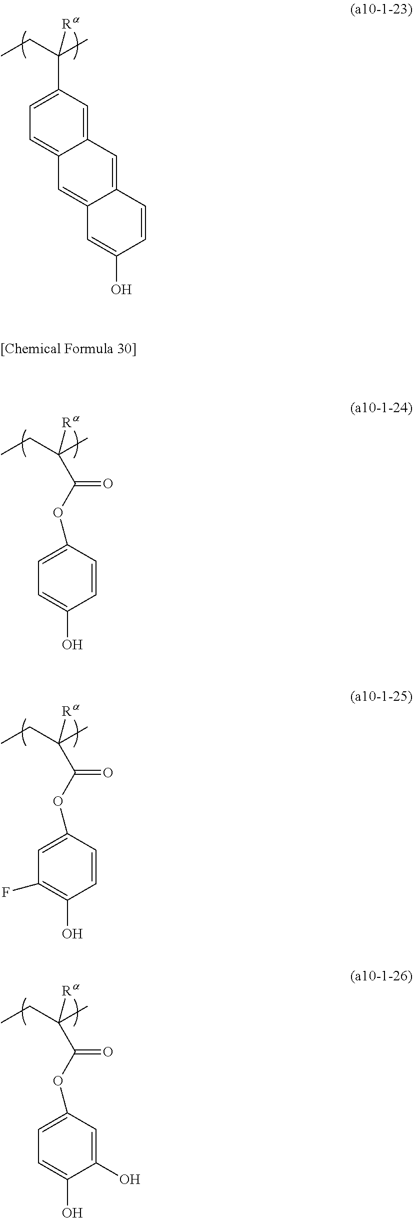

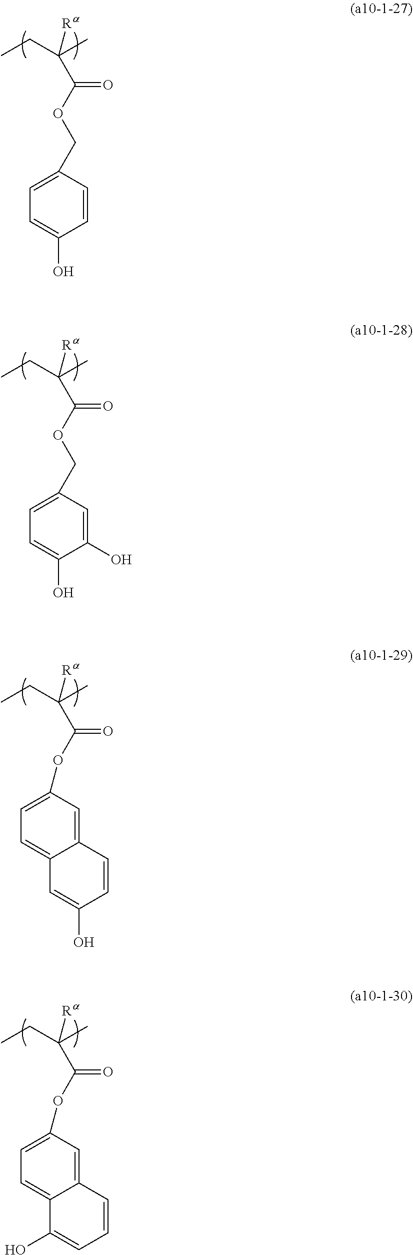

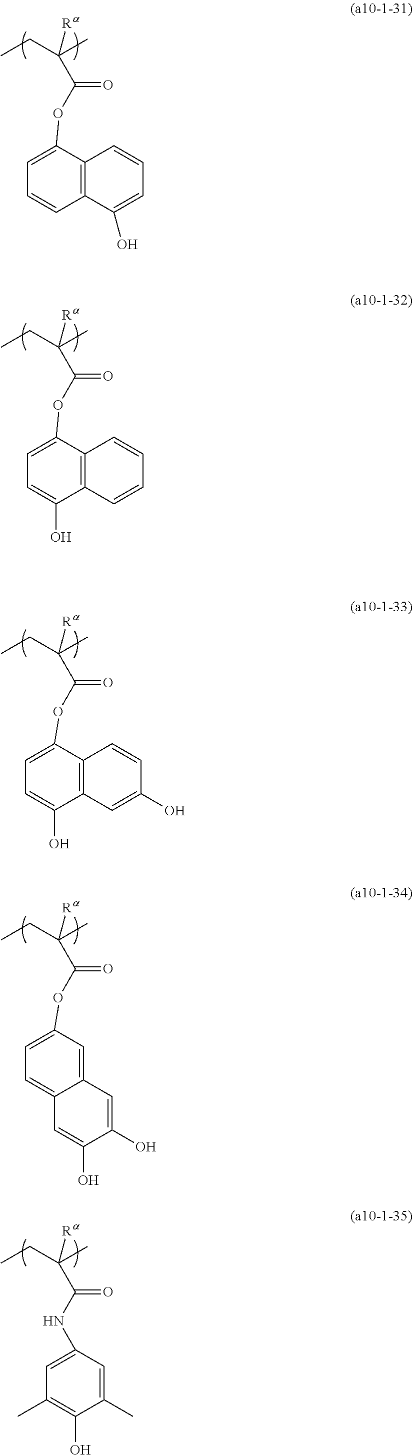

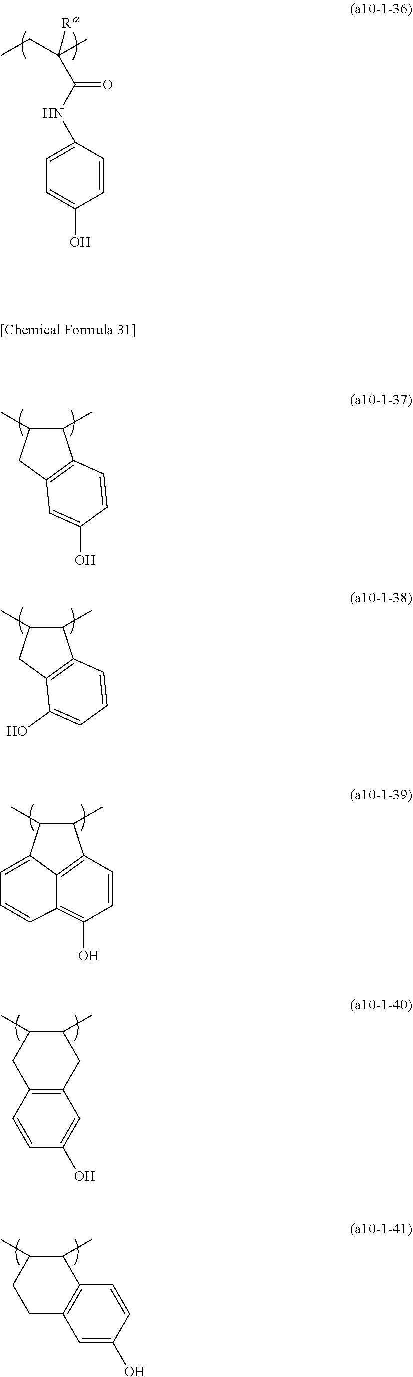

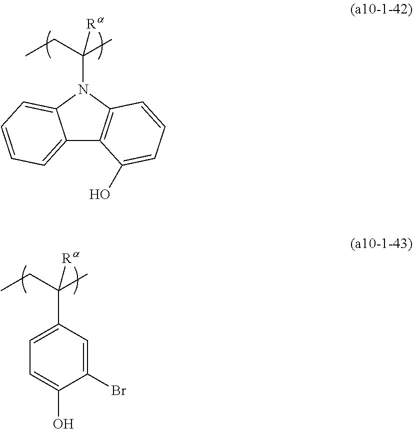

Among the above examples, as the structural unit (a10), at least one member selected from the group consisting of structural units represented by chemical formulae (a10-1-11), (a10-1-18) and (a10-1-24) shown below is preferable, and at least one member selected from the group consisting of structural units represented by chemical formulae (a10-1-11) and (a10-1-24) shown below is more preferable.

As the structural unit (a10) contained in the component (A1), 1 kind of structural unit may be used, or 2 or more kinds of structural units may be used.

When the component (A1) includes the structural unit (a10), the amount of the structural unit (a10) based on the combined total of all structural units constituting the component (A1) (100 mol %) is preferably 5 to 80 mol %, more preferably 10 to 75 mol %, still more preferably 20 to 70 mol %, and still more preferably 25 to 60 mol %.

When the amount of the structural unit (a10) is within the above-mentioned preferable range, the efficiency of supplying proton within the resist film may be improved, solubility in a developing solution may be reliably assured, and the effects of the present invention may be more reliably achieved.

Structural Unit (a8):

The structural unit (a8) is a structural unit derived from a compound represented by general formula (a8-1) shown below. Specifically, the structural unit (a8) is a structural unit in which a compound represented by general formula (a8-1) has a polymerizable group within the W² portion converted into a main chain.

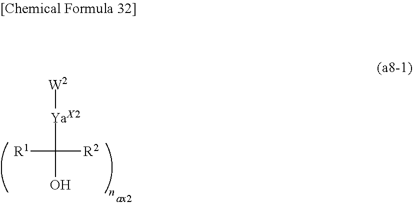

In the formula, W² represents a polymerizable group-containing group; Ya^{x2} represents a single bond or a (nₐₓ₂+1)-valent linking group; Ya^{x2} may form a condensed ring together with W²; R¹ represents a fluorinated alkylene group having 1 to 12 carbon atoms; R² represents a hydrogen atom or an organic group having 1 to 12 carbon atoms optionally containing a fluorine atom; and nₐₓ₂ represents an integer of 1 to 3.

In formula (a8-1), the polymerizable group-containing group for W² is the same as defined for the polymerizable group-containing group for W in the aforementioned formula (a10-1).

In formula (a8-1), Ya^{x2} represents a single bond or a (nₐₓ₂+1)-valent linking group, i.e., a divalent linking group, a trivalent linking group or a tetravalent linking group.

The divalent linking group for Ya^{x2} is the same as defined for the divalent linking group for Ya^{x0} within W in the aforementioned general formula (a10-1). As the trivalent linking group for Ya^{x2}, a group in which one hydrogen atom has been removed from the aforementioned divalent linking group and a group in which the divalent linking group has been bonded to another divalent linking group may be mentioned. As the tetravalent linking group, a group in which two hydrogen atom has been removed from the aforementioned divalent linking group may be mentioned.

Ya^{x2} may form a condensed ring together with W².

In the case where Ya^{x2} [symbol] and W² form a condensed ring, examples of the ring structure include a condensed ring of an alicyclic hydrocarbon group and an aromatic hydrocarbon group. The condensed ring formed by Ya^{x2} and W² may contain a hetero atom.

In the condensed ring formed by Ya^{x2} and W², the alicyclic hydrocarbon portion may be monocyclic or polycyclic.

Examples of the condensed ring formed by Ya^{x2} and W² include a condensed ring formed by the polymerizable group of the W² and Ya^{x2}, and a condensed ring formed by the group other than the polymerizable group of the W² portion and Ya^{x2}. Specific examples of the condensed ring include a bicyclic condensed ring of a cycloalkene and an aromatic ring, a tricyclic condensed ring of a cycloalkene and 2 aromatic rings, a bicyclic condensed ring of a cycloalkane having a polymerizable group as a substituent and an aromatic ring, and a tricyclic condensed ring of a cycloalkane having a polymerizable group as a substituent and 2 aromatic rings.

The condensed ring formed by Ya^{x2} and W² may have a substituent. Examples of the substituent include a methyl group, an ethyl group, a propyl group, a hydroxy group, a hydroxyalkyl group, a carboxy group, a halogen atom (such as a fluorine atom, a chlorine atom or bromine atom), an alkoxy group (such as a methoxy group, an ethoxy group, a propoxy group or a butoxy group), an acyl group, an alkyloxycarbonyl group, and an alkylcarbonyloxy group.

Specific examples of the condensed ring formed by Ya^{x2} and W² are shown below. W^{α} represents a polymerizable group.

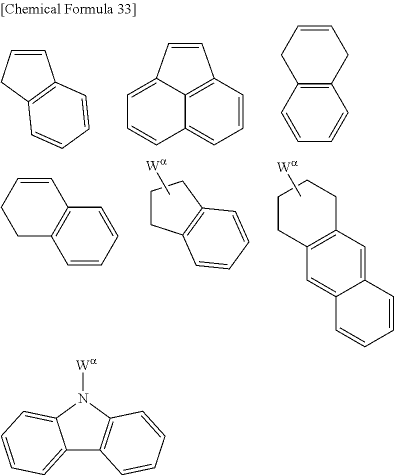

In formula (a8-1), R¹ represents a fluorinated alkyl group of 1 to 12 carbon atoms.

The fluorinated alkyl group of 1 to 12 carbon atoms is a group in which part or all of the hydrogen atoms of the aforementioned alkyl group of 1 to 12 carbon atoms have been substituted with fluorine atom(s). The alkyl group may be linear or branched.

Specific examples of the fluorinated alkyl group of 1 to 12 carbon atoms include a group in which part or all of the hydrogen atoms of a methyl group, an ethyl group, a propyl group, a butyl group, a pentyl group, a hexyl group, a heptyl group, an octyl group, a nonyl group, a decyl group, an undecyl group or a dodecyl group have been substituted with fluorine atom(s). Specific examples of the branched fluorinated alkyl group of 1 to 12 carbon atoms include a group in which part or all of the hydrogen atoms of a 1-methylethyl group, a 1,1-dimethylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group or a 4-methylpentyl group have been substituted with fluorine atom(s).

Among the above examples, as the fluorinated alkyl group of 1 to 12 carbon atoms for R¹, a fluorinated alkyl group of 1 to 5 carbon atoms is preferable, and a trifluoromethyl group is more preferable.

In formula (a8-1), R² represents a hydrogen atom or an organic group having 1 to 12 carbon atoms optionally containing a fluorine atom.

Examples of the organic group having 1 to 12 carbon atoms optionally containing a fluorine atom include R² a monovalent hydrocarbon group having 1 to 12 carbon atoms optionally containing a fluorine atom.

Examples of the hydrocarbon group include a linear or branched alkyl group, and a cyclic hydrocarbon group.

Specific examples of the linear alkyl group include a methyl group, an ethyl group, a propyl group, a butyl group, a pentyl group, a hexyl group, a heptyl group, an octyl group, a nonyl group, a decyl group, an undecyl group and a dodecyl group.

Specific examples of the branched alkyl group include a 1-methylethyl group, a 1,1-dimethylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

In the case where R² represents a cyclic hydrocarbon group, the cyclic hydrocarbon group may be an aliphatic hydrocarbon group or an aromatic hydrocarbon group, and may be polycyclic or monocyclic.

As the monocyclic aliphatic hydrocarbon group, a group in which 1 hydrogen atom has been removed from a monocycloalkane is preferable. The monocycloalkane preferably has 3 to 6 carbon atoms, and specific examples thereof include cyclopentane and cyclohexane.

As the polycyclic aliphatic hydrocarbon group, a group in which 1 hydrogen atom has been removed from a polycycloalkane is preferable, and the polycyclic group preferably has 7 to 12 carbon atoms. Examples of the polycycloalkane include adamantane, norbornane, isobornane, tricyclodecane and tetracyclododecane.

In the case where the cyclic hydrocarbon group for R² is an aromatic hydrocarbon group, the aromatic hydrocarbon group is a hydrocarbon group having at least one aromatic ring. Examples of the aromatic hydrocarbon group include a group in which one hydrogen atom has been removed from an aromatic hydrocarbon ring such as benzene, naphthalene, anthracene, phenanthrene, biphenyl or fluorene.

The organic group of 1 to 12 carbon atoms for R² may have a substituent other than a fluorine atom. Examples of the substituent include a hydroxy group, a carboxy group, a halogen atom (such as a chlorine atom or a chlorine atom), an alkoxy group (such as a methoxy group, an ethoxy group, a propoxy group or a butoxy group), and an alkyloxycarbonyl group.

R² is preferably a fluorinated alkyl group of 1 to 12 carbon atoms, more preferably a fluorinated alkyl group of 1 to 5 carbon atoms, and still more preferably a trifluoromethyl group.

In formula (a8-1), nₐₓ₂ is an integer of 1 to 3, preferably 1 or 2, and more preferably 1.

The structural unit (a8) is preferably a structural unit (a81) in which a compound represented by general formula (a8-1-1) has a polymerizable group within the W² portion converted into a main chain.

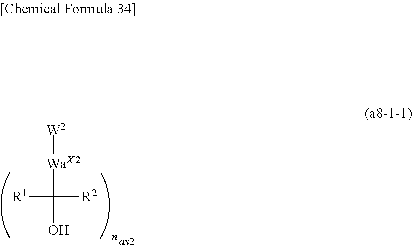

In formula (a8-1-1), W² represents a polymerizable group-containing group; Wa^{x2} represents a (nₐₓ₂+1)-valent cyclic group; W² may form a condensed ring together with Wa^{x2}; R¹ represents a fluorinated alkylene group having 1 to 12 carbon atoms; R² represents a hydrogen atom or an organic group having 1 to 12 carbon atoms optionally containing a fluorine atom; and nₐₓ₂ represents an integer of 1 to 3.

In formula (a8-1-1), W², R¹, R² and nₐₓ₂ are the same as defined for W², R¹, R² and nₐₓ₂ in the aforementioned general formula (a8-1), respectively.

In formula (a8-1-1), Wa^{x2} represents a (nₐₓ₂+1)-valent cyclic group.

Examples of the cyclic group for Wa^{x2} include an aliphatic cyclic group and an aromatic cyclic group, and may be monocyclic or polycyclic.

As the monocyclic aliphatic hydrocarbon group, a group in which one hydrogen atoms have been removed from a monocycloalkane is preferable. The monocycloalkane preferably has 3 to 6 carbon atoms, and specific examples thereof include cyclopentane and cyclohexane.

As the polycyclic aliphatic cyclic group, a group in which one hydrogen atoms have been removed from a polycycloalkane is preferable, and the polycyclic group preferably has 7 to 12 carbon atoms. Specific examples include a group in which 1 or more hydrogen atoms have been removed from a polycycloalkane such as decalin, perhydroazulene, or perhydroanthracene.

The aromatic cyclic group is a hydrocarbon group having at least one aromatic ring. The aromatic ring is not particularly limited, as long as it is a cyclic conjugated compound having (4n+2)π electrons The aromatic ring preferably has 5 to 30 carbon atoms, more preferably 5 to 20, still more preferably 6 to 15, and most preferably 6 to 12. Examples of the aromatic ring include aromatic hydrocarbon rings, such as benzene, naphthalene, anthracene and phenanthrene; and aromatic hetero rings in which part of the carbon atoms constituting the aforementioned aromatic hydrocarbon rings has been substituted with a hetero atom. Examples of the hetero atom within the aromatic hetero rings include an oxygen atom, a sulfur atom and a nitrogen atom. Specific examples of the aromatic hetero ring include a pyridine ring and a thiophene ring. Specific examples of the aromatic hydrocarbon group include a group in which one hydrogen atom has been removed from the aforementioned aromatic hydrocarbon ring or aromatic hetero ring (aryl group or heteroaryl group); a group in which one hydrogen atom has been removed from an aromatic compound having two or more aromatic rings (biphenyl, fluorene or the like); and a group in which one hydrogen atom of the aforementioned aromatic hydrocarbon ring or aromatic hetero ring has been substituted with an alkylene group (an arylalkyl group such as a benzyl group, a phenethyl group, a 1-naphthylmethyl group, a 2-naphthylmethyl group, a 1-naphthylethyl group, or a 2-naphthylethyl group). The alkylene group bonded to the aforementioned aromatic hydrocarbon ring or the aromatic hetero ring preferably has 1 to 4 carbon atoms, more preferably 1 or 2 carbon atoms, and most preferably 1 carbon atom.

Examples of the substituent for the cyclic group represented by Wa^{x2} include a carboxy group, a halogen atom (such as a fluorine atom, a chlorine atom or a chlorine atom), an alkoxy group (such as a methoxy group, an ethoxy group, a propoxy group or a butoxy group), and an alkyloxycarbonyl group.

W² may form a condensed ring together with Wa^{x2}, and is the same as defined for the condensed ring formed by Ya^{x2} and W² in the aforementioned formula (a8-1).

Specific examples of the structural unit (a8) are shown below.

In the following formulae, R^{α} represents a hydrogen atom, a methyl group or a trifluoromethyl group.

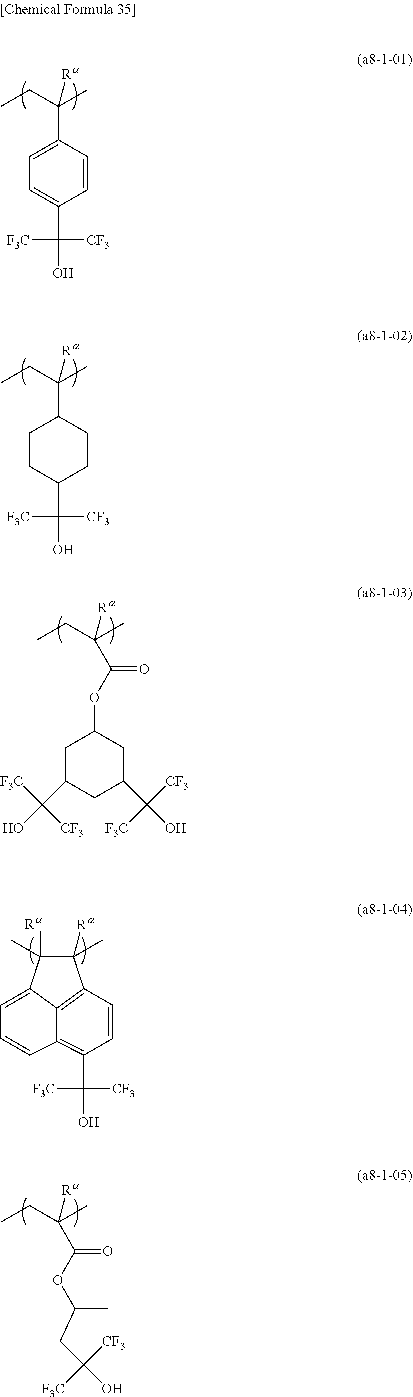

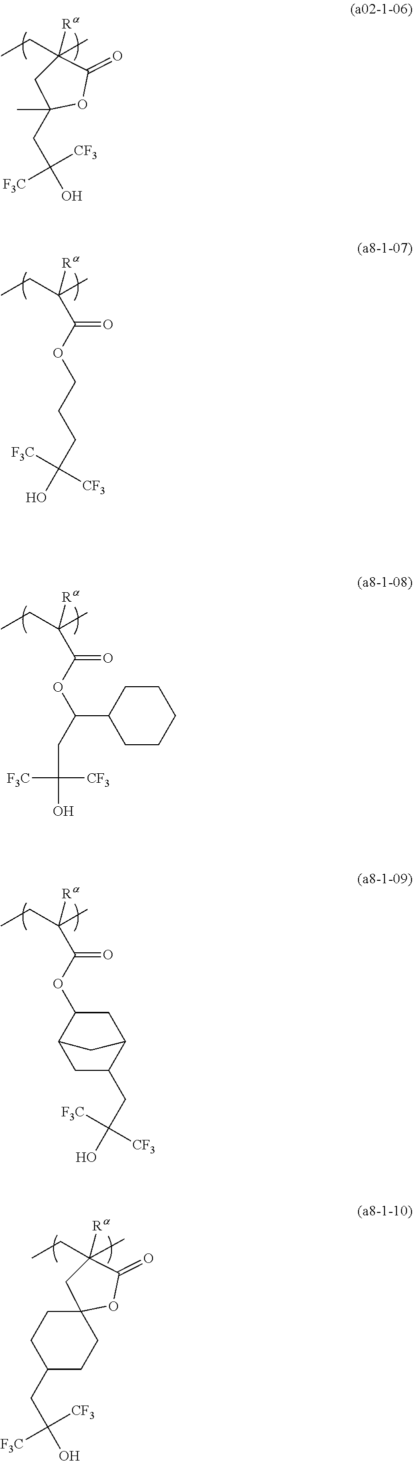

Among the above examples, as the structural unit (a8), at least one member selected from the group consisting of structural units represented by chemical formulae (a8-1-01) to (a8-1-04), (a8-1-06), (a8-1-08), (a8-1-09) and (a8-1-10) is preferable, and at least one member selected from the group consisting of structural units represented by chemical formulae (a8-1-01) to (a8-1-04) and (a8-1-09) is more preferable.

As the structural unit (a8) contained in the component (A1), 1 kind of structural unit may be used, or 2 or more kinds may be used.

When the component (A1) includes the structural unit (a8), the amount of the structural unit (a8) based on the combined total (100 mol %) of all structural units constituting the component (A1) is preferably 1 to 50 mol %, more preferably 5 to 45 mol %, and still more preferably 5 to 40 mol %.

When the amount of the structural unit (a8) is at least as large as the lower limit of the above preferable range, the effect of using the structural unit (a8) may be satisfactorily achieved. On the other hand, when the amount of the structural unit (a8) is no more than the upper limit of the above preferable range, a good balance may be achieved with the other structural units, and various lithography properties may be improved.

Structural Unit (a2):

The component (A1) may have, in addition to the structural unit (a1), a structural unit (a2) containing a lactone-containing cyclic group, an —SO₂— containing cyclic group or a carbonate-containing cyclic group (provided that structural units which fall under the definition of the structural unit (a1) are excluded).

When the component (A1) is used for forming a resist film, the lactone-containing cyclic group, the —SO₂— containing cyclic group or the carbonate-containing cyclic group within the structural unit (a2) is effective in improving the adhesion between the resist film and the substrate. In addition, by virtue of containing the structural unit (a2), for example, the acid diffusion length is appropriately adjusted, the adhesion of the resist film to the substrate is enhanced, or the solubility during development is appropriately adjusted. As a result, the lithography properties are enhanced.

The term “lactone-containing cyclic group” refers to a cyclic group including a ring containing a —O—C(═O)— structure (lactone ring). The term “lactone ring” refers to a single ring containing a —O—C(O)— structure, and this ring is counted as the first ring. A lactone-containing cyclic group in which the only ring structure is the lactone ring is referred to as a monocyclic group, and groups containing other ring structures are described as polycyclic groups regardless of the structure of the other rings. The lactone-containing cyclic group may be either a monocyclic group or a polycyclic group.

The lactone-containing cyclic group for the structural unit (a2) is not particularly limited, and an arbitrary structural unit may be used. Specific examples include groups represented by general formulae (a2-r-1) to (a2-r-7) shown below.

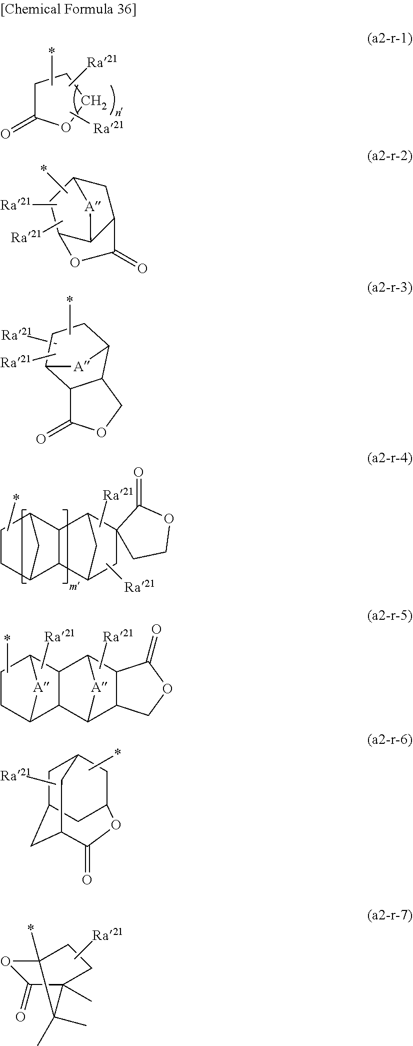

In the formulae, each Ra′²¹ independently represents a hydrogen atom, an alkyl group, an alkoxy group, a halogen atom, a halogenated alkyl group, a hydroxy group, —COOR″, —OC(═O)R″, a hydroxyalkyl group or a cyano group; R″ represents a hydrogen atom, an alkyl group, a lactone-containing cyclic group, a carbonate-containing cyclic group or an —SO₂— containing cyclic group; A″ represents an oxygen atom (—O—), a sulfur atom (—S—) or an alkylene group of 1 to 5 carbon atoms which may contain an oxygen atom or a sulfur atom; n′ represents an integer of 0 to 2; and m′ represents 0 or 1.

In formulae (a2-r-1) to (a2-r-7), the alkyl group for Ra′²¹ is preferably an alkyl group of 1 to 6 carbon atoms. Further, the alkyl group is preferably a linear alkyl group or a branched alkyl group. Specific examples include a methyl group, an ethyl group, a propyl group, an isopropyl group, an n-butyl group, an isobutyl group, a tert-butyl group, a pentyl group, an isopentyl group, a neopentyl group and a hexyl group. Among these, a methyl group or ethyl group is preferable, and a methyl group is particularly desirable.

The alkoxy group for Ra′²¹ is preferably an alkoxy group of 1 to 6 carbon atoms. Further, the alkoxy group is preferably a linear or branched alkoxy group. Specific examples of the alkoxy groups include the aforementioned alkyl groups for Ra′²¹ having an oxygen atom (—O—) bonded thereto.

The halogen atom for Ra′²¹ is preferably a fluorine atom.

Examples of the halogenated alkyl group for Ra′²¹ include groups in which part or all of the hydrogen atoms within the aforementioned alkyl group for Ra′²¹ has been substituted with the aforementioned halogen atoms. As the halogenated alkyl group, a fluorinated alkyl group is preferable, and a perfluoroalkyl group is particularly desirable.

With respect to —COOR″ and —OC(═O)R″ for Ra′²¹, R″ represents a hydrogen atom, an alkyl group, a lactone-containing cyclic group, a carbonate-containing cyclic group or an —SO₂— containing cyclic group.

The alkyl group for R″ may be linear, branched or cyclic, and preferably has 1 to carbon atoms.

When R″ represents a linear or branched alkyl group, it is preferably an alkyl group of 1 to 10 carbon atoms, more preferably an alkyl group of 1 to 5 carbon atoms, and most preferably a methyl group or an ethyl group.

When R″ is a cyclic alkyl group (cycloalkyl group), it preferably has 3 to 15 carbon atoms, more preferably 4 to 12 carbon atoms, and most preferably 5 to 10 carbon atoms. Specific examples include groups in which one or more hydrogen atoms have been removed from a monocycloalkane or a polycycloalkane such as a bicycloalkane, tricycloalkane or tetracycloalkane which may or may not be substituted with a fluorine atom or a fluorinated alkyl group. Specific examples include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

Examples of the lactone-containing cyclic group for R″ include groups represented by the aforementioned general formulae (a2-r-1) to (a2-r-7).

The carbonate-containing cyclic group for R″ is the same as defined for the carbonate-containing cyclic group described later. Specific examples of the carbonate-containing cyclic group include groups represented by general formulae (ax3-r-1) to (ax3-r-3).

The —SO₂— containing cyclic group for R″ is the same as defined for the —SO₂— containing cyclic group described later. Specific examples of the —SO₂— containing cyclic group include groups represented by general formulae (a5-r-1) to (a5-r-4).

The hydroxyalkyl group for Ra′²¹ preferably has 1 to 6 carbon atoms, and specific examples thereof include the alkyl groups for Ra′²¹ in which at least one hydrogen atom has been substituted with a hydroxy group.

In formulae (a2-r-2), (a2-r-3) and (a2-r-5), as the alkylene group of 1 to 5 carbon atoms represented by A″, a linear or branched alkylene group is preferable, and examples thereof include a methylene group, an ethylene group, an n-propylene group and an isopropylene group. Examples of alkylene groups that contain an oxygen atom or a sulfur atom include the aforementioned alkylene groups in which —O— or —S— is bonded to the terminal of the alkylene group or present between the carbon atoms of the alkylene group. Specific examples of such alkylene groups include O—CH₂—, —CH₂—O—CH₂—, —S—CH₂—, and —CH₂—S—CH₂—. As A″, an alkylene group of 1 to 5 carbon atoms or —O— is preferable, more preferably an alkylene group of 1 to 5 carbon atoms, and most preferably a methylene group.

Specific examples of the groups represented by the aforementioned general formulae (a2-r-1) to (a2-r-7) are shown below.

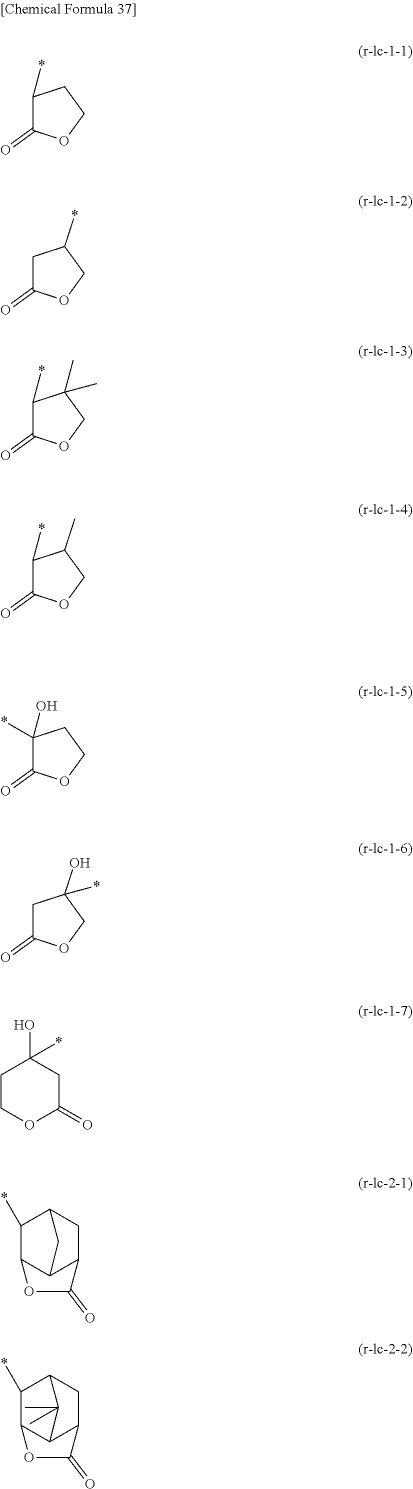

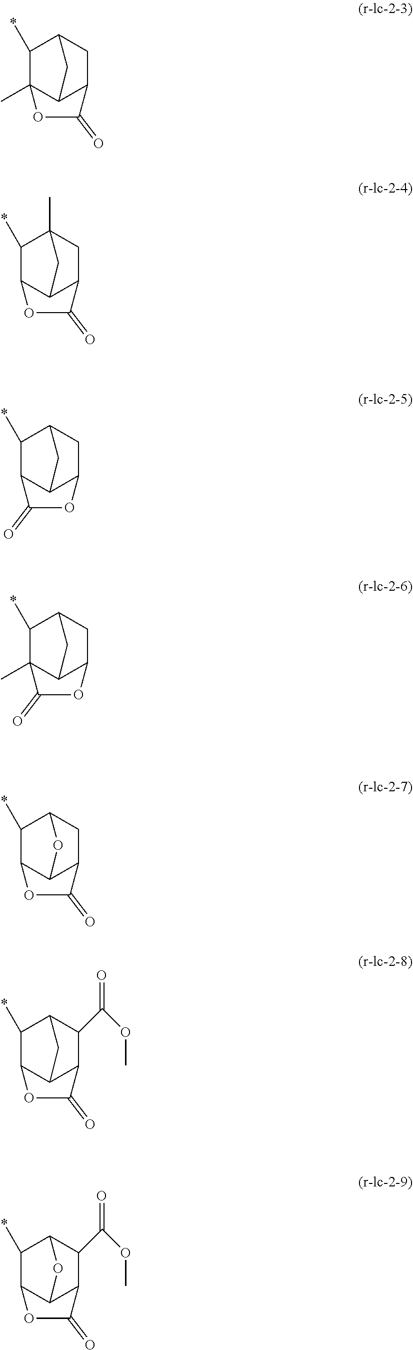

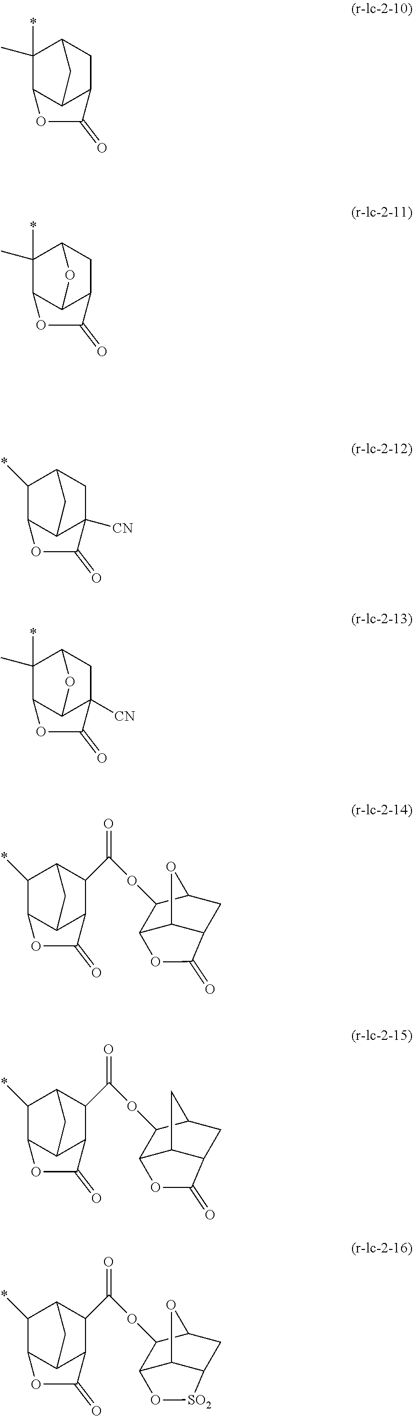

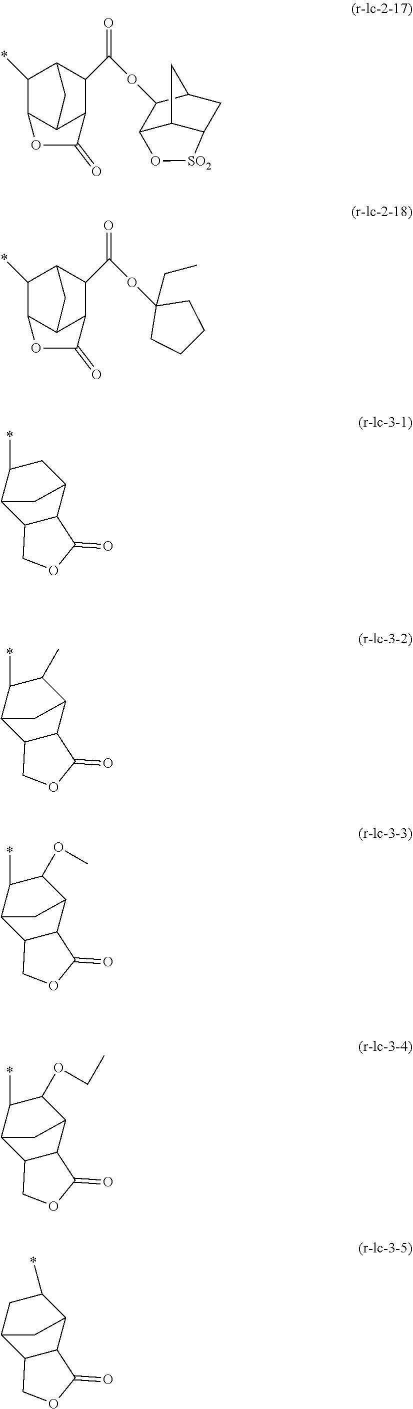

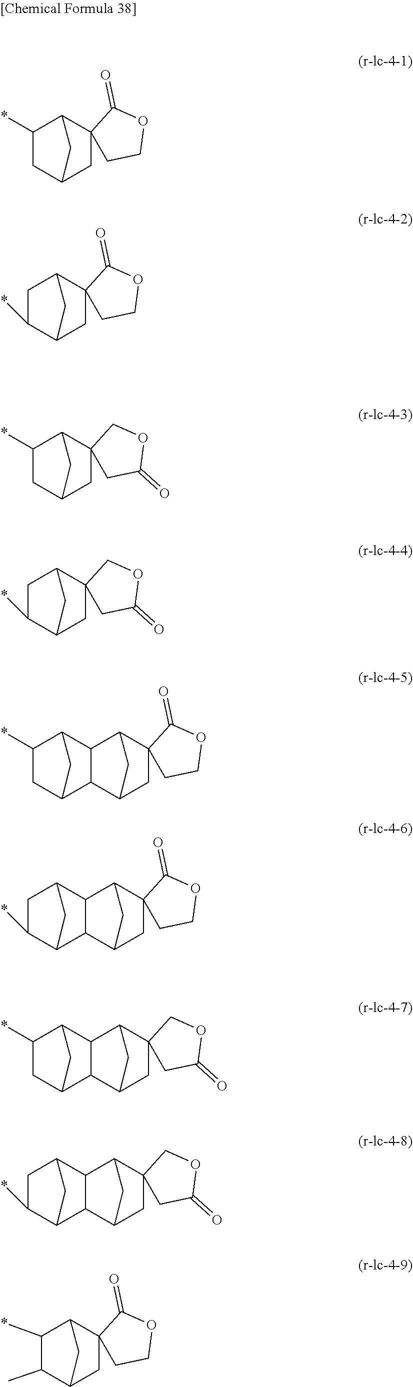

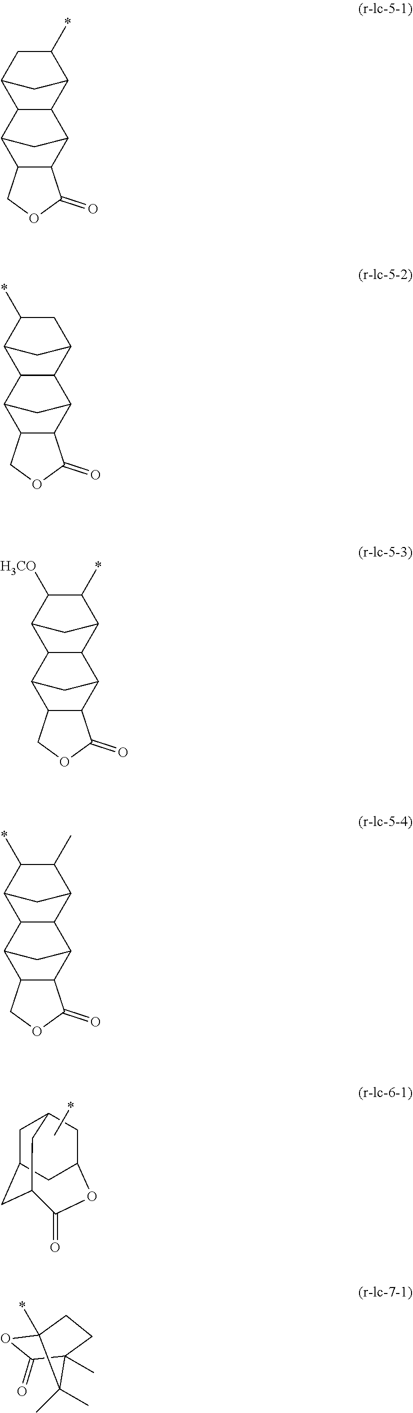

An “—SO₂— containing cyclic group” refers to a cyclic group having a ring containing —SO₂— within the ring structure thereof, i.e., a cyclic group in which the sulfur atom (S) within —SO₂— forms part of the ring skeleton of the cyclic group. The ring containing —SO₂— within the ring skeleton thereof is counted as the first ring. A cyclic group in which the only ring structure is the ring that contains —SO₂— in the ring skeleton thereof is referred to as a monocyclic group, and a group containing other ring structures is described as a polycyclic group regardless of the structure of the other rings. The —SO₂— containing cyclic group may be either a monocyclic group or a polycyclic group. As the —SO₂— containing cyclic group, a cyclic group containing —O—SO₂— within the ring skeleton thereof, i.e., a cyclic group containing a sultone ring in which —O—S— within the —O—SO₂— group forms part of the ring skeleton thereof is particularly desirable.

More specific examples of the —SO₂— containing cyclic group include groups represented by general formulas (a5-r-1) to (a5-r-4) shown below.

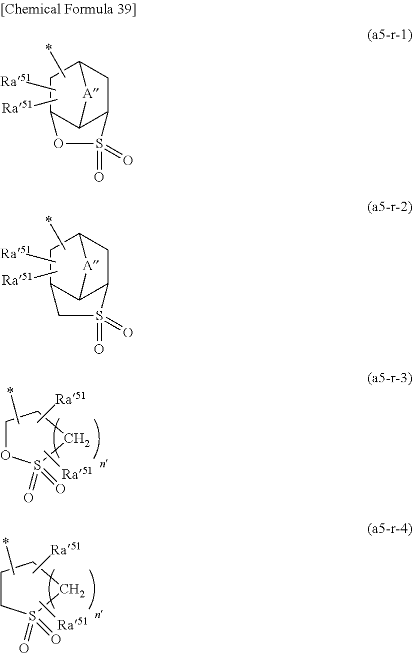

In the formulae, each Ra′⁵¹ independently represents a hydrogen atom, an alkyl group, an alkoxy group, a halogen atom, a halogenated alkyl group, a hydroxy group, —COOR″, —OC(═O)R″, a hydroxyalkyl group or a cyano group; R″ represents a hydrogen atom, an alkyl group, a lactone-containing cyclic group, a carbonate-containing cyclic group or an —SO₂— containing cyclic group; A″ represents an oxygen atom, a sulfur atom or an alkylene group of 1 to 5 carbon atoms which may contain an oxygen atom or a sulfur atom; and n′ represents an integer of 0 to 2.

In general formulae (a5-r-1) and (a5-r-2), A″ is the same as defined for A″ in general formulae (a2-r-2), (a2-r-3) and (a2-r-5).

Examples of the alkyl group, alkoxy group, halogen atom, halogenated alkyl group, —COOR″, —OC(═O)R″ and hydroxyalkyl group for Ra′⁵¹ include the same groups as those described above in the explanation of Ra′²¹ in the general formulas (a2-r-1) to (a2-r-7).

Specific examples of the groups represented by the aforementioned general formulae (a5-r-1) to (a5-r-4) are shown below. In the formulae shown below, “Ac” represents an acetyl group.

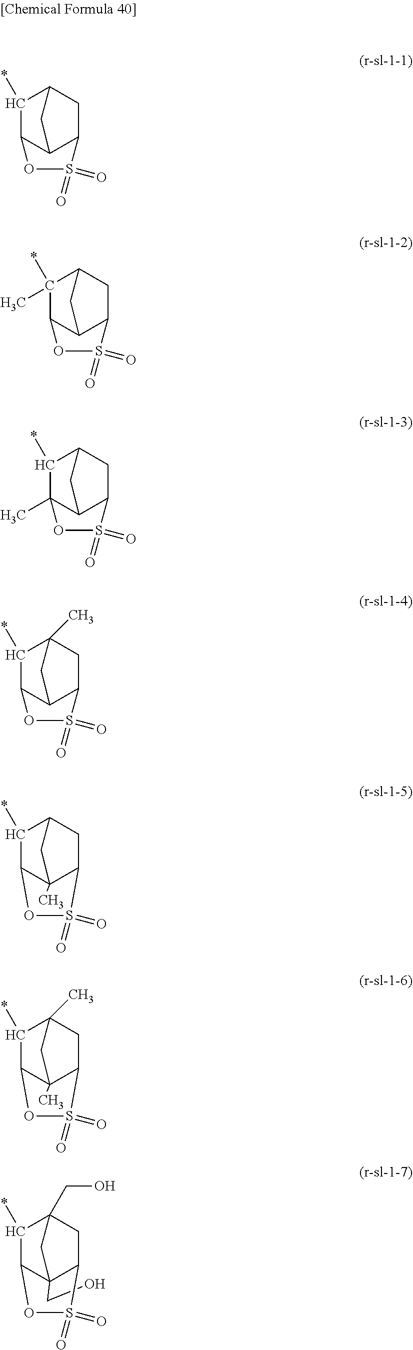

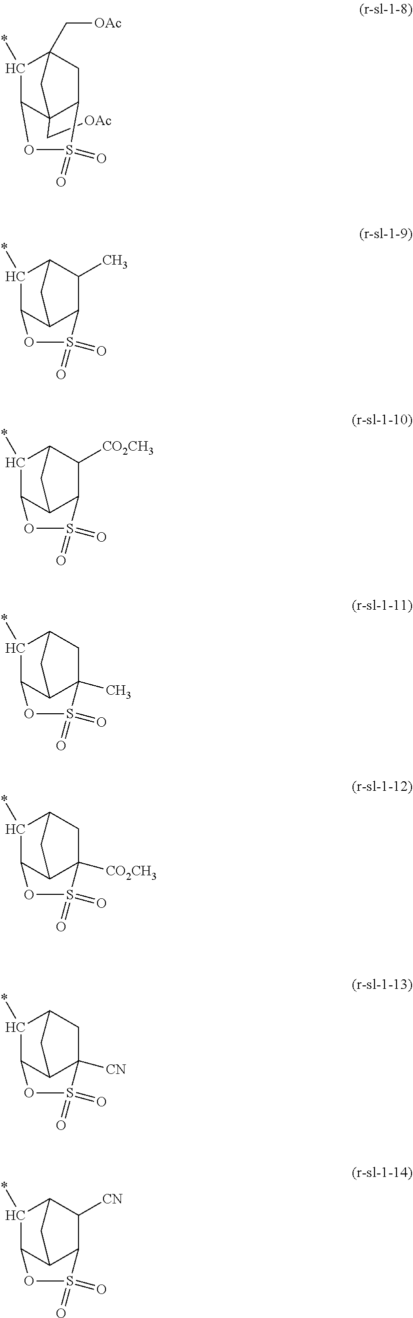

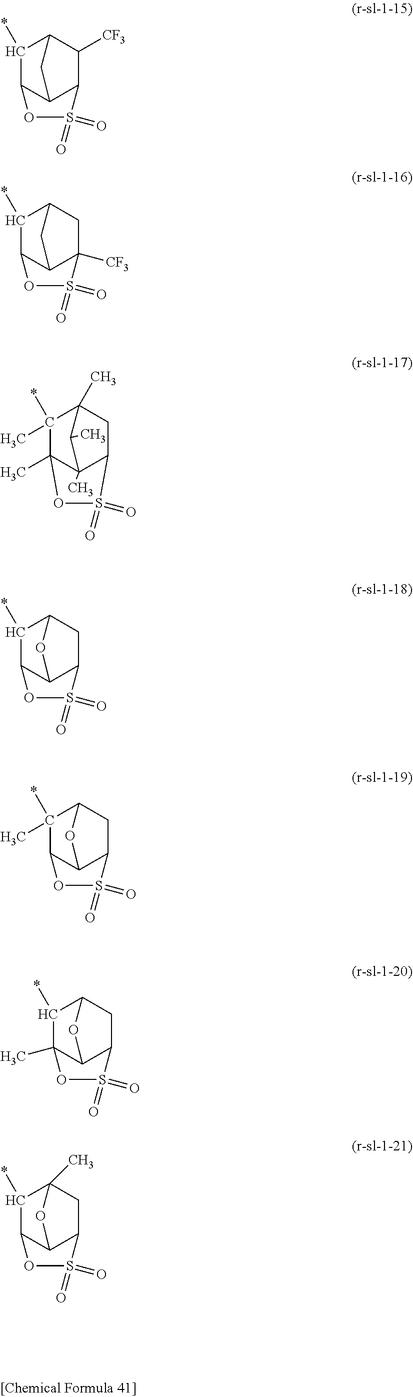

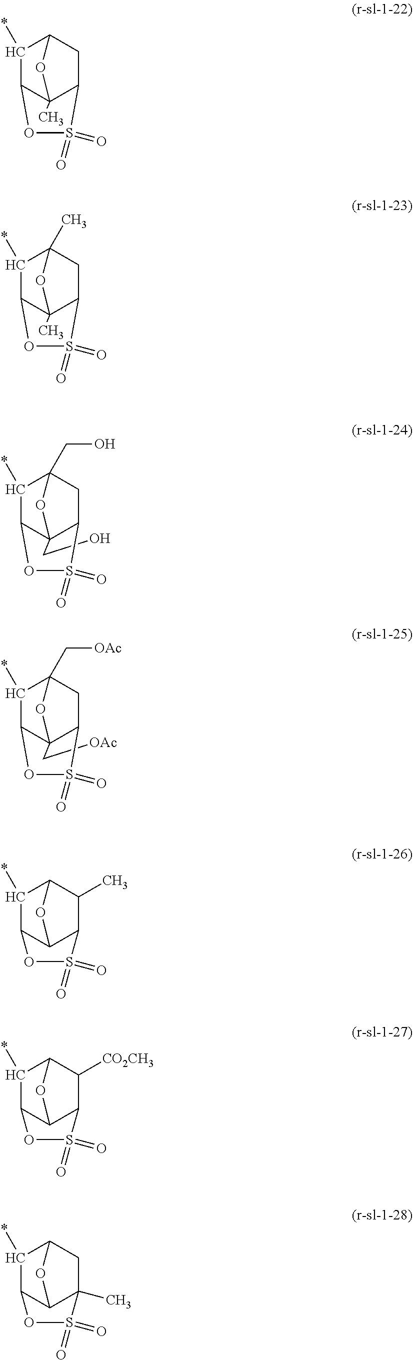

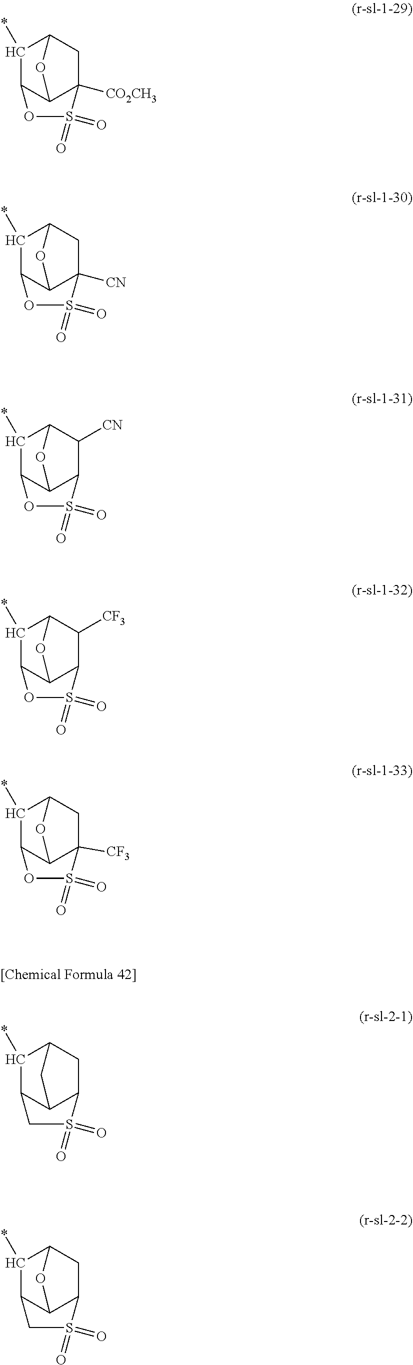

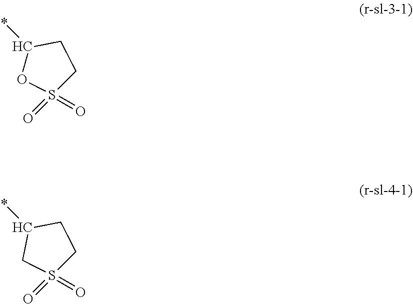

The term “carbonate-containing cyclic group” refers to a cyclic group including a ring containing a —O—C(═O)—O— structure (carbonate ring). The term “carbonate ring” refers to a single ring containing a —O—C(═O)—O— structure, and this ring is counted as the first ring. A carbonate-containing cyclic group in which the only ring structure is the carbonate ring is referred to as a monocyclic group, and groups containing other ring structures are described as polycyclic groups regardless of the structure of the other rings. The carbonate-containing cyclic group may be either a monocyclic group or a polycyclic group.

The carbonate-containing cyclic group is not particularly limited, and an arbitrary group may be used. Specific examples include groups represented by general formulae (ax3-r-1) to (ax3-r-3) shown below.

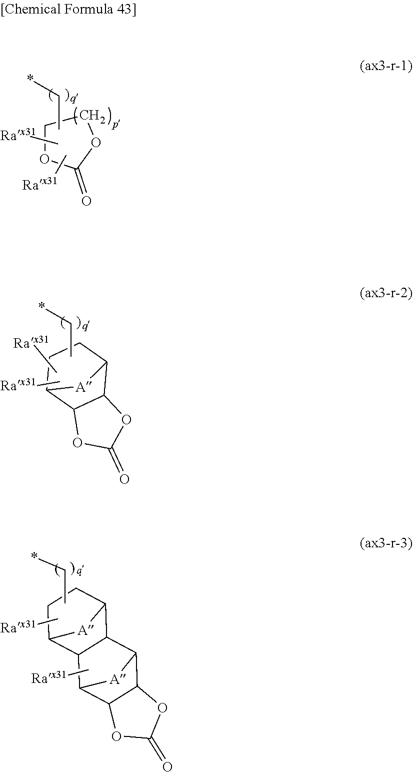

In the formulae, each Ra′^{x31} independently represents a hydrogen atom, an alkyl group, an alkoxy group, a halogen atom, a halogenated alkyl group, a hydroxy group, —COOR″, —OC(═O)R″, a hydroxyalkyl group or a cyano group; R″ represents a hydrogen atom, an alkyl group, a lactone-containing cyclic group, a carbonate-containing cyclic group or an —SO₂— containing cyclic group; A″ represents an oxygen atom, a sulfur atom or an alkylene group of 1 to 5 carbon atoms which may contain an oxygen atom or a sulfur atom; p′ represents an integer of 0 to 3; and q′ represents 0 or 1.

In general formulae (ax3-r-2) and (ax3-r-3), A″ is the same as defined for A″ in general formulae (a2-r-2), (a2-r-3) and (a2-r-5).

Examples of the alkyl group, alkoxy group, halogen atom, halogenated alkyl group, —COOR″, —OC(═O)R″ and hydroxyalkyl group for Ra′³¹ include the same groups as those described above in the explanation of Ra′²¹ in the general formulas (a2-r-1) to (a2-r-7).

Specific examples of the groups represented by the aforementioned general formulae (ax3-r-1) to (ax3-r-3) are shown below.

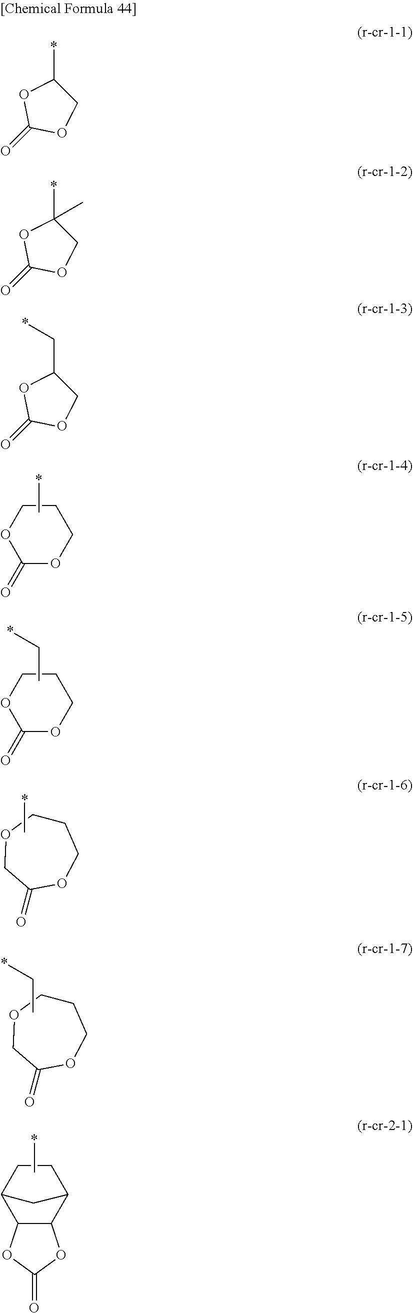

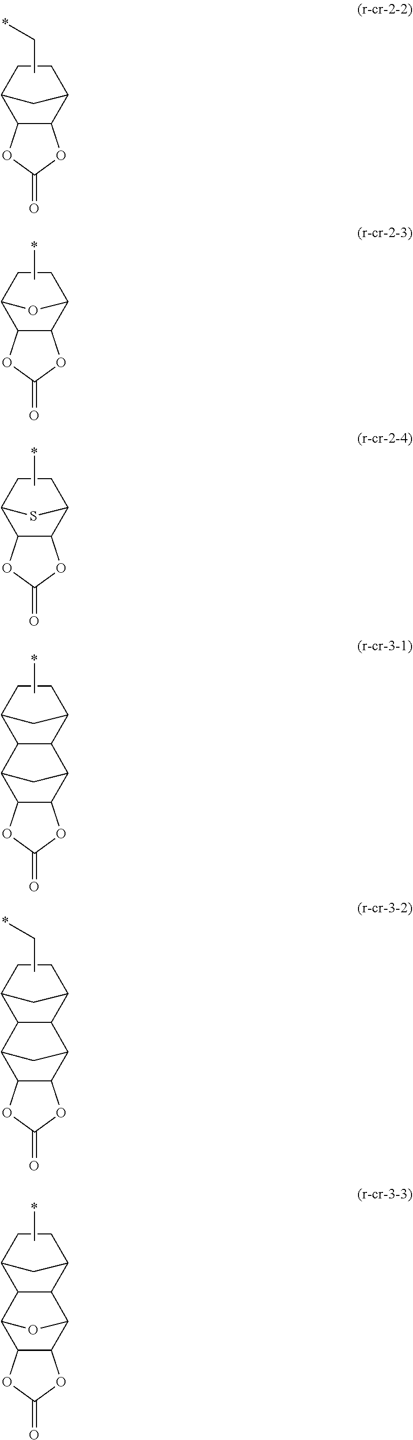

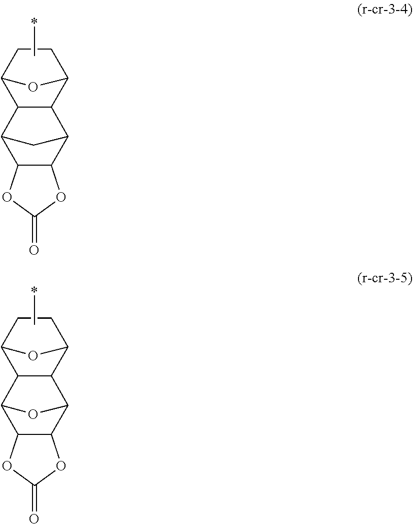

As the structural unit (a2), a structural unit derived from an acrylate ester which may have the hydrogen atom bonded to the carbon atom on the α-position substituted with a substituent is preferable.

The structural unit (a2) is preferably a structural unit represented by general formula (a2-1) shown below.

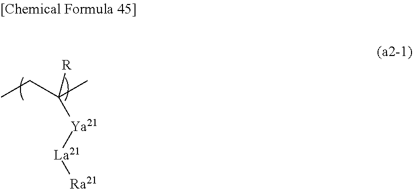

In the formula, R represents a hydrogen atom, an alkyl group of 1 to 5 carbon atoms or a halogenated alkyl group of 1 to 5 carbon atoms; Ya²¹ represents a single bond or a divalent linking group; La²¹ represents —O—, —COO—, —CON(R′)—, —OCO—, —CONHCO— or —CONHCS—; and R′ represents a hydrogen atom or a methyl group; provided that, when La²¹ represents —O—, Ya²¹ does not represents —CO—; and Ra²¹ represents a lactone-containing cyclic group, a carbonate-containing cyclic group or an —SO₂— containing cyclic group.

In the formula (a2-1), R is the same as defined above. As R, a hydrogen atom, an alkyl group of 1 to 5 carbon atoms or a fluorinated alkyl group of 1 to 5 carbon atoms is preferable, and a hydrogen atom or a methyl group is particularly desirable in terms of industrial availability.

In the formula (a2-1), the divalent linking group for Ya²¹ is not particularly limited, and preferable examples thereof include a divalent hydrocarbon group which may have a substituent and a divalent linking group containing a hetero atom.

Divalent Hydrocarbon Group which May have a Substituent:

In the case where Ya²¹ is a divalent linking group which may have a substituent, the hydrocarbon group may be either an aliphatic hydrocarbon group or an aromatic hydrocarbon group.

Aliphatic Hydrocarbon Group for Ya²¹

An “aliphatic hydrocarbon group” refers to a hydrocarbon group that has no aromaticity. The aliphatic hydrocarbon group may be saturated or unsaturated. In general, the aliphatic hydrocarbon group is preferably saturated. Examples of the aliphatic hydrocarbon group include a linear or branched aliphatic hydrocarbon group, and an aliphatic hydrocarbon group containing a ring in the structure thereof can be given.

Linear or Branched Aliphatic Hydrocarbon Group

The linear aliphatic hydrocarbon group preferably has 1 to 10 carbon atoms, more preferably 1 to 6, still more preferably 1 to 4, and most preferably 1 to 3.

As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅—].

The branched aliphatic hydrocarbon group preferably has 2 to 10 carbon atoms, more preferably 3 to 6, still more preferably 3 or 4, and most preferably 3.

As the branched aliphatic hydrocarbon group, branched alkylene groups are preferred, and specific examples include various alkylalkylene groups, including alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group within the alkylalkylene group, a linear alkyl group of 1 to 5 carbon atoms is preferable.

The linear or branched aliphatic hydrocarbon group may or may not have a substituent. Examples of the substituent include a fluorine atom, a fluorinated alkyl group of 1 to 5 carbon atoms, and a carbonyl group.

Aliphatic Hydrocarbon Group Containing a Ring in the Structure Thereof

As examples of the hydrocarbon group containing a ring in the structure thereof, a cyclic aliphatic hydrocarbon group containing a hetero atom in the ring structure thereof and may have a substituent (a group in which two hydrogen atoms have been removed from an aliphatic hydrocarbon ring), a group in which the cyclic aliphatic hydrocarbon group is bonded to the terminal of the aforementioned chain-like aliphatic hydrocarbon group, and a group in which the cyclic aliphatic group is interposed within the aforementioned linear or branched aliphatic hydrocarbon group, can be given. As the linear or branched aliphatic hydrocarbon group, the same groups as those described above can be used.

The cyclic aliphatic hydrocarbon group preferably has 3 to 20 carbon atoms, and more preferably 3 to 12 carbon atoms.

The cyclic aliphatic hydrocarbon group may be either a polycyclic group or a monocyclic group. As the monocyclic aliphatic hydrocarbon group, a group in which 2 hydrogen atoms have been removed from a monocycloalkane is preferable. The monocycloalkane preferably has 3 to 6 carbon atoms, and specific examples thereof include cyclopentane and cyclohexane. As the polycyclic group, a group in which 2 hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane.

The cyclic aliphatic hydrocarbon group may or may not have a substituent. Examples of the substituent include an alkyl group, an alkoxy group, a halogen atom, a halogenated alkyl group, a hydroxyl group and a carbonyl group.

The alkyl group as the substituent is preferably an alkyl group of 1 to 5 carbon atoms, and more preferably a methyl group, an ethyl group, a propyl group, an n-butyl group or a tert-butyl group.

The alkoxy group as the substituent is preferably an alkoxy group having 1 to 5 carbon atoms, more preferably a methoxy group, ethoxy group, n-propoxy group, iso-propoxy group, n-butoxy group or tert-butoxy group, and still more preferably a methoxy group or an ethoxy group.

The halogen atom as the substituent is preferably a fluorine atom.

Examples of the halogenated alkyl group for the substituent include groups in which part or all of the hydrogen atoms within the aforementioned alkyl groups has been substituted with the aforementioned halogen atoms.

The cyclic aliphatic hydrocarbon group may have part of the carbon atoms constituting the ring structure thereof substituted with a substituent containing a hetero atom. As the substituent containing a hetero atom, —O—, —C(═O)—O—, —S—, —S(═O)₂— or —S(═O)₂—O— is preferable.

Aromatic Hydrocarbon Group for Ya²¹

The aromatic hydrocarbon group is a hydrocarbon group having at least one aromatic ring.

The aromatic ring is not particularly limited, as long as it is a cyclic conjugated compound having (4n+2)π electrons, and may be either monocyclic or polycyclic. The aromatic ring preferably has 5 to 30 carbon atoms, more preferably 5 to 20 carbon atoms, and still more preferably 6 to 15 carbon atoms, and most preferably 6 to 12 carbon atoms. Here, the number of carbon atoms within a substituent(s) is not included in the number of carbon atoms of the aromatic hydrocarbon group.

Examples of the aromatic ring include aromatic hydrocarbon rings, such as benzene, naphthalene, anthracene and phenanthrene; and aromatic hetero rings in which part of the carbon atoms constituting the aforementioned aromatic hydrocarbon rings has been substituted with a hetero atom. Examples of the hetero atom within the aromatic hetero rings include an oxygen atom, a sulfur atom and a nitrogen atom. Specific examples of the aromatic hetero ring include a pyridine ring and a thiophene ring.

Specific examples of the aromatic hydrocarbon group include a group in which two hydrogen atoms have been removed from the aforementioned aromatic hydrocarbon ring or aromatic hetero ring (arylene group or heteroarylene group); a group in which two hydrogen atoms have been removed from an aromatic compound having two or more aromatic rings (biphenyl, fluorene or the like); and a group in which one hydrogen atom of the aforementioned aromatic hydrocarbon ring or aromatic hetero ring has been substituted with an alkylene group (a group in which one hydrogen atom has been removed from the aryl group within the aforementioned arylalkyl group such as a benzyl group, a phenethyl group, a 1-naphthylmethyl group, a 2-naphthylmethyl group, a 1-naphthylethyl group, or a 2-naphthylethyl group, or a heteroarylalkyl group). The alkylene group which is bonded to the aforementioned aryl group or heteroaryl group preferably has 1 to 4 carbon atoms, more preferably 1 or 2 carbon atoms, and most preferably 1 carbon atom.

With respect to the aromatic hydrocarbon group, the hydrogen atom within the aromatic hydrocarbon group may be substituted with a substituent. For example, the hydrogen atom bonded to the aromatic ring within the aromatic hydrocarbon group may be substituted with a substituent. Examples of substituents include an alkyl group, an alkoxy group, a halogen atom, a halogenated alkyl group, and a hydroxyl group.

The alkyl group as the substituent is preferably an alkyl group of 1 to 5 carbon atoms, and more preferably a methyl group, an ethyl group, a propyl group, an n-butyl group or a tert-butyl group.

As the alkoxy group, the halogen atom and the halogenated alkyl group for the substituent, the same groups as the aforementioned substituent groups for substituting a hydrogen atom within the cyclic aliphatic hydrocarbon group can be used.

Divalent Linking Group Containing a Hetero Atom

In the case where Ya²¹ is a divalent linking group containing a hetero atom, examples of the linking group include —O—, —C(═O)—O—, —O—C(═O)—, —C(═O)—, —O—C(═O)—O—, —C(═O)—NH—, —NH—, —NH—C(═NH)— (H may be substituted with a substituent such as an alkyl group or an acyl group), —S—, —S(═O)₂—, —S(═O)₂—O—, and a group represented by general formula —Y²¹—O—Y²²—, —Y²¹—O—, —Y²¹—C(═O)—O—, —C(═O)—O—Y²¹—, —[Y²¹—C(═O)—O]_{m″}—Y²²—, —Y²¹—O—C(═O)—Y²²— or —Y²¹—S(═O)₂—O—Y²²— [in the formulae, Y²¹ and Y²² each independently represents a divalent hydrocarbon group which may have a substituent, O represents an oxygen atom, and m″ represents an integer of 0 to 3.

In the case where the divalent linking group containing a hetero atom is —C(═O)—NH—, —C(═O)—NH—C(═O)—, —NH— or —NH—C(═NH)—, H may be substituted with a substituent such as an alkyl group, an acyl group or the like. The substituent (an alkyl group, an acyl group or the like) preferably has 1 to 10 carbon atoms, more preferably 1 to 8, and most preferably 1 to 5.

In general formulae —Y²¹—O—Y²², —Y²¹—O—, —Y²¹—C(═O)—O—, —C(═O)—O—Y²¹—, —[Y²¹—C(═O)—O]_{m″}—Y²²—, —Y²¹—O—C(═O)—Y²²— or —Y²¹—S(═O)₂—O—Y²²—, Y²¹ and Y²² each independently represents a divalent hydrocarbon group which may have a substituent. Examples of the divalent hydrocarbon group include the same groups as those described above as the “divalent hydrocarbon group which may have a substituent” in the explanation of the aforementioned divalent linking group for Ya²¹.

As Y²¹, a linear aliphatic hydrocarbon group is preferable, more preferably a linear alkylene group, still more preferably a linear alkylene group of 1 to 5 carbon atoms, and a methylene group or an ethylene group is particularly desirable.

As Y²², a linear or branched aliphatic hydrocarbon group is preferable, and a methylene group, an ethylene group or an alkylmethylene group is more preferable. The alkyl group within the alkylmethylene group is preferably a linear alkyl group of 1 to 5 carbon atoms, more preferably a linear alkyl group of 1 to 3 carbon atoms, and most preferably a methyl group.

In the group represented by the formula —[Y²¹—C(═O)—O]ₘ″—Y²²—, m″ represents an integer of 0 to 3, preferably an integer of 0 to 2, more preferably 0 or 1, and most preferably 1. Namely, it is particularly desirable that the group represented by the formula —[Y²¹—C(═O)—O]ₘ″—Y²²— is a group represented by the formula —Y²¹—C(═O)—O—Y²²—. Among these, a group represented by the formula —(CH₂)_{a′}—C(═O)—O—(CH₂)_{b′}— is preferable. In the formula, a′ is an integer of 1 to 10, preferably an integer of 1 to 8, more preferably an integer of 1 to 5, still more preferably 1 or 2, and most preferably 1. b′ is an integer of 1 to 10, preferably an integer of 1 to 8, more preferably an integer of 1 to 5, still more preferably 1 or 2, and most preferably 1.

Among these examples, as Ya²¹, a single bond, an ester bond [—C(═O)—O—], an ether bond (—O—), a linear or branched alkylene group, or a combination thereof is preferable.

In formula (a2-1), Ra²¹ represents a lactone-containing cyclic group, an —SO₂— containing cyclic group or a carbonate-containing cyclic group.

Preferable examples of the lactone-containing cyclic group, the —SO₂— containing cyclic group and the carbonate-containing cyclic group for Ra²¹ include groups represented by general formulae (a2-r-1) to (a2-r-7), groups represented by general formulae (a5-r-1) to (a5-r-4) and groups represented by general formulae (ax3-r-1) to (ax3-r-3).

Among the above examples, a lactone-containing cyclic group or a —SO₂— containing cyclic group is preferable, and a group represented by general formula (a2-r-1), (a2-r-2), (a2-r-6) or (a5-r-1) is more preferable. Specifically, a group represented by any of chemical formulae (r-lc-1-1) to (r-lc-1-7), (r-lc-2-1) to (r-lc-2-18), (r-lc-6-1), (r-sl-1-1) and (r-sl-1-18) is still more preferable.

As the structural unit (a2) contained in the component (A1), 1 kind of structural unit may be used, or 2 or more kinds may be used.

When the component (A1) contains the structural unit (a2), the amount of the structural unit (a2) based on the combined total (100 mol %) of all structural units constituting the component (A1) is preferably 5 to 60 mol %, more preferably 10 to 60 mol %, still more preferably 20 to 55 mol %, and most preferably 30 to 50 mol %.

When the amount of the structural unit (a2) is at least as large as the lower limit of the above preferable range, the effect of using the structural unit (a2) may be satisfactorily achieved due to the aforementioned effects. On the other hand, when the amount of the structural unit (a2) is no more than the upper limit of the above preferable range, a good balance may be achieved with the other structural units, and various lithography properties may be improved.

Structural Unit (a3):

The component (A1) may have, in addition to the structural unit (a1), a structural unit (a3) containing a polar group-containing aliphatic hydrocarbon group (provided that the structural units that fall under the definition of structural units (a1) and (a2) are excluded). When the component (A1) includes the structural unit (a3), the hydrophilicity of the component (A1) is enhanced, thereby contributing to improvement in resolution. Further, the acid diffusion length may be appropriately adjusted.

Examples of the polar group include a hydroxyl group, cyano group, carboxyl group, or hydroxyalkyl group in which part of the hydrogen atoms of the alkyl group have been substituted with fluorine atoms, although a hydroxyl group is particularly desirable.

Examples of the aliphatic hydrocarbon group include linear or branched hydrocarbon groups (preferably alkylene groups) of 1 to 10 carbon atoms, and cyclic aliphatic hydrocarbon groups (cyclic groups). These cyclic groups can be selected appropriately from the multitude of groups that have been proposed for the resins of resist compositions designed for use with ArF excimer lasers.

In the case where the cyclic group is a monocyclic group, the monocyclic group preferably has 3 to 10 carbon atoms. Of the various possibilities, structural units derived from an acrylate ester that include an aliphatic monocyclic group that contains a hydroxyl group, cyano group, carboxyl group or a hydroxyalkyl group in which part of the hydrogen atoms of the alkyl group have been substituted with fluorine atoms are particularly desirable. Examples of the monocyclic groups include groups in which two or more hydrogen atoms have been removed from a monocycloalkane. Specific examples include groups in which two or more hydrogen atoms have been removed from a monocycloalkane such as cyclopentane, cyclohexane or cyclooctane. Of these polycyclic groups, groups in which two or more hydrogen atoms have been removed from cyclopentane or cyclohexane are preferred industrially.

In the case where the cyclic group is a polycyclic group, the polycyclic group preferably has 7 to 30 carbon atoms. Of the various possibilities, structural units derived from an acrylate ester that include an aliphatic polycyclic group that contains a hydroxyl group, cyano group, carboxyl group or a hydroxyalkyl group in which part of the hydrogen atoms of the alkyl group have been substituted with fluorine atoms are particularly desirable. Examples of the polycyclic group include groups in which two or more hydrogen atoms have been removed from a bicycloalkane, tricycloalkane, tetracycloalkane or the like. Specific examples include groups in which two or more hydrogen atoms have been removed from a polycycloalkane such as adamantane, norbornane, isobornane, tricyclodecane or tetracyclododecane. Of these polycyclic groups, groups in which two or more hydrogen atoms have been removed from adamantane, norbornane or tetracyclododecane are preferred industrially.

As the structural unit (a3), there is no particular limitation as long as it is a structural unit containing a polar group-containing aliphatic hydrocarbon group, and an arbitrary structural unit may be used.

The structural unit (a3) is preferably a structural unit derived from an acrylate ester which may have the hydrogen atom bonded to the carbon atom on the α-position substituted with a substituent and contains a polar group-containing aliphatic hydrocarbon group.

When the aliphatic hydrocarbon group within the polar group-containing aliphatic hydrocarbon group is a linear or branched hydrocarbon group of 1 to 10 carbon atoms, the structural unit (a3) is preferably a structural unit derived from a hydroxyethyl ester of acrylic acid.

On the other hand, in the structural unit (a3), when the hydrocarbon group within the polar group-containing aliphatic hydrocarbon group is a polycyclic group, structural units represented by formulas (a3-1), (a3-2), (a3-3) and (a3-4) shown below are preferable.

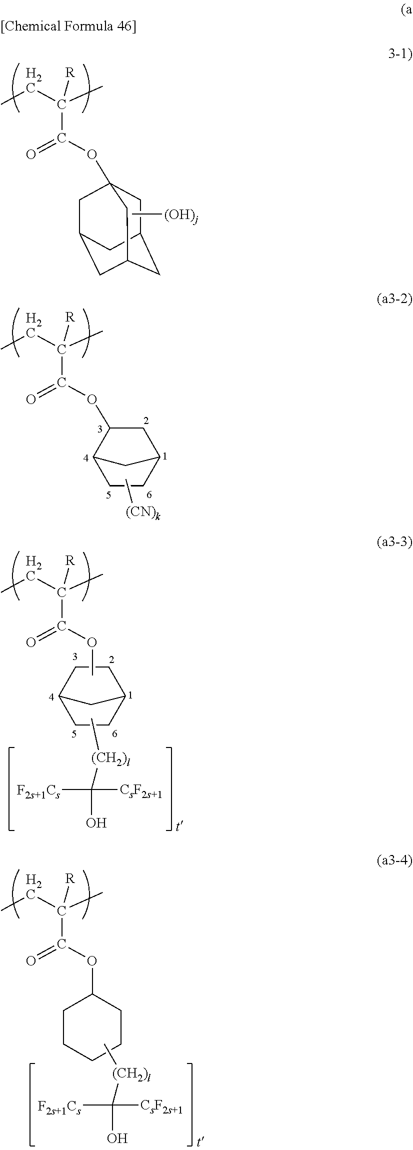

In the formulas, R is the same as defined above; j is an integer of 1 to 3; k is an integer of 1 to 3; t′ is an integer of 1 to 3; 1 is an integer of 0 to 5; and s is an integer of 1 to 3.

In formula (a3-1), j is preferably 1 or 2, and more preferably 1. When j is 2, it is preferable that the hydroxyl groups be bonded to the 3rd and 5th positions of the adamantyl group. When j is 1, it is preferable that the hydroxyl group be bonded to the 3rd position of the adamantyl group, j is preferably 1, and it is particularly desirable that the hydroxyl group be bonded to the 3rd position of the adamantyl group.

In formula (a3-2), k is preferably 1. The cyano group is preferably bonded to the 5th or 6th position of the norbornyl group.

In formula (a3-3), t′ is preferably 1. l is preferably 1. s is preferably 1. Further, it is preferable that a 2-norbornyl group or 3-norbornyl group be bonded to the terminal of the carboxy group of the acrylic acid. The fluorinated alkyl alcohol is preferably bonded to the 5th or 6th position of the norbornyl group.

In formula (a3-4), t′ is preferably 1 or 2.1 is preferably 0 or 1. s is preferably 1. The fluorinated alkyl alcohol is preferably bonded to the 3rd or 5th position of the cyclohexyl group.

As the structural unit (a3) contained in the component (A1), 1 type of structural unit may be used, or 2 or more types may be used.

When the component (A1) includes the structural unit (a3), the amount of the structural unit (a3) based on the combined total (100 mol %) of all structural units constituting the component (A1) is preferably 1 to 30 mol %, more preferably 2 to 25 mol %, and still more preferably 5 to 20 mol %.

When the amount of the structural unit (a3) is at least as large as the lower limit of the above preferable range, the effect of using the structural unit (a3) may be satisfactorily achieved due to the aforementioned effects. On the other hand, when the amount of the structural unit (a3) is no more than the upper limit of the above preferable range, a good balance may be achieved with the other structural units, and various lithography properties may be improved.

Structural Unit (a4):

The component (A1) may be further include, in addition to the structural unit (a1), a structural unit (a4) containing an acid non-dissociable, aliphatic cyclic group.

When the component (A1) includes the structural unit (a4), dry etching resistance of the resist pattern to be formed is improved. Further, the hydrophobicity of the component (A) is further improved. Increase in the hydrophobicity contributes to improvement in terms of resolution, shape of the resist pattern and the like, particularly in a solvent developing process. An “acid non-dissociable, aliphatic cyclic group” in the structural unit (a4) refers to a cyclic group which is not dissociated by the action of the acid (e.g., acid generated from a structural unit which generates acid upon exposure or acid generated from the component (B)) upon exposure, and remains in the structural unit.

As the structural unit (a4), a structural unit which contains a non-acid-dissociable aliphatic cyclic group, and is also derived from an acrylate ester is preferable. As the cyclic group, any of the multitude of conventional polycyclic groups used within the resin component of resist compositions for ArF excimer lasers or KrF excimer lasers (and particularly for ArF excimer lasers) can be used.

As the aliphatic polycyclic group, at least one polycyclic group selected from amongst a tricyclodecyl group, adamantyl group, tetracyclododecyl group, isobornyl group, and norbornyl group is particularly desirable in consideration of industrial availability and the like. These polycyclic groups may be substituted with a linear or branched alkyl group of 1 to 5 carbon atoms.

Specific examples of the structural unit (a4) include structural units represented by general formulae (a4-1) to (a4-7) shown below.

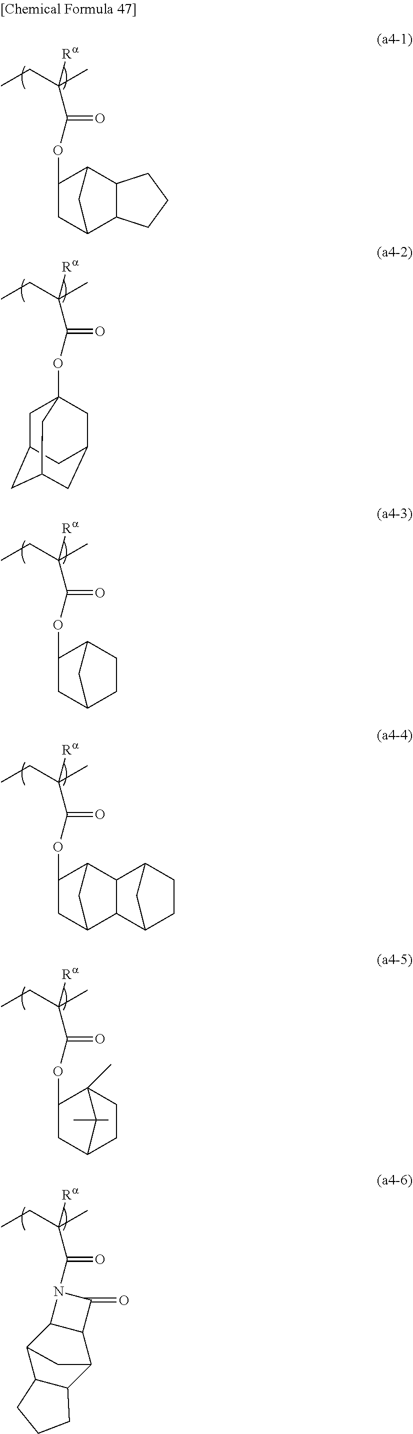

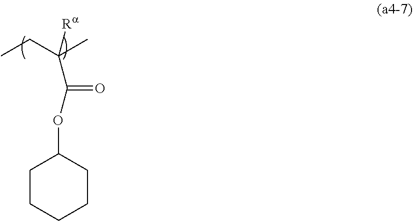

In the formulae, R^{α} is the same as defined above.

As the structural unit (a4) contained in the component (A1), 1 type of structural unit may be used, or 2 or more types may be used.

When the component (A1) contains the structural unit (a4), the amount of the structural unit (a4) based on the combined total (100 mol %) of all structural units constituting the component (A1) is preferably 1 to 40 mol %, and more preferably 5 to 20 mol %.

When the amount of the structural unit (a4) is at least as large as the lower limit of the above-mentioned preferable range, the effect of using the structural unit (a4) can be satisfactorily achieved. On the other hand, when the amount of the structural unit (a4) is no more than the upper limit of the above-mentioned preferable range, a good balance can be achieved with the other structural units.

Structural Unit (st)

The structural unit (st) is a structural unit derived from styrene or a styrene derivative. A “structural unit derived from styrene” refers to a structural unit that is formed by the cleavage of the ethylenic double bond of styrene. A “structural unit derived from a styrene derivative” refers to a structural unit that is formed by the cleavage of the ethylenic double bond of a styrene derivative (provided that structural units which fall under the definition of the structural unit (a10) is excluded).

A “styrene derivative” refers to a compound in which at least part of the hydrogen atoms of styrene has been substituted with a substituent. Examples of the styrene derivative include a compound in which the hydrogen at the α-position of styrene has been substituted with a substituent, a compound in which at least one hydrogen atom on the benzene ring of styrene has been substituted with a substituent, and a compound in which the hydrogen at the α-position of styrene and at least one hydrogen atom on the benzene ring of styrene has been substituted with a substituent.

Examples of the substituent which substitutes the hydrogen atom at the α-position of styrene include an alkyl group having 1 to 5 carbon atoms, and a halogenated alkyl group having 1 to 5 carbon atoms.

The alkyl group of 1 to 5 carbon atoms is preferably a linear or branched alkyl group of 1 to 5 carbon atoms, and specific examples include a methyl group, an ethyl group, a propyl group, an isopropyl group, an n-butyl group, an isobutyl group, a tert-butyl group, a pentyl group, an isopentyl group, and a neopentyl group.

The halogenated alkyl group of 1 to 5 carbon atoms is a group in which part or all of the hydrogen atoms of the aforementioned alkyl group of 1 to 5 carbon atoms have been substituted with halogen atom(s). As the halogen atom, a fluorine atom is most preferable.

As the substituent which substitutes the hydrogen atom at the α-position of styrene, an alkyl group having 1 to 5 carbon atoms or a fluorinated alkyl group having 1 to 5 carbon atoms is preferable, an alkyl group having 1 to 3 carbon atoms or a fluorinated alkyl group having 1 to 3 carbon atoms is more preferable, and in terms of industrial availability, a methyl group is more preferable.

Examples of the substituent which substitutes a hydrogen atom on the benzene ring of styrene include an alkyl group, an alkoxy group, a halogen atom, and a halogenated alkyl group.

The alkyl group as the substituent is preferably an alkyl group of 1 to 5 carbon atoms, and more preferably a methyl group, an ethyl group, a propyl group, an n-butyl group or a tert-butyl group.

The alkoxy group as the substituent is preferably an alkoxy group having 1 to 5 carbon atoms, more preferably a methoxy group, ethoxy group, n-propoxy group, iso-propoxy group, n-butoxy group or tert-butoxy group, and still more preferably a methoxy group or an ethoxy group.

The halogen atom as the substituent is preferably a fluorine atom.

Examples of the halogenated alkyl group for the substituent include groups in which part or all of the hydrogen atoms within the aforementioned alkyl groups has been substituted with the aforementioned halogen atoms.

As the substituent which substitutes a hydrogen atom on the benzene ring of styrene, an alkyl group having 1 to 5 carbon atoms is preferable, a methyl group or an ethyl group is more preferable, and a methyl group is still more preferable.

As the structural unit (st), a structural unit derived from styrene or a structural unit derived from a styrene derivative in which the hydrogen atom at the α-position of styrene has been substituted with an alkyl group having 1 to 5 carbon atoms or a halogenated alkyl group having 1 to 5 carbon atoms is preferable, a structural unit derived from styrene or a structural unit derived from a styrene derivative in which the hydrogen atom at the op-position of styrene has been substituted with a methyl group is more preferable, and a structural unit derived from styrene is still more preferable.

As the structural unit (st) contained in the component (A1), 1 kind of structural unit may be used, or 2 or more kinds of structural units may be used.

When the component (A1) includes the structural unit (st), the amount of the structural unit (st) based on the combined total of all structural units constituting the component (A1) (100 mol %) is preferably 1 to 30 mol %, and more preferably 3 to 20 mol %.

In the resist composition, as the component (A), one kind of compound may be used, or two or more kinds of compounds may be used in combination.

In the resist composition of the present embodiment, examples of the component (A1) include a polymeric compound having a repeating structure of the structural unit (a1).

As the component (A1), a polymeric compound having a repeating structure of the structural units (a1) and (a2) is preferable, and a polymeric compound having a repeating structure of the structural units (a1), (a2) and (a3) is more preferable.

In the case of a polymeric compound having a repeating structure of the structural units (a1), (a2) and (a3),

the amount of the structural unit (a1) within the polymeric compound, based on the combined total (100 mol %) of all the structural units that constitute the polymeric compound is preferably 10 to 75 mol %, more preferably 30 to 70 mol %, still more preferably 40 to 60 mol %;

the amount of the structural unit (a2) within the polymeric compound, based on the combined total (100 mol %) of all the structural units that constitute the polymeric compound is preferably 10 to 60 mol %, more preferably 20 to 55 mol %, still more preferably 30 to 50 mol %;

the amount of the structural unit (a3) within the polymeric compound, based on the combined total (100 mol %) of all the structural units that constitute the polymeric compound is preferably 1 to 30 mol %, more preferably 2 to 25 mol %, still more preferably to 20 mol %.

Further, preferable examples of the component (A1) include a polymeric compound having at least the structural unit (a1) and the structural unit (a10).

In such a case, the amount of the structural unit (a1) within the polymeric compound, based on the combined total (100 mol %) of all the structural units that constitute the polymeric compound is preferably 5 to 80 mol %, more preferably 10 to 75 mol %, still more preferably 30 to 70 mol %, and most preferably 40 to 60 mol %. Further, the amount of the structural unit (a10) within the polymeric compound, based on the combined total (100 mol %) of all the structural units that constitute the polymeric compound is preferably 5 to 80 mol %, more preferably 10 to 75 mol %, still more preferably 30 to 70 mol %, and most preferably 40 to 60 mol %.

In the case where the resist composition according to the present embodiment contains a compound (B0) represented by general formula (b0) described later as the component (B), preferable examples of the component (A1) include a polymeric compound having a repeating structure of the structural units (a1) and (a10) (hereafter, sometimes referred to as “polymeric compound (A1)-1”), and a polymeric compound having a repeating structure of the structural units (a1), (a10) and (a8) (hereafter, sometimes referred to as “polymeric compound (A1)-2”).

In the polymeric compound (A1)-1, the amount of the structural unit (a1) based on the combined total (100 mol %) of all the structural units that constitute the polymeric compound (A1)-1 is preferably 30 to 80 mol %, more preferably 30 to 70 mol %, still more preferably 35 to 65 mol %.

In the polymeric compound (A1)-1, the amount of the structural unit (a10) based on the combined total (100 mol %) of all the structural units that constitute the polymeric compound (A1)-1 is preferably 20 to 75 mol %, more preferably 25 to 70 mol %, still more preferably 30 to 65 mol %.

In the polymeric compound (A1)-2, the amount of the structural unit (a1) based on the combined total (100 mol %) of all the structural units that constitute the polymeric compound (A1)-2 is preferably 30 to 80 mol %, more preferably 30 to 70 mol %, still more preferably 35 to 65 mol %.

In the polymeric compound (A1)-2, the amount of the structural unit (a10) based on the combined total (100 mol %) of all the structural units that constitute the polymeric compound (A1)-2 is preferably 20 to 75 mol %, more preferably 25 to 70 mol %, still more preferably 30 to 65 mol %.

In the polymeric compound (A1)-2, the amount of the structural unit (a8) based on the combined total (100 mol %) of all the structural units that constitute the polymeric compound (A1)-2 is preferably 1 to 50 mol %, more preferably 5 to 45 mol %, still more preferably 5 to 40 mol %.

In the case where the resist composition according to the present embodiment contains a compound (D0′) represented by general formula (d0′) described later as the component (D0), preferable examples of the component (A1) include a polymeric compound having a repeating structure of the structural units (a1) and (a10).

In such a case, the amount of the structural unit (a1) within the polymeric compound, based on the combined total (100 mol %) of all the structural units that constitute the polymeric compound is preferably 25 to 80 mol %, more preferably 30 to 70 mol %, still more preferably 35 to 65 mol %.

Further, the amount of the structural unit (a10) within the polymeric compound, based on the combined total (100 mol %) of all the structural units that constitute the polymeric compound is preferably 20 to 75 mol %, more preferably 25 to 70 mol %, still more preferably 30 to 65 mol %.

In the polymeric compound, the molar ratio of the structural unit (a1) to the structural unit (a10) (structural unit (a1)/structural unit (a10)) is preferably 2/8 to 8/2, more preferably 3/7 to 7/3, and still more preferably 3.5/6.5 to 5.5/4.5.

The component (A1) may be produced, for example, by dissolving the monomers corresponding with each of the structural units in a polymerization solvent, followed by addition of a radical polymerization initiator such as azobisisobutyronitrile (AIBN) or dimethyl-2,2′-azobisisoutyrate (e.g., V-601).

Alternatively, the component (A1) may be prepared by dissolving a monomer from which the structural unit (a1) is derived, and a monomer from which the structural unit other than the structural unit (a1) is derived in a polymerization solvent, polymerizing the dissolved monomers using the radical polymerization initiator described above, followed by performing a deprotection reaction.

In the polymerization, a chain transfer agent such as HS—CH₂—CH₂—CH₂—C(CF₃)₂—OH may be used to introduce a —C(CF₃)₂—OH group at the terminal(s) of the polymer. Such a copolymer having introduced a hydroxyalkyl group in which some of the hydrogen atoms of the alkyl group are substituted with fluorine atoms is effective in reducing developing defects and LER (line edge roughness: unevenness of the side walls of a line pattern).

The weight average molecular weight (Mw) (the polystyrene equivalent value determined by gel permeation chromatography (GPC)) of the component (A1) is not particularly limited, but is preferably 1,000 to 50,000, more preferably 2,000 to 30,000, and still more preferably 3,000 to 20,000.

When the Mw of the component (A1) is no more than the upper limit of the above-mentioned preferable range, the resist composition exhibits a satisfactory solubility in a resist solvent. On the other hand, when the Mw of the component (A1) is at least as large as the lower limit of the above-mentioned preferable range, dry etching resistance and the cross-sectional shape of the resist pattern becomes satisfactory.

The dispersity (Mw/Mn) of the component (A1) is not particularly limited, but is preferably 1.0 to 4.0, more preferably 1.0 to 3.0, and most preferably 1.0 to 2.0. Here, Mn is the number average molecular weight.

Component (A2)

In the resist composition of the present embodiment, as the component (A), “a base component which exhibits changed solubility in a developing solution under action of acid” other than the component (A1) (hereafter, referred to as “component (A2)”) may be used in combination.

As the component (A2), there is no particular limitation, and any of the multitude of conventional base resins used within chemically amplified resist compositions may be arbitrarily selected for use.

As the component (A2), one kind of a polymer or a low molecular weight compound may be used, or a combination of two or more kinds may be used.

In the component (A), the amount of the component (A1) based on the total weight of the component (A) is preferably 25% by weight or more, more preferably 50% by weight or more, still more preferably 75% by weight or more, and may be even 100% by weight. When the amount of the component (A1) is 25% by weight or more, a resist pattern with improved lithography properties such as improvement in roughness may be reliably formed.

In the resist composition of the present embodiment, the amount of the component (A) may be appropriately adjusted depending on the thickness of the resist film to be formed, and the like.

<Component (B)>

In the resist composition according to the present embodiment, the component (B) is an acid generator component which generates acid upon exposure.

As the component (B), there is no particular limitation, and any of the known acid generators used in conventional chemically amplified resist compositions may be used.

Examples of these acid generators are numerous, and include onium salt acid generators such as iodonium salts and sulfonium salts; oxime sulfonate acid generators; diazomethane acid generators such as bisalkyl or bisaryl sulfonyl diazomethanes and poly(bis-sulfonyl)diazomethanes; nitrobenzylsulfonate acid generators; iminosulfonate acid generators; and disulfone acid generators.

As the onium salt acid generator, a compound represented by general formula (b-1) below (hereafter, sometimes referred to as “component (b-1)”), a compound represented by general formula (b-2) below (hereafter, sometimes referred to as “component (b-2)”) or a compound represented by general formula (b-3) below (hereafter, sometimes referred to as “component (b-3)”) may be mentioned.

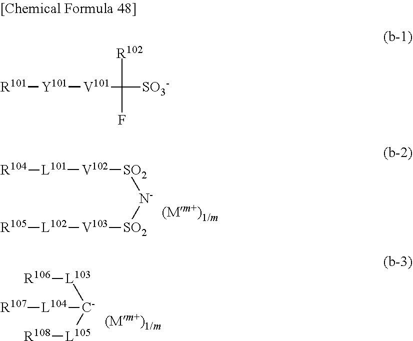

In the formulae, R¹⁰¹ and R¹⁰⁴ to R¹⁰⁸ each independently represents a cyclic group which may have a substituent, a chain-like alkyl group which may have a substituent or a chain-like alkenyl group which may have a substituent, provided that R¹⁰⁴ and R¹⁰⁵ may be mutually bonded to form a ring structure; R¹⁰² represents a fluorine atom or a fluorinated alkyl group having 1 to 5 carbon atoms; Y¹⁰¹ represents a single bond or a divalent group containing an oxygen atom; V¹⁰¹ to V¹⁰³ each independently represents a single bond, an alkylene group or a fluorinated alkylene group; L¹⁰¹ and L¹⁰² each independently represents a single bond or an oxygen atom; L¹⁰³ to L¹⁰⁵ each independently represents a single bond, —CO— or —SO₂—; m represents an integer of 1 or more; and M′^{m+} represents an m-valent onium cation.

{Anion Moiety}

Anion Moiety of Component (b-1)

In the formula (b-1), R¹⁰¹ represents a cyclic group which may have a substituent, a chain-like alkyl group which may have a substituent or a chain-like alkenyl group which may have a substituent.

Cyclic group which may have a substituent:

The cyclic group is preferably a cyclic hydrocarbon group, and the cyclic hydrocarbon group may be either an aromatic hydrocarbon group or an aliphatic hydrocarbon group. An “aliphatic hydrocarbon group” refers to a hydrocarbon group that has no aromaticity. The aliphatic hydrocarbon group may be either saturated or unsaturated, but in general, the aliphatic hydrocarbon group is preferably saturated.

The aromatic hydrocarbon group for R¹⁰¹ is a hydrocarbon group having an aromatic ring. The aromatic hydrocarbon ring preferably has 3 to 30 carbon atoms, more preferably 5 to 30, still more preferably 5 to 20, still more preferably 6 to 15, and most preferably 6 to 10. Here, the number of carbon atoms within a substituent(s) is not included in the number of carbon atoms of the aromatic hydrocarbon group.

Examples of the aromatic ring contained in the aromatic hydrocarbon group represented by R¹⁰¹ include benzene, fluorene, naphthalene, anthracene, phenanthrene and biphenyl; and aromatic hetero rings in which part of the carbon atoms constituting the aforementioned aromatic rings has been substituted with a hetero atom. Examples of the hetero atom within the aromatic hetero rings include an oxygen atom, a sulfur atom and a nitrogen atom.

Specific examples of the aromatic hydrocarbon group represented by R¹⁰¹ include a group in which one hydrogen atom has been removed from the aforementioned aromatic ring (i.e., an aryl group, such as a phenyl group or a naphthyl group), and a group in which one hydrogen of the aforementioned aromatic ring has been substituted with an alkylene group (e.g., an arylalkyl group such as a benzyl group, a phenethyl group, a 1-naphthylmethyl group, a 2-naphthylmethyl group, a 1-naphthylethyl group or a 2-naphthylethyl group). The alkylene group (alkyl chain within the arylalkyl group) preferably has 1 to 4 carbon atom, more preferably 1 or 2, and most preferably 1.

Examples of the cyclic aliphatic hydrocarbon group for R¹⁰¹ include aliphatic hydrocarbon groups containing a ring in the structure thereof.

As examples of the hydrocarbon group containing a ring in the structure thereof, an alicyclic hydrocarbon group (a group in which one hydrogen atom has been removed from an aliphatic hydrocarbon ring), a group in which the alicyclic hydrocarbon group is bonded to the terminal of the aforementioned chain-like aliphatic hydrocarbon group, and a group in which the alicyclic group is interposed within the aforementioned linear or branched aliphatic hydrocarbon group, can be given.

The alicyclic hydrocarbon group preferably has 3 to 20 carbon atoms, and more preferably 3 to 12 carbon atoms.

The alicyclic hydrocarbon group may be either a polycyclic group or a monocyclic group. As the monocyclic alicyclic hydrocarbon group, a group in which one or more hydrogen atoms have been removed from a monocycloalkane is preferable. The monocycloalkane preferably has 3 to 6 carbon atoms, and specific examples thereof include cyclopentane and cyclohexane. As the polycyclic alicyclic hydrocarbon group, a group in which one or more hydrogen atoms have been removed from a polycycloalkane is preferable, and the polycyclic group preferably has 7 to 30 carbon atoms. Among polycycloalkanes, a polycycloalkane having a bridged ring polycyclic skeleton, such as adamantane, norbornane, isobornane, tricyclodecane or tetracyclododecene, and a polycycloalkane having a condensed ring polycyclic skeleton, such as a cyclic group having a steroid skeleton are preferable.

Among these examples, as the cyclic aliphatic hydrocarbon group for R¹⁰¹, a group in which one or more hydrogen atoms have been removed from a monocycloalkane or a polycycloalkane is preferable, a group in which one or more hydrogen atoms have been removed from a polycycloalkane is more preferable, an adamantyl group or a norbornyl group is still more preferable, and an adamantyl group is most preferable.

The linear aliphatic hydrocarbon group which may be bonded to the alicyclic hydrocarbon group preferably has 1 to 10 carbon atoms, more preferably 1 to 6 carbon atoms, still more preferably 1 to 4 carbon atoms, and most preferably 1 to 3 carbon atoms. As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅—].

The branched aliphatic hydrocarbon group which may be bonded to the alicyclic hydrocarbon group preferably has 2 to 10 carbon atoms, more preferably 3 to 6 carbon atoms, still more preferably 3 or 4 carbon atoms, and most preferably 3 carbon atoms. As the branched aliphatic hydrocarbon group, branched alkylene groups are preferred, and specific examples include various alkylalkylene groups, including alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group within the alkylalkylene group, a linear alkyl group of 1 to 5 carbon atoms is preferable.

The cyclic hydrocarbon group for R¹⁰¹ may contain a hetero atom such as a heterocycle. Specific examples include lactone-containing cyclic groups represented by the aforementioned general formulae (a2-r-1) to (a2-r-7), the —SO₂— containing cyclic group represented by the aforementioned formulae (a5-r-1) to (a5-r-4), and other heterocyclic groups represented by chemical formulae (r-hr-1) to (r-hr-16) shown below. In the formulae, * indicates the bonding site which bonds to Y¹⁰¹ in formula (b-1).

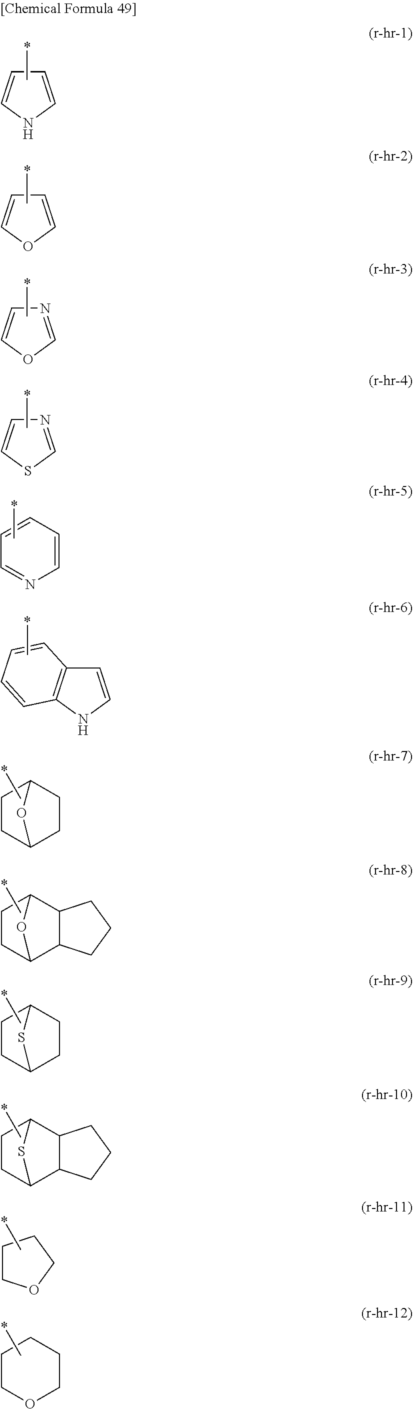

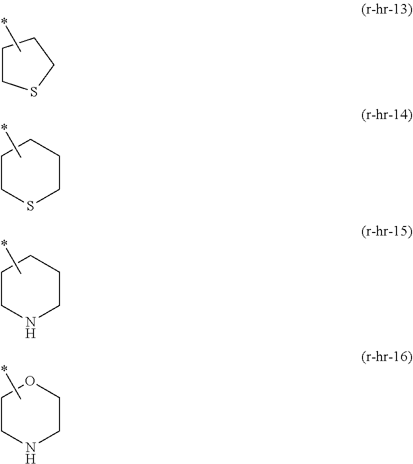

As the substituent for the cyclic group for R¹⁰¹, an alkyl group, an alkoxy group, a halogen atom, a halogenated alkyl group, a hydroxyl group, a carbonyl group, a nitro group or the like can be used. The alkyl group as the substituent is preferably an alkyl group of 1 to 5 carbon atoms, and a methyl group, an ethyl group, a propyl group, an n-butyl group or a tert-butyl group is particularly desirable.

The alkoxy group as the substituent is preferably an alkoxy group having 1 to 5 carbon atoms, more preferably a methoxy group, ethoxy group, n-propoxy group, iso-propoxy group, n-butoxy group or tert-butoxy group, and most preferably a methoxy group or an ethoxy group.

The halogen atom as the substituent is preferably a fluorine atom.

Example of the aforementioned halogenated alkyl group includes a group in which a part or all of the hydrogen atoms within an alkyl group of 1 to 5 carbon atoms (e.g., a methyl group, an ethyl group, a propyl group, an n-butyl group or a tert-butyl group) have been substituted with the aforementioned halogen atoms.

The carbonyl group as the substituent is a group that substitutes a methylene group (—CH₂—) constituting the cyclic hydrocarbon group.

The cyclic hydrocarbon group for R¹⁰¹ may be a condensed cyclic group in which an aliphatic hydrocarbon ring and an aromatic hydrocarbon ring are fused. Examples of the condensed ring include a compound in which one or more aromatic rings are fused with a polycycloalkane having a bridged polycyclic skeleton. Specific examples of the bridged polycycloalkane include a bicycloalkane, such as bicyclo[2.2.1]heptane (norbornane) or bicyclo[2.2.2]octane. As the condensed cyclic group, a group containing a condensed ring in which 2 or 3 aromatic rings are fused with a bicycloalkane is preferable, and a group containing a condensed ring in which 2 or 3 aromatic rings are fused with bicyclo[2.2.2]octane is more preferable. Specific examples of the condensed cyclic group for R¹⁰¹ include condensed cyclic groups represented by formulae (r-br-1) and (r-br-2) shown below. In the formulae, * indicates the bonding site which bonds to Y¹⁰¹ in formula (b-1).

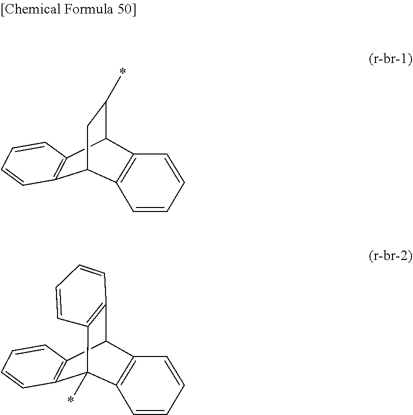 [SMILES: *C1CC2c3ccccc3C1c1ccccc12 ; *C12c3ccccc3C(c3ccccc31)c1ccccc12]

As the substituent for the condensed cyclic group for R¹⁰¹, an alkyl group, an alkoxy group, a halogen atom, a halogenated alkyl group, a hydroxy group, a carbonyl group, a nitro group, an aromatic hydrocarbon group or an alicyclic hydrocarbon group may be mentioned.

The alkyl group, the alkoxy group, the halogen atom and the halogenated alkyl group as the substituent for the condensed cyclic group are the same as defined for the substituents for the cyclic group represented by R¹⁰¹.

Examples of the aromatic hydrocarbon group as the substituent for the condensed cyclic group include a group in which one hydrogen atom has been removed from an aromatic hydrocarbon ring (an aryl group, such as a phenyl group or a naphthyl group); a group in which one hydrogen atom of the aforementioned aromatic hydrocarbon ring has been substituted with an alkylene group (an arylalkyl group such as a benzyl group, a phenethyl group, a 1-naphthylmethyl group, a 2-naphthylmethyl group, a 1-naphthylethyl group, or a 2-naphthylethyl group); and a heterocyclic group represented by any of the aforementioned formulae (r-hr-1) to (r-hr-6).

Examples of the alicyclic hydrocarbon group as the substituent for the condensed cyclic group include a group in which one hydrogen atom has been removed from a monocycloalkane such as cyclopentane or cyclohexane; a group in which one hydrogen atom has been removed from a polycycloalkane such as adamantane, norbornane, isobornane, tricyclodecane or tetracyclododecane; a lactone-containing cyclic group represented by any one of the aforementioned general formulae (a2-r-1) to (a2-r-7); an —SO₂— containing cyclic group represented by any one of the aforementioned general formulae (a5-r-1) to (a5-r-4); and a heterocyclic group represented by any one of the aforementioned formulae (r-hr-7) to (r-hr-16).

Chain alkyl group which may have a substituent:

The chain-like alkyl group for R¹⁰¹ may be linear or branched.

The linear alkyl group preferably has 1 to 20 carbon atoms, more preferably 1 to 15, and most preferably 1 to 10. Specific examples include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group and a docosyl group.

The branched alkyl group preferably has 3 to 20 carbon atoms, more preferably 3 to 15, and most preferably 3 to 10. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

Chain alkenyl group which may have a substituent:

The chain-like alkenyl group for R¹⁰¹ may be linear or branched, and preferably has 2 to 10 carbon atoms, more preferably 2 to 5 carbon atoms, still more preferably 2 to 4 carbon atoms, and most preferably 3 carbon atoms. Examples of linear alkenyl groups include a vinyl group, a propenyl group (an allyl group) and a butynyl group. Examples of branched alkenyl groups include a 1-methylvinyl group, a 2-methylvinyl group, a 1-methylpropenyl group and a 2-methylpropenyl group.

Among these examples, as the chain alkenyl group, a linear alkenyl group is preferable, a vinyl group or a propenyl group is more preferable, and a vinyl group is most preferable.

As the substituent for the chain-like alkyl group or alkenyl group for R¹⁰¹, an alkoxy group, a halogen atom, a halogenated alkyl group, a hydroxyl group, a carbonyl group, a nitro group, an amino group, a cyclic group for R¹⁰¹ or the like can be used.

Among the above examples, as R¹⁰¹, a cyclic group which may have a substituent is preferable, and a cyclic hydrocarbon group which may have a substituent is more preferable. Specifically, a phenyl group, a naphthyl group, a group in which one or more hydrogen atoms have been removed from a polycycloalkane, a lactone-containing cyclic group represented by any one of the aforementioned formula (a2-r-1) to (a2-r-7), and an —SO₂— containing cyclic group represented by any one of the aforementioned formula (a5-r-1) to (a5-r-4).

In formula (b-1), Y¹⁰¹ represents a single bond or a divalent linking group containing an oxygen atom.

In the case where Y¹⁰¹ is a divalent linking group containing an oxygen atom, Y¹⁰¹ may contain an atom other than an oxygen atom. Examples of atoms other than an oxygen atom include a carbon atom, a hydrogen atom, a sulfur atom and a nitrogen atom.

Examples of divalent linking groups containing an oxygen atom include non-hydrocarbon, oxygen atom-containing linking groups such as an oxygen atom (an ether bond; —O—), an ester bond (—C(═O)—O—), an oxycarbonyl group (—O—C(═O)—), an amido bond (—C(═O)—NH—), a carbonyl group (—C(═O)—) and a carbonate bond (—O—C(═O)—O—); and combinations of the aforementioned non-hydrocarbon, hetero atom-containing linking groups with an alkylene group. Furthermore, the combinations may have a sulfonyl group (—SO₂—) bonded thereto. Examples of the divalent linking group containing an oxygen atom include divalent linking groups represented by general formula (y-a1-1) to (y-a1-7) shown below.

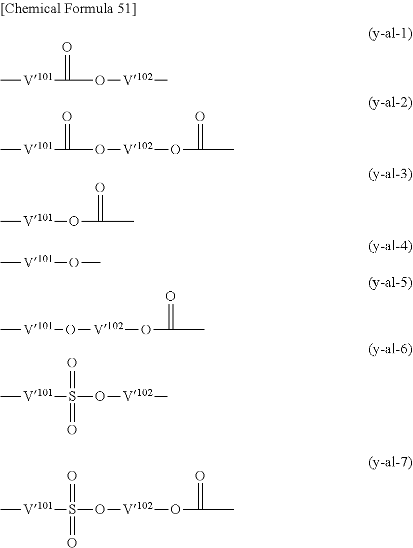

In the formulae, V′¹⁰¹ represents a single bond or an alkylene group of 1 to 5 carbon atoms; V′¹⁰² represents a divalent saturated hydrocarbon group of 1 to 30 carbon atoms.

The divalent saturated hydrocarbon group for V′¹⁰² is preferably an alkylene group of 1 to 30 carbon atoms, more preferably an alkylene group of 1 to 10 carbon atoms, and still more preferably an alkylene group of 1 to 5 carbon atoms.

The alkylene group for V′¹⁰¹ and V′¹⁰² may be a linear alkylene group or a branched alkylene group, and a linear alkylene group is preferable.

Specific examples of the alkylene group for V′¹⁰¹ and V′¹⁰² include a methylene group [—CH₂—]; an alkylmethylene group, such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; an ethylene group [—CH₂CH₂—]; an alkylethylene group, such as —CH(CH₃)CH₂—, —CH(CH₃)CH(CH₃)—, —C(CH₃)₂CH₂—; and —CH(CH₂CH₃)CH₂—; a trimethylene group (n-propylene group) [—CH₂CH₂CH₂—]; an alkyltrimethylene group, such as —CH(CH₃)CH₂CH₂— and —CH₂CH(CH₃)CH₂—; a tetramethylene group [—CH₂CH₂CH₂CH₂—]; an alkyltetramethylene group, such as —CH(CH₃)CH₂CH₂CH₂—, —CH₂CH(CH₃)CH₂CH₂—; and a pentamethylene group [—CH₂CH₂CH₂CH₂CH₂—].

Further, part of methylene group within the alkylene group for V′¹⁰¹ and V′¹⁰² may be substituted with a divalent aliphatic cyclic group of 5 to 10 carbon atoms. The aliphatic cyclic group is preferably a divalent group in which one hydrogen atom has been removed from the cyclic aliphatic hydrocarbon group (monocyclic aliphatic hydrocarbon group or polycyclic aliphatic hydrocarbon group) for Ra′³ in the aforementioned formula (a1-r-1), and a cyclohexylene group, 1,5-adamantylene group or 2,6-adamantylene group is preferable.

Y¹⁰¹ is preferably a divalent linking group containing an ether bond or a divalent linking group containing an ester bond, and groups represented by the aforementioned formulas (y-a1-1) to (y-a1-5) are preferable.

In formula (b-1), V¹⁰¹ represents a single bond, an alkylene group or a fluorinated alkylene group. The alkylene group and the fluorinated alkylene group for V¹⁰¹ preferably has 1 to 4 carbon atoms. Examples of the fluorinated alkylene group for V¹⁰¹ include a group in which part or all of the hydrogen atoms within the alkylene group for V¹⁰¹ have been substituted with fluorine. Among these examples, as V¹⁰¹, a single bond or a fluorinated alkylene group of 1 to 4 carbon atoms is preferable.

In formula (b-1), R¹⁰² represents a fluorine atom or a fluorinated alkyl group of 1 to 5 carbon atoms. R¹⁰² is preferably a fluorine atom or a perfluoroalkyl group of 1 to 5 carbon atoms, and more preferably a fluorine atom.

Specific examples of the anion moiety represented by formula (b-1) include a fluorinated alkylsulfonate anion such as a trifluoromethanesulfonate anion or a perfluorobutanesulfonate anion in the case where Y¹⁰¹ is a single bond; and an anion represented by any one of formulae (an-1) to (an-3) in the case where Y¹⁰¹ represents a divalent linking group containing an oxygen atom.

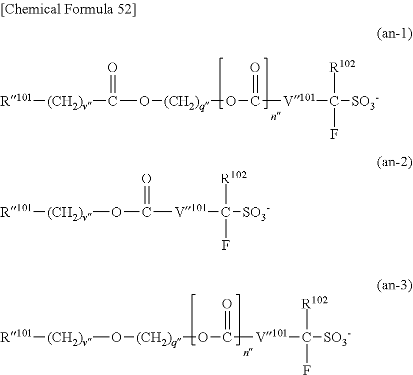

In the formulae, R″¹⁰¹ represents an aliphatic cyclic group which may have a substituent, a monovalent heterocyclic group represented by any of the aforementioned formulae (r-hr-1) to (r-hr-6), a condensed cyclic group represented by the aforementioned formula (r-br-1) or (r-br-2), or a chain-like alkyl group which may have a substituent; R″¹⁰² represents an aliphatic cyclic group which may have a substituent, a condensed cyclic group represented by the aforementioned formula (r-br-1) or (r-br-2), a lactone-containing cyclic group represented by any of the aforementioned formulae (a2-r-1) and (a2-r-3) to (a2-r-7), or a —SO₂-containing cyclic group represented by any of formulae (a5-r-1) to (a5-r-4); R″¹⁰³ represents an aromatic cyclic group which may have a substituent, an aliphatic cyclic group which may have a substituent, or a chain-like alkenyl group which may have a substituent; V″¹⁰¹ represents a single bond, an alkylene group having 1 to 4 carbon atoms or a fluorinated alkylene group having 1 to 4 carbon atoms; R¹⁰² represents a fluorine atom or a fluorinated alkyl group of 1 to 5 carbon atoms; each v″ independently represents an integer of 0 to 3; each q″ independently represents an integer of 0 to 20; and n″ represents 0 or 1.

As the aliphatic cyclic group for R″¹⁰¹, R″¹⁰² and R″¹⁰³ which may have a substituent, the same groups as the cyclic aliphatic hydrocarbon group for R¹⁰¹ in the aforementioned formula (b-1) are preferable. Examples of the substituent include the same substituents as those described above for the cyclic aliphatic hydrocarbon group for R¹⁰¹ in the aforementioned formula (b-1).

As the aromatic cyclic group for R″¹⁰³ which may have a substituent, the same groups as the aromatic hydrocarbon group for the cyclic hydrocarbon group represented by R¹⁰¹ in the aforementioned formula (b-1) is preferable. Examples of the substituent include the same substituents as those described above for the aromatic hydrocarbon group for R¹⁰¹ in the aforementioned formula (b-1).

As the chain alkyl group for R″¹⁰¹ which may have a substituent, the same chain alkyl groups as those described above for R¹⁰¹ in the aforementioned formula (b-1) are preferable.

As the chain alkenyl group for R″¹⁰³ which may have a substituent, the same chain alkenyl groups as those described above for R¹⁰¹ in the aforementioned formula (b-1) are preferable.

Anion Moiety of Component (b-2)

In formula (b-2), R¹⁰⁴ and R¹⁰⁵ each independently represents a cyclic group which may have a substituent, a chain-like alkyl group which may have a substituent or a chain-like alkenyl group which may have a substituent, and is the same as defined for R¹⁰¹ in formula (b-1). R¹⁰⁴ and R¹⁰⁵ may be mutually bonded to form a ring.

As R¹⁰⁴ and R¹⁰⁵, a chain-like alkyl group which may have a substituent is preferable, and a linear or branched alkyl group or a linear or branched fluorinated alkyl group is more preferable.

The chain-like alkyl group preferably has 1 to 10 carbon atoms, more preferably 1 to 7 carbon atoms, and still more preferably 1 to 3 carbon atoms. The smaller the number of carbon atoms of the chain-like alkyl group for R¹⁰⁴ and R¹⁰⁵, the more the solubility in a resist solvent is improved. Further, in the chain alkyl group for R¹⁰⁴ and R¹⁰⁵, the larger the number of hydrogen atoms being substituted with fluorine atom(s), the acid strength becomes stronger, and the transparency to a high energy beam having a wavelength of no more than 250 nm or electron beam may be improved. The fluorination ratio of the chain-like alkyl group is preferably from 70 to 100%, more preferably from 90 to 100%, and it is particularly desirable that the chain-like alkyl group be a perfluoroalkyl group in which all hydrogen atoms are substituted with fluorine atoms.

In formula (b-2), V¹⁰² and V¹⁰³ each independently represents a single bond, an alkylene group or a fluorinated alkylene group, and is the same as defined for V¹⁰¹ in formula (b-1).

In formula (b-2), L¹⁰¹ and L¹⁰² each independently represents a single bond or an oxygen atom.

Anion Moiety of Component (b-3)

In formula (b-3), R¹⁰⁶ to R¹⁰⁸ each independently represents a cyclic group which may have a substituent, a chain-like alkyl group which may have a substituent or a chain-like alkenyl group which may have a substituent, and is the same as defined for R¹⁰¹ in formula (b-1).

In formula (b-3), L¹⁰³ to L¹⁰⁵ each independently represents a single bond, —CO— or —SO₂—.

Among these examples, as the anion moiety of the component (B), an anion for the component (b-1) is preferable. Among these, an anion represented by any one of the aforementioned general formulae (an-1) to (an-3) is more preferable, and an anion represented by the aforementioned general formula (an-1) or (an-2) is more preferable, and an anion represented by the aforementioned general formula (an-2) is still more preferable.

{Cation Moiety}

In formulae (b-1), (b-2) and (b-3), M′^{m+} represents an m-valent onium cation. Among these, a sulfonium cation or an iodonium cation is preferable, m represents an integer of 1 or more.

Preferable examples of the cation moiety ((M′^{m+})_{1/m}) include an organic cation represented by any of general formulae (ca-1) to (ca-5) shown below.

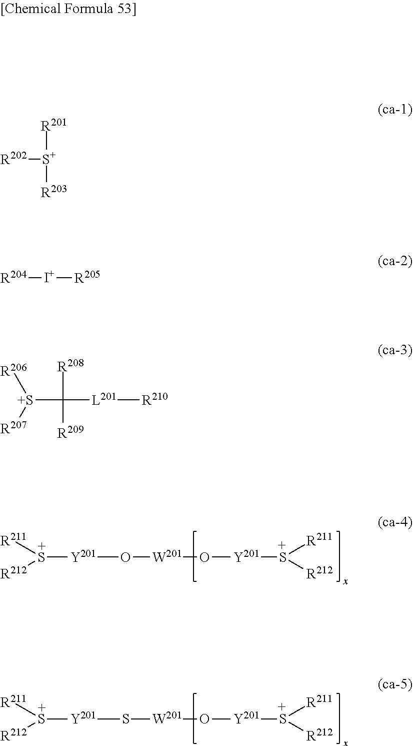

In the formulae, R²⁰¹ to R²⁰⁷, R²¹¹ and R²¹² each independently represents an aryl group which may have a substituent, an alkyl group which may have a substituent, or an alkenyl group which may have a substituent. R²⁰¹ to R²⁰³, R²⁰⁶ and R²⁰⁷, and R²¹¹ and R²¹² may be mutually bonded to form a ring with the sulfur atom. R²⁰⁸ and R²⁰⁹ each independently represents a hydrogen atom or an alkyl group of 1 to 5 carbon atoms. R²¹⁰ represents an aryl group which may have a substituent, an alkyl group which may have a substituent, an alkenyl group which may have a substituent, or an —SO₂— containing cyclic group which may have a substituent. L²⁰¹ represents —C(═O)— or —C(═O)—O—. Each Y²⁰¹ independently represents an arylene group, an alkylene group or an alkenylene group, x represents 1 or 2. W²⁰¹ represents an (x+1) valent linking group.

In formulae (ca-1) to (ca-5), as the aryl group for R²⁰¹ to R²⁰⁷, R²¹¹ and R²¹², an unsubstituted aryl group of 6 to 20 carbon atoms can be mentioned, and a phenyl group or a naphthyl group is preferable.

The alkyl group for R²⁰¹ to R²⁰⁷, R²¹¹ and R²¹² is preferably a chain-like or cyclic alkyl group having 1 to 30 carbon atoms.

The alkenyl group for R²⁰¹ to R²⁰⁷, R²¹¹ and R²¹² preferably has 2 to 10 carbon atoms.

Specific examples of the substituent which R²⁰¹ to R²⁰⁷ and R²¹⁰ to R²¹² may have include an alkyl group, a halogen atom, a halogenated alkyl group, a carbonyl group, a cyano group, an amino group, an aryl group, and groups represented by general formulae (ca-r-1) to (ca-r-7) shown below.

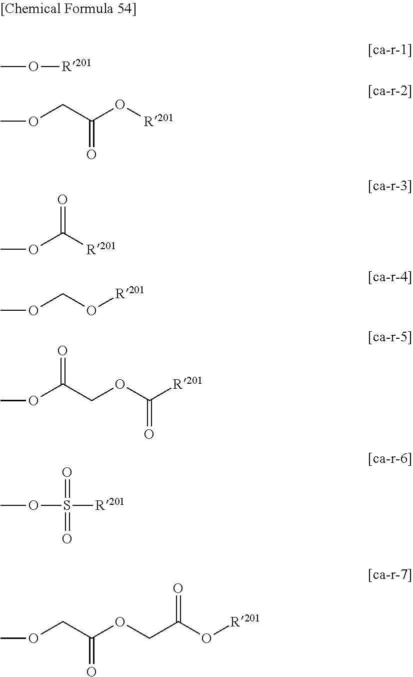

In the formulae, each R′²⁰¹ independently represents a hydrogen atom, a cyclic group which may have a substituent, a chain-like alkyl group which may have a substituent, or a chain-like alkenyl group which may have a substituent.

Cyclic group which may have a substituent:

The cyclic group is preferably a cyclic hydrocarbon group, and the cyclic hydrocarbon group may be either an aromatic hydrocarbon group or an aliphatic hydrocarbon group. An “aliphatic hydrocarbon group” refers to a hydrocarbon group that has no aromaticity. The aliphatic hydrocarbon group may be either saturated or unsaturated, but in general, the aliphatic hydrocarbon group is preferably saturated.

The aromatic hydrocarbon group for R′²⁰¹ is a hydrocarbon group having an aromatic ring. The aromatic hydrocarbon group preferably has 3 to 30 carbon atoms, more preferably 5 to 30 carbon atoms, still more preferably 5 to 20 carbon atoms, still more preferably 6 to 15 carbon atoms, and most preferably 6 to 10 carbon atoms. Here, the number of carbon atoms within a substituent(s) is not included in the number of carbon atoms of the aromatic hydrocarbon group.

Examples of the aromatic ring contained in the aromatic hydrocarbon group for R′²⁰¹ include benzene, fluorene, naphthalene, anthracene, phenanthrene, biphenyl, or an aromatic hetero ring in which part of the carbon atoms constituting the aromatic ring has been substituted with a hetero atom. Examples of the hetero atom within the aromatic hetero rings include an oxygen atom, a sulfur atom and a nitrogen atom.

Specific examples of the aromatic hydrocarbon group for R′²⁰¹ include a group in which 1 hydrogen atom has been removed from the aforementioned aromatic ring (an aryl group, such as a phenyl group or a naphthyl group), and a group in which 1 hydrogen atom of the aforementioned aromatic ring has been substituted with an alkylene group (an arylalkyl group, such as a benzyl group, a phenethyl group, a 1-naphthylmethyl group, a 2-naphthylmethyl group, a 1-naphthylethyl group, or a 2-naphthylethyl group). The alkylene group (alkyl chain within the arylalkyl group) preferably has 1 to 4 carbon atom, more preferably 1 or 2, and most preferably 1.

Examples of the cyclic aliphatic hydrocarbon group for R′²⁰¹ include aliphatic hydrocarbon groups containing a ring in the structure thereof.

As examples of the hydrocarbon group containing a ring in the structure thereof, an alicyclic hydrocarbon group (a group in which one hydrogen atom has been removed from an aliphatic hydrocarbon ring), a group in which the alicyclic hydrocarbon group is bonded to the terminal of the aforementioned chain-like aliphatic hydrocarbon group, and a group in which the alicyclic group is interposed within the aforementioned linear or branched aliphatic hydrocarbon group, can be given.

The alicyclic hydrocarbon group preferably has 3 to 20 carbon atoms, and more preferably 3 to 12 carbon atoms.

The alicyclic hydrocarbon group may be either a polycyclic group or a monocyclic group. As the monocyclic alicyclic hydrocarbon group, a group in which one or more hydrogen atoms have been removed from a monocycloalkane is preferable. The monocycloalkane preferably has 3 to 6 carbon atoms, and specific examples thereof include cyclopentane and cyclohexane. As the polycyclic alicyclic hydrocarbon group, a group in which one or more hydrogen atoms have been removed from a polycycloalkane is preferable, and the polycyclic group preferably has 7 to 30 carbon atoms. Among poly cycloalkanes, a polycycloalkane having a bridged ring polycyclic skeleton, such as adamantane, norbornane, isobornane, tricyclodecane or tetracyclododecene, and a polycycloalkane having a condensed ring polycyclic skeleton, such as a cyclic group having a steroid skeleton are preferable.

Among these examples, as the cyclic aliphatic hydrocarbon group for R′²⁰¹, a group in which one or more hydrogen atoms have been removed from a monocycloalkane or a polycycloalkane is preferable, a group in which one or more hydrogen atoms have been removed from a polycycloalkane is more preferable, an adamantyl group or a norbornyl group is still more preferable, and an adamantyl group is most preferable.

The linear or branched aliphatic hydrocarbon group which may be bonded to the alicyclic hydrocarbon group preferably has 1 to 10 carbon atoms, more preferably 1 to 6 carbon atoms, still more preferably 1 to 4 carbon atoms, and most preferably 1 to 3 carbon atoms.

As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅—].

As the branched aliphatic hydrocarbon group, branched alkylene groups are preferred, and specific examples include various alkylalkylene groups, including alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group within the alkylalkylene group, a linear alkyl group of 1 to 5 carbon atoms is preferable.

The cyclic hydrocarbon group for R′²⁰¹ may contain a hetero atom such as a heterocycle. Specific examples include lactone-containing cyclic groups represented by the aforementioned general formulae (a2-r-1) to (a2-r-7), the —SO₂— containing cyclic group represented by the aforementioned formulae (a5-r-1) to (a5-r-4), and other heterocyclic groups represented by the aforementioned chemical formulae (r-hr-1) to (r-hr-16).

As the substituent for the cyclic group for R′²⁰¹, an alkyl group, an alkoxy group, a halogen atom, a halogenated alkyl group, a hydroxyl group, a carbonyl group, a nitro group or the like can be used.

The alkyl group as the substituent is preferably an alkyl group of 1 to 5 carbon atoms, and a methyl group, an ethyl group, a propyl group, an n-butyl group or a tert-butyl group is particularly desirable.

The alkoxy group as the substituent is preferably an alkoxy group having 1 to 5 carbon atoms, more preferably a methoxy group, ethoxy group, n-propoxy group, iso-propoxy group, n-butoxy group or tert-butoxy group, and most preferably a methoxy group or an ethoxy group.

The halogen atom as the substituent is preferably a fluorine atom.

Example of the aforementioned halogenated alkyl group includes a group in which a part or all of the hydrogen atoms within an alkyl group of 1 to 5 carbon atoms (e.g., a methyl group, an ethyl group, a propyl group, an n-butyl group or a tert-butyl group) have been substituted with the aforementioned halogen atoms.

The carbonyl group as the substituent is a group that substitutes a methylene group (—CH₂—) constituting the cyclic hydrocarbon group.

Chain alkyl group which may have a substituent:

The chain alkyl group for R′²⁰¹ may be linear or branched.

The linear alkyl group preferably has 1 to 20 carbon atoms, more preferably 1 to carbon atoms, and still more preferably 1 to 10 carbon atoms.

The branched alkyl group preferably has 3 to 20 carbon atoms, more preferably 3 to 15 carbon atoms, and still more preferably 3 to 10 carbon atoms. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

Chain alkenyl group which may have a substituent:

The chain alkenyl group for R′²⁰¹ may be linear or branched, and preferably has 2 to 10 carbon atoms, more preferably 2 to 5 carbon atoms, still more preferably 2 to 4 carbon atoms, and most preferably 3 carbon atoms. Examples of linear alkenyl groups include a vinyl group, a 1-propenyl group, a 2-propenyl group (an allyl group) and a butynyl group. Examples of branched alkenyl groups include a 1-methylvinyl group, a 1-methylpropenyl group and a 2-methylpropenyl group.

Among these examples, as the chain alkenyl group, a linear alkenyl group is preferable, a vinyl group or a propenyl group is more preferable, and a vinyl group is most preferable.

As the substituent for the chain-like alkyl group or alkenyl group for R′²⁰¹, an alkoxy group, a halogen atom, a halogenated alkyl group, a hydroxyl group, a carbonyl group, a nitro group, an amino group, a cyclic group for R′²⁰¹ or the like may be used.

As the cyclic group which may have a substituent, the chain alkyl group which may have a substituent and the chain alkenyl group which may have a substituent for R′²⁰¹, the same groups as those described above may be mentioned. As the cyclic group which may have a substituent and chain alkyl group which may have a substituent, the same groups as those described above for the acid dissociable group represented by the aforementioned formula (a1-r-2) may be also mentioned.

Among these examples, as R′²⁰¹, a cyclic group which may have a substituent is preferable, and a cyclic hydrocarbon group which may have a substituent is more preferable. Specifically, for example, a phenyl group, a naphthyl group, a group in which one or more hydrogen atoms have been removed from a polycycloalkane, a lactone-containing cyclic group represented by any one of the aforementioned formula (a2-r-1) to (a2-r-7), and an —SO₂— containing cyclic group represented by any one of the aforementioned formula (a5-r-1) to (a5-r-4) are preferable.

In general formulae (ca-1) to (ca-5), among the above examples, the substituent for R²⁰¹ to R²⁰⁷ and R²¹⁰ to R²¹² is preferably an electron-withdrawing group. The electron-withdrawing group, 1 kind of group may be used, or 2 or more kinds of groups may be used.

Specific examples of the electron-withdrawing group include an acyl group, a methanesulfonyl group (a mesyl group), a halogen atom, a halogenated alkyl group, a halogenated alkoxy group, a halogenated aryloxy group, a halogenated alkylamino group, a halogenated alkylthio group, a cyano group, a nitro group, a dialkylphosphono group, a diarylphosphono group, an alkylsulfonyl group, an arylsulfonyl group, a sulfonyloxy group, acylthio group, a sulfamoyl group, a thiocyanate group and a thiocarbonyl group.

Among the above examples, in terms of improving sensitivity, a fluorine atom or a fluorinated alkyl group is preferable. The fluorinated alkyl group is preferably a fluorinated alkyl group having 1 to 5 carbon atoms.

In the case where the electron-withdrawing group is a fluorine atom or a fluorinated alkyl group, the number of fluorine atoms within the cation moiety of the component (B) is preferably 1 to 9, more preferably 2 to 6, and still more preferably 3 or 4.

As the number of fluorine atoms becomes larger, the better the sensitivity. However, when the number of the fluorine atoms is no more than the upper limit of the above-mentioned preferable range, the solubility of each component of the resist composition in a developing solution may be reliably assured, and deterioration in roughness may be suppressed.

In formulae (ca-1) to (ca-5), in the case where R²⁰¹ to R²⁰³, R²⁰⁶ and R²⁰⁷, or R²¹¹ and R²¹² are mutually bonded to form a ring with the sulfur atom, these groups may be mutually bonded via a hetero atom such as a sulfur atom, an oxygen atom or a nitrogen atom, or a functional group such as a carbonyl group, —SO—, —SO₂—, —SO₃—, —COO—, —CONH— or —N(R_{N})— (R_{N} represents an alkyl group of 1 to 5 carbon atoms). The ring containing the sulfur atom in the skeleton thereof is preferably a 3 to 10-membered ring, and most preferably a 5 to 7-membered ring. Specific examples of the ring formed include a thiophene ring, a thiazole ring, a benzothiophene ring, a dibenzothiophene ring, a 9H-thioxanthene ring, a thioxanthone ring, a thianthrene ring, a phenoxathiin ring, a tetrahydrothiophenium ring, and a tetrahydrothiopyranium ring.

R²⁰⁸ and R²⁰⁹ each independently represents a hydrogen atom or an alkyl group of 1 to 5 carbon atoms, preferably a hydrogen atom or an alkyl group of 1 to 3 carbon atoms, and when R²⁰⁸ and R²⁰⁹ each represents an alkyl group, R²⁰⁸ and R²⁰⁹ may be mutually bonded to form a ring.

R²¹⁰ represents an aryl group which may have a substituent, an alkyl group which may have a substituent, an alkenyl group which may have a substituent, or an SO₂— containing cyclic group which may have a substituent.

Examples of the aryl group for R²¹⁰ include an unsubstituted aryl group of 6 to 20 carbon atoms, and a phenyl group or a naphthyl group is preferable.

As the alkyl group for R²¹⁰, a chain-like or cyclic alkyl group having 1 to 30 carbon atoms is preferable.

The alkenyl group for R²¹⁰ preferably has 2 to 10 carbon atoms. As the —SO₂-containing cyclic group for R²¹⁰ which may have a substituent, an “—SO₂-containing polycyclic group” is preferable, and a group represented by the aforementioned general formula (a5-r-1) is more preferable.

Each Y²⁰¹ independently represents an arylene group, an alkylene group or an alkenylene group.

Examples of the arylene group for Y²⁰¹ include groups in which one hydrogen atom has been removed from an aryl group given as an example of the aromatic hydrocarbon group for R¹⁰¹ in the aforementioned formula (b-1).

Examples of the alkylene group and alkenylene group for Y²⁰¹ include groups in which one hydrogen atom has been removed from the chain-like alkyl group or the chain-like alkenyl group given as an example of R¹⁰¹ in the aforementioned formula (b-1).

In the formula (ca-4), x represents 1 or 2.

W²⁰¹ represents a linking group having a valency of (x+1), i.e., a divalent or trivalent linking group.

As the divalent linking group for W²⁰¹, a divalent hydrocarbon group which may have a substituent is preferable, and as examples thereof, the same hydrocarbon groups (which may have a substituent) as those described above for Ya²¹ in the general formula (a2-1) can be mentioned. The divalent linking group for W²⁰¹ may be linear, branched or cyclic, and cyclic is more preferable. Among these, an arylene group having two carbonyl groups, each bonded to the terminal thereof is preferable. Examples of the arylene group include a phenylene group and a naphthylene group, and a phenylene group is particularly desirable.

As the trivalent linking group for W²⁰¹, a group in which one hydrogen atom has been removed from the aforementioned divalent linking group for W²⁰¹ and a group in which the divalent linking group has been bonded to another divalent linking group can be mentioned. The trivalent linking group for W²⁰¹ is preferably a group in which 2 carbonyl groups are bonded to an arylene group.

Specific examples of preferable cations represented by formula (ca-1) are shown below.

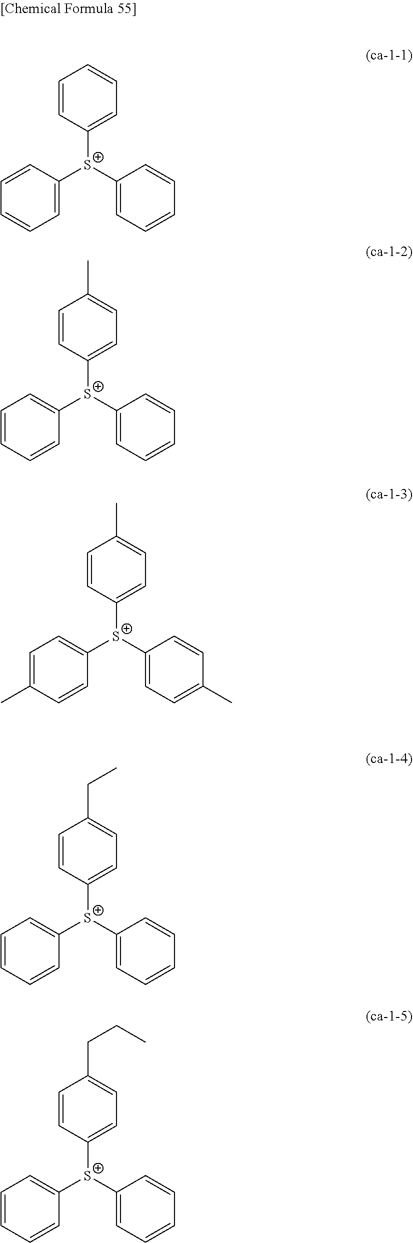

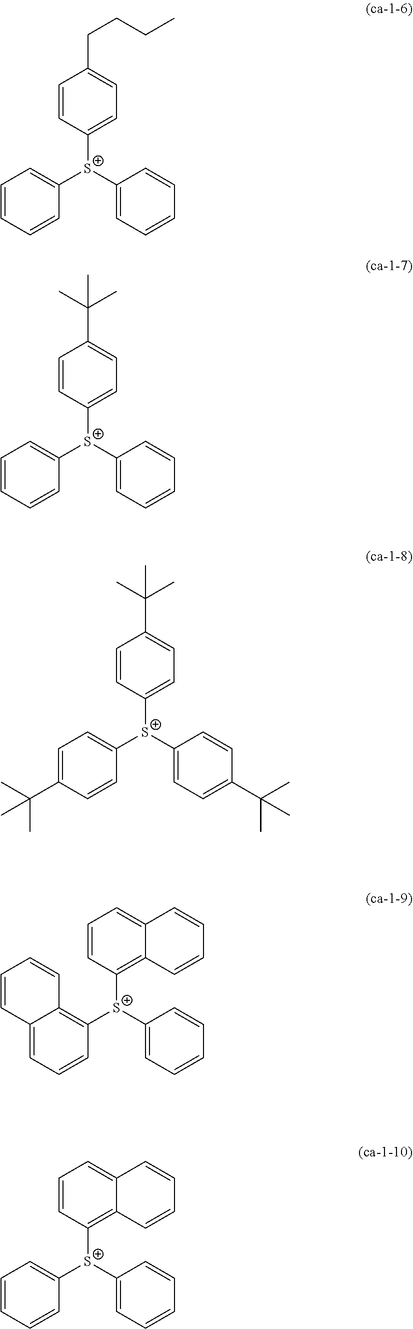

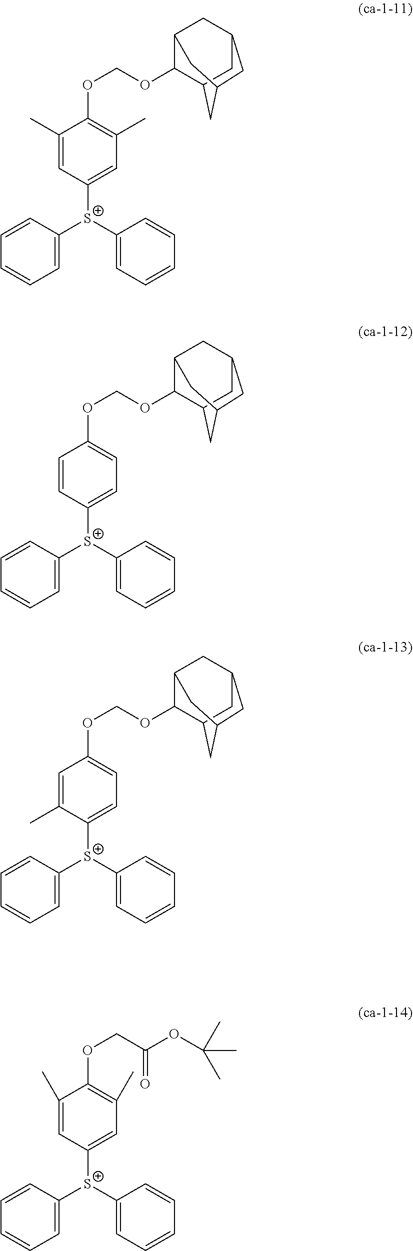

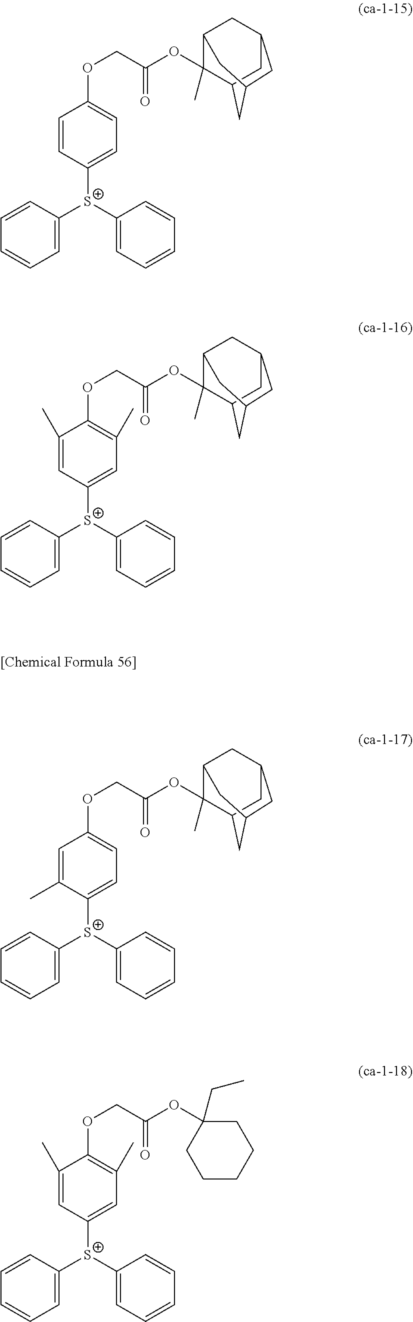

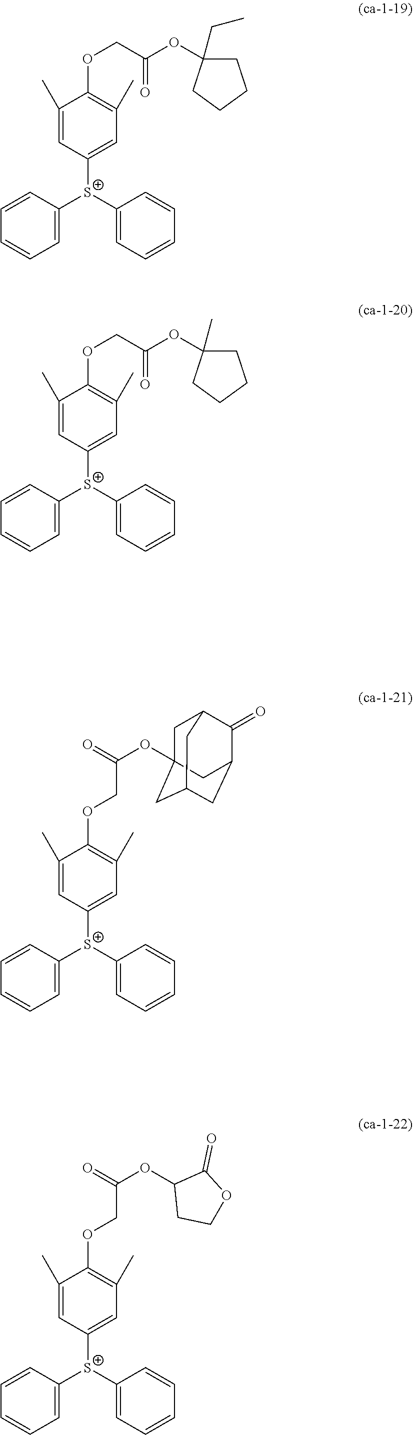

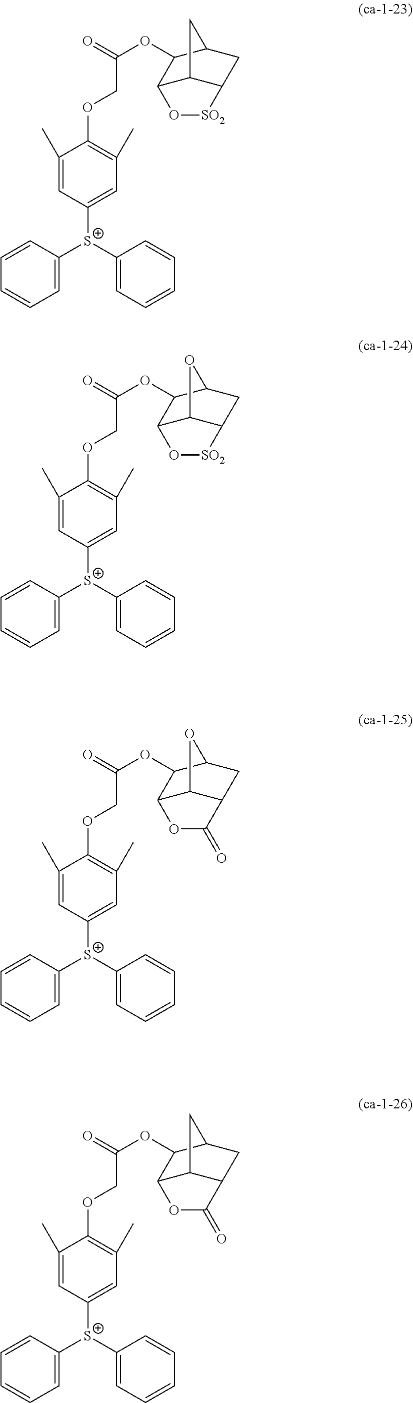

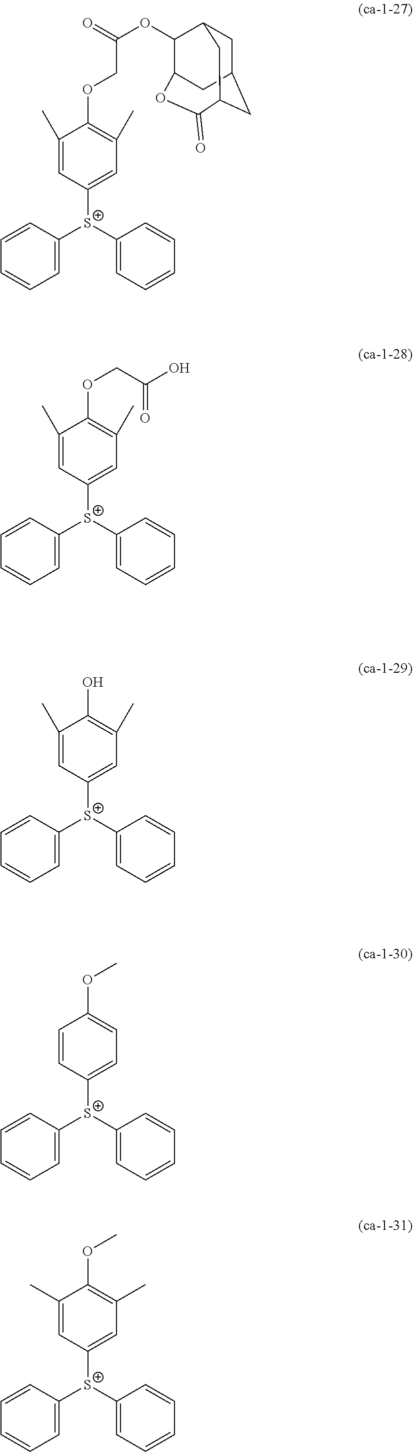

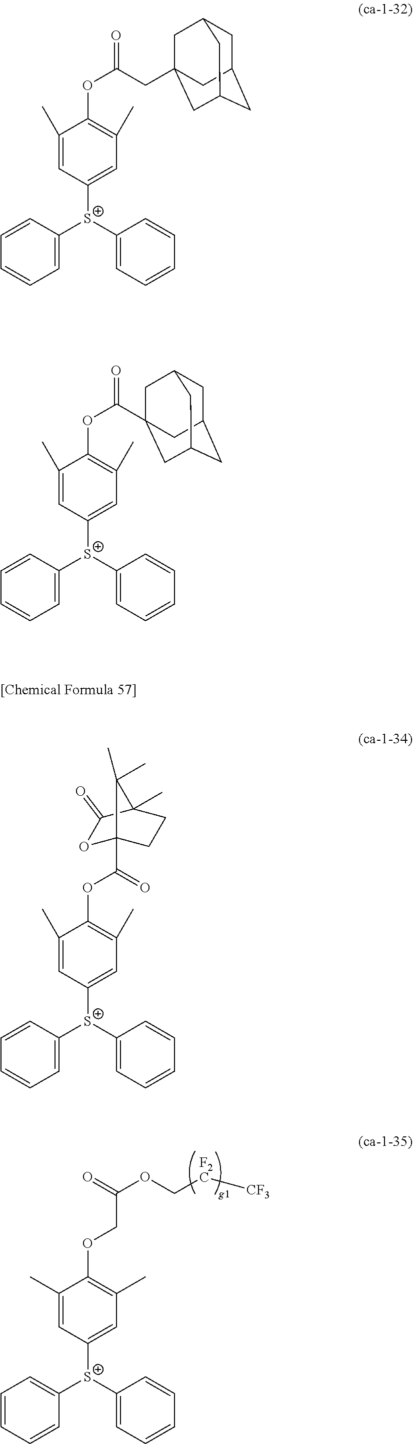

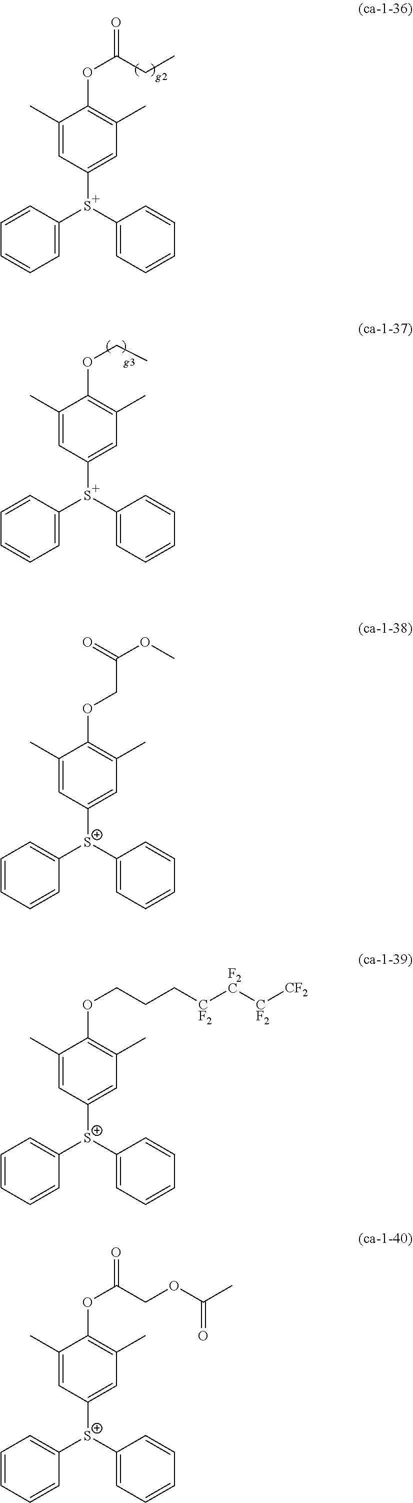

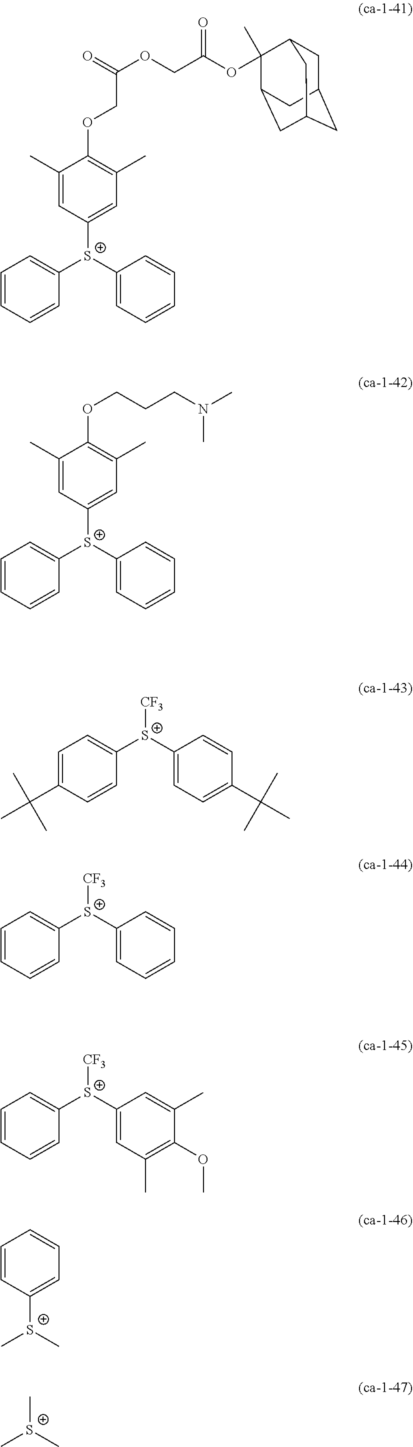

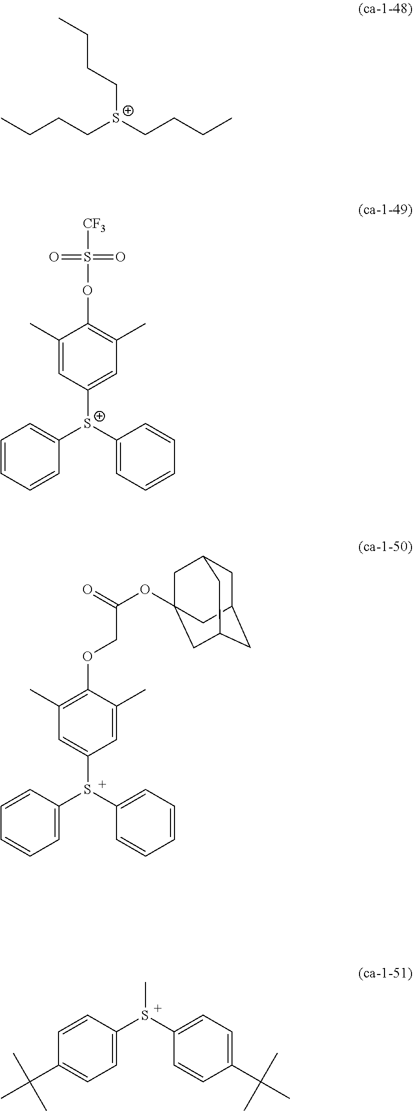

In the formulae, g1, g2 and g3 represent recurring numbers, wherein g1 is an integer of 1 to 5, g2 is an integer of 0 to 20, and g3 is an integer of 0 to 20.

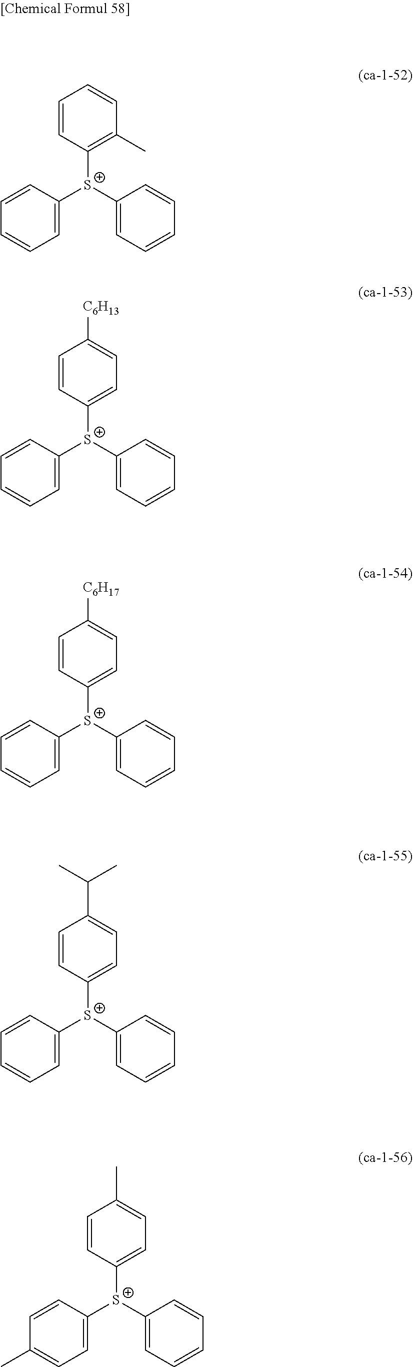

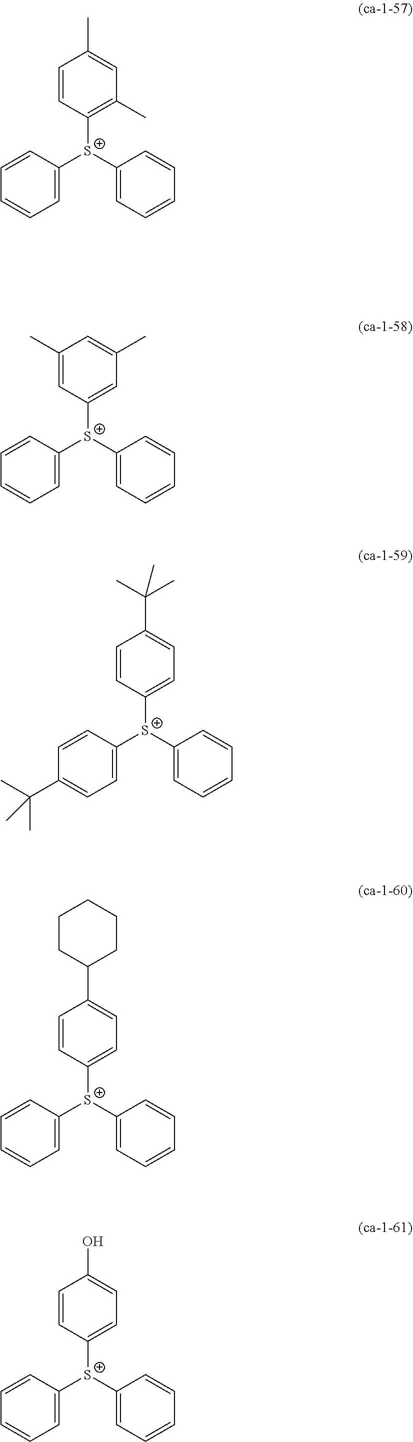

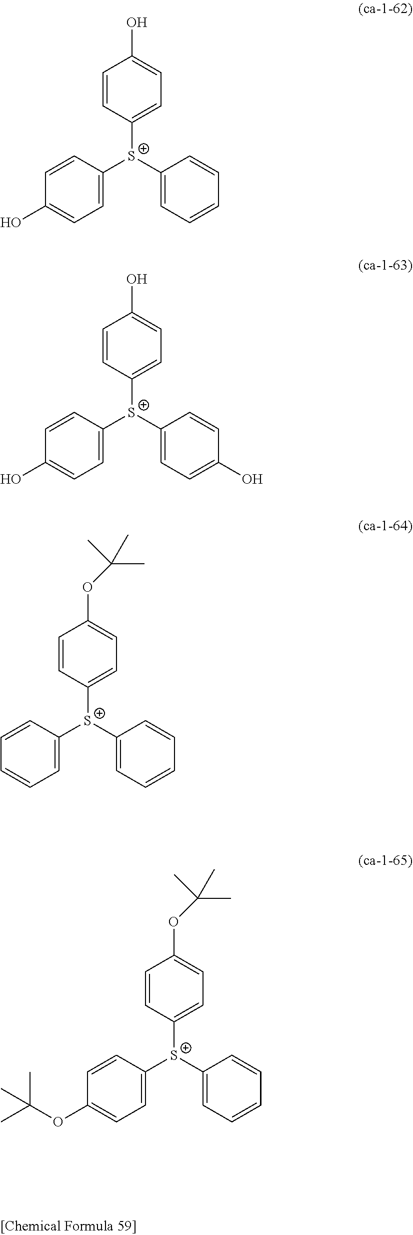

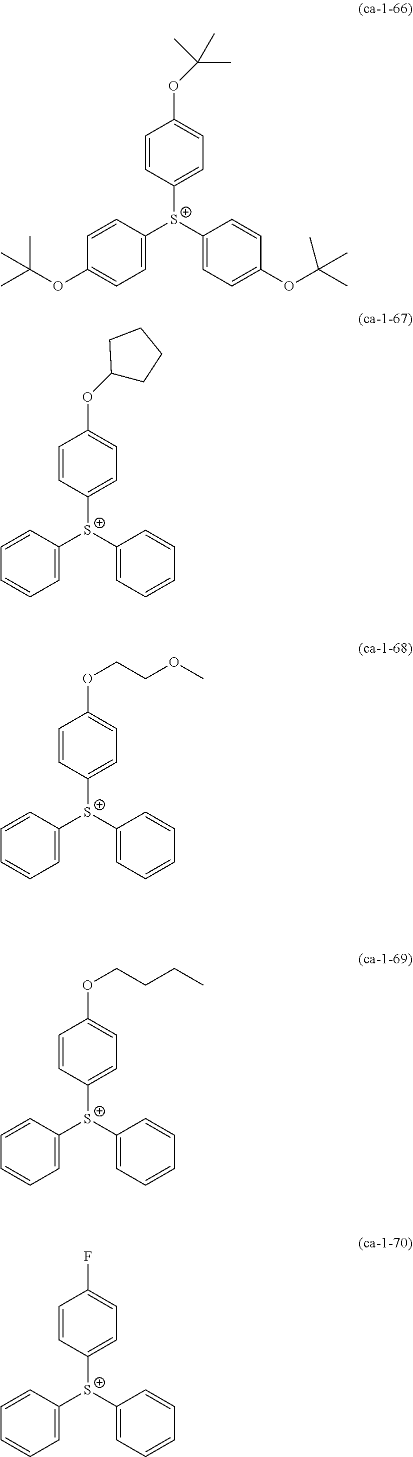

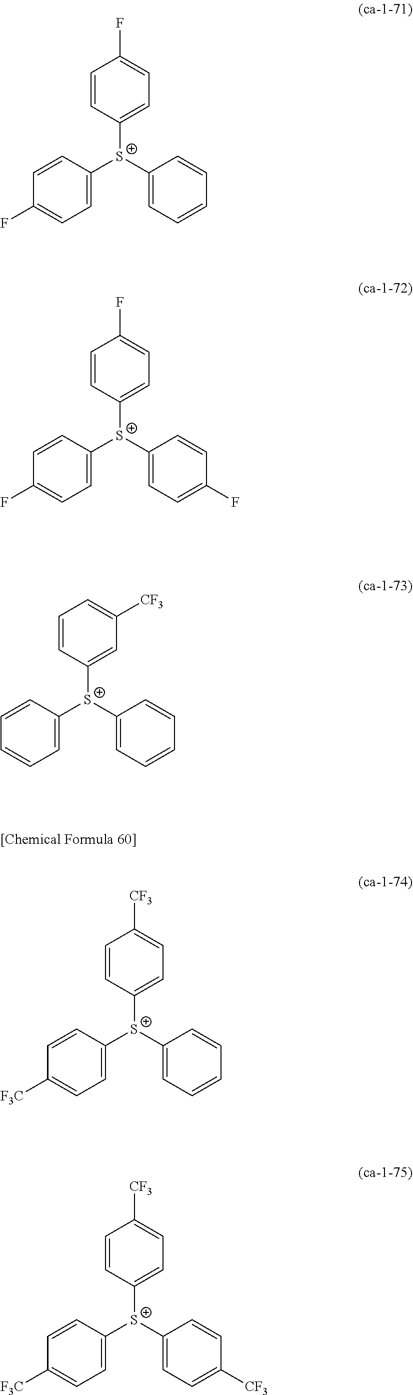

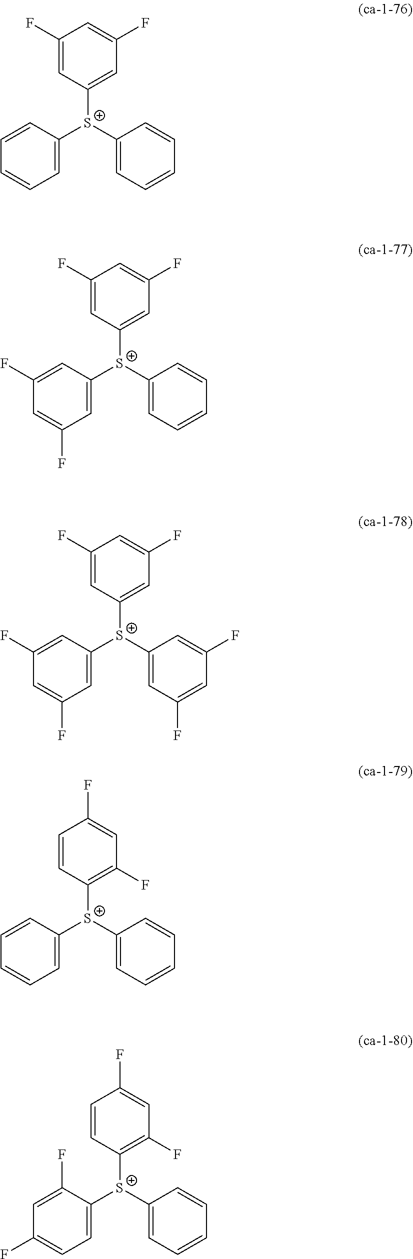

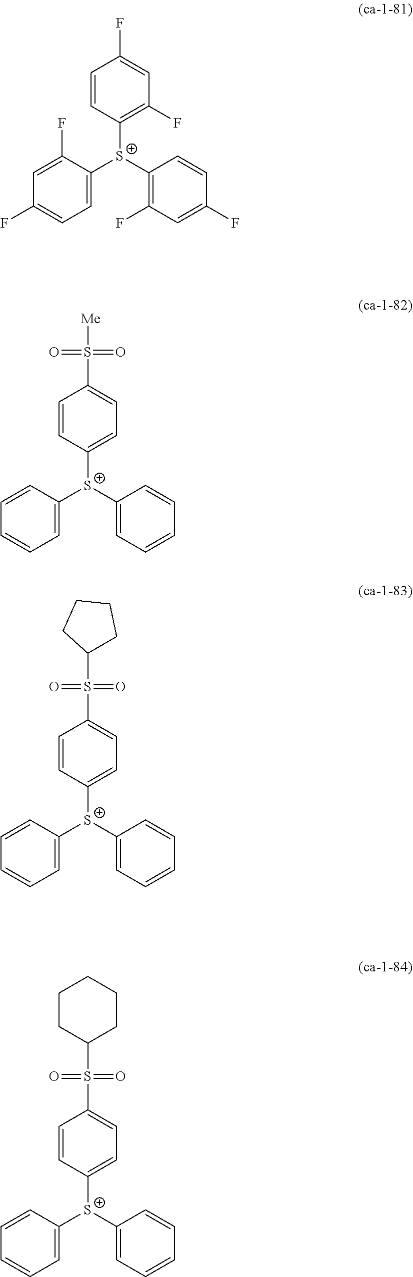

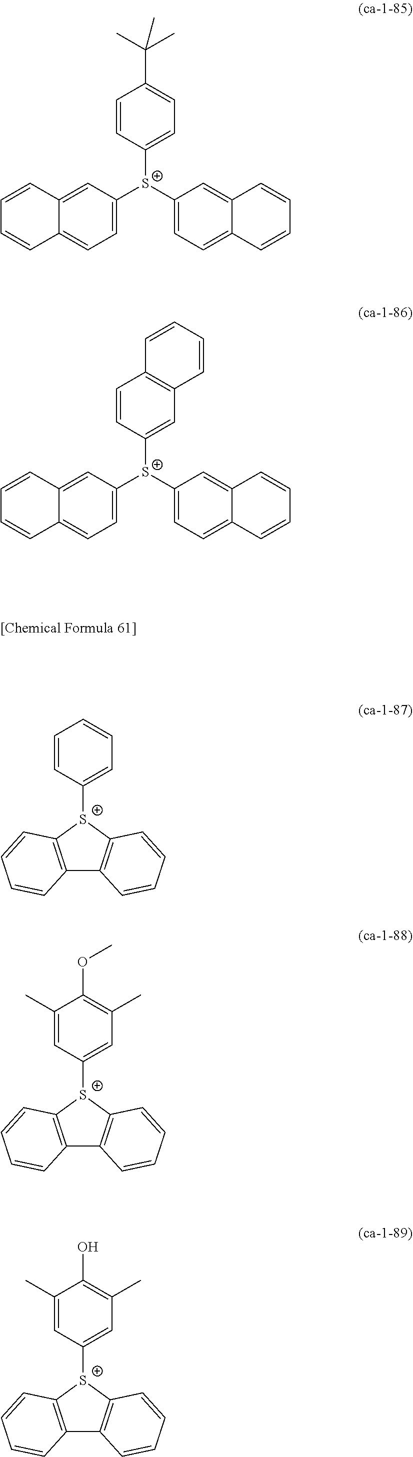

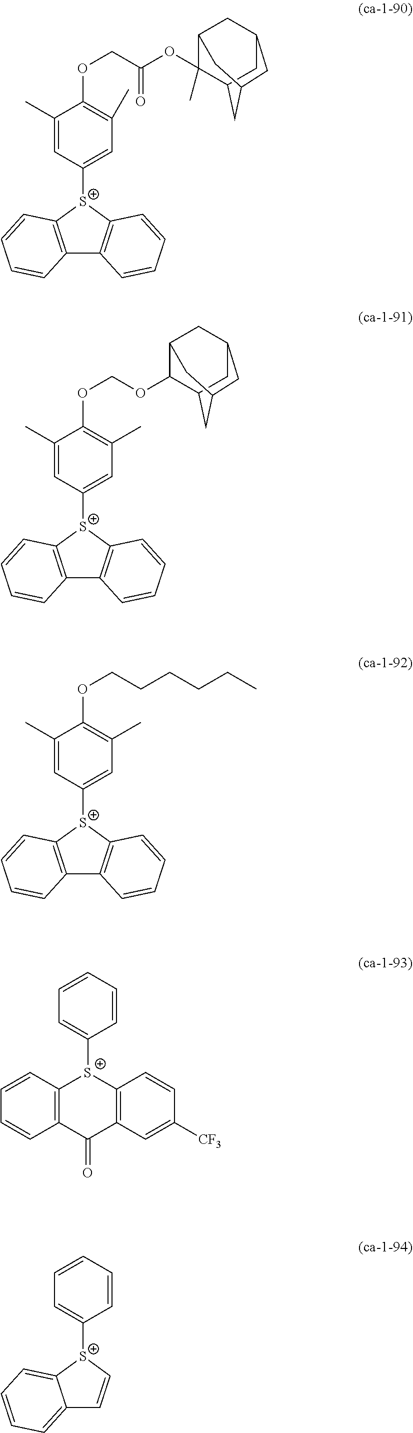

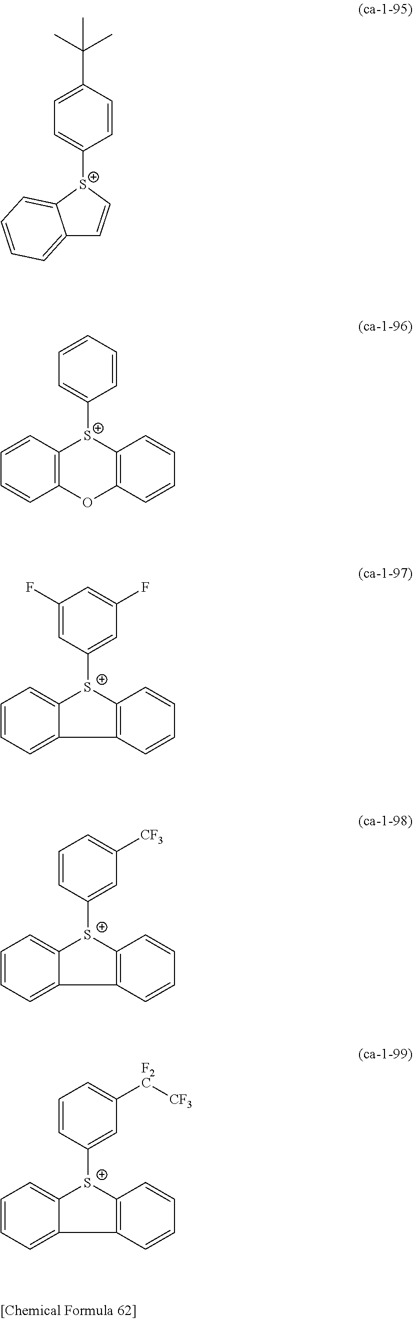

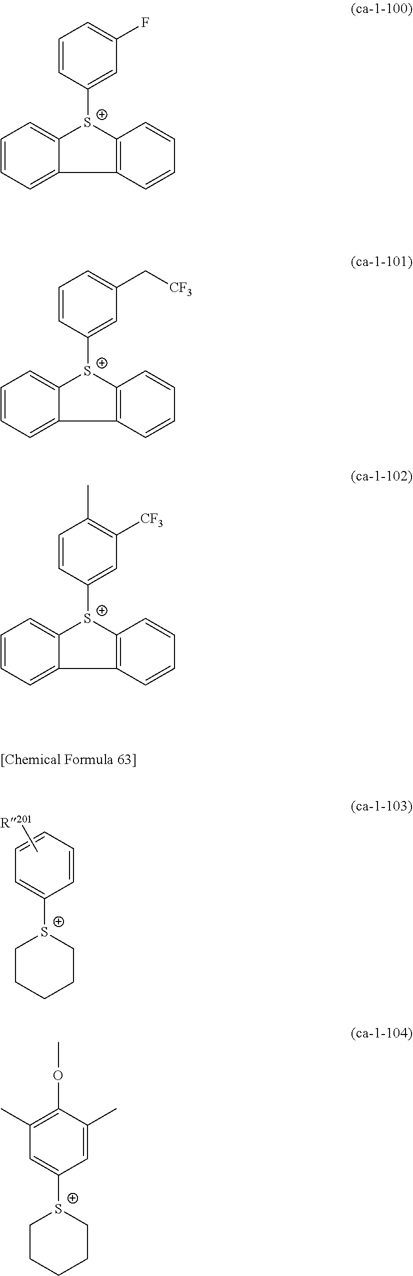

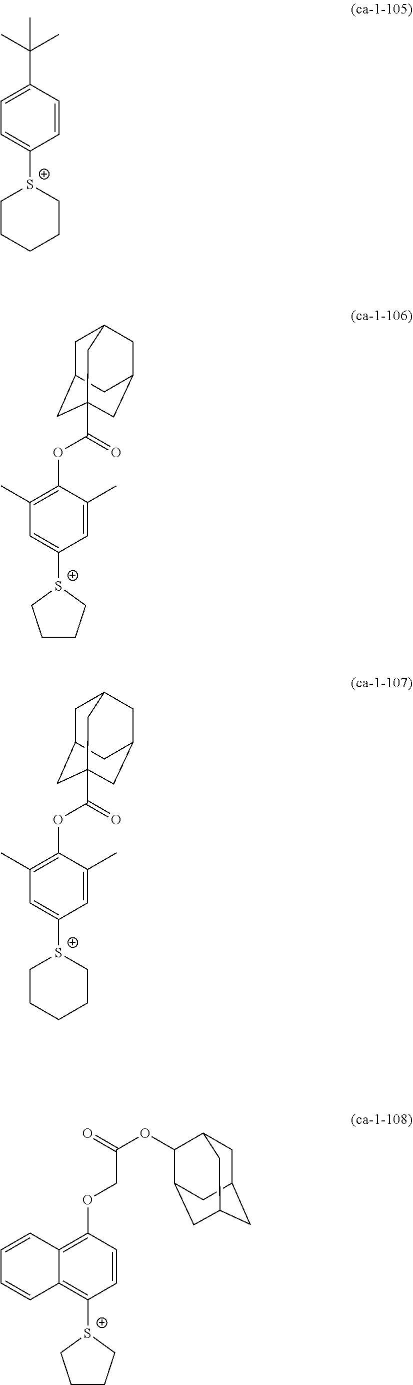

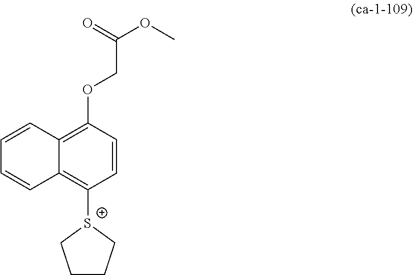

In the formulae, R″²⁰¹ represents a hydrogen atom or a substituent, and as the substituent, the same groups as those described above for substituting R²⁰¹ to R²⁰⁷ and R²¹⁰ to R²¹² can be mentioned.

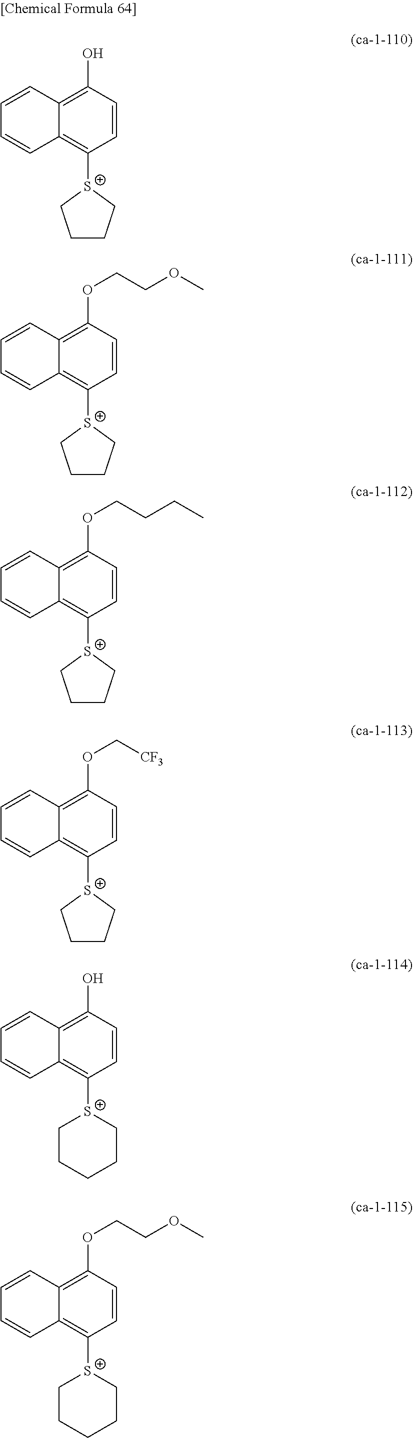 [SMILES: Oc1ccc([S+]2CCCC2)c2ccccc12 ; COCCOc1ccc([S+]2CCCC2)c2ccccc12 ; CCCCOc1ccc([S+]2CCCC2)c2ccccc12 ; FC(F)(F)COc1ccc([S+]2CCCC2)c2ccccc12 ; Oc1ccc([S+]2CCCCC2)c2ccccc12 ; COCCOc1ccc([S+]2CCCCC2)c2ccccc12]

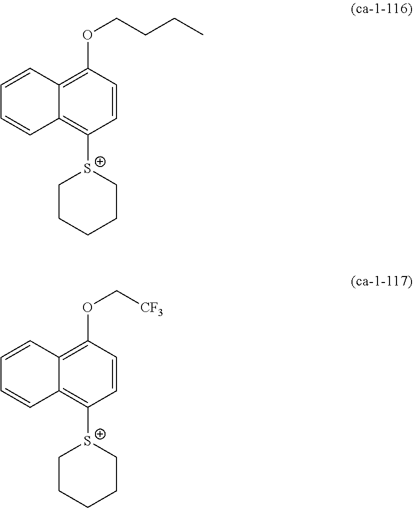 [SMILES: CCCCOc1ccc([S+]2CCCCC2)c2ccccc12 ; FC(F)(F)COc1ccc([S+]2CCCCC2)c2ccccc12]

Specific examples of preferable cations represented by the formula (ca-2) include a diphenyliodonium cation and a bis(4-tert-butylphenyl)iodonium cation.

Specific examples of preferable cations represented by formula (ca-3) include cations represented by formulae (ca-3-1) to (ca-3-6) shown below.

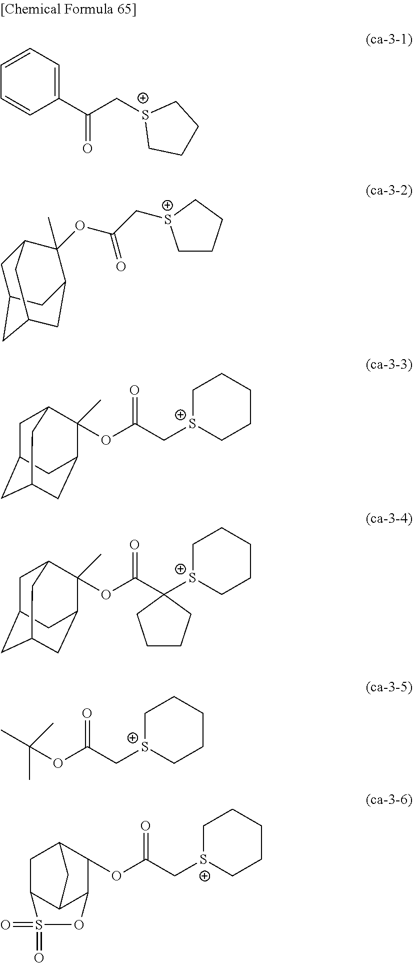 [SMILES: O=C(C[S+]1CCCC1)c1ccccc1 ; CC1(OC(=O)C[S+]2CCCC2)C2CC3CC(C2)CC1C3 ; CC1(OC(=O)C[S+]2CCCCC2)C2CC3CC(C2)CC1C3 ; CC1(OC(=O)C2([S+]3CCCCC3)CCCC2)C2CC3CC(C2)CC1C3 ; CC(C)(C)OC(=O)C[S+]1CCCCC1 ; O=C(C[S+]1CCCCC1)OC1C2CC3C1OS(=O)(=O)C3C2]

Specific examples of preferable cations represented by formula (ca-4) include cations represented by formulae (ca-4-1) and (ca-4-2) shown below.

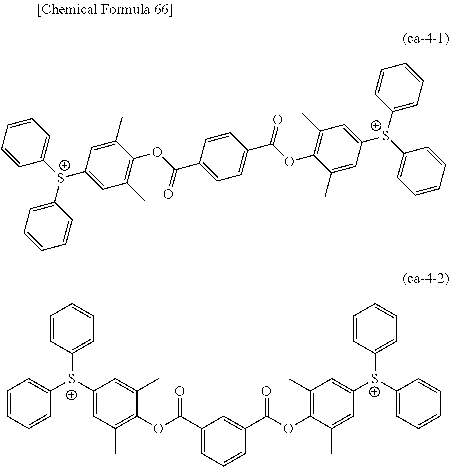 [SMILES: Cc1cc([S+](c2ccccc2)c2ccccc2)cc(C)c1OC(=O)c1ccc(C(=O)Oc2c(C)cc([S+](c3ccccc3)c3ccccc3)cc2C)cc1 ; Cc1cc([S+](c2ccccc2)c2ccccc2)cc(C)c1OC(=O)c1cccc(C(=O)Oc2c(C)cc([S+](c3ccccc3)c3ccccc3)cc2C)c1]

Specific examples of preferable cations represented by formula (ca-5) include cations represented by formulae (ca-5-1) to (ca-5-3) shown below.

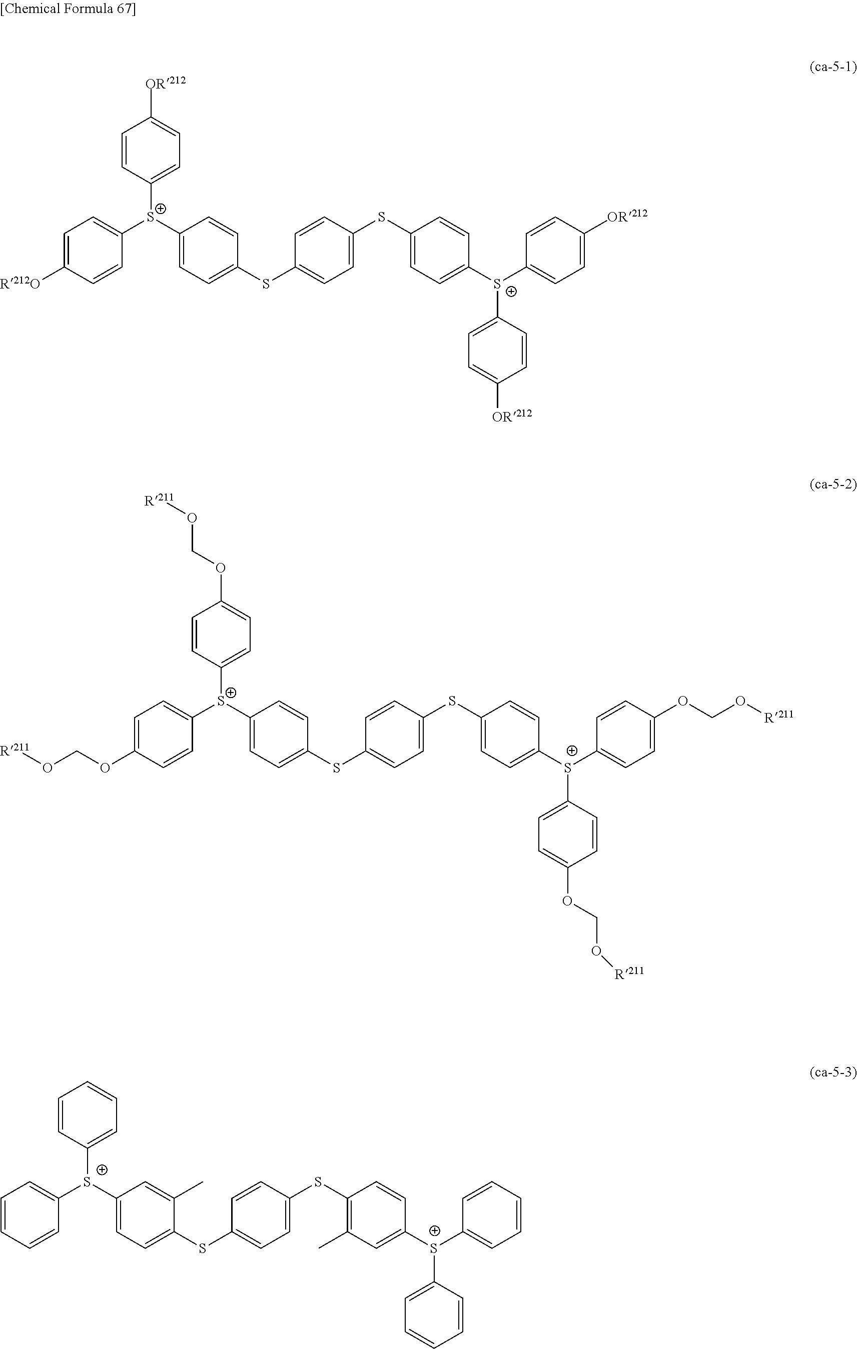

In the resist composition according to the present embodiment, the cation moiety of the component (B) is preferably an organic cation having an electron-withdrawing group, and more preferably an organic cation represented by any one of the aforementioned general formula (ca-1) to (ca-5) which has an electron-withdrawing group.

In the resist composition of the present embodiment, among the above examples, as the cation moiety of the component (B), a cation represented by general formula (ca-1) having an electron-withdrawing group is preferable. Specifically, a cation represented by any one of the aforementioned chemical formulae (ca-1-1) to (ca-1-8), (ca-1-43) to (ca-1-45), (ca-1-70) to (ca-1-84) and (ca-1-97) to (ca-1-102) is preferable, and a cation represented by any one of the aforementioned chemical formulae (ca-1-1), (ca-1-7) or (ca-1-76) is more preferable.

In the resist composition of the present embodiment, among the above examples, as the component (B), a compound represented by general formula (b-1-1) shown below (hereafter, sometimes referred to as “component (b-1-1)”) is preferable.

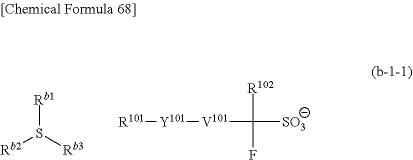

In the formula, R^{b1}, R^{b2} and R^{b3} each independently represents an aryl group which may have a substituent, or 2 or more of R^{b1}, R^{b2} and R^{b3} are mutually bonded with the sulfur atom to form a ring; R¹⁰¹ represent a cyclic group which may have a substituent, a chain alkyl group which may have a substituent or a chain alkenyl group which may have a substituent; R¹⁰² represents a fluorine atom or a fluorinated alkyl group having 1 to 5 carbon atoms; Y¹⁰¹ represents a single bond or a divalent group containing an oxygen atom; and V¹⁰¹ represents a single bond or an oxygen atom.

{Anion Moiety of Component (b-1-1)}

The anion moiety of the component (b-1-1) is the same as defined for the anion moiety of the aforementioned component (b-1).

{Cation Moiety of Component (b-1-1)}

R^{b1} represents an aryl group having an electron-withdrawing group. The aryl group for R^{b1} is the same as defined for the aryl group for R²⁰¹ to R²⁰³ in the aforementioned formula (ca-1).

The aryl group for R^{b1} preferably has an electron-withdrawing group as a substituent. The electron-withdrawing group is the same as defined for the electron withdrawing group for the aryl group represented by R²⁰¹ to R²⁰³ in the aforementioned formula (ca-1). In such a case, the aryl group for R^{b1} may have 1 electron-withdrawing group, or 2 or more electron-withdrawing groups. In the case where the aryl group for R^{b1} has plurality of electron-withdrawing groups, the electron-withdrawing groups may be the same or different.

R^{b2} and R^{b3} each independently represents an aryl group which may have a substituent, or R^{b2} and R^{b3} are mutually bonded with the sulfur atom to form a ring. The aryl group is the same as defined for the aryl group for R^{b1}. The substituent for the aryl group for R^{b2} and R^{b3} is the same as defined for the substituent for the aryl group for R²⁰¹ to R²⁰³ in the aforementioned formula (ca-1).

The ring formed by R^{b2} and R^{b3} being mutually bonded with the sulfur atom in the formula is the same as defined for the ring formed by R²⁰¹ to R²⁰³ being mutually bonded with the sulfur atom in the aforementioned formula (ca-1), and the ring formed is preferably a dibenzothiophene ring.

As the cation moiety of the component (b-1-1), in terms of enhancing sensitivity, it is preferable that R^{b2} and R^{b3} are mutually bonded with the sulfur atom in the formula.

On the other hand, in terms of reducing roughness, it is preferable that R^{b2} and R^{b3} each independently represents an aryl group which may have a substituent, it is more preferable that R^{b2} and R^{b3} each independently represents an aryl group which may have an electron-withdrawing group.

Specific examples of the component (B) are shown below, although the component (B) is not limited to these examples.

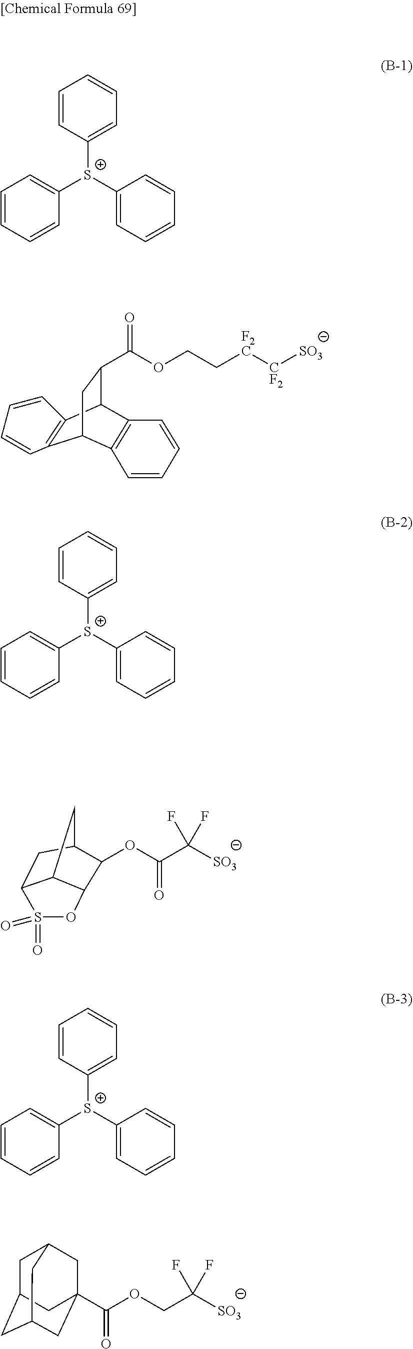

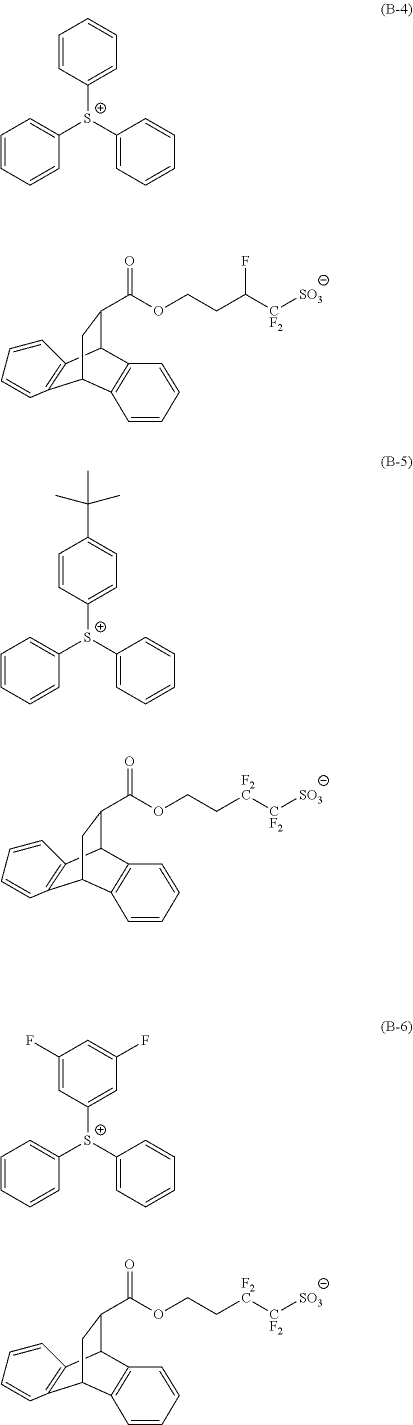

Among the above examples, as the component (B) for the resist composition of the present embodiment, in terms of enhancing sensitivity, an acid generator represented by the aforementioned chemical formula (B-6) is preferable.

On the other hand, in terms of reducing roughness, an acid generator represented by the aforementioned chemical formula (B-1), (B-4) or (B-6) is preferable.

In the resist composition of the present embodiment, as the component (B), one kind of compound may be used, or two or more kinds of compounds may be used in combination.

In the resist composition of the present embodiment, the amount of the component (B) relative to 100 parts by weight of the component (A) is preferably 20 parts by weight or more, more preferably 20 to 60 parts by weight, still more preferably 25 to 55 parts by weight, and most preferably 30 to 50 parts by weight.

When the amount of the component (B) is at least as large as the lower limit of the above-mentioned preferable range, in the formation of a resist pattern, various lithography properties such as sensitivity, resolution, LWR (line width roughness) and pattern shape may be further improved. On the other hand, when the amount of the component (B) is no more than the upper limit of the above-mentioned preferable range, the solubility of the resist composition in a developing solution may be further improved.

<Compound (B0)>

The resist composition according to the present embodiment preferably contains, as the component (B), a compound (B0) represented by general formula (b0) shown below (hereafter, sometimes referred to as “component (B0)”).

[Chemical Formula 70]

Rb⁰-Yb⁰-Vb⁰-SO₃^{⊖}(M^{m⊕})_{1/m} (b0)

In the formula, Rb⁰ represents a condensed cyclic group containing a condensed ring having at least one aromatic ring; Yb⁰ represents a divalent linking group or a single bond; Vb⁰ represents a single bond, an alkylene group or a fluorinated alkylene group; M^{m+} represents a m-valent organic cation; and m represents an integer of 1 or more.

In formula (b0), examples of the condensed cyclic group containing a condensed ring having at least one aromatic ring represented by Rb⁰ include a polycyclic aromatic cyclic group, and a condensed cyclic group containing a condensed ring in which an aliphatic hydrocarbon ring is fused with an aromatic ring.

Examples of the polycyclic aromatic ring within the polycyclic aromatic group for Rb⁰ include fluorene, naphthalene, anthracene, phenanthrene, biphenyl, or an aromatic hetero ring in which part of the carbon atoms constituting any of these aromatic rings have been substituted with a hetero atom. Examples of the hetero atom within the aromatic hetero rings include an oxygen atom, a sulfur atom and a nitrogen atom.

Specific examples of the polycyclic aromatic cyclic group for Rb⁰ a group in which 1 hydrogen atom has been removed from any of the aforementioned aromatic ring (an aryl group, such as a naphthyl group), and a group in which 1 hydrogen atom of the aforementioned aromatic ring has been substituted with an alkylene group (e.g., a phenethyl group, a 1-naphthylmethyl group, a 2-naphthylmethyl group, a 1-naphthylethyl group or a 2naphthylethyl group). The alkylene group (alkyl chain within the arylalkyl group) preferably has 1 to 4 carbon atom, more preferably 1 or 2, and most preferably 1.

The polycyclic aromatic cyclic group for Rb⁰ may have a substituent. Examples of the substituent include an alkyl group, an alkoxy group, a halogen atom, a halogenated alkyl group, a hydroxy group, a carbonyl group and a nitro group.

The alkyl group as the substituent is preferably an alkyl group of 1 to 5 carbon atoms, and a methyl group, an ethyl group, a propyl group, an n-butyl group or a tert-butyl group is particularly desirable.

The alkoxy group as the substituent is preferably an alkoxy group having 1 to 5 carbon atoms, more preferably a methoxy group, ethoxy group, n-propoxy group, iso-propoxy group, n-butoxy group or tert-butoxy group, and most preferably a methoxy group or an ethoxy group.

The halogen atom as the substituent is preferably a fluorine atom.

Example of the aforementioned halogenated alkyl group includes a group in which a part or all of the hydrogen atoms within an alkyl group of 1 to 5 carbon atoms (e.g., a methyl group, an ethyl group, a propyl group, an n-butyl group or a tert-butyl group) have been substituted with the aforementioned halogen atoms.

The carbonyl group as the substituent is a group that substitutes a methylene group (—CH₂—) constituting the cyclic hydrocarbon group.

The condensed cyclic group containing at least 1 aromatic ring for Rb⁰ may be a condensed cyclic group containing a condensed ring in which an aliphatic hydrocarbon ring is fused with an aromatic ring. Examples of the condensed ring include a compound in which one or more aromatic rings are fused with a polycycloalkane having a bridged polycyclic skeleton. Specific examples of the bridged polycycloalkane include a bicycloalkane, such as bicyclo[2.2.1]heptane (norbornane) or bicyclo[2.2.2]octane. As the condensed cyclic group, a group containing a condensed ring in which 2 or 3 aromatic rings are fused with a bicycloalkane is preferable, and a group containing a condensed ring in which 2 or 3 aromatic rings are fused with bicyclo[2.2.2]octane is more preferable. Specific examples of the condensed cyclic group for Rb⁰ include groups represented by formulae (r-br-1) and (r-br-2) shown below. In the formulae, * indicates the bonding site which bonds to Yb⁰ in formula (b0).

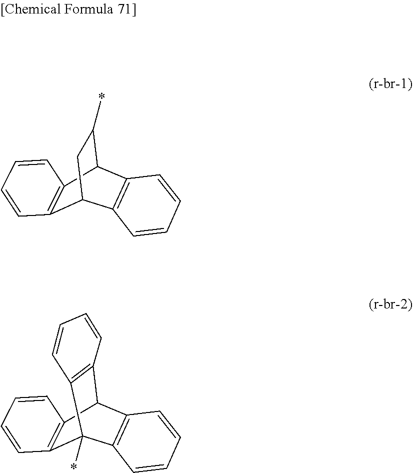 [SMILES: *C1CC2c3ccccc3C1c1ccccc12 ; *C12c3ccccc3C(c3ccccc31)c1ccccc12]

As the substituent for the condensed cyclic group for Rb⁰, an alkyl group, an alkoxy group, a halogen atom, a halogenated alkyl group, a hydroxy group, a carbonyl group, a nitro group, an aromatic hydrocarbon group or an alicyclic hydrocarbon group may be mentioned.

The alkyl group, the alkoxy group, the halogen atom and the halogenated alkyl group as the substituent for the condensed cyclic group are the same as defined for the substituents for the polycyclic aromatic cyclic group represented by Rb⁰.

Examples of the aromatic hydrocarbon group as the substituent for the condensed cyclic group include a group in which 1 hydrogen atom has been removed from an aromatic ring (an aryl group, such as a phenyl group or a naphthyl group), a group in which 1 hydrogen atom of an aromatic ring has been substituted with an alkylene group (e.g., an arylalkyl group, such as a benzyl group, a phenethyl group, a 1-naphthylmethyl group, a 2-naphthylmethyl group, a 1-naphthylethyl group or a 2-naphthylethyl group), and a heterocyclic group represented by any one of the aforementioned formulae (r-hr-1) to (r-hr-6).

Examples of the alicyclic hydrocarbon group as the substituent for the condensed cyclic group include a group in which one hydrogen atom has been removed from a monocycloalkane such as cyclopentane or cyclohexane; a group in which one hydrogen atom has been removed from a polycycloalkane such as adamantane, norbornane, isobornane, tricyclodecane or tetracyclododecane; a lactone-containing cyclic group represented by any of the aforementioned general formulae (a2-r-1) to (a2-r-7); an —SO₂-containing cyclic group represented by any of the aforementioned general formulae (a5-r-1) to (a5-r-4); and a heterocyclic group represented by any of the aforementioned formulae (r-hr-7) to (r-hr-16).

In formula (b0), Y^{b0} represents a divalent linking group or a single bond.

As the divalent linking group for Y^{b0}, a divalent linking group containing an oxygen atom may be given as a preferable example.

The divalent linking group containing an oxygen atom represented by Y^{b0} is the same as defined for the divalent linking group containing an oxygen atom represented by Y¹⁰¹ in the aforementioned formula (b-1-1).

In formula (b0), V^{b0} represents an alkylene group, a fluorinated alkylene group or a single bond.

The alkylene group or the fluorinated alkylene group for V^{b0} preferably has 1 to 4 carbon atoms, and more preferably 1 to 3 carbon atoms. Examples of the fluorinated alkyl group for V^{b0} include a group in which part or all of the hydrogen atoms within an alkylene group have been substituted with fluorine. Among these examples, as V^{b0}, an alkylene group having 1 to 4 carbon atoms, a fluorinated alkylene group having 1 to 4 carbon atoms or a single bond is preferable.

In the present embodiment, in terms of reducing roughness and improving resolution, the component (B0) preferably contains a compound represented by general formula (b0-1) shown below (hereafter, sometimes referred to as “component (B01)”).

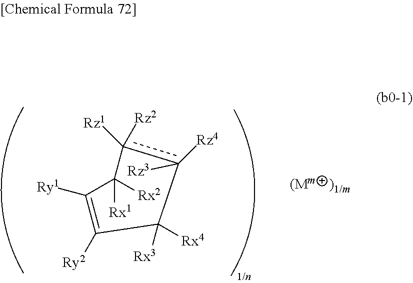

In the formula, Rx¹ to Rx⁴ each independently represents a hydrogen atom or a hydrocarbon group which may have a substituent, or two or more of Rx¹ to Rx⁴ may be mutually bonded to form a ring structure; Ry¹ and Ry² each independently represents a hydrogen atom or a hydrocarbon group which may have a substituent, or Ry¹ and Ry² may be mutually bonded to form a ring structure;

[symbol]

[Chemical Formula 73]

represents a double bond or a single bond; Rz¹ to Rz⁴ each independently represents, where valence allows, a hydrogen atom or a hydrocarbon group which may have a substituent, or two or more of Rz¹ to Rz⁴ may be mutually bonded to form a ring structure; provided that 2 or more of Rx¹ to Rx⁴, Ry¹ and Ry², or 2 or more of Rz¹ to Rz⁴ are mutually bonded to form an aromatic ring; at least one of Rx¹ to Rx⁴, Ry¹, Ry² and Rz¹ to Rz⁴ has an anionic group represented by general formula (b0-r-an1) shown below, and the whole anion moiety is an n-valent anion; n represents an integer of 1 or more; m represents an integer of 1 or more; and M^{m+} represents an organic cation having a valency of m.

[Chemical Formula 74]

*—Yb⁰-Vb⁰-SO₃^{⊖} (b0-r-an1)

In the formula, Yb⁰ represents a divalent linking group or a single bond; Vb⁰ represents a single bond, an alkylene group or a fluorinated alkylene group; and * represents a bonding site.

Anion Moiety

In formula (b0-1), Rx¹ to Rx⁴ each independently represents a hydrocarbon group which may have a substituent or a hydrogen atom, or alternatively, two or more of Rx¹ to Rx⁴ may be bonded to each other to form a ring structure.

Ry¹ and Ry² each independently represents a hydrocarbon group which may have a substituent or a hydrogen atom, or alternatively, Ry¹ and Ry² may be bonded to each other to form a ring structure.

Rz¹ to Rz⁴ each independently represents, where valence allows, a hydrogen atom or a hydrocarbon group which may have a substituent, or two or more of Rz¹ to Rz⁴ may be mutually bonded to form a ring structure.

The hydrocarbon group as Rx¹ to Rx⁴, Ry¹, Ry² and Rz¹ to Rz⁴ may be an aliphatic hydrocarbon group or an aromatic hydrocarbon group, or may be a cyclic hydrocarbon group or a chain-like hydrocarbon group.

For example, examples of the hydrocarbon group, which may have a substituent as Rx¹ to Rx⁴, Ry¹, Ry² and Rz¹ to Rz⁴, include a cyclic group which may have a substituent, a chain-like alkyl group which may have a substituent, or a chain-like alkenyl group which may have a substituent.

Cyclic group which may have a substituent:

The cyclic group is preferably a cyclic hydrocarbon group, and the cyclic hydrocarbon group may be either an aromatic hydrocarbon group or an aliphatic hydrocarbon group. An “aliphatic hydrocarbon group” refers to a hydrocarbon group that has no aromaticity. The aliphatic hydrocarbon group may be either saturated or unsaturated, but in general, the aliphatic hydrocarbon group is preferably saturated. The cyclic hydrocarbon group as Rx¹ to Rx⁴, Ry¹, Ry² and Rz¹ to Rz⁴ may contain a hetero atom as in a case of a heterocyclic ring and the like.

The aromatic hydrocarbon group as Rx¹ to Rx⁴, Ry¹, Ry² and Rz¹ to Rz⁴ is a hydrocarbon group having an aromatic ring. The aromatic hydrocarbon group preferably has 3 to 30 carbon atoms, more preferably 5 to 30 carbon atoms, still more preferably 5 to carbon atoms, still more preferably 6 to 15 carbon atoms, and most preferably 6 to 12 carbon atoms. Here, the number of carbon atoms within a substituent(s) is not included in the number of carbon atoms of the aromatic hydrocarbon group.

Specific examples of the aromatic ring contained in the aromatic hydrocarbon group as Rx¹ to Rx⁴, Ry¹, Ry² and Rz¹ to Rz⁴ include benzene, fluorene, naphthalene, anthracene, phenanthrene, biphenyl, or an aromatic heterocyclic ring in which some carbon atoms constituting any of these aromatic rings have been substituted with hetero atoms. Examples of the hetero atom within the aromatic hetero rings include an oxygen atom, a sulfur atom and a nitrogen atom. Specific examples of the aromatic ring contained in the aromatic hydrocarbon group as Rx¹ to Rx⁴, Ry¹, Ry² and Rz¹ to Rz⁴ include benzene, fluorene, naphthalene, anthracene, phenanthrene, biphenyl, an aromatic heterocyclic ring in which a part of carbon atoms constituting the aromatic ring is substituted with hetero atoms, and the like, from the viewpoint of compatibility with the component (A).

Specific examples of the aromatic hydrocarbon group as Rx¹ to Rx⁴, Ry¹, Ry² and Rz¹ to Rz⁴ include a group in which one hydrogen atom has been removed from the above-described aromatic ring (an aryl group such as a phenyl group, a naphthyl group or the like), and a group in which one hydrogen atom in the aromatic ring has been substituted with an alkylene group (an arylalkyl group such as a benzyl group, a phenethyl group, a 1-naphthylmethyl group, a 2-naphthylmethyl group, 1-naphthylethyl group, a 2-naphthylethyl group or the like). The alkylene group (alkyl chain within the arylalkyl group) preferably has 1 to 4 carbon atom, more preferably 1 or 2, and most preferably 1.

Examples of the cyclic aliphatic hydrocarbon group as Rx¹ to Rx⁴, Ry¹, Ry² and Rz¹ to Rz⁴ include aliphatic hydrocarbon groups containing a ring in the structure thereof.

As examples of the hydrocarbon group containing a ring in the structure thereof, an alicyclic hydrocarbon group (a group in which one hydrogen atom has been removed from an aliphatic hydrocarbon ring), a group in which the alicyclic hydrocarbon group is bonded to the terminal of the aforementioned chain-like aliphatic hydrocarbon group, and a group in which the alicyclic group is interposed within the aforementioned linear or branched aliphatic hydrocarbon group, can be given.

The alicyclic hydrocarbon group preferably has 3 to 20 carbon atoms, and more preferably 3 to 12 carbon atoms.

The alicyclic hydrocarbon group may be either a polycyclic group or a monocyclic group. As the monocyclic alicyclic hydrocarbon group, a group in which one or more hydrogen atoms have been removed from a monocycloalkane is preferable. The monocycloalkane preferably has 3 to 6 carbon atoms, and specific examples thereof include cyclopentane and cyclohexane. As the polycyclic alicyclic hydrocarbon group, a group in which one or more hydrogen atoms have been removed from a polycycloalkane is preferable, and the polycyclic group preferably has 7 to 30 carbon atoms. Among polycycloalkanes, a polycycloalkane having a bridged ring polycyclic skeleton, such as adamantane, norbornane, isobornane, tricyclodecane or tetracyclododecene, and a polycycloalkane having a condensed ring polycyclic skeleton, such as a cyclic group having a steroid skeleton are preferable.

Among these examples, as the cyclic aliphatic hydrocarbon group as Rx¹ to Rx⁴, Ry¹, Ry² and Rz¹ to Rz⁴, a group in which one or more hydrogen atoms have been removed from a monocycloalkane or a poly cycloalkane is preferable, a group in which one hydrogen atom has been removed from a monocycloalkane is more preferable, and a group in which one hydrogen atom has been removed from cyclopentane or cyclohexane is particularly preferable.

The linear aliphatic hydrocarbon group which may be bonded to the alicyclic hydrocarbon group preferably has 1 to 10 carbon atoms, more preferably 1 to 6 carbon atoms, still more preferably 1 to 4 carbon atoms, and most preferably 1 to 3 carbon atoms. As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅—].

The branched aliphatic hydrocarbon group which may be bonded to the alicyclic hydrocarbon group preferably has 2 to 10 carbon atoms, more preferably 3 to 6 carbon atoms, still more preferably 3 or 4 carbon atoms, and most preferably 3 carbon atoms. As the branched aliphatic hydrocarbon group, branched alkylene groups are preferred, and specific examples include various alkylalkylene groups, including alkylmethylene groups such as —CH(CH₃>, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group within the alkylalkylene group, a linear alkyl group of 1 to 5 carbon atoms is preferable.

Further, examples of the cyclic group as Rx¹ to Rx⁴, Ry¹, Ry² and Rz¹ to Rz⁴ also include —COOR^{XYZ} and —OC(═O)R^{XYZ}, in which R^{XYZ} is a lactone-containing cyclic group, a carbonate-containing cyclic group or —SO₂-containing cyclic group.

Examples of the substituent for the cyclic group as Rx¹ to Rx⁴, Ry¹, Ry² and Rz¹ to Rz⁴ include an alkyl group, an alkoxy group, a halogen atom, a halogenated alkyl group, a hydroxyl group, a nitro group, a carbonyl group and the like.

The alkyl group as the substituent is preferably an alkyl group of 1 to 5 carbon atoms, and a methyl group, an ethyl group, a propyl group, an n-butyl group or a tert-butyl group is particularly desirable.

The alkoxy group as the substituent is preferably an alkoxy group having 1 to 5 carbon atoms, more preferably a methoxy group, ethoxy group, n-propoxy group, iso-propoxy group, n-butoxy group or tert-butoxy group, and most preferably a methoxy group or an ethoxy group.

Examples of the halogen atom for the substituent include a fluorine atom, a chlorine atom, a bromine atom and an iodine atom, and a fluorine atom is preferable.

Example of the aforementioned halogenated alkyl group includes a group in which a part or all of the hydrogen atoms within an alkyl group of 1 to 5 carbon atoms (e.g., a methyl group, an ethyl group, a propyl group, an n-butyl group or a tert-butyl group) have been substituted with the aforementioned halogen atoms.

The carbonyl group as the substituent is a group that substitutes a methylene group (—CH₂—) constituting the cyclic hydrocarbon group.

Among these, as the substituent in the cyclic group as Rx¹ to Rx⁴, Ry¹, Ry² and Rz¹ to Rz⁴, an alkyl group, a halogen atom, a halogenated alkyl group and the like are preferable from the viewpoint of compatibility with the component (A). An Alkyl group is more preferable.

Chain alkyl group which may have a substituent:

The chain alkyl group as Rx¹ to Rx⁴, Ry¹, Ry² and Rz¹ to Rz⁴ may be linear or branched.

The linear alkyl group preferably has 1 to 20 carbon atoms, more preferably 1 to carbon atoms, and still more preferably 1 to 10 carbon atoms. Specific examples include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group and a docosyl group.

The branched alkyl group preferably has 3 to 20 carbon atoms, more preferably 3 to 15 carbon atoms, and still more preferably 3 to 10 carbon atoms. Specific examples thereof include a 1-methylethyl group, a 1,1-dimethylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain alkenyl group which may have a substituent:

Such a chain alkenyl group as Rx¹ to Rx⁴, Ry¹, Ry² and Rz¹ to Rz⁴ may be linear or branched, and the number of carbon atoms thereof is preferably in a range of 2 to 10, more preferably in a range of 2 to 5, still more preferably in a range of 2 to 4, and particularly preferably 3. Examples of linear alkenyl groups include a vinyl group, a propenyl group (an allyl group) and a butynyl group. Examples of branched alkenyl groups include a 1-methylvinyl group, a 2-methylvinyl group, a 1-methylpropenyl group and a 2-methylpropenyl group. Among these examples, as the chain alkenyl group, a linear alkenyl group is preferable, a vinyl group or a propenyl group is more preferable, and a vinyl group is most preferable.

As the substituent for the chain-like alkyl group or alkenyl group as Rx¹ to Rx⁴, Ry¹, Ry² and Rz¹ to Rz⁴, an alkoxy group, a halogen atom (a fluorine atom, a chlorine atom, a bromine atom, an iodine atom etc.), a halogenated alkyl group, a hydroxyl group, a carbonyl group, a nitro group, an amino group, a cyclic group as Rx¹ to Rx⁴, Ry¹, Ry² and Rz¹ to Rz⁴ or the like may be used. Among these, as the substituent in the chain alkyl group or alkenyl group as Rx¹ to Rx⁴, Ry¹, Ry² and Rz¹ to Rz⁴, a halogen atom, a halogenated alkyl group, groups exemplified as the cyclic group as Rx¹ to Rx⁴, Ry¹, Ry² and Rz¹ to Rz⁴, and the like are preferable, and the groups exemplified as the cyclic group as Rx¹ to Rx⁴, Ry¹, Ry² and Rz¹ to Rz⁴ are more preferable from the viewpoint of compatibility with the component (A).

Among those hydrocarbon groups, as the group as Rx¹ to Rx⁴, Ry¹, Ry² and Rz¹ to Rz⁴, an aromatic hydrocarbon group which may have a substituent, a cyclic group which may have a substituent and a chain alkyl group which may have a substituent are preferable.

In formula (b0-1), Ry¹ and Ry² may be bonded to each other to form a ring structure.

Specific examples of the ring structure formed by Ry¹ and Ry² include a ring structure sharing one side of a six-membered ring in formula (b0-1) (bond between a carbon atom to which Ry¹ is bonded and a carbon atom to which Ry² is bonded). The ring structure may be an alicyclic hydrocarbon or an aromatic hydrocarbon. Additionally, the ring structure may be a polycyclic structure composed of other ring structures.

The alicyclic hydrocarbon formed by Ry¹ and Ry² may be polycyclic or monocyclic. As a monocyclic alicyclic hydrocarbon, a monocycloalkane is preferable. The monocycloalkane preferably has 3 to 6 carbon atoms, and specific examples thereof include cyclopentane and cyclohexane. As a polycyclic alicyclic hydrocarbon, a poly cycloalkane is preferable. The polycycloalkane preferably has 7 to 30 carbon atoms. Specific examples of the polycycloalkane include a polycycloalkane having a polycyclic skeleton with a bridged ring, such as adamantane, norbornane, isobornane, tricyclodecane or tetracyclododecane; and a polycycloalkane having a polycyclic skeleton with a condensed ring, such as a cyclic ring having a steroid skeleton.

Examples of the aromatic hydrocarbon ring formed by Ry¹ and Ry² include benzene, fluorene, naphthalene, anthracene, phenanthrene, biphenyl, an aromatic heterocyclic ring in which some carbon atoms constituting any of these aromatic rings have been substituted with hetero atoms, and the like. The aromatic hydrocarbon ring formed by Ry¹ and Ry² preferably contains no hetero atom from the viewpoint of compatibility with the component (A), and an aromatic ring such as benzene, fluorene, naphthalene, anthracene, phenanthrene, biphenyl or the like is more preferable.

The ring structure (alicyclic hydrocarbon, aromatic hydrocarbon) formed by Ry¹ and Ry² may have a substituent. Examples of the substituent include the same substituents as those for the cyclic group as Rx¹ to Rx⁴, Ry¹, Ry² and Rz¹ to Rz⁴ (for example, an alkyl group, an alkoxy group, a halogen atom, a halogenated alkyl group, a hydroxyl group, a nitro group, a carbonyl group, and the like). Among these, the substituent in the ring structure formed by Ry¹ and Ry² is preferably an alkyl group, a halogen atom, a halogenated alkyl group or the like, and an alkyl group is more preferable, from the viewpoint of compatibility with the component (A).

Among the ring structures formed by Ry¹ and Ry², an aromatic hydrocarbon which may have a substituent is more preferable in terms of short diffusion and diffusion controllability of an acid generated upon exposure.

In formula (b0-1), two of Rz¹ to Rz⁴ may be mutually bonded to form a ring structure. For example, Rz¹ may form a ring structure with any of Rz² to Rz⁴. Specific examples of the ring structure include a ring structure sharing one side of a six-membered ring in formula (b0-1) (bond between a carbon atom to which Rz¹ and Rz² are bonded and a carbon atom to which Rz³ and Rz⁴ are bonded), a ring structure formed by bonding Rz¹ and Rz², and a ring structure formed by bonding Rz³ and Rz⁴.

The ring structure formed by two or more of Rz¹ to Rz⁴ may be an alicyclic hydrocarbon or an aromatic hydrocarbon, and is particularly preferably an aromatic hydrocarbon. Additionally, the ring structure may be a polycyclic structure composed of other ring structures.

The alicyclic hydrocarbon formed by two or more of Rz¹ to Rz⁴ may be polycyclic or monocyclic. As a monocyclic alicyclic hydrocarbon, a monocycloalkane is preferable. The monocycloalkane preferably has 3 to 6 carbon atoms, and specific examples thereof include cyclopentane and cyclohexane. As a polycyclic alicyclic hydrocarbon, a poly cycloalkane is preferable. The polycycloalkane preferably has 7 to 30 carbon atoms. Specific examples of the polycycloalkane include a polycycloalkane having a polycyclic skeleton with a bridged ring, such as adamantane, norbornane, isobornane, tricyclodecane or tetracyclododecane; and a polycycloalkane having a polycyclic skeleton with a condensed ring, such as a cyclic ring having a steroid skeleton.

It may be a heterocyclic structure in which a part of carbon atoms is substituted with hetero atoms. A nitrogen-containing heterocyclic ring is particularly preferable, and specific examples thereof include cyclic imide and the like.

Examples of the aromatic hydrocarbon ring formed by two or more of Rz¹ to Rz⁴ include benzene, fluorene, naphthalene, anthracene, phenanthrene, biphenyl, an aromatic heterocyclic ring in which some carbon atoms constituting any of these aromatic rings have been substituted with hetero atoms, and the like. The aromatic hydrocarbon ring formed by two or more of Rz¹ to Rz⁴ preferably contains no hetero atom from the viewpoint of compatibility with the component (A), and an aromatic ring such as benzene, fluorene, naphthalene, anthracene, phenanthrene, biphenyl or the like is more preferable.

The ring structure (alicyclic hydrocarbon, aromatic hydrocarbon) formed by Rz¹ to Rz⁴ may have a substituent. Examples of the substituent include the same substituents as those for the cyclic group as Rx¹ to Rx⁴, Ry¹, Ry² and Rz¹ to Rz⁴ (for example, an alkyl group, an alkoxy group, a halogen atom, a halogenated alkyl group, a hydroxyl group, a nitro group, a carbonyl group, and the like). Among these examples, the substituent in the ring structure formed by Rz¹ to Rz⁴ is preferably an alkyl group, a halogen atom, a halogenated alkyl group or the like, and an alkyl group is more preferable, from the viewpoint of compatibility with the component (A).

Among the ring structures formed by two or more of Rz¹ to Rz⁴, in terms of diffusion controllability of an acid generated upon exposure, a ring structure sharing one side of a six-membered ring in formula (b0-1) (bond between a carbon atom to which Rz¹ and Rz² are bonded and a carbon atom to which Rz³ and Rz⁴ are bonded) is preferable, and an aromatic ring structure is more preferable.

In formula (b0-1), the phase “where valence allows” is defined as follows.

That is, in a case where a bond between a carbon atom to which Rz¹ and Rz² are bonded and a carbon atom to which Rz³ and Rz⁴ are bonded is a single bond, all of Rz¹, Rz², Rz³ and Rz⁴ are presents. In a case where a bond between a carbon atom to which Rz¹ and Rz² are bonded and a carbon atom to which Rz³ and Rz⁴ are bonded is a double bond, only one of Rz¹ and Rz², and only one of Rz³ and Rz⁴ are present. For example, in a case where Rz¹ and Rz³ are bonded to form an aromatic ring structure, Rz² and Rz⁴ are not present.

In formula (b0-1), two or more of Rx¹ to Rx⁴ may be bonded to each other to form a ring structure. For example, Rx¹ may form a ring structure with any of Rx² to Rx⁴.

A ring structure formed by two or more of Rx¹ to Rx⁴ may be an alicyclic hydrocarbon or an aromatic hydrocarbon. Additionally, the ring structure may be a polycyclic structure composed of other ring structures.

The alicyclic hydrocarbon formed by two or more of Rx¹ to Rx⁴ may be polycyclic or monocyclic. As a monocyclic alicyclic hydrocarbon, a monocycloalkane is preferable. The monocycloalkane preferably has 3 to 6 carbon atoms, and specific examples thereof include cyclopentane and cyclohexane. As a polycyclic alicyclic hydrocarbon, a poly cycloalkane is preferable. The polycycloalkane preferably has 7 to 30 carbon atoms. Specific examples of the polycycloalkane include a polycycloalkane having a polycyclic skeleton with a bridged ring, such as adamantane, norbornane, isobornane, tricyclodecane or tetracyclododecane; and a polycycloalkane having a polycyclic skeleton with a condensed ring, such as a cyclic ring having a steroid skeleton.

Examples of the aromatic hydrocarbon ring formed by two or more of Rx¹ to Rx⁴ include benzene, fluorene, naphthalene, anthracene, phenanthrene, biphenyl, an aromatic heterocyclic ring in which some carbon atoms constituting any of these aromatic rings have been substituted with hetero atoms, and the like. The aromatic hydrocarbon ring formed by two or more of Rx¹ to Rx⁴ preferably contains no hetero atom from the viewpoint of compatibility with the component (A), and an aromatic ring such as benzene, fluorene, naphthalene, anthracene, phenanthrene, biphenyl or the like is more preferable.

The ring structure (alicyclic hydrocarbon, aromatic hydrocarbon) formed by Rx¹ to Rx⁴ may have a substituent. Examples of the substituent include the same substituents as those for the cyclic group as Rx¹ to Rx⁴, Ry¹, Ry² and Rz¹ to Rz⁴ (for example, an alkyl group, an alkoxy group, a halogen atom, a halogenated alkyl group, a hydroxyl group, a nitro group, a carbonyl group, and the like). Among these examples, the substituent in the ring structure formed by Rx¹ to Rx⁴ is preferably an alkyl group, a halogen atom, a halogenated alkyl group or the like, and an alkyl group is more preferable, from the viewpoint of compatibility with the component (A).

Among the ring structures formed by two or more of Rx¹ to Rx⁴, an alicyclic hydrocarbon is preferable in terms of diffusion controllability of an acid.

Further, in terms of diffusion controllability of an acid, the ring structure formed by two or more of Rx¹ to Rx⁴ is preferably a bridged ring structure in which at least one of Rx¹ and Rx² and at least one of Rx³ and Rx⁴ are bonded to each other, and more preferably a bridged ring structure which is an alicyclic hydrocarbon group.

In a case where at least one of Rx¹ and Rx² and at least one of Rx³ and Rx⁴ are bonded to each other to form a ring structure, the number of carbon atoms of a bicyclic structure (ring structure containing carbon atoms to which Ry¹, Ry², Rz¹ and Rz², and Rz³ and Rz⁴ are respectively bonded) is preferably in a range of 7 to 16.

In formula (b0-1), at least one of Rx¹ to Rx⁴, Ry¹, Ry² and Rz¹ to Rz⁴ has an anionic group represented by the aforementioned general formula (b0-r-an1), and the whole anion moiety is an n-valent anion, n represents an integer of 1 or more, n represents an integer of 1 or more;

In the component (B01), each of Rx¹ to Rx⁴, Ry¹, Ry² and Rz¹ to Rz⁴ may be the anionic groups described above. Alternatively, in the component (B01), in a case where two or more of Rx¹ to Rx⁴ are bonded to each other to form a ring structure, a carbon atom forming the ring structure or a hydrogen atom bonded to this carbon atom may be substituted by the anionic group. In a case where two or more of Ry¹ and Ry² are bonded to each other to form a ring structure, a carbon atom forming the ring structure or a hydrogen atom bonded to this carbon atom may be substituted by the anionic group. In a case where two or more of Rz¹ to Rz⁴ are bonded to each other to form a ring structure, a carbon atom forming the ring structure or a hydrogen atom bonded to this carbon atom may be substituted by the anionic group.

In formula (b0-r-an1), the divalent linking group for Y^{b0} is the same as defined for the divalent linking group for Y^{b0} in the aforementioned formula (b0).

In formula (b0-r-an1), the alkylene group and the fluorinated alkylene group for Vb⁰ are the same as defined for the alkylene group and the fluorinated alkylene group for Vb⁰ in the aforementioned formula (b0).

Specific examples of the anionic group represented by general formula (b0-r-an1) include: in a case where Y^{b0} is a single bond, a fluorinated alkyl sulfonate anion such as —CH₂CF₂SO₃⁻, —CF₂CF₂SO₃⁻, trifluoromethane sulfonate anion, and perfluorobutane sulfonate anion.

In the case where Y^{b0} represents a divalent linking group containing an oxygen atom, anions represented by general formulae (bd1-r-an11) to (bd1-r-an13).

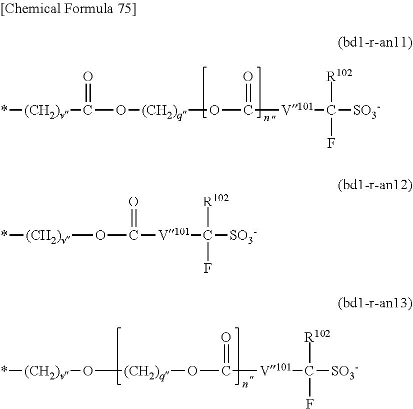

In the formulae, V″¹⁰¹ represents a single bond, an alkylene group having 1 to 4 carbon atoms or a fluorinated alkylene group having 1 to 4 carbon atoms; R¹⁰² represents a fluorine atom or a fluorinated alkyl group having 1 to 5 carbon atoms; each v″ independently represents an integer of 0 to 3; each q″ independently represents an integer of 1 to 20; and n″ is 0 or 1.

In formulae (bd1-r-an11) to (bd1-r-an13), V″¹⁰¹ represents a single bond, an alkylene group having 1 to 4 carbon atoms, or a fluorinated alkylene group having 1 to 4 carbon atoms. V″¹⁰¹ is preferably a single bond, an alkylene group having 1 carbon atom (methylene group), or a fluorinated alkylene group having 1 to 3 carbon atoms.

In formulae (bd1-r-an11) to (bd1-r-an13), R¹⁰² represents a fluorine atom or a fluorinated alkyl group having 1 to 5 carbon atoms. R¹⁰² is preferably a perfluoroalkyl group having 1 to 5 carbon atoms or a fluorine atom, and more preferably a fluorine atom.

In formulae (bd1-r-an11) to (bd1-r-an13), v″ represents an integer of 0 to 3, preferably 0 or 1.

q″ represents an integer of 1 to 20, preferably an integer of 1 to 10, more preferably an integer of 1 to 5, still more preferably 1, 2 or 3, and most preferably 1 or 2.

n″ is 0 or 1, preferably 0.

In the component (B01), the number of anionic group(s) may be 1 or 2 or more.

The component (B01) has an n-valent anion for the whole anion moiety, n is an integer of 1 or more, preferably 1 or 2.

As the anion moiety in the component (B01), an anion represented by the following formula (bd1-an1) is preferable from the viewpoint of acid diffusion controllability.

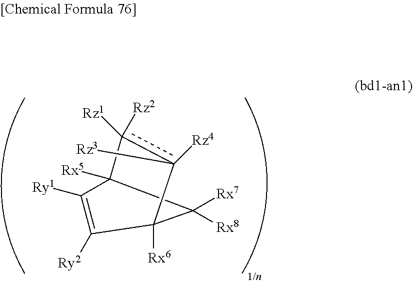

In the formula, Rx⁵ and Rx⁶ each independently represents a hydrocarbon group which may have a substituent or a hydrogen atom; Rx⁷ and Rx⁸ each independently represents a hydrocarbon group which may have a substituent or a hydrogen atom, or alternatively, may be bonded to each other to form a ring structure; p is 1 or 2, and when p is 2, a plurality of Rx⁷s and Rx⁸s may be different from each other; Ry¹ and Ry² each independently represents a hydrogen atom or a hydrocarbon group which may have a substituent, or Ry¹ and Ry² may be mutually bonded to form a ring structure;

[symbol]

[Chemical Formula 77]

represents a double bond or a single bond; Rz¹ to Rz⁴ each independently represents, where valence allows, a hydrogen atom or a hydrocarbon group which may have a substituent, or two or more of Rz¹ to Rz⁴ may be mutually bonded to form a ring structure; provided that at least one of Rx⁵ to Rx⁸, Ry¹, Ry² and Rz¹ to Rz⁴ has an anionic group, and the whole anion moiety is an n-valent anion; and n represents an integer of 1 or more.

In formula (bd1-an1), Rx⁵ and Rx⁶ each independently represents a hydrocarbon group which may have a substituent or a hydrogen atom. The hydrocarbon group which may have a substituent as Rx⁵ and Rx⁶ is the same as the hydrocarbon group which may have a substituent as Rx¹ to Rx⁴ in the aforementioned formula (bd1).

In formula (bd1-an1), Rx⁷ and Rx⁸ each independently represents a hydrocarbon group which may have a substituent or a hydrogen atom, or alternatively, may be bonded to each other to form a ring structure. Rx⁷ and Rx⁸ are the same as defined for Rx¹ to Rx⁴ in the aforementioned formula (b0), respectively.

In formula (bd1-an1), p is 1 or 2, and when p is 2, a plurality of Rx⁷s and Rx⁸s may be different from each other. The anion represented by Formula (bd1-an1) has a bicycloheptane ring structure when p is 1, and a bicyclooctane ring structure when p is 2.

In formula (bd1-an1), Ry¹ and Ry² each independently represents a hydrocarbon group which may have a substituent or a hydrogen atom, or alternatively, may be bonded to each other to form a ring structure. Ry¹ and Ry² are the same as defined for Ry¹ and Ry² in the aforementioned formula (b0), respectively.

Rz¹ to Rz⁴ each independently represents, where valence allows, a hydrogen atom or a hydrocarbon group which may have a substituent, or two or more of Rz¹ to Rz⁴ may be mutually bonded to form a ring structure. Rz¹ to Rz⁴ are the same as defined for Rz¹ to Rz⁴ in the aforementioned formula (b0), respectively.

In formula (bd1-an1), at least one of Rx⁵ to Rx⁸, Ry¹, Ry² and Rz¹ to Rz⁴ has an anionic group, and the whole anion moiety is an n-valent anion, n represents an integer of 1 or more;

Among these examples, as the anion moiety in the component (B01), an anion represented by formula (bd1-an1) and p is 2, i.e. an anion represented by the following Formula (bd1-an2) is more preferable from the viewpoint of acid diffusion controllability.

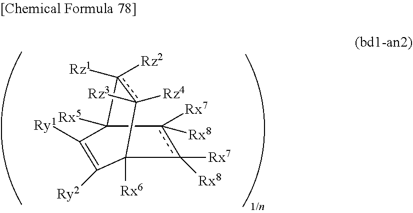

In the formula, Rx⁵ and Rx⁶ each independently represents a hydrocarbon group which may have a substituent or a hydrogen atom; a plurality of Rx⁷s and Rx⁸s each independently represents a hydrocarbon group which may have a substituent or a hydrogen atom, or alternatively, two or more of Rx⁷ and Rx⁸ may be bonded to each other to form a ring structure; Ry¹ and Ry² each independently represents a hydrocarbon group which may have a substituent or a hydrogen atom, or alternatively, may be bonded to each other to form a ring structure;

[symbol]

[Chemical Formula 79]

represents a double bond or a single bond; Rz¹ to Rz⁴ each independently represents, where valence allows, a hydrogen atom or a hydrocarbon group which may have a substituent, or two or more of Rz¹ to Rz⁴ may be mutually bonded to form a ring structure; provided that at least one of Rx⁵ to Rx⁸, Ry¹, Ry² and Rz¹ to Rz⁴ has an anionic group, and the whole anion moiety is an n-valent anion; and n represents an integer of 1 or more.

In formula (bd1-an2), Rx⁵, Rx⁶, Rx⁷, Rx⁸, Ry¹, Ry² and Rz¹ to Rz⁴ are the same as defined for Rx⁵, Rx⁶, Rx⁷, Rx⁸, Ry¹, Ry² and Rz¹ to Rz⁴ in the aforementioned formula (b0).

In formula (bd1-an2), at least one of Rx⁵ to Rx⁸, Ry¹, Ry² and Rz¹ to Rz⁴ has an anionic group, and the whole anion moiety is an n-valent anion, n represents an integer of 1 or more, n represents an integer of 1 or more;

In formulae (b0), (bd1-an1) and (bd1-an2), Ry¹ and Ry² are preferably bonded to each other to form a ring structure, in terms of short diffusion and diffusion controllability of an acid generated upon exposure. The ring structure formed by Ry¹ and Ry² is more preferably an aromatic hydrocarbon (aromatic ring or aromatic heterocyclic ring) which may have a substituent.

In formulae (bd1), (bd1-an1) and (bd1-an2), Rz¹ to Rz⁴ are preferably bonded to each other to form a ring structure, in terms of diffusion controllability of an acid generated upon exposure. The ring structure formed by Rz¹ to Rz⁴ is preferably a ring structure sharing one side of a six-membered ring in the formulae (bond between a carbon atom to which Rz¹ and Rz² are bonded and a carbon atom to which Rz³ and Rz⁴ are bonded), more preferably an aromatic hydrocarbon (aromatic ring or aromatic heterocyclic ring) which may have a substituent.

In formulae (bd1-an1) and (bd1-an2), Rx⁷ and Rx⁸ are preferably bonded to each other to form a ring structure, in terms of short diffusion and diffusion controllability of an acid generated upon exposure. The ring structure formed by Rx⁷ and Rx⁸ is more preferably an aromatic hydrocarbon (aromatic ring or aromatic heterocyclic ring) which may have a substituent, and still more preferably an aromatic hydrocarbon (aromatic ring or aromatic heterocyclic ring) which may have an alkyl group as a substituent.

In formula (bd1-an2), the ring structure formed by Rx⁷ and Rx⁸ is preferably a ring structure sharing one side of a six-membered ring in Formula (bd1-an2) (bond between the same carbon atoms to which Rx⁷ and Rx⁸ are bonded), more preferably an aromatic hydrocarbon (aromatic ring or aromatic heterocyclic ring) which may have a substituent, and still more preferably an aromatic hydrocarbon (aromatic ring or aromatic heterocyclic ring) which may have an alkyl group as a substituent.

In the whole anion represented by Formula (bd1-an2), the number of ring structures formed by any of Rx⁷ and Rx⁸, Ry¹ and Ry², and Rz¹ to Rz⁴ being bonded to each other may be 1, or 2 or more, and preferably 2 or 3.

In particular, suitable examples of the anion moiety in the component (B01) include an anion represented by the following formula (bd1-an3).

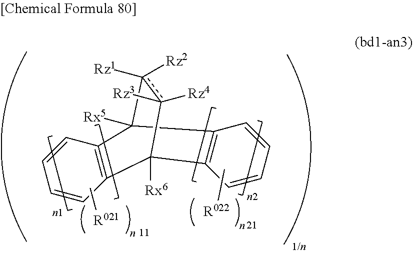

In the formula, Rx⁵ and Rx⁶ each independently represents a hydrocarbon group which may have a substituent or a hydrogen atom;

[symbol]

[Chemical Formula 81]

represents a double bond or a single bond; Rz¹ to Rz⁴ each independently represents, where valence allows, a hydrogen atom or a hydrocarbon group which may have a substituent, or two or more of Rz¹ to Rz⁴ may be mutually bonded to form a ring structure; provided that at least one of Rx⁵ and Rx⁶ and Rz¹ to Rz⁴ has an anionic group, and the whole anion moiety is an n-valent anion; n represents an integer of 1 or more; R⁰²¹ represents an alkyl group, an alkoxy group, a halogen atom, a halogenated alkyl group, a hydroxyl group, a carbonyl group, and a nitro group; n represents an integer of 1 to 3; n11 represents an integer of 0 to 8; R⁰²² represents an alkyl group, an alkoxy group, a halogen atom, a halogenated alkyl group, a hydroxyl group, a carbonyl group, and a nitro group; n2 represents an integer of 1 to 3; and n21 represents an integer of 0 to 8.

In formula (b1-an3), Rx⁵, Rx⁶ and Rz¹ to Rz⁴ are the same as defined for Rx⁵, Rx⁶ and Rz¹ to Rz⁴ in the aforementioned formula (b1-an1), respectively.

In formula (b1-an3), R⁰²¹ represents an alkyl group, an alkoxy group, a halogen atom, a halogenated alkyl group, a hydroxyl group, a carbonyl group, and a nitro group.

The alkyl group as R⁰²¹ is preferably an alkyl group having 1 to 5 carbon atoms, and a methyl group, an ethyl group, a propyl group, an n-butyl group, or a tert-butyl group is most preferable.

The alkoxy group as R⁰²¹ is preferably an alkoxy group having 1 to 5 carbon atoms, more preferably a methoxy group, an ethoxy group, an n-propoxy group, an iso-propoxy group, an n-butoxy group, or a tert-butoxy group, and most preferably a methoxy group or an ethoxy group.

The halogen atom as R⁰²¹ is preferably a fluorine atom, a chlorine atom, a bromine atom and an iodine atom, and a fluorine atom is preferable.

Examples of the halogenated alkyl group as R⁰²¹ include a group in which some or all hydrogen atoms in an alkyl group having 1 to 5 carbon atoms such as a methyl group, an ethyl group, a propyl group, an n-butyl group, or a tert-butyl group have been substituted with the halogen atoms.

Among these examples, R⁰²¹ is preferably an alkyl group, a halogen atom, a halogenated alkyl group or the like, and more preferably an alkyl group, from the viewpoint of compatibility with the component (A).

In formula (bd1-an3), n1 represents an integer of 1 to 3, preferably 1 or 2, and particularly preferably 1.

In formula (bd1-an3), n11 represents an integer of 0 to 8, preferably an integer of 0 to 4, more preferably 0, 1 and 2, and particularly preferably 0 or 1.

In formula (bd1-an3), R⁰²² represents an alkyl group, an alkoxy group, a halogen atom, a halogenated alkyl group, a hydroxyl group, a carbonyl group, and a nitro group, and examples thereof include the same as described above as R⁰²¹. Among these examples, R⁰²² is preferably an alkyl group, a halogen atom, a halogenated alkyl group or the like, and more preferably an alkyl group, from the viewpoint of compatibility with the component (A).

In formula (bd1-an3), n2 represents an integer of 1 to 3, preferably 1 or 2, and particularly preferably 1.

In formula (bd1-an3), n21 represents an integer of 0 to 8, preferably an integer of 0 to 4, more preferably 0, 1 and 2, and particularly preferably 0 or 1.

In formula (bd1-an3), at least one of Rx⁵, Rx⁶ and Rz¹ to Rz⁴ has an anionic group, and the whole anion moiety is an n-valent anion, n represents an integer of 1 or more;

Suitable examples of the anionic group include anionic groups represented by *—V′¹⁰—COO⁻ (V′¹⁰ is a single bond or an alkylene group having 1 to 5 carbon atoms), and an anion group represented by general formula (bd1-r-an1).

In formulae (b0), (bd1-an1), (bd1-an2) and (bd1-an3), at least one of Rz¹ to Rz⁴ preferably has an anionic group since it allows to obtain the excellent advantageous effect of the present embodiment. In a case where two or more of Rz¹ to Rz⁴ are bonded to each other to form a ring structure, a carbon atom forming the ring structure or a hydrogen atom bonded to this carbon atom may be substituted by the anionic group.

Alternatively, in Formulae (bd1-an1), (bd1-an2) and (bd1-an3), at least one of Rx⁵ and Rx⁶ preferably has an anionic group since it allows to obtain the excellent advantageous effect of the present embodiment.

Alternatively, in Formulae (bd1-an1), (bd1-an2) and (bd1-an3), at least one of Rx⁵, Rx⁶ and Rz¹ to Rz⁴ preferably has an anionic group since it allows to obtain the excellent advantageous effect of the present embodiment.

Specific examples of the anion moiety of the component (B0) are shown below.

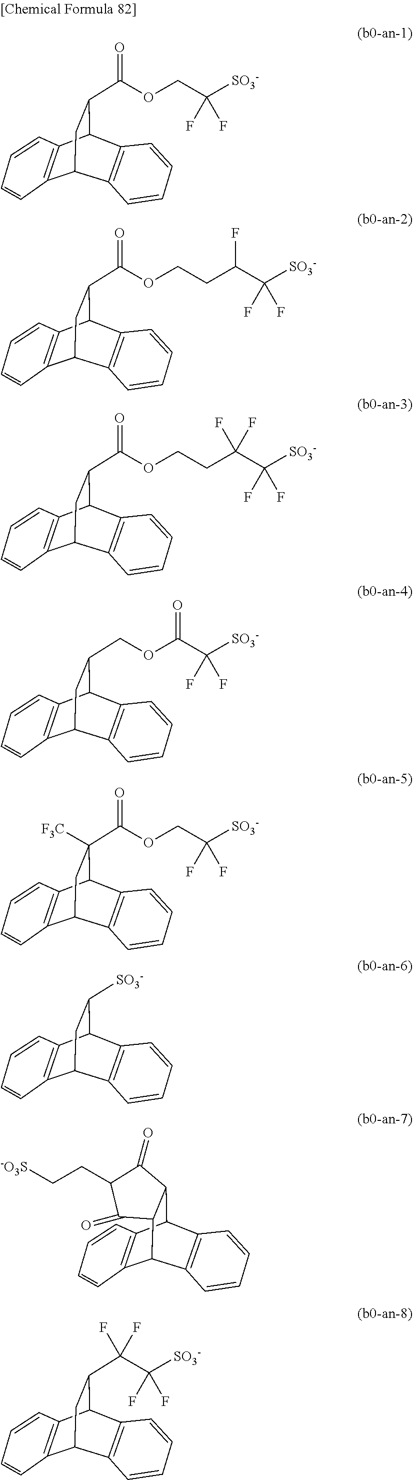

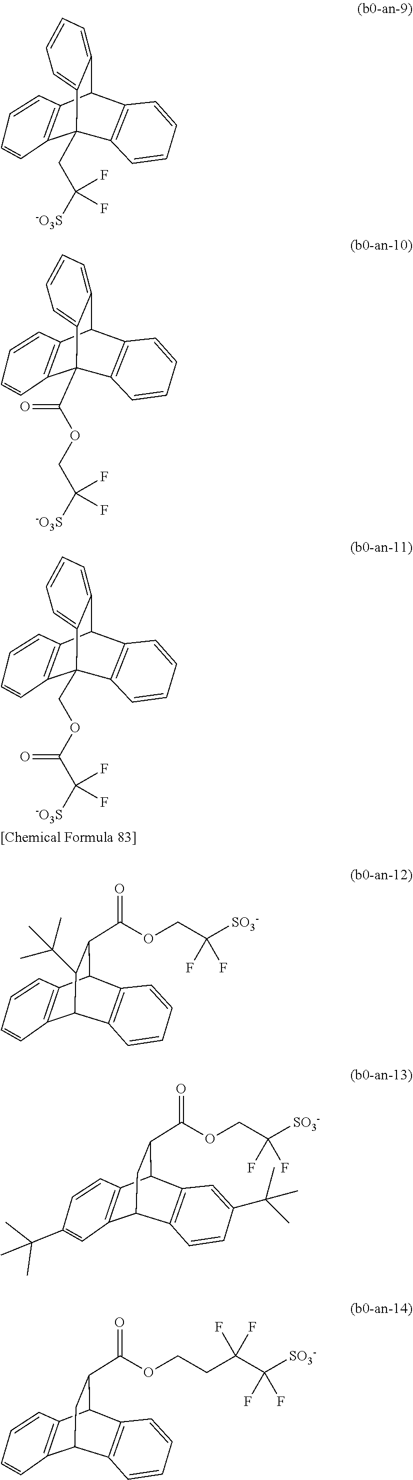

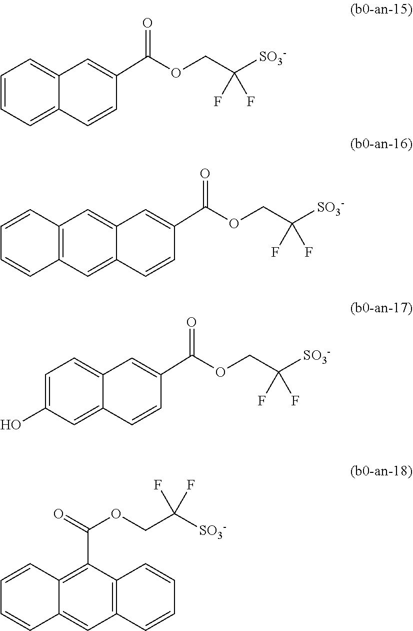

Cation Moiety ((M^{m+})_{1/m})

In formula (b0) and (b0-1), M^{m+} represents an organic cation having a valency of m. m represents an integer of 1 or more.

As preferable examples of the cation moiety ((M^{m+})_{1/m}), organic cations represented by the aforementioned general formulae (ca-1) to (ca-5) may be given.

In the resist composition of the present embodiment, as the component (B0), one kind of compound may be used, or two or more kinds of compounds may be used in combination.

In the resist composition of the present embodiment, the amount of the component (B0) relative to 100 parts by weight of the component (A) is preferably within a range from 5 to 65 parts by weight, more preferably from 5 to 55 parts by weight, and still more preferably from 10 to 50 parts by weight.

When the amount of the component (B0) is at least as large as the lower limit of the above-mentioned preferable range, in the formation of a resist pattern, various lithography properties such as sensitivity, resolution, LWR (line width roughness) and pattern shape are improved. On the other hand, in the case where the amount of the component (B0) is no more than the upper limit of the above-mentioned preferable range, when each of the components of the resist composition are dissolved in an organic solvent, a homogeneous solution may be more reliably obtained and the storage stability of the resist composition becomes satisfactory.

<Component (D)>

In the resist composition of the present embodiment, the component (D) is a basic component which suppresses diffusion of acid generated from the component (B) upon exposure. When a resist pattern is formed using a resist composition containing the component (D), the contrast between exposed portions and unexposed portions of the resist film is further improved.

Further, the component (D) includes a compound (D0) represented by general formula (d0) described later (hereafter, sometimes referred to as “component (D0)”).

The component (D) may include, in addition to the component (D0), a basic component which does not fall under the definition of the component (D0).

Component (D0)

The component (D0) is a compound represented by general formula (d0) shown below.

[Chemical Formula 84]

Rd⁰-Xd⁰-Yd⁰-COO^{⊖}(M^{m⊕})_{1/m} (d0)

In the formula, Rd⁰ represents a monovalent organic group; Xd⁰ represents —O—, —C(═O)—, —O—C(═O)—, —C(═O)—O—, —S— or —SO₂—; Yd⁰ represents a single bond or a divalent hydrocarbon group which may have a substituent; M^{m+} represents a m-valent organic cation; and m represents an integer of 1 or more.

{Anion Moiety of Component (D0)}

In formula (d0), Rd⁰ represents a monovalent organic group. Examples of the monovalent organic group include a hydrocarbon group which may have a substituent.

Examples of the hydrocarbon group (which may have a substituent) for Rd⁰ in formula (d0) include a cyclic group which may have a substituent, a chain alkyl group which may have a substituent, and a chain alkenyl group which may have a substituent.

Cyclic group which may have a substituent:

The cyclic group is preferably a cyclic hydrocarbon group, and the cyclic hydrocarbon group may be either an aromatic hydrocarbon group or an aliphatic hydrocarbon group. An “aliphatic hydrocarbon group” refers to a hydrocarbon group that has no aromaticity. The aliphatic hydrocarbon group may be either saturated or unsaturated, but in general, the aliphatic hydrocarbon group is preferably saturated.

The aromatic hydrocarbon group for X Rd⁰ is a hydrocarbon group having an aromatic ring. The aromatic hydrocarbon ring preferably has 3 to 30 carbon atoms, more preferably 5 to 30, still more preferably 5 to 20, still more preferably 6 to 15, and most preferably 6 to 10. Here, the number of carbon atoms within a substituent(s) is not included in the number of carbon atoms of the aromatic hydrocarbon group.

Specific examples of the aromatic ring which the aromatic hydrocarbon group has as Rd⁰ include benzene, fluorene, naphthalene, anthracene, phenanthrene, biphenyl, or an aromatic heterocyclic ring in which some carbon atoms constituting any of these aromatic rings have been substituted with a hetero atom. Examples of the hetero atom within the aromatic hetero rings include an oxygen atom, a sulfur atom and a nitrogen atom. Specific examples of the aromatic hydrocarbon group as Rd⁰ include a group in which one hydrogen atom has been removed from the above-described aromatic ring (an aryl group such as a phenyl group or a naphthyl group) and a group in which one hydrogen atom in the aromatic ring has been substituted with an alkylene group (an arylalkyl group such as a benzyl group, a phenethyl group, a 1-naphthylmethyl group, a 2-naphthylmethyl group, 1-naphthylethyl group, or a 2-naphthylethyl group). The alkylene group (alkyl chain within the arylalkyl group) preferably has 1 to 4 carbon atom, more preferably 1 or 2, and most preferably 1.

Examples of the cyclic aliphatic hydrocarbon group for Rd⁰ include aliphatic hydrocarbon groups containing a ring in the structure thereof.

As examples of the hydrocarbon group containing a ring in the structure thereof, an alicyclic hydrocarbon group (a group in which one hydrogen atom has been removed from an aliphatic hydrocarbon ring), a group in which the alicyclic hydrocarbon group is bonded to the terminal of the aforementioned chain-like aliphatic hydrocarbon group, and a group in which the alicyclic group is interposed within the aforementioned linear or branched aliphatic hydrocarbon group, can be given.

The alicyclic hydrocarbon group preferably has 3 to 20 carbon atoms, and more preferably 3 to 12 carbon atoms.

The alicyclic hydrocarbon group may be either a polycyclic group or a monocyclic group. As the monocyclic alicyclic hydrocarbon group, a group in which one or more hydrogen atoms have been removed from a monocycloalkane is preferable. The monocycloalkane preferably has 3 to 6 carbon atoms, and specific examples thereof include cyclopentane and cyclohexane. As the polycyclic alicyclic hydrocarbon group, a group in which one or more hydrogen atoms have been removed from a polycycloalkane is preferable, and the polycyclic group preferably has 7 to 30 carbon atoms. Among poly cycloalkanes, a polycycloalkane having a bridged ring polycyclic skeleton, such as adamantane, norbornane, isobornane, tricyclodecane or tetracyclododecene, and a polycycloalkane having a condensed ring polycyclic skeleton, such as a cyclic group having a steroid skeleton are preferable.

Among these examples, as the cyclic aliphatic hydrocarbon group for Rd⁰, a group in which one or more hydrogen atoms have been removed from a monocycloalkane or a polycycloalkane is preferable, a group in which one or more hydrogen atoms have been removed from a polycycloalkane is more preferable, an adamantyl group or a norbornyl group is still more preferable, and an adamantyl group is most preferable.

The linear aliphatic hydrocarbon group which may be bonded to the alicyclic hydrocarbon group preferably has 1 to 10 carbon atoms, more preferably 1 to 6 carbon atoms, still more preferably 1 to 4 carbon atoms, and most preferably 1 to 3 carbon atoms. As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅—].

The branched aliphatic hydrocarbon group which may be bonded to the alicyclic hydrocarbon group preferably has 2 to 10 carbon atoms, more preferably 3 to 6 carbon atoms, still more preferably 3 or 4 carbon atoms, and most preferably 3 carbon atoms. As the branched aliphatic hydrocarbon group, branched alkylene groups are preferred, and specific examples include various alkylalkylene groups, including alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group within the alkylalkylene group, a linear alkyl group of 1 to 5 carbon atoms is preferable.

The cyclic hydrocarbon group for Rd⁰ may contain a hetero atom such as a heterocycle. Specific examples include lactone-containing cyclic groups represented by the aforementioned general formulae (a2-r-1) to (a2-r-7), the —SO₂— containing cyclic group represented by the aforementioned formulae (a5-r-1) to (a5-r-4), and other heterocyclic groups represented by the aforementioned chemical formulae (r-hr-1) to (r-hr-16). In the formulae, * represents a bonding site that is bonded to Xd⁰ in general formula (d0).

Chain alkyl group which may have a substituent:

The chain alkyl group for Rd⁰ may be linear or branched.

The linear alkyl group preferably has 1 to 20 carbon atoms, more preferably 1 to 15, and most preferably 1 to 10. Specific examples include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group and a docosyl group.

The branched alkyl group preferably has 3 to 20 carbon atoms, more preferably 3 to 15, and most preferably 3 to 10. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

Chain alkenyl group which may have a substituent:

The chain alkenyl group for Rd⁰ may be linear or branched, and preferably has 2 to 10 carbon atoms, more preferably 2 to 5 carbon atoms, still more preferably 2 to 4 carbon atoms, and most preferably 3 carbon atoms. Examples of linear alkenyl groups include a vinyl group, a propenyl group (an allyl group) and a butynyl group. Examples of branched alkenyl groups include a 1-methylvinyl group, a 2-methylvinyl group, a 1-methylpropenyl group and a 2-methylpropenyl group.

Among these examples, as the chain alkenyl group, a linear alkenyl group is preferable, a vinyl group or a propenyl group is more preferable, and a vinyl group is most preferable.

In general formula (d0), among the above examples, Rd⁰ is preferably a cyclic group which may have a substituent, more preferably a cyclic hydrocarbon group which may have a substituent, still more preferably an aromatic hydrocarbon group which may have a substituent, particularly preferably a phenyl group or a naphthyl group, which may have a substituent, and most preferably a phenyl group or a naphthyl group.

The substituent in the hydrocarbon group which may have a substituent may be a monovalent substituent or a divalent substituent.

Examples of the monovalent substituent include a carboxy group, a hydroxy group, an amino group, a sulfo group, a halogen atom, a halogenated alkyl group, an alkoxy group, an alkyloxycarbonyl group, and a nitro group.

Examples of the divalent substituent include —O—, —C(═O)—O—, —C(═O)—, —O—C(═O)—O—, —C(═O)—NH—, —NH—, ═N—, —NH—C(═NH)—, —S—, —S(═O)₂—, and —S(═O)₂—O—. In addition, H in the divalent substituent may be substituted with a substituent, for example, an alkyl group or an acyl group.

In formula (d0), Xd⁰ is —O—, —C(═O)—, —O—C(═O)—, —C(═O)—O—, —S— or —SO₂—, and preferably —O—, —C(═O)—, —O—C(═O)— or —S—.

In formula (d0), Yd⁰ represents a divalent hydrocarbon group which may have a substituent or a single bond.

Divalent Hydrocarbon Group which May have a Substituent:

The divalent hydrocarbon group which may have a substituent, as Yd⁰, may be an aliphatic hydrocarbon group or an aromatic hydrocarbon group.

Aliphatic Hydrocarbon Group for Yd⁰

An “aliphatic hydrocarbon group” refers to a hydrocarbon group that has no aromaticity. The aliphatic hydrocarbon group may be saturated or unsaturated. In general, the aliphatic hydrocarbon group is preferably saturated. Examples of the aliphatic hydrocarbon group include a linear or branched aliphatic hydrocarbon group, and an aliphatic hydrocarbon group containing a ring in the structure thereof can be given.

Linear or Branched Aliphatic Hydrocarbon Group

The linear aliphatic hydrocarbon group preferably has 1 to 10 carbon atoms, more preferably 1 to 6, still more preferably 1 to 4, and most preferably 1 to 3.

As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅—].

The branched aliphatic hydrocarbon group preferably has 2 to 10 carbon atoms, more preferably 3 to 6, still more preferably 3 or 4, and most preferably 3.

As the branched aliphatic hydrocarbon group, branched alkylene groups are preferred, and specific examples include various alkylalkylene groups, including alkylmethylene groups such as —CH(CH₃)—, —CH(CH₂CH₃)—, —C(CH₃)₂—, C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group within the alkylalkylene group, a linear alkyl group of 1 to 5 carbon atoms is preferable.

The linear or branched aliphatic hydrocarbon group may or may not have a substituent. Examples of the substituent include a fluorine atom, a fluorinated alkyl group of 1 to 5 carbon atoms, and a carbonyl group.

Aliphatic Hydrocarbon Group Containing a Ring in the Structure Thereof

As examples of the hydrocarbon group containing a ring in the structure thereof, a cyclic aliphatic hydrocarbon group containing a hetero atom in the ring structure thereof and may have a substituent (a group in which two hydrogen atoms have been removed from an aliphatic hydrocarbon ring), a group in which the cyclic aliphatic hydrocarbon group is bonded to the terminal of the aforementioned chain-like aliphatic hydrocarbon group, and a group in which the cyclic aliphatic group is interposed within the aforementioned linear or branched aliphatic hydrocarbon group, can be given. As the linear or branched aliphatic hydrocarbon group, the same groups as those described above can be used.

The cyclic aliphatic hydrocarbon group preferably has 3 to 20 carbon atoms, and more preferably 3 to 12 carbon atoms.

The cyclic aliphatic hydrocarbon group may be either a polycyclic group or a monocyclic group. As the monocyclic aliphatic hydrocarbon group, a group in which 2 hydrogen atoms have been removed from a monocycloalkane is preferable. The monocycloalkane preferably has 3 to 6 carbon atoms, and specific examples thereof include cyclopentane and cyclohexane. As the polycyclic group, a group in which 2 hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane.

The cyclic aliphatic hydrocarbon group may or may not have a substituent. Examples of the substituent include an alkyl group, an alkoxy group, a halogen atom, a halogenated alkyl group, a hydroxyl group and a carbonyl group.

The alkyl group as the substituent is preferably an alkyl group of 1 to 5 carbon atoms, and more preferably a methyl group, an ethyl group, a propyl group, an n-butyl group or a tert-butyl group.

The alkoxy group as the substituent is preferably an alkoxy group having 1 to 5 carbon atoms, more preferably a methoxy group, ethoxy group, n-propoxy group, iso-propoxy group, n-butoxy group or tert-butoxy group, and still more preferably a methoxy group or an ethoxy group.

The halogen atom as the substituent is preferably a fluorine atom.

Examples of the halogenated alkyl group for the substituent include groups in which part or all of the hydrogen atoms within the aforementioned alkyl groups has been substituted with the aforementioned halogen atoms.

The cyclic aliphatic hydrocarbon group may have part of the carbon atoms constituting the ring structure thereof substituted with a substituent containing a hetero atom. As the substituent containing a hetero atom, —O—, —C(═O)—O—, —S—, —S(═O)₂— or —S(═O)₂—O— is preferable.

Aromatic Hydrocarbon Group for Yd⁰

The aromatic hydrocarbon group is a hydrocarbon group having at least one aromatic ring.

The aromatic ring is not particularly limited, as long as it is a cyclic conjugated compound having (4n+2)π electrons, and may be either monocyclic or polycyclic. The aromatic ring preferably has 5 to 30 carbon atoms, more preferably 5 to 20 carbon atoms, and still more preferably 6 to 15 carbon atoms, and most preferably 6 to 12 carbon atoms. Here, the number of carbon atoms within a substituent(s) is not included in the number of carbon atoms of the aromatic hydrocarbon group.

Examples of the aromatic ring include aromatic hydrocarbon rings, such as benzene, naphthalene, anthracene and phenanthrene; and aromatic hetero rings in which part of the carbon atoms constituting the aforementioned aromatic hydrocarbon rings has been substituted with a hetero atom. Examples of the hetero atom within the aromatic hetero rings include an oxygen atom, a sulfur atom and a nitrogen atom. Specific examples of the aromatic hetero ring include a pyridine ring and a thiophene ring.

Specific examples of the aromatic hydrocarbon group include a group in which two hydrogen atoms have been removed from the aforementioned aromatic hydrocarbon ring or aromatic hetero ring (arylene group or heteroarylene group); a group in which two hydrogen atoms have been removed from an aromatic compound having two or more aromatic rings (biphenyl, fluorene or the like); and a group in which one hydrogen atom of the aforementioned aromatic hydrocarbon ring or aromatic hetero ring has been substituted with an alkylene group (a group in which one hydrogen atom has been removed from the aryl group within the aforementioned arylalkyl group such as a benzyl group, a phenethyl group, a 1-naphthylmethyl group, a 2-naphthylmethyl group, a 1-naphthylethyl group, or a 2-naphthylethyl group, or a heteroarylalkyl group). The alkylene group which is bonded to the aforementioned aryl group or heteroaryl group preferably has 1 to 4 carbon atoms, more preferably 1 or 2 carbon atoms, and most preferably 1 carbon atom.

With respect to the aromatic hydrocarbon group, the hydrogen atom within the aromatic hydrocarbon group may be substituted with a substituent. For example, the hydrogen atom bonded to the aromatic ring within the aromatic hydrocarbon group may be substituted with a substituent. Examples of substituents include an alkyl group, an alkoxy group, a halogen atom, a halogenated alkyl group, and a hydroxyl group.

The alkyl group as the substituent is preferably an alkyl group of 1 to 5 carbon atoms, and more preferably a methyl group, an ethyl group, a propyl group, an n-butyl group or a tert-butyl group.

As the alkoxy group, the halogen atom and the halogenated alkyl group for the substituent, the same groups as the aforementioned substituent groups for substituting a hydrogen atom within the cyclic aliphatic hydrocarbon group can be used.

In general formula (d0), among the above examples, Yd⁰ is preferably a single bond or a linear or branched aliphatic hydrocarbon group, more preferably a single bond or a linear or branched aliphatic hydrocarbon group having 1 to 10 carbon atoms, and still more preferably a single bond, or a linear or branched aliphatic hydrocarbon group having 1 to 5 carbon atoms.

Preferred anions as the anion moiety of the component (D0) are shown below.

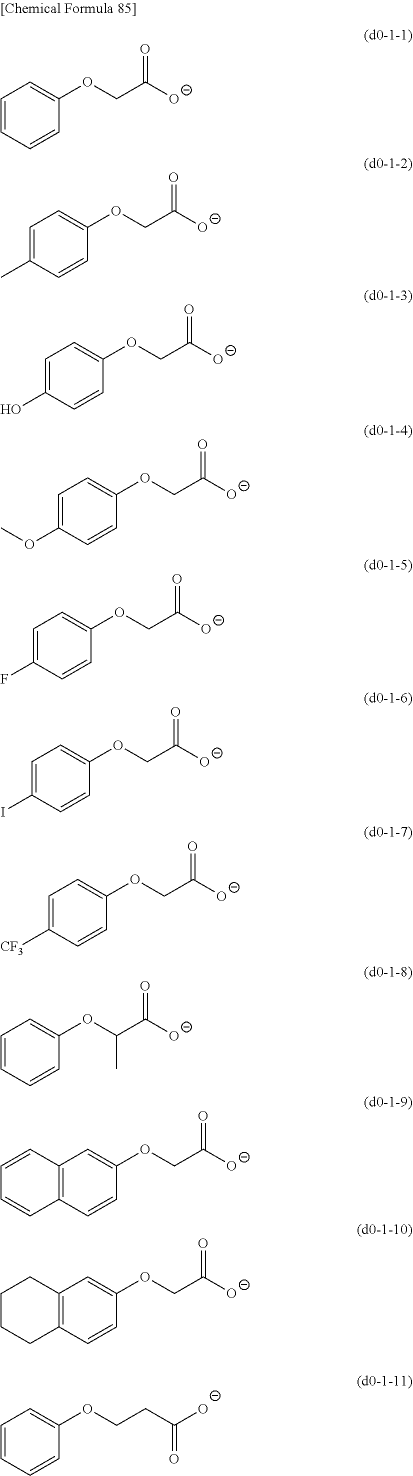

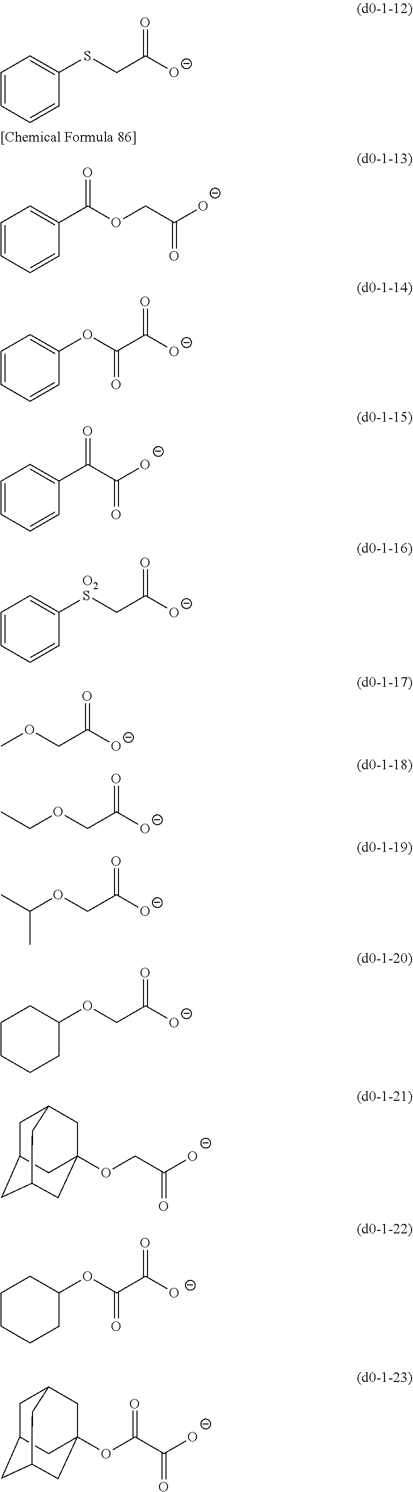

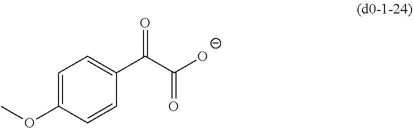

{Cation Moiety of Component (D0)}

In formula (d0), M^{m+} represents an organic cation having a valency of m. Among these, a sulfonium cation or a iodonium cation is preferable, m represents an integer of 1 or more.

Preferable examples of the cation moiety ((M^{m+})_{1/m}) include an organic cation represented by any of the aforementioned general formulae (ca-1) to (ca-5) for the component (B) is preferable. Among these examples, a cation represented by general formula (ca-1) is preferable.

In the resist composition of the present embodiment, among the above examples, as the component (D0), a compound represented by general formula (d01) shown below (hereafter, sometimes referred to as “component (D01)”) is preferable.

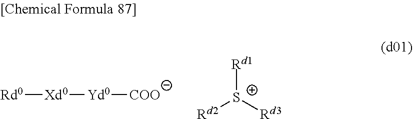

In the formula, Rd⁰ represents a monovalent organic group; Xd⁰ represents —O—, —C(═O)—, —O—C(═O)—, —C(═O)—O—, —S— or —SO₂—; Yd⁰ represents a single bond or a divalent hydrocarbon group which may have a substituent; R^{d1} to R^{d3} each independently represents an aryl group which may have a substituent, or two or more of R^{d1} to R^{d3} are mutually bonded to form a ring with the sulfur atom in the formula.

{Anion Moiety of Component (D01)}

The anion moiety of the component (D01) is the same as defined for the anion moiety of the aforementioned component (D0).

{Cation Moiety of Component (D01)}

In General Formula (d01), R^{d1} to R^{d3} each independently represents an aryl group which may have a substituent or are bonded to each other to form a ring together with the sulfur atom in the formula. Examples of the aryl group which may have a substituent include the same aryl group which may have a substituent, as the organic cation represented by general formula (ca-1) described above.

Examples of the rings that are bonded to each other, thereby being formed together with the sulfur atom in the formula, as R^{d1} to R^{d3}, include the same rings as those in which R²⁰¹ to R²⁰³ in the organic cation represented by General Formula (ca-1) are bonded to each other, thereby being formed together with the sulfur atom in the formula.

Specific examples of the component (D0) are shown below, although the component (D0) is not limited to these examples.

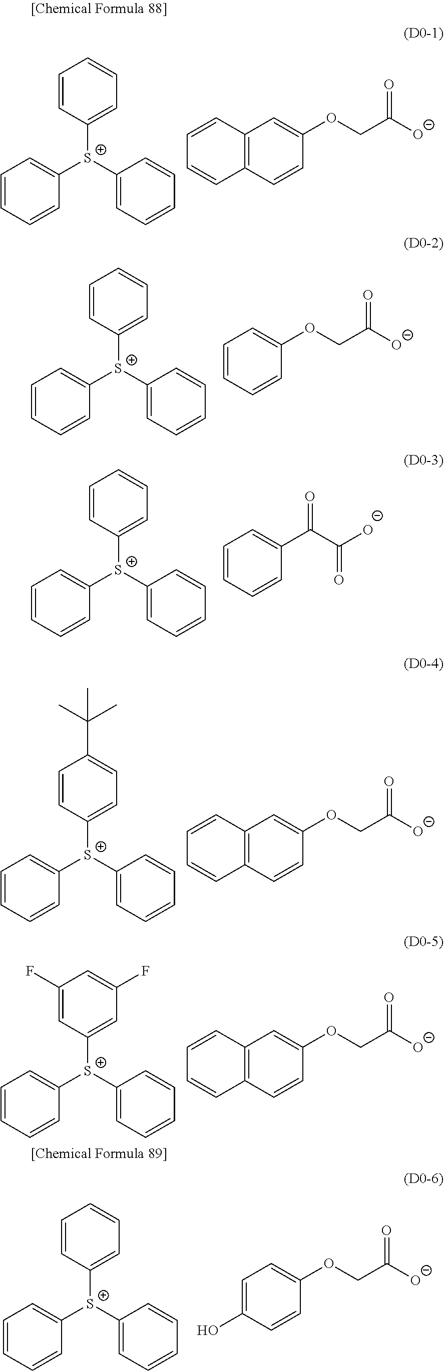

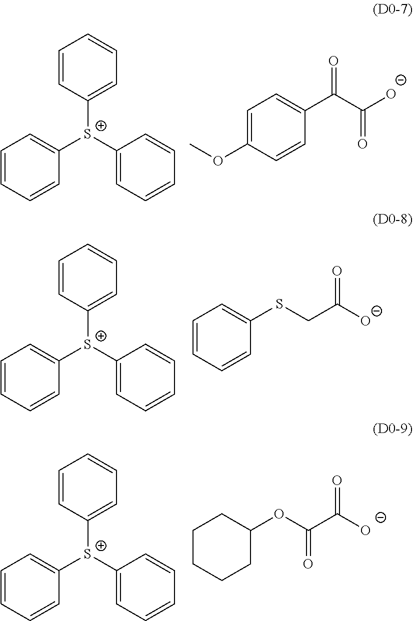 [SMILES: c1ccc([S+](c2ccccc2)c2ccccc2)cc1 ; COc1ccc(C(=O)C(=O)[O-])cc1 ; c1ccc([S+](c2ccccc2)c2ccccc2)cc1 ; O=C([O-])CSc1ccccc1 ; c1ccc([S+](c2ccccc2)c2ccccc2)cc1 ; O=C([O-])C(=O)OC1CCCCC1]

In the resist composition of the present embodiment, as the component (D0), one kind of compound may be used, or two or more kinds of compounds may be used in combination.

In the resist composition of the present embodiment, the amount of the component (D0) relative to 100 parts by weight of the component (A) is preferably 4 parts by weight or more, more preferably 4 to 20 parts by weight, still more preferably 4 to 15 parts by weight, and most preferably 4.5 to 15 parts by weight.

In a case where the amount of the component (D0) is at least as large as the lower limit of the above-mentioned range, the solubility of the resist composition in a developing solution may be appropriately ensured, and thus the effects of the present embodiment may be more reliably obtained. On the other hand, when the amount of the component (D0) is no more than the upper limit of the above-mentioned preferable range, various lithography properties may be improved.

In the component (D), the amount of the component (D0) based on the total weight of the component (D) is preferably 50% by weight or more, more preferably 75% by weight or more, still more preferably 90% by weight or more, and may be even 100% by weight. When the amount of the component (D0) is 50% by weight or more, the effects of the present embodiment may be more reliably achieved.

<Compound (D0′)>

The resist composition of the present embodiment preferably contains, as the component (D0), a compound (D0′) represented by general formula (d0′) shown below.

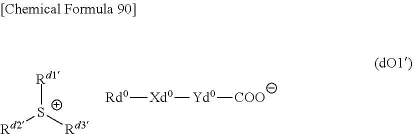

In the formula, Rd¹′ represents an aryl group having an electron-withdrawing group selected from a halogen atom, a halogenated alkyl group, a cyano group, a nitro group, an alkylsulfone group or an arylsufone group. The aryl group for Rd¹′ may have, as a substituent, an alkyl group, an alkoxy group, an oxycarbonyl group, a sulfenyl group or an aryl group. Rd²′ and Rd³′ each independently represents an aryl group, alkyl group or alkenyl group which may have a substituent. Rd²′ and Rd³′ may be mutually bonded to form a ring with the sulfur atom in the formula. However, in the case where Rd²′ and Rd³′ are mutually bonded to form a ring with the sulfur atom in the formula, a ring structure formed via —C(═O)— is excluded. Rd⁰ represents a monovalent organic group. Xd⁰ represents —O—, —C(═O)—, —O—C(═O)—, —C(═O)—O—, —S— or —SO₂—. Yd⁰ represents a single bond or a divalent hydrocarbon group which may have a substituent.

{Cation Moiety of Component (D0′)}

In formula (d0), Rd¹ represents an aryl group having an electron-withdrawing group selected from a halogen atom, a halogenated alkyl group, a cyano group, a nitro group, an alkylsulfone group or an arylsufone group.

The aryl group for Rd¹′ preferably as 5 to 30 carbon atoms, more preferably 5 to carbon atoms, still more preferably 6 to 15 carbon atoms, and most preferably 6 to 10 carbon atoms. Here, the number of carbon atoms within a substituent(s) is not included in the number of carbon atoms of the aromatic hydrocarbon group.

Specifically, as the aryl group for Rd¹′, a phenyl group, a naphthyl group, an anthryl group, a phenanthryl group or a biphenyl group is preferable, a phenyl group or a naphthyl group is more preferable, and a phenyl group is still more preferable.

Examples of the alkylsulfone group as the electron-withdrawing group for the aryl group represented by Rd¹′ include a cyclohexylsulfonyl group and a methylsulfonyl group. Among the above examples, as the alkylsulfone group, a cyclohexylsulfonyl group and a cyclopentylsulfonyl group is preferable.

Examples of the arylsulfone group as the electron-withdrawing group for the aryl group represented by Rd¹′ include a phenylsulfonyl group and a naphthylsulfonyl group. Among the above examples, as the arylsulfone group, a phenylsulfonyl group is preferable.

Among the above examples, as the electron-withdrawing group for the aryl group represented by Rd¹′, an electron-withdrawing group selected from a halogen atom, a halogenated alkyl group and an arylsulfone group is preferable, and in terms of enhancing sensitivity, the halogen atom is preferably a fluorine atom.

The aryl group for Rd¹′ may have a substituent other than the aforementioned electron-withdrawing group. Examples of the substituent include an alkyl group (a methyl group, an ethyl group, or the like), an alkoxy group (a methoxy group, an ethoxy group, a propoxy group, a butoxy group, or the like), an oxycarbonyl group, a sulfenyl group, and an aryl group.

The aryl group for Rd¹′ preferably has no substituent other than the aforementioned electron-withdrawing group.

In formula (d0), the aryl group, alkyl group or alkenyl group (which may have a substituent) for Rd²′ and Rd³′ are the same as defined for the aryl group, alkyl group or alkenyl group (which may have a substituent) for R²⁰¹ to R²⁰³ in the aforementioned general formula (ca-1).

As the cation moiety of the component (D0′), a cation represented by general formula (ca-d0′-1) shown below is preferable.

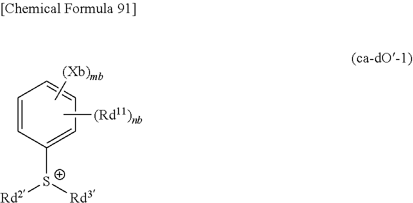

In the formula, Xb represents a halogen atom, a halogenated alkyl group, a cyano group, a nitro group, an alkylsulfone group or an arylsulfone group; Rd¹¹ represents an alkyl group, an alkoxy group, an oxycarbonyl group, a sulfenyl group or an aryl group; mb represents an integer of 1 to 5; nb represents an integer of 0 or more and (5-mb) or less; in the case where mb is 2 or more, the plurality of Xb may be the same or different from each other; in the case where nb is 2 or more, the plurality of Rd¹¹ may be the same or different from each other; Rd²′ and Rd³′ each independently represents an aryl group, alkyl group or alkenyl group which may have a substituent. Rd²′ and Rd³′ may be mutually bonded to form a ring with the sulfur atom in the formula. However, in the case where Rd²′ and Rd³′ are mutually bonded to form a ring with the sulfur atom in the formula, a ring structure formed via —C(═O)— is excluded.

In formula (ca-d0′-1), Xb is the same as defined for the electron-withdrawing group in Rd¹′ in the aforementioned formula (d0).

In formula (ca-d0′-1), Rd¹¹ is the same as defined for the substituent other than the electron-withdrawing group for the aryl group represented by Rd¹′ in the aforementioned formula (d0).

In formula (ca-d0′-1), Rd²′ and Rd³′ are the same as defined for Rd²′ and Rd³′ in the aforementioned formula (d0).

In formula (ca-d0′-1), mb is preferably an integer of 1 to 3, more preferably 1 or 2.

In formula (ca-d0′-1), nb is preferably 0 or 1, and more preferably 0.

Preferable cations as the cation moiety of the component (D0′) are shown below.

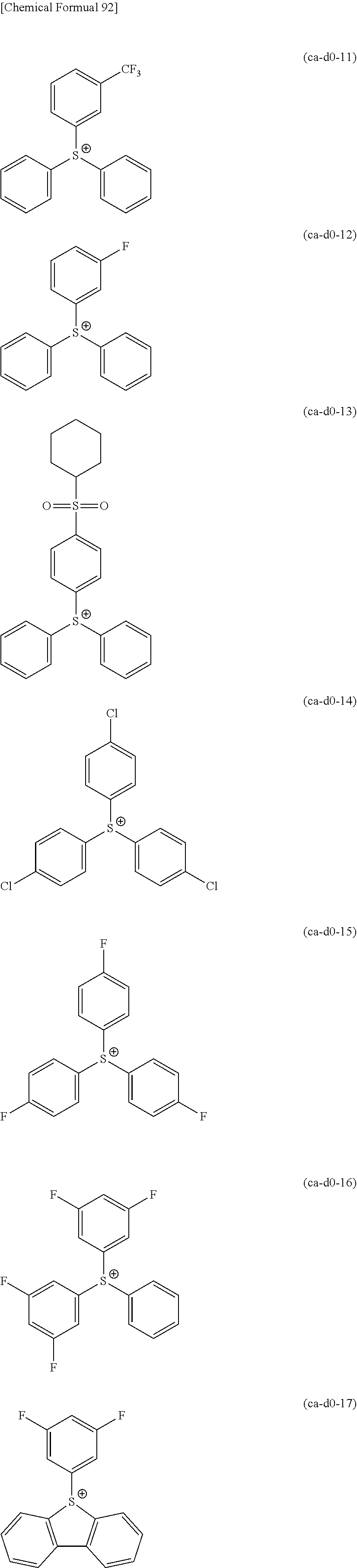

{Anion Moiety of Component (D0′)}

The anion moiety of the component (D0′) is the same as defined for the anion moiety of the aforementioned component (D01).

In the resist composition of the present embodiment, among the above examples, as the component (D0′), a compound represented by general formula (d0′-1) shown below (hereafter, sometimes referred to as “component (D01′)”) is preferable.

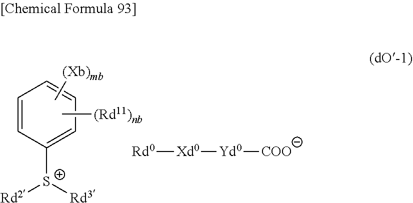

In the formula, Xb represents a halogen atom, a halogenated alkyl group, a cyano group, a nitro group, an alkylsulfone group or an arylsulfone group; Rd¹¹ represents an alkyl group, an alkoxy group, an oxycarbonyl group, a sulfenyl group or an aryl group; mb represents an integer of 1 to 5; nb represents an integer of 0 or more and (5-mb) or less; in the case where mb is 2 or more, the plurality of Xb may be the same or different from each other; in the case where nb is 2 or more, the plurality of Rd¹¹ may be the same or different from each other; Rd²′ and Rd³′ each independently represents an aryl group, alkyl group or alkenyl group which may have a substituent. Rd²′ and Rd³′ may be mutually bonded to form a ring with the sulfur atom in the formula. However, in the case where Rd² and Rd³ are mutually bonded to form a ring with the sulfur atom in the formula, a ring structure formed via —C(═O)— is excluded. Rd⁰ represents a monovalent organic group. Xd⁰ represents —O—, —C(═O)—, —O—C(═O)—, —C(═O)—O—, —S— or —SO₂—. Yd⁰ represents a single bond or a divalent hydrocarbon group which may have a substituent.

In formula (d0′-1), the cation moiety is the same as the cation represented by the aforementioned general formula (ca-d0-1).

In formula (d0′-1), the anion moiety is the same as defined for the anion moiety of the aforementioned formula (d0′).

Specific examples of the (D0′) component are given below, but the present invention is not limited thereto.

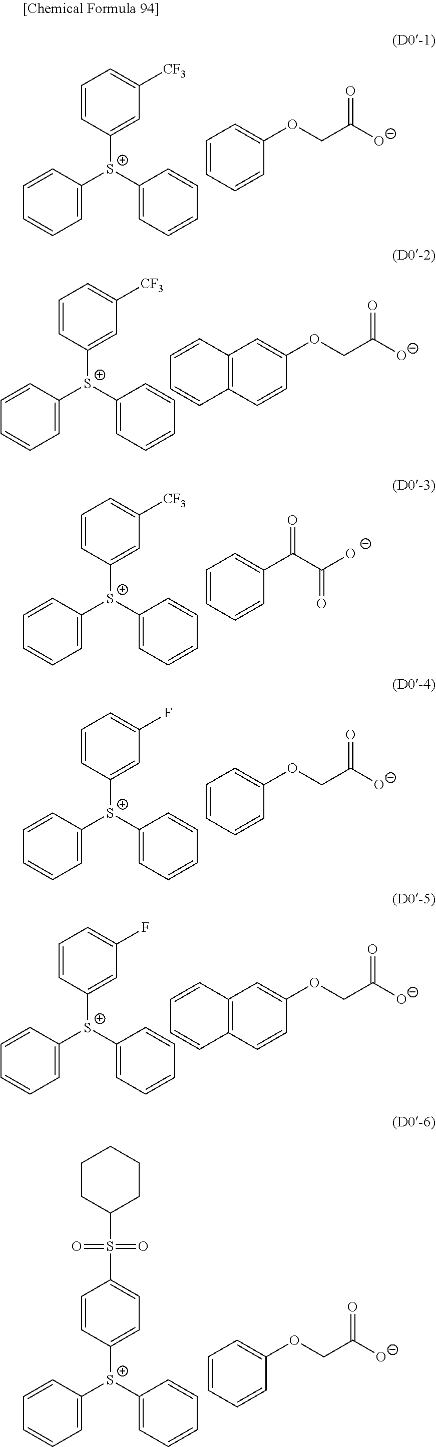

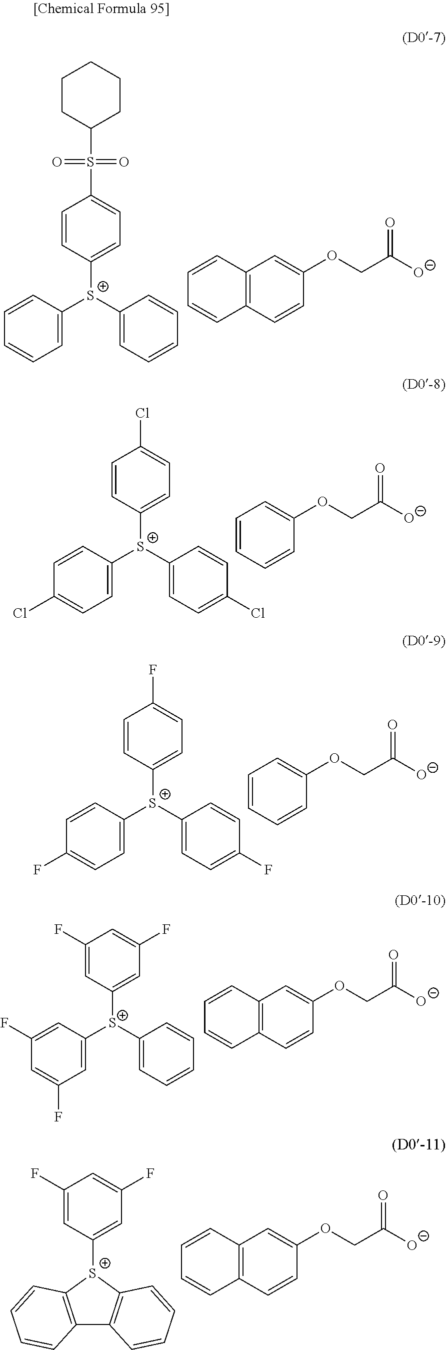

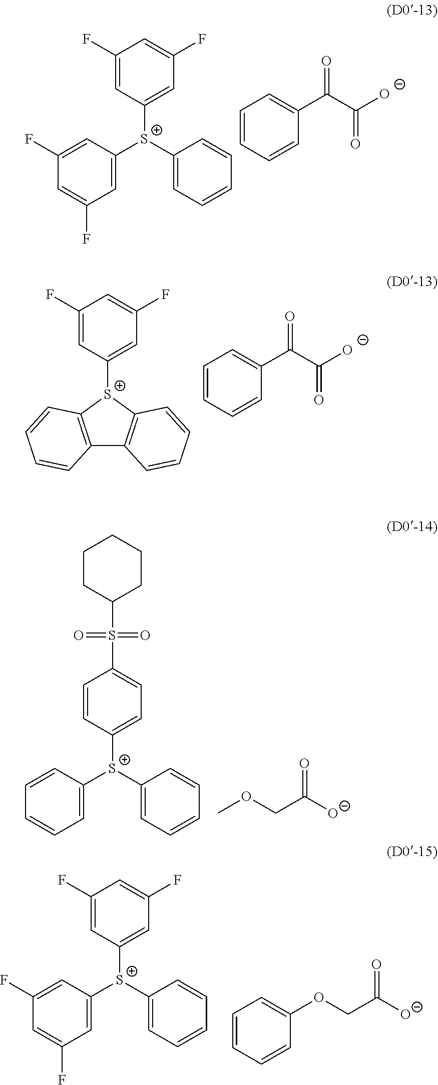

In the resist composition of the present embodiment, as the component (D0′), one kind of compound may be used, or two or more kinds of compounds may be used in combination.

In the resist composition of the present embodiment, the amount of the component (D0′) relative to 100 parts by weight of the component (A) is preferably 1 to 35 parts by weight, more preferably from 2 to 25 parts by weight, still more preferably from 3 to 20 parts by weight, and most preferably 3 to 15 parts by weight.

In a case where the amount of the component (D0′) is within the above-mentioned preferable range, the solubility of the resist composition in a developing solution may be appropriately ensured, and thus the effects of the present embodiment may be more reliably obtained.

The component (D) may include a photodegradable base (D1) (hereafter, sometimes referred to as “component (D1)”) which is decomposed by exposure to lose acid diffusion controlling ability, or a nitrogen-containing organic compound (D2) (hereafter, sometimes referred to as “component (D2)”) which does not fall under the definition of the component (D0) and the component (D1).

Component (D1)

The component (D1) is not particularly limited, as long as it does not fall under the definition of component (D0), and it is decomposed upon exposure and then loses the ability of controlling of acid diffusion. As the component (D1), at least one compound selected from the group consisting of a compound represented by general formula (d1-1) shown below (hereafter, referred to as “component (d1-1)”), a compound represented by general formula (d1-2) shown below (hereafter, referred to as “component (d1-2)”) and a compound represented by general formula (d1-3) shown below (hereafter, referred to as “component (d1-3)”) is preferably used.

At exposed portions of the resist film, the components (d1-1) to (d1-3) are decomposed and then lose the ability of controlling of acid diffusion (i.e., basicity), and therefore the components (d1-1) to (d1-3) cannot function as a quencher, whereas at unexposed portions of the resist film, the components (d1-1) to (d1-3) functions as a quencher.

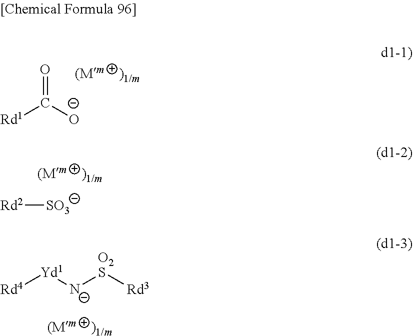

In the formulae, Rd¹ to Rd⁴ represent a cyclic group which may have a substituent, a chain-like alkyl group which may have a substituent or a chain-like alkenyl group which may have a substituent, provided that, the carbon atom adjacent to the sulfur atom within the Rd² in general formula (d1-2) has no fluorine atom bonded thereto; Yd¹ represents a single bond or a divalent linking group; m represents an integer of 1 or more, and each M′^{m+} independently represents an onium cation having a valency of m.

{Component (d1-1)}

Anion Moiety

In formula (d1-1), Rd¹ represents a cyclic group which may have a substituent, a chain-like alkyl group which may have a substituent or a chain-like alkenyl group which may have a substituent, and is the same groups as those defined above for R¹⁰¹ in the aforementioned formula (b-1).

Among these, as the group for Rd¹, an aromatic hydrocarbon group which may have a substituent, an aliphatic cyclic group which may have a substituent and a chain-like alkyl group which may have a substituent are preferable. Examples of the substituent for these groups include a hydroxy group, an oxo group, an alkyl group, an aryl group, a fluorine atom, a fluorinated alkyl group, a lactone-containing cyclic group represented by any one of the aforementioned formulae (a2-r-1) to (a2-r-7), an ether bond, an ester bond, and a combination thereof. In the case where an ether bond or an ester bond is included as the substituent, the substituent may be bonded via an alkylene group, and a linking group represented by any one of the aforementioned formulae (y-a1-1) to (y-a1-5) is preferable as the substituent.

Preferable examples of the aromatic hydrocarbon group include a phenyl group, a naphthyl group, and a polycyclic structure (for example, a polycyclic structure formed of a ring structure having a bicyclooctane skeleton and a ring structure other than the bicyclooctane skeleton) containing a bicyclooctane skeleton.

Examples of the aliphatic cyclic group include groups in which one or more hydrogen atoms have been removed from a polycycloalkane such as adamantane, norbornane, isobornane, tricyclodecane or tetracyclododecane.

The chain-like alkyl group preferably has 1 to 10 carbon atoms, and specific examples thereof include a linear alkyl group such as a methyl group, an ethyl group, a propyl group, a butyl group, a pentyl group, a hexyl group, a heptyl group, an octyl group, a nonyl or a decyl group, and a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group or a 4-methylpentyl group.

In the case where the chain-like alkyl group is a fluorinated alkyl group having a fluorine atom or a fluorinated alkyl group, the fluorinated alkyl group preferably has 1 to 11 carbon atoms, more preferably 1 to 8 carbon atoms, and still more preferably 1 to 4 carbon atoms. The fluorinated alkyl group may contain an atom other than fluorine. Examples of the atom other than fluorine include an oxygen atom, a sulfur atom and a nitrogen atom.

As Rd¹, a fluorinated alkyl group in which part or all of the hydrogen atoms constituting a linear alkyl group have been substituted with fluorine atom(s) is preferable, and a fluorinated alkyl group in which all of the hydrogen atoms constituting a linear alkyl group have been substituted with fluorine atoms (i.e., a linear perfluoroalkyl group) is particularly desirable.

Specific examples of preferable anion moieties for the component (d1-1) are shown below.

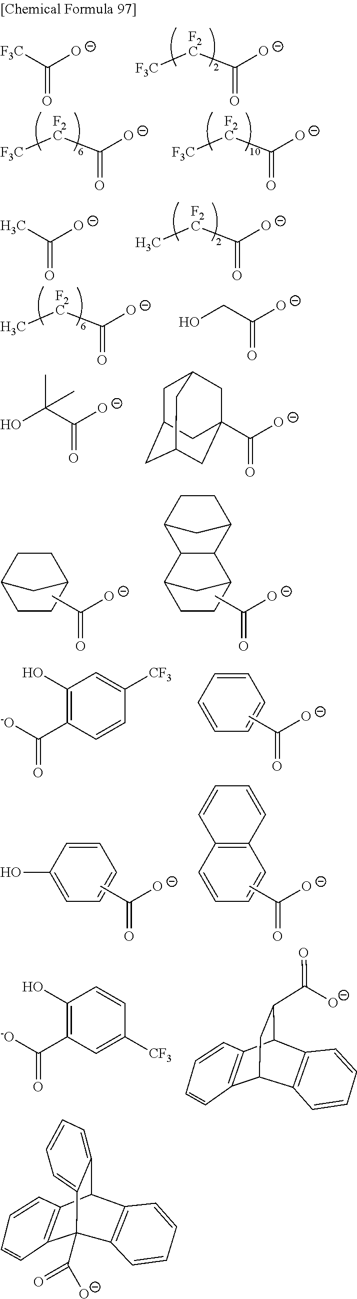

Cation Moiety

In formula (d1-1), M′^{m+} represents an m-valent organic cation.

Preferable examples of the organic cation for M′^{m+} include the same cation moieties as those represented by the aforementioned general formulae (ca-1) to (ca-5). Among these examples, a cation represented by general formula (ca-1) is preferable.

As the component (d1-1), one kind of compound may be used, or two or more kinds of compounds may be used in combination.

{Component (d1-2)}

Anion Moiety

In formula (d1-2), Rd² represents a cyclic group which may have a substituent, a chain-like alkyl group which may have a substituent or a chain-like alkenyl group which may have a substituent, and is the same groups as those defined above for R¹⁰¹ in the aforementioned formula (b-1).

However, the carbon atom adjacent to the sulfur atom within the Rd² has no fluorine atom bonded thereto. As a result, the component (d1-2) becomes a suitably weakly acidic anion, and the quenching ability of the component (D1) is improved.

As Rd², a chain-like alkyl group which may have a substituent or an aliphatic cyclic group which may have a substituent is preferable. The chain-like alkyl group preferably has 1 to 10 carbon atoms, and more preferably 3 to 10 carbon atoms. As the aliphatic cyclic group, a group in which one or more hydrogen atoms have been removed from adamantane, norbornane, isobornane, tricyclodecane, tetracyclododecane or camphor (which may have a substituent) is more preferable.

The hydrocarbon group for Rd² may have a substituent. As the substituent, the same groups as those described above for substituting the hydrocarbon group (e.g., aromatic hydrocarbon group, aliphatic cyclic group, chain-like alkyl group) for Rd¹ in the formula (d1-1) can be mentioned.

Specific examples of preferable anion moieties for the component (d1-2) are shown below.

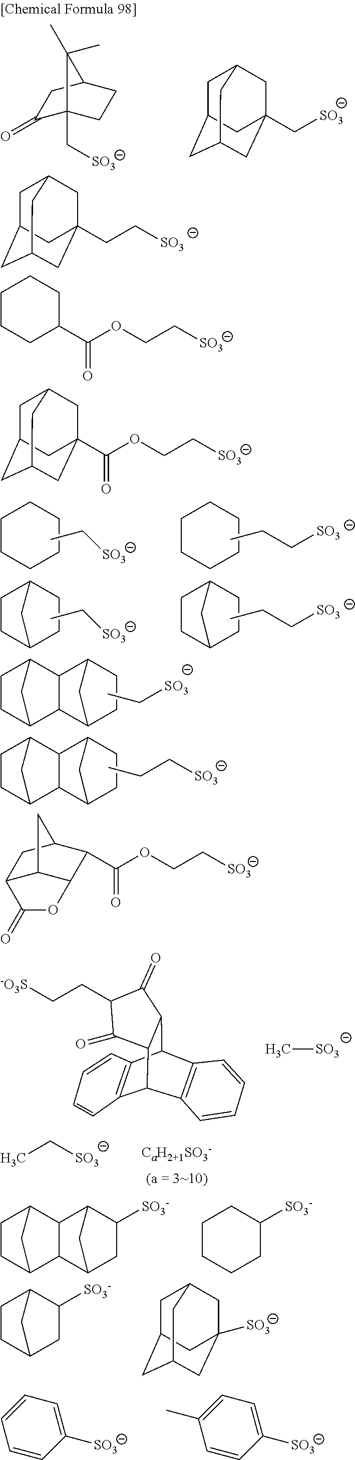

Cation Moiety

In formula (d1-2), M′^{m+} is an m-valent onium cation, and is the same as defined for M′^{m+} in the aforementioned formula (d1-1).

As the component (d1-2), one type of compound may be used, or two or more types of compounds may be used in combination.

{Component (d1-3)}

Anion Moiety

In formula (d1-3), Rd³ represents a cyclic group which may have a substituent, a chain-like alkyl group which may have a substituent or a chain-like alkenyl group which may have a substituent, and is the same groups as those defined above for R¹⁰¹ in the aforementioned formula (b-1), and a cyclic group containing a fluorine atom, a chain-like alkyl group or a chain-like alkenyl group is preferable. Among these, a fluorinated alkyl group is preferable, and more preferably the same fluorinated alkyl groups as those described above for Rd¹.

In formula (d1-3), Rd⁴ represents a cyclic group which may have a substituent, a chain-like alkyl group which may have a substituent or a chain-like alkenyl group which may have a substituent, and is the same groups as those defined above for R¹⁰¹ in the aforementioned formula (b-1).

Among these, an alkyl group which may have substituent, an alkoxy group which may have substituent, an alkenyl group which may have substituent or a cyclic group which may have substituent is preferable.

The alkyl group for Rd⁴ is preferably a linear or branched alkyl group of 1 to 5 carbon atoms, and specific examples include a methyl group, an ethyl group, a propyl group, an isopropyl group, an n-butyl group, an isobutyl group, a tert-butyl group, a pentyl group, an isopentyl group, and a neopentyl group. Part of the hydrogen atoms within the alkyl group for Rd⁴ may be substituted with a hydroxy group, a cyano group or the like.

The alkoxy group for Rd⁴ is preferably an alkoxy group of 1 to 5 carbon atoms, and specific examples thereof include a methoxy group, an ethoxy group, an n-propoxy group, an iso-propoxy group, an n-butoxy group and a tert-butoxy group. Among these, a methoxy group and an ethoxy group are preferable.

As the alkenyl group for Rd⁴, the same groups as those described above for R¹⁰¹ in the aforementioned formula (b-1) may be mentioned, and a vinyl group, a propenyl group (an allyl group), a 1-methylpropenyl group and a 2-methylpropenyl group are preferable. These groups may have an alkyl group of 1 to 5 carbon atoms or a halogenated alkyl group of 1 to 5 carbon atoms as a substituent.

As the cyclic group for Rd⁴, the same groups as those described above for R¹⁰¹ in the aforementioned formula (b-1) may be mentioned. Among these, as the cyclic group, an alicyclic group (e.g., a group in which one or more hydrogen atoms have been removed from a cycloalkane such as cyclopentane, cyclohexane, adamantane, norbornane, isobornane, tricyclodecane or tetracyclododecane) or an aromatic group (e.g., a phenyl group or a naphthyl group) is preferable. When Rd⁴ is an alicyclic group, the resist composition can be satisfactorily dissolved in an organic solvent, thereby improving the lithographic properties.

In formula (d1-3), Yd¹ represents a single bond or a divalent linking group.

The divalent linking group for Yd¹ is not particularly limited, and examples thereof include a divalent hydrocarbon group (aliphatic hydrocarbon group, or aromatic hydrocarbon group) which may have a substituent and a divalent linking group containing a hetero atom. The divalent linking groups are the same as defined for the divalent hydrocarbon group which may have a substituent and the divalent linking group containing a hetero atom explained above as the divalent linking group for Ya^{x1} in the aforementioned formula (a10-1).

As Yd¹, a carbonyl group, an ester bond, an amide bond, an alkylene group or a combination of these is preferable. As the alkylene group, a linear or branched alkylene group is more preferable, and a methylene group or an ethylene group is still more preferable.

Specific examples of preferable anion moieties for the component (d1-3) are shown below.

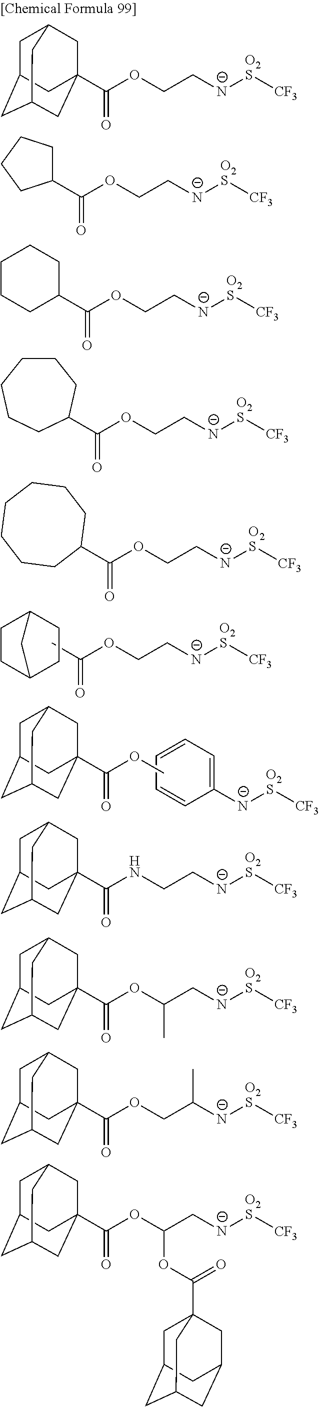

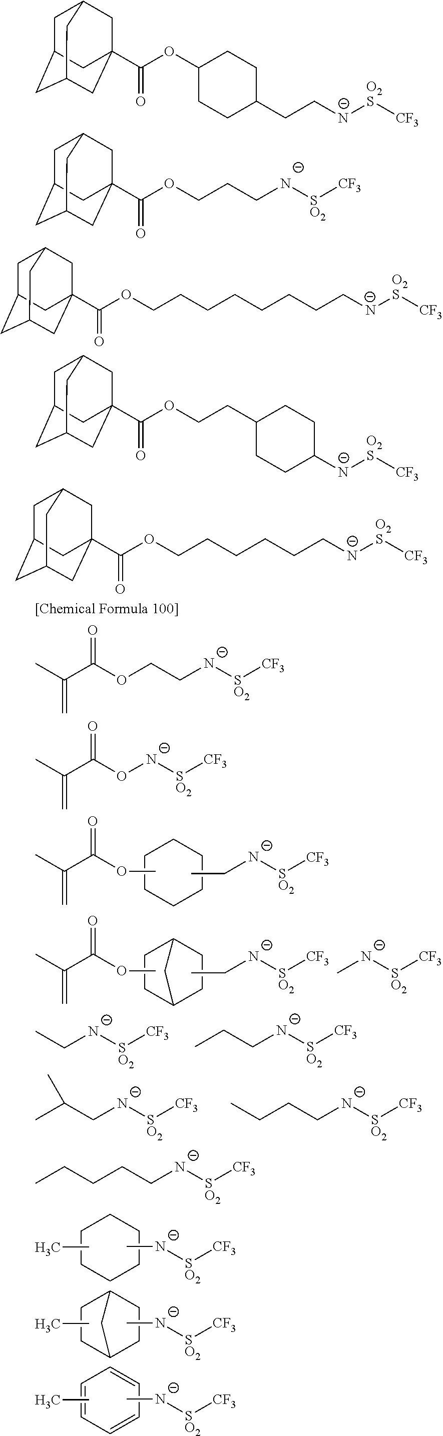

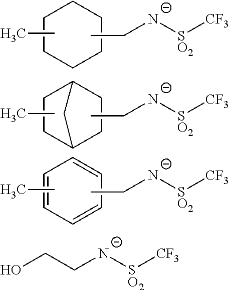

Cation Moiety

In formula (d1-3), M′^{m+} is an m-valent onium cation, and is the same as defined for M′^{m+} in the aforementioned formula (d1-1).

As the component (d1-3), one type of compound may be used, or two or more types of compounds may be used in combination.

As the component (D1), one type of the aforementioned components (d1-1) to (d1-3), or at least two types of the aforementioned components (d1-1) to (d1-3) can be used in combination.

In the case where the resist composition contains the component (D1), the amount of the component (D1) relative to 100 parts by weight of the component (A) is preferably within a range from 0.5 to 10 parts by weight.

When the amount of the component (D1) is at least as large as the lower limit of the above-mentioned range, excellent lithographic properties and excellent resist pattern shape may be more reliably obtained. On the other hand, when the amount of the component (D1) is no more than the upper limit of the above-mentioned preferable range, a good balance may be achieved with the other structural units, and the lithography properties may be improved.

Production Method of Component (D1):

The production methods of the components (d1-1) and (d1-2) are not particularly limited, and the components (d1-1) and (d1-2) can be produced by conventional methods.

Further, the production method of the component (d1-3) is not particularly limited, and the component (d1-3) can be produced in the same manner as disclosed in US2012-0149916.

Component (D2)

The component (D2) is a basic component, and is a nitrogen-containing organic compound which acts as an acid diffusion control agent in the resist composition.

The component (D2) is not particularly limited as long as it acts as an acid diffusion control agent and does not fall under the definition of the component (D0) and the component (D1). Examples thereof include aliphatic amines and aromatic amines.

Among the aliphatic amines, secondary aliphatic amines and tertiary aliphatic amines are preferable.

An aliphatic amine is an amine having one or more aliphatic groups, and the aliphatic groups preferably have 1 to 12 carbon atoms.

Examples of these aliphatic amines include amines in which at least one hydrogen atom of ammonia (NH₃) has been substituted with an alkyl group or hydroxyalkyl group of no more than 12 carbon atoms (i.e., alkylamines or alkylalcoholamines), and cyclic amines.

Specific examples of alkylamines and alkylalcoholamines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decylamine, and tri-n-dodecylamine; and alkyl alcohol amines such as diethanolamine, triethanolamine, diisopropanolamine, triisopropanolamine, di-n-octanolamine, and tri-n-octanolamine. Among these, trialkylamines of 5 to 10 carbon atoms are preferable, and tri-n-pentylamine and tri-n-octylamine are particularly desirable.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine).

Specific examples of the aliphatic monocyclic amine include piperidine, and piperazine. The aliphatic polycyclic amine preferably has 6 to 10 carbon atoms, and specific examples thereof include 1, 5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxy ethoxy)ethyl}amine, tris{2-(1-ethoxypropoxy)ethyl}amine, tris[2-{2-(2-hydroxyethoxy)ethoxy}ethyl]amine and triethanolamine triacetate, and triethanolamine triacetate is preferable.

Examples of aromatic amines include 4-dimethylaminopyridine, pyrrole, indole, pyrazole, imidazole and derivatives thereof, as well as tribenzylamine, aniline compound and N-tert-butoxycarbonylpyrrolidine.

As the component (D2), one kind of compound may be used, or two or more kinds of compounds may be used in combination. Among the above examples, as the component (D2), an aromatic amine is preferable, and an aniline compound is more preferable. Examples of the aniline compound include 2,6-diisopropylaniline, N, N-dimethylaniline, N, N-dibutylaniline, and N, N-dihexylaniline.

When the resist composition contains the component (D2), the amount of the component (D2) is typically used in an amount within a range from 0.01 to 5 parts by weight, relative to 100 parts by weight of the component (A). When the amount of the component (D2) is within the above-mentioned preferable range, a good balance may be achieved with the other structural units, and the lithography properties may be improved.

In the resist composition of the present embodiment, the total amount of the component (B) and the component (D) relative to 100 parts by weight of the component (A) is 25 to 60 parts by weight, preferably 25 to 55 parts by weight, and more preferably to 50 parts by weight.

When the total amount of the component (B) and the component (D) is at least as large as the lower limit of the above-mentioned range, in the formation of a resist pattern, various lithography properties such as sensitivity, reduction of roughness and pattern shape may be improved. On the other hand, when the total amount of the component (B) and the component (D) is no more than the upper limit of the above-mentioned range, film thickness loss of the resist pattern may be more reliably suppressed.

Further, in the resist composition, in terms of enhancing the effects of the present embodiment, the ratio of the amount of the component (B) to the amount of the component (D0) [molar ratio (B)/(D0)] is preferably more than 1, more preferably 1.5 to 10, still more preferably 3.8 to 5.3, and most preferably 4.0 to 5.1.

When the molar ratio (B)/(D0) is at least as large as the lower limit of the above-mentioned preferable range, in the formation of a resist pattern, various lithography properties such as sensitivity, reduction of roughness and pattern shape may be improved. On the other hand, when the molar ratio (B)/(D0) is no more than the upper limit of the above-mentioned preferable range, film thickness loss the resist pattern may be more reliably suppressed.

<Optional Components>

The resist composition of the present embodiment may contain, in addition to the aforementioned components (A), (B) and (D), any other optional components.

Examples of optional components include the component (E), the component (F) and the component (S) described below.

<<At Least One Compound (E) Selected from the Group Consisting of an Organic Carboxylic Acid, or a Phosphorus Oxo Acid or Derivative Thereof>>

In the resist composition of the present embodiment, for preventing any deterioration in sensitivity, and improving the resist pattern shape and the post exposure stability of the latent image formed by the pattern-wise exposure of the resist layer, at least one compound (E) (hereafter referred to as the component (E)) selected from the group consisting of an organic carboxylic acid, or a phosphorus oxo acid or derivative thereof may be added.

Examples of suitable organic carboxylic acids include acetic acid, malonic acid, citric acid, malic acid, succinic acid, benzoic acid, and salicylic acid.

Examples of phosphorus oxo acids include phosphoric acid, phosphonic acid and phosphinic acid. Among these, phosphonic acid is particularly desirable.

Examples of oxo acid derivatives include esters in which a hydrogen atom within the above-mentioned oxo acids is substituted with a hydrocarbon group. Examples of the hydrocarbon group include an alkyl group of 1 to 5 carbon atoms and an aryl group of 6 to carbon atoms.

Examples of phosphoric acid derivatives include phosphoric acid esters such as di-n-butyl phosphate and diphenyl phosphate.

Examples of phosphonic acid derivatives include phosphonic acid esters such as dimethyl phosphonate, di-n-butyl phosphonate, phenylphosphonic acid, diphenyl phosphonate and dibenzyl phosphonate.

Examples of phosphinic acid derivatives include phosphinic acid esters and phenylphosphinic acid.

In the resist composition of the present embodiment, as the component (E), one kind of compound may be used, or two or more kinds of compounds may be used in combination.

When the resist composition contains the component (E), the amount of the component (E) is typically used in an amount within a range from 0.01 to 5 parts by weight, relative to 100 parts by weight of the component (A).

<<Fluorine Additive (F)>>

In the present embodiment, the resist composition may further include a fluorine additive (hereafter, referred to as “component (F)”) for imparting water repellency to the resist film, or improving lithography properties.

As the component (F), for example, a fluorine-containing polymeric compound described in Japanese Unexamined Patent Application, First Publication No. 2010-002870, Japanese Unexamined Patent Application, First Publication No. 2010-032994, Japanese Unexamined Patent Application, First Publication No. 2010-277043, Japanese Unexamined Patent Application, First Publication No. 2011-13569, and Japanese Unexamined Patent Application, First Publication No. 2011-128226 can be used.

Specific examples of the component (F) include polymers having a structural unit (f1) represented by general formula (f1-1) shown below. As the polymer, a polymer (homopolymer) consisting of a structural unit (f1) represented by formula (f1-1) shown below; a copolymer of the structural unit (f1) and the aforementioned structural unit (a1); and a copolymer of the structural unit (f1), a structural unit derived from acrylic acid or methacrylic acid and the aforementioned structural unit (a1) are preferable. As the structural unit (a1) to be copolymerized with the structural unit (f1), a structural unit derived from 1-ethyl-1-cyclooctyl (meth)acrylate or a structural unit derived from 1-methyl-1-adamantyl (meth)acrylate is preferable.

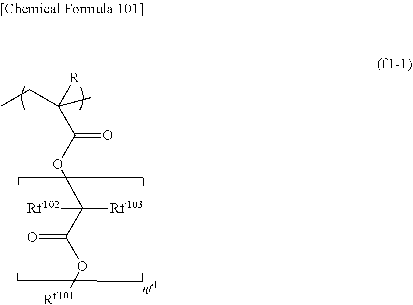

In the formula, R is the same as defined above; Rf¹⁰² and Rf¹⁰³ each independently represents a hydrogen atom, a halogen atom, an alkyl group of 1 to 5 carbon atoms, or a halogenated alkyl group of 1 to 5 carbon atoms, provided that Rf¹⁰² and Rf¹⁰³ may be the same or different; nf¹ represents an integer of 0 to 5; and Rf¹⁰¹ represents an organic group containing a fluorine atom.

In formula (f1-1), R bonded to the carbon atom on the α-position is the same as defined above. As R, a hydrogen atom or a methyl group is preferable.

In formula (f1-1), as the halogen atom for Rf¹⁰² and Rf¹⁰³, a fluorine atom is preferable. Examples of the alkyl group of 1 to 5 carbon atoms for Rf¹⁰² and Rf¹⁰³ include the same alkyl group of 1 to 5 carbon atoms as those described above for R, and a methyl group or an ethyl group is preferable. Specific examples of the halogenated alkyl group of 1 to 5 carbon atoms represented by Rf¹⁰² or Rf¹⁰³ include groups in which part or all of the hydrogen atoms of the aforementioned alkyl groups of 1 to 5 carbon atoms have been substituted with halogen atoms. As the halogen atom, a fluorine atom is most preferable. Among these, as Rf¹⁰² and Rf¹⁰³, a hydrogen atom, a fluorine atom or an alkyl group of 1 to 5 carbon atoms is preferable, and a hydrogen atom, a fluorine atom, a methyl group or an ethyl group is more preferable. In formula (f1-1), nf¹ represents an integer of 0 to 5, preferably an integer of 0 to 3, and more preferably 1 or 2.

In formula (f1-1), Rf¹⁰¹ represents an organic group containing a fluorine atom, and is preferably a hydrocarbon group containing a fluorine atom.

The hydrocarbon group containing a fluorine atom may be linear, branched or cyclic, and preferably has 1 to 20 carbon atoms, more preferably 1 to 15 carbon atoms, and most preferably 1 to 10 carbon atoms.

It is preferable that the hydrocarbon group having a fluorine atom has 25% or more of the hydrogen atoms within the hydrocarbon group fluorinated, more preferably 50% or more, and most preferably 60% or more, as the hydrophobicity of the resist film during immersion exposure is enhanced.

Among these, as Rf¹⁰¹, a fluorinated hydrocarbon group of 1 to 6 carbon atoms is preferable, and a trifluoromethyl group, —CH₂—CF₃, —CH₂—CF₂—CF₃, —CH(CF₃)₂, —CH₂—CH₂—CF₃, and —CH₂—CH₂—CF₂—CF₂—CF₂—CF₃ are most preferable.

The weight average molecular weight (Mw) (the polystyrene equivalent value determined by gel permeation chromatography) of the component (F) is preferably 1,000 to 50,000, more preferably 5,000 to 40,000, and most preferably 10,000 to 30,000. When the weight average molecular weight (Mw) is no more than the upper limit of the above-mentioned range, the resist may exhibit satisfactory solubility in a resist solvent. On the other hand, when the weight average molecular weight (Mw) is at least as large as the lower limit of the above-mentioned range, the water repellency of the resist film may become satisfactory.

Further, the dispersity (Mw/Mn) of the component (F) is preferably 1.0 to 5.0, more preferably 1.0 to 3.0, and most preferably 1.0 to 2.5.

In the resist composition of the present embodiment, as the component (F), one kind of compound may be used, or two or more kinds of compounds may be used in combination.

When the resist composition contains the component (F), the component (F) is used in an amount within a range from 0.5 to 10 parts by weight, relative to 100 parts by weight of the component (A).

<<Organic Solvent (S)>>

The resist composition of the present embodiment may be prepared by dissolving the resist materials for the resist composition in an organic solvent (hereafter, referred to as “component (S)”).

The component (S) may be any organic solvent which can dissolve the respective components to give a homogeneous solution, and any organic solvent can be appropriately selected from those which have been conventionally known as solvents for a chemically amplified resist composition.

Examples thereof include lactones such as γ-butyrolactone; ketones such as acetone, methyl ethyl ketone, cyclohexanone, methyl-n-pentyl ketone, methyl isopentyl ketone, and 2-heptanone; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether (e.g., monomethylether, monoethylether, monopropylether or monobutylether) or monophenylether of any of these polyhydric alcohols or compounds having an ester bond (among these, propylene glycol monomethyl ether acetate (PGMEA) and propylene glycol monomethyl ether (PGME) are preferable); cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene and mesitylene; and dimethylsulfoxide (DMSO).

In the resist composition of the present embodiment, as the component (S), one kind of solvent may be used, or two or more kinds of compounds may be used as a mixed solvent. Among these examples, PGMEA, PGME, γ-butyrolactone, EL and cyclohexanone are preferable.

Further, as the component (S), a mixed solvent obtained by mixing PGMEA with a polar solvent is preferable. The mixing ratio (weight ratio) of the mixed solvent can be appropriately determined, taking into consideration the compatibility of the PGMEA with the polar solvent, but is preferably in the range of 1:9 to 9:1, more preferably from 2:8 to 8:2.

Specifically, when EL or cyclohexanone is mixed as the polar solvent, the PGMEA:EL or cyclohexanone weight ratio is preferably from 1:9 to 9:1, and more preferably from 2:8 to 8:2. Alternatively, when PGME is mixed as the polar solvent, the PGMEA:PGME weight ratio is preferably from 1:9 to 9:1, more preferably from 2:8 to 8:2, and still more preferably 3:7 to 7:3. Furthermore, a mixed solvent of PGMEA, PGME and cyclohexanone is also preferable.

Further, as the component (S), a mixed solvent of at least one of PGMEA and EL with γ-butyrolactone is also preferable. The mixing ratio (former:latter) of such a mixed solvent is preferably from 70:30 to 95:5.

The amount of the component (S) is not particularly limited, and is appropriately adjusted to a concentration which enables coating of a coating solution to a substrate. In general, the component (S) is used in an amount such that the solid content of the resist composition becomes within the range from 0.1 to 20% by weight, and preferably from 0.2 to 15% by weight.

If desired, other miscible additives can also be added to the resist composition of the present invention. Examples of such miscible additives include additive resins for improving the performance of the resist film, dissolution inhibitors, plasticizers, stabilizers, colorants, halation prevention agents, and dyes.

After dissolving the resist materials in the organic solvent (S), the resist composition of the present embodiment may have impurities or the like removed by using a polyimide porous film, a polyamide-imide porous film, or the like. For example, the resist composition may be subjected to filtration using a filter formed of a polyimide porous membrane, a filter formed of a polyamide-imide porous film, or a filter formed of a polyimide porous membrane and a polyamide-imide porous film. Examples of the polyimide porous membrane and the polyamide-imide porous film include those described in Japanese Unexamined Patent Application, First Publication No. 2016-155121.

The resist composition of the present embodiment as described above contains the acid-generator component (B) and the basic component (D) in a total amount of 25 to 60 parts by weight, relative to 100 parts by weight of the base material component (A). Further, the component (D) includes a compound (D0) represented by general formula (d0). Since the component (D0) has a polar linking group Xd⁰ and a terminal organic group Rd⁰, the solubility of the resist composition in a developing solution may be appropriately controlled. As a result, even when the component (B) and the component (D) are blended in the resist composition in larger amounts, the conventional problem of film thickness loss is unlikely to occur. Further, since the component (D0) has a polar linking group Xd⁰, the acidity of the acid generated from the component (D0) may be enhanced.

Therefore, it is presumed that, according to the resist composition of the present embodiment, sensitivity may be enhanced, lithography properties may be improved (such as reduction of roughness), and resist pattern in which film thickness loss is unlikely to occur and exhibit a high film retention ratio may be reliably formed.

Further, by using the resist composition of the present embodiment, the uniformity of the compound (D0) within the resist film may be enhanced. Therefore, a resist pattern may be reliably formed with high resolution and reduced roughness.

The resist composition according to the present embodiment may contain, as the acid-generator component (B), a compound (B0) represented by general formula (b0).

Since the compound (B0) has a specific structure primarily constituted of hydrocarbon (a bulky structure) in the anion moiety, hydrophobicity is relatively enhanced. As a result, the compatibility of the compound (B0) with the base material component (A) is enhanced, and the diffusion of acid within the resist film may be appropriately controlled.

On the other hand, since the component (D0) has a polar linking group Xd⁰ in the anion moiety, the hydrophilicity is enhanced, and the solubility of the resist composition in a developing solution is improved.

Therefore, in the resist composition adopting the combination of the compound (B0) and the compound (D0), the balance of the hydrophobicity/hydrophilicity of the entire resist composition is appropriately controlled.

Combined with the above effects, it is presumed that when the resist composition of the present embodiment contains the component (B0), a resist pattern having reduced roughness and fine resolution may be formed.

The resist composition of the present embodiment may contain, as the component (D0), a compound (D0′) represented by general formula (d0′).

Since the component (D0′) has a specific electron-withdrawing group in the cation moiety, decomposition by exposure is promoted. Therefore, in the formation of a resist pattern using the resist composition according to the present embodiment, for example, in an unexposed portion of the resist film, the component (D0′) functions as a quencher (acid diffusion control agent) which traps acid generated from the component (B) upon exposure. On the other hand, in an exposed portion of the resist film, decomposition of the component (D0′) is promoted, and the component (D0′) loses the function of a quenched (acid diffusion control agent). As a result, the contrast between the exposed portion and the unexposed portion of the resist film may be improved.

Further, since the component (D0′) has a polar linking group Xd⁰ in the anion moiety, the solubility of the resist composition in a developing solution is enhanced. In addition, since the component (D0′) has a polar linking group Xd⁰ acid diffusion length may be appropriately controlled.

Combined with the above effects, when the resist composition of the present embodiment contains the (D0′) component, it is presumed that sensitivity may be enhanced, and a resist pattern having fine resolution may be formed.

(Method of Forming a Resist Pattern)

The method of forming a resist pattern according to the second aspect of the present invention includes: using a resist composition according to the first aspect to form a resist film on a substrate; exposing the resist film; and developing the exposed resist film to form a resist pattern.

The method for forming a resist pattern according to the present embodiment can be performed, for example, as follows.

Firstly, a resist composition of the first aspect is applied to a substrate using a spinner or the like, and a bake treatment (post applied bake (PAB)) is conducted at a temperature of 80 to 150° C. for 40 to 120 seconds, preferably 60 to 90 seconds, to form a resist film.

Following selective exposure of the thus formed resist film, either by exposure through a mask having a predetermined pattern formed thereon (mask pattern) using an exposure apparatus such an electron beam lithography apparatus or an EUV exposure apparatus, or by patterning via direct irradiation with an electron beam without using a mask pattern, baking treatment (post exposure baking (PEB)) is conducted under temperature conditions of 80 to 150° C. for 40 to 120 seconds, and preferably 60 to 90 seconds.

Next, the resist film is subjected to a developing treatment. The developing treatment is conducted using an alkali developing solution in the case of an alkali developing process, and a developing solution containing an organic solvent (organic developing solution) in the case of a solvent developing process.

After the developing treatment, it is preferable to conduct a rinse treatment. The rinse treatment is preferably conducted using pure water in the case of an alkali developing process, and a rinse solution containing an organic solvent in the case of a solvent developing process.

In the case of a solvent developing process, after the developing treatment or the rinsing, the developing solution or the rinse liquid remaining on the pattern can be removed by a treatment using a supercritical fluid.

After the developing treatment or the rinse treatment, drying is conducted. If desired, bake treatment (post bake) can be conducted following the developing.

In this manner, a resist pattern can be formed.

The substrate is not specifically limited and a conventionally known substrate can be used. For example, substrates for electronic components, and such substrates having wiring patterns formed thereon can be used. Specific examples of the material of the substrate include metals such as silicon wafer, copper, chromium, iron and aluminum; and glass. Suitable materials for the wiring pattern include copper, aluminum, nickel, and gold.

Further, as the substrate, any one of the above-mentioned substrates provided with an inorganic and/or organic film on the surface thereof may be used. As the inorganic film, an inorganic antireflection film (inorganic BARC) can be used. As the organic film, an organic antireflection film (organic BARC) and an organic film such as a lower-layer organic film used in a multilayer resist method can be used.

Here, a “multilayer resist method” is method in which at least one layer of an organic film (lower-layer organic film) and at least one layer of a resist film (upper resist film) are provided on a substrate, and a resist pattern formed on the upper resist film is used as a mask to conduct patterning of the lower-layer organic film. This method is considered as being capable of forming a pattern with a high aspect ratio. More specifically, in the multilayer resist method, a desired thickness can be ensured by the lower-layer organic film, and as a result, the thickness of the resist film can be reduced, and an extremely fine pattern with a high aspect ratio can be formed.

The multilayer resist method is broadly classified into a method in which a double-layer structure consisting of an upper-layer resist film and a lower-layer organic film is formed (double-layer resist method), and a method in which a multilayer structure having at least three layers consisting of an upper-layer resist film, a lower-layer organic film and at least one intermediate layer (thin metal film or the like) provided between the upper-layer resist film and the lower-layer organic film (triple-layer resist method).

The wavelength to be used for exposure is not particularly limited and the exposure can be conducted using radiation such as ArF excimer laser, KrF excimer laser, F₂ excimer laser, extreme ultraviolet rays (EUV), vacuum ultraviolet rays (VUV), electron beam (EB), X-rays, and soft X-rays. The resist composition of the present embodiment is effective to KrF excimer laser, ArF excimer laser, EB and EUV, and more effective to ArF excimer laser, EB and EUV, and most effective to EB and EUV. That is, the method of forming a resist pattern according to the present embodiment is effective in the case where the step of exposing the resist film includes exposing the resist film with extreme ultraviolet rays (EUV) or electron beam (EB).

The exposure of the resist film can be either a general exposure (dry exposure) conducted in air or an inert gas such as nitrogen, or immersion exposure (immersion lithography).

In immersion lithography, the region between the resist film and the lens at the lowermost point of the exposure apparatus is pre-filled with a solvent (immersion medium) that has a larger refractive index than the refractive index of air, and the exposure (immersion exposure) is conducted in this state.

The immersion medium preferably exhibits a refractive index larger than the refractive index of air but smaller than the refractive index of the resist film to be exposed. The refractive index of the immersion medium is not particularly limited as long as it satisfies the above-mentioned requirements.

Examples of this immersion medium which exhibits a refractive index that is larger than the refractive index of air but smaller than the refractive index of the resist film include water, fluorine-based inert liquids, silicon-based solvents and hydrocarbon-based solvents.

Specific examples of the fluorine-based inert liquids include liquids containing a fluorine-based compound such as C₃HCl₂F₅, C₄F₉OCH₃, C₄F₉OC₂H₅ or C₅H₃F₇ as the main component, which have a boiling point within a range from 70 to 180° C. and preferably from 80 to 160° C. A fluorine-based inert liquid having a boiling point within the above-mentioned range is advantageous in that the removal of the immersion medium after the exposure can be conducted by a simple method.

As a fluorine-based inert liquid, a perfluoroalkyl compound in which all of the hydrogen atoms of the alkyl group are substituted with fluorine atoms is particularly desirable. Examples of these perfluoroalkyl compounds include perfluoroalkylether compounds and perfluoroalkylamine compounds.

Specifically, one example of a suitable perfluoroalkylether compound is perfluoro(2-butyl-tetrahydrofuran) (boiling point 102° C.), and an example of a suitable perfluoroalkylamine compound is perfluorotributylamine (boiling point 174° C.).

As the immersion medium, water is preferable in terms of cost, safety, environment and versatility.

As an example of the alkali developing solution used in an alkali developing process, a 0.1 to 10% by weight aqueous solution of tetramethylammonium hydroxide (TMAH) can be given.

As the organic solvent contained in the organic developing solution used in a solvent developing process, any of the conventional organic solvents can be used which are capable of dissolving the component (A) (prior to exposure). Specific examples of the organic solvent include polar solvents such as ketone solvents, ester solvents, alcohol solvents, nitrile solvents, amide solvents and ether solvents, and hydrocarbon solvents.

A ketone solvent is an organic solvent containing C—C(═O)—C within the structure thereof. An ester solvent is an organic solvent containing C—C(═O)—O—C within the structure thereof. An alcohol solvent is an organic solvent containing an alcoholic hydroxy group in the structure thereof. An “alcoholic hydroxy group” refers to a hydroxy group bonded to a carbon atom of an aliphatic hydrocarbon group. A nitrile solvent is an organic solvent containing a nitrile group in the structure thereof. An amide solvent is an organic solvent containing an amide group within the structure thereof. An ether solvent is an organic solvent containing C—O—C within the structure thereof.

Some organic solvents have a plurality of the functional groups which characterizes the aforementioned solvents within the structure thereof. In such a case, the organic solvent can be classified as any type of the solvent having the characteristic functional group. For example, diethylene glycol monomethyl ether may be classified as an alcohol solvent or an ether solvent.

A hydrocarbon solvent consists of a hydrocarbon which may be halogenated, and does not have any substituent other than a halogen atom. As the halogen atom, a fluorine atom is preferable.

As the organic solvent contained in the organic developing solution, among these, a polar solvent is preferable, and ketone solvents, ester solvents and nitrile solvents are preferable.

Examples of ketone solvents include 1-octanone, 2-octanone, 1-nonanone, 2-nonanone, acetone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonylalcohol, acetylcarbinol, acetophenone, methyl naphthyl ketone, isophorone, propylenecarbonate, γ-butyrolactone and methyl amyl ketone (2-heptanone). Among these examples, as a ketone solvent, methyl amyl ketone (2-heptanone) is preferable.

Examples of ester solvents include methyl acetate, butyl acetate, ethyl acetate, isopropyl acetate, amyl acetate, isoamyl acetate, ethyl methoxyacetate, ethyl ethoxyacetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate and propyl-3-methoxypropionate. Among these examples, as an ester solvent, butyl acetate is preferable. Among these examples, as an ester solvent, butyl acetate is preferable.

Examples of nitrile solvents include acetonitrile, propionitrile, valeronitrile, and butyronitrile.

If desired, the organic developing solution may have a conventional additive blended. Examples of the additive include surfactants. The surfactant is not particularly limited, and for example, an ionic or non-ionic fluorine and/or silicon surfactant may be used. As the surfactant, a non-ionic surfactant is preferable, and a non-ionic fluorine surfactant or a non-ionic silicon surfactant is more preferable.

When a surfactant is added, the amount thereof based on the total amount of the organic developing solution is generally 0.001 to 5% by weight, preferably 0.005 to 2% by weight, and more preferably 0.01 to 0.5% by weight.

The developing treatment may be performed by a conventional developing method. Examples thereof include a method in which the substrate is immersed in the developing solution for a predetermined time (a dip method), a method in which the developing solution is cast up on the surface of the substrate by surface tension and maintained for a predetermined period (a puddle method), a method in which the developing solution is sprayed onto the surface of the substrate (spray method), and a method in which the developing solution is continuously ejected from a developing solution ejecting nozzle while scanning at a constant rate to apply the developing solution to the substrate while rotating the substrate at a constant rate (dynamic dispense method).

As the organic solvent contained in the rinse liquid used in the rinse treatment after the developing treatment in the case of a solvent developing process, any of the aforementioned organic solvents contained in the organic developing solution can be used which hardly dissolves the resist pattern. In general, at least one solvent selected from the group consisting of hydrocarbon solvents, ketone solvents, ester solvents, alcohol solvents, amide solvents and ether solvents is used. Among these, at least one solvent selected from the group consisting of hydrocarbon solvents, ketone solvents, ester solvents, alcohol solvents and amide solvents is preferable, more preferably at least one solvent selected from the group consisting of alcohol solvents and ester solvents, and an alcohol solvent is particularly desirable.

The alcohol solvent used for the rinse liquid is preferably a monohydric alcohol of 6 to 8 carbon atoms, and the monohydric alcohol may be linear, branched or cyclic. Specific examples thereof include 1-hexanol, 1-heptanol, 1-octanol, 2-hexanol, 2-heptanol, 2-octanol, 3-hexanol, 3-heptanol, 3-octanol, 4-octanol and benzyl alcohol. Among these, 1-hexanol, 2-heptanol and 2-hexanol are preferable, and 1 hexanol and 2-hexanol are more preferable.

As the organic solvent, one kind of solvent may be used alone, or two or more kinds of solvents may be used in combination. Further, an organic solvent other than the aforementioned examples or water may be mixed together. However, in consideration of the development characteristics, the amount of water within the rinse liquid, based on the total amount of the rinse liquid is preferably 30% by weight or less, more preferably 10% by weight or less, still more preferably 5% by weight or less, and most preferably 3% by weight or less.

If desired, the rinse solution may have a conventional additive blended. Examples of the additive include surfactants. Examples of the additive include surfactants. As the surfactant, the same surfactants as those described above can be mentioned, a non-ionic surfactant is preferable, and a non-ionic fluorine surfactant or a non-ionic silicon surfactant is more preferable.

When a surfactant is added, the amount thereof based on the total amount of the rinse liquid is generally 0.001 to 5% by weight, preferably 0.005 to 2% by weight, and more preferably 0.01 to 0.5% by weight.

The rinse treatment using a rinse liquid (washing treatment) can be conducted by a conventional rinse method. Examples of the rinse method include a method in which the rinse liquid is continuously applied to the substrate while rotating it at a constant rate (rotational coating method), a method in which the substrate is immersed in the rinse liquid for a predetermined time (dip method), and a method in which the rinse liquid is sprayed onto the surface of the substrate (spray method).

In the method forming a resist pattern according to the present embodiment described above, by virtue of using the resist composition according to the above embodiment, it becomes possible to enhance sensitivity in the formation of a resist pattern, and a resist pattern having improved lithography properties (such as reduced roughness) can be formed.

In addition, in the method of forming a resist pattern according to the present embodiment, even when the total amount of the acid-generator component (B) and the basic component (D) in the resist composition is increased, a resist pattern which is unlikely to have occurrence of film thickness loss, and a high film retention ratio can be formed.

### EXAMPLES

As follows is a description of examples of the present invention, although the scope of the present invention is by no way limited by these examples.

### Production Examples of Polymeric Compounds (A-1) to (A-5)

Each of the polymeric compounds (A-1) to (A-5) was obtained by a conventional radical polymerization of monomers which derive the structural units constituting the polymeric compound, at a predetermined ratio.

The obtained polymeric compounds (A-1) to (A-5) are shown below.

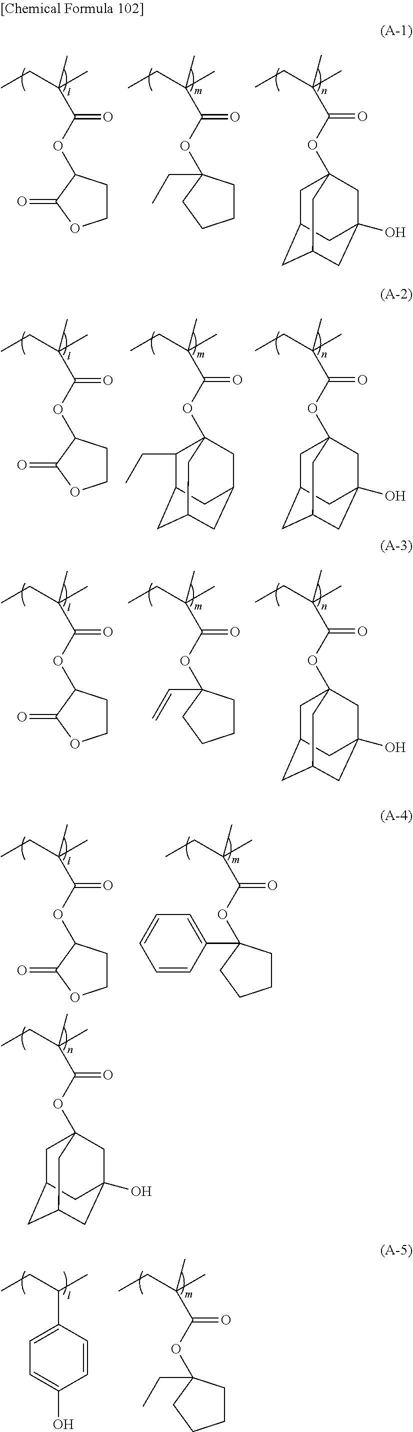

With respect to each polymeric compound, the compositional ratio of the polymers (the molar ratio of the structural units derived from respective monomers) as determined by ¹³C-NMR, the weight average molecular weight (Mw) and the dispersity (Mw/Mn) determined by the polystyrene equivalent value as measured by GPC are also shown in Table 1.

TABLE 1

| | Copolymer | | |
|---|---|---|---|
| | compositional ratio of | Weight average | |
| Polymeric | polymeric compound | molecular weight | Dispersity |
| compound | (molar ratio) | (Mw) | (Mw/Mn) |
| (A-1) | l/m/n = 30/60/10 | 6800 | 1.65 |
| (A-2) | l/m/n = 40/40/20 | 6900 | 1.68 |
| (A-3) | l/m/n = 30/60/10 | 7000 | 1.64 |
| (A-4) | l/m/n = 30/60/10 | 7200 | 1.67 |
| (A-5) | l/m = 50/50 | 7200 | 1.69 |

<Production of Resist Composition (1)>

### Examples 1 to 16, Comparative Examples 1 to 22

The components shown in Table 2 and 3 were mixed together and dissolved to obtain each resist composition (solid content: 1.7% by weight).

TABLE 2

| | | | | | Total |
|---|---|---|---|---|---|
| | | | | | amount of |
| | | | | | components |
| | Com- | Com- | Com- | Com- | (B) and (D) |
| | ponent | ponent | ponent | ponent | (parts by |
| | (A) | (B) | (D) | (S) | weight) |
| Example 1 | (A)-1 | (B)-1 | (D0)-1 | (S)-1 | 26.5 |
| | [100] | [21.9] | [4.6] | | |
| Example 2 | (A)-1 | (B)-1 | (D0)-1 | (S)-1 | 39.9 |
| | [100] | [32.9] | [7.0] | | |
| Example 3 | (A)-1 | (B)-1 | (D0)-1 | (S)-1 | 59.8 |
| | [100] | [49.4] | [10.4] | | |
| Example 4 | (A)-1 | (B)-1 | (D0)-2 | (S)-1 | 39.1 |
| | [100] | [32.9] | [6.2] | | |
| Example 5 | (A)-1 | (B)-1 | (D0)-3 | (S)-1 | 39.1 |
| | [100] | [32.9] | [6.2] | | |
| Example 6 | (A)-1 | (B)-2 | (D0)-1 | (S)-1 | 34.9 |
| | [100] | [27.9] | [7.0] | | |
| Example 7 | (A)-1 | (B)-3 | (D0)-1 | (S)-1 | 33.8 |
| | [100] | [26.8] | [7.0] | | |
| Example 8 | (A)-1 | (B)-4 | (D0)-1 | (S)-1 | 39.1 |
| | [100] | [32.1] | [7.0] | | |
| Example 9 | (A)-1 | (B)-5 | (D0)-1 | (S)-1 | 42.5 |
| | [100] | [35.5] | [7.0] | | |
| Example 10 | (A)-1 | (B)-6 | (D0)-1 | (S)-1 | 40.7 |
| | [100] | [33.7] | [7.0] | | |
| Example 11 | (A)-1 | (B)-1 | (D0)-4 | (S)-1 | 40.7 |
| | [100] | [32.9] | [7.8] | | |
| Example 12 | (A)-1 | (B)-1 | (D0)-5 | (S)-1 | 40.1 |
| | [100] | [32.9] | [7.2] | | |
| Example 13 | (A)-2 | (B)-1 | (D0)-1 | (S)-1 | 39.9 |
| | [100] | [32.9] | [7.0] | | |
| Example 14 | (A)-3 | (B)-1 | (D0)-1 | (S)-1 | 39.9 |
| | [100] | [32.9] | [7.0] | | |
| Example 15 | (A)-4 | (B)-1 | (D0)-1 | (S)-1 | 39.9 |
| | [100] | [32.9] | [7.0] | | |
| Example 16 | (A)-5 | (B)-1 | (D0)-1 | (S)-1 | 39.9 |
| | [100] | [32.9] | [7.0] | | |

TABLE 3

| | | | | | Total |
|---|---|---|---|---|---|
| | | | | | amount of |
| | | | | | components |
| | Com- | Com- | Com- | Com- | (B) and (D) |
| | ponent | ponent | ponent | ponent | (parts by |
| | (A) | (B) | (D) | (S) | weight) |
| Comparative | (A)-1 | (B)-1 | (D1)-1 | (S)-1 | 25.7 |
| Example 1 | [100] | [21.9] | [3.8] | | |
| Comparative | (A)-1 | (B)-1 | (D1)-1 | (S)-1 | 38.7 |
| Example 2 | [100] | [32.9] | [5.8] | | |
| Comparative | (A)-1 | (B)-1 | (D1)-1 | (S)-1 | 58.0 |
| Example 3 | [100] | [49.4] | [8.6] | | |
| Comparative | (A)-1 | (B)-1 | (D1)-2 | (S)-1 | 38.8 |
| Example 4 | [100] | [32.9] | [5.9] | | |
| Comparative | (A)-1 | (B)-1 | (D1)-3 | (S)-1 | 39.0 |
| Example 5 | [100] | [32.9] | [6.1] | | |
| Comparative | (A)-1 | (B)-1 | (D0)-1 | (S)-1 | 13.3 |
| Example 6 | [100] | [11.0] | [2.3] | | |
| Comparative | (A)-1 | (B)-1 | (D0)-1 | (S)-1 | 23.6 |
| Example 7 | [100] | [19.5] | [4.1] | | |
| Comparative | (A)-1 | (B)-1 | (D0)-1 | (S)-1 | 79.7 |
| Example 8 | [100] | [65.8] | [13.9] | | |
| Comparative | (A)-1 | (B)-1 | (D0)-2 | (S)-1 | 13.1 |
| Example 9 | [100] | [11.0] | [2.1] | | |
| Comparative | (A)-1 | (B)-1 | (D0)-3 | (S)-1 | 13.1 |
| Example 10 | [100] | [11.0] | [2.1] | | |
| Comparative | (A)-1 | (B)-2 | (D0)-1 | (S)-1 | 11.6 |
| Example 11 | [100] | [9.3] | [2.3] | | |
| Comparative | (A)-1 | (B)-2 | (D0)-1 | (S)-1 | 69.6 |
| Example 12 | [100] | [55.7] | [13.9] | | |
| Comparative | (A)-1 | (B)-3 | (D0)-1 | (S)-1 | 11.2 |
| Example 13 | [100] | [8.9] | [2.3] | | |
| Comparative | (A)-1 | (B)-4 | (D0)-1 | (S)-1 | 13.0 |
| Example 14 | [100] | [10.7] | [2.3] | | |
| Comparative | (A)-1 | (B)-5 | (D0)-1 | (S)-1 | 14.1 |
| Example 15 | [100] | [11.8] | [2.3] | | |
| Comparative | (A)-1 | (B)-6 | (D0)-1 | (S)-1 | 13.5 |
| Example 16 | [100] | [11.2] | [2.3] | | |
| Comparative | (A)-1 | (B)-1 | (D0)-4 | (S)-1 | 13.6 |
| Example 17 | [100] | [11.0] | [2.6] | | |
| Comparative | (A)-1 | (B)-1 | (D0)-5 | (S)-1 | 13.4 |
| Example 18 | [100] | [11.0] | [2.4] | | |
| Comparative | (A)-2 | (B)-1 | (D0)-1 | (S)-1 | 13.3 |
| Example 19 | [100] | [11.0] | [2.3] | | |
| Comparative | (A)-3 | (B)-1 | (D0)-1 | (S)-1 | 13.3 |
| Example 20 | [100] | [11.0] | [2.3] | | |
| Comparative | (A)-4 | (B)-1 | (D0)-1 | (S)-1 | 13.3 |
| Example 21 | [100] | [11.0] | [2.3] | | |
| Comparative | (A)-5 | (B)-1 | (D0)-1 | (S)-1 | 13.3 |
| Example 22 | [100] | [11.0] | [2.3] | | |

In Tables 2 and 3, the reference characters indicate the following. The values in brackets [ ] indicate the amount (in terms of parts by weight) of the component added.

(A)-1 to (A)-5: the aforementioned polymeric compounds (A-1) to (A-5).

(B)-1: an acid generator represented by chemical formula (B-1) shown below.

(B)-2: an acid generator represented by chemical formula (B-2) shown below

(B)-3: an acid generator represented by chemical formula (B-3) shown below

(B)-4: an acid generator represented by chemical formula (B-4) shown below

(B)-5: an acid generator represented by chemical formula (B-5) shown below

(B)-6: an acid generator represented by chemical formula (B-6) shown below

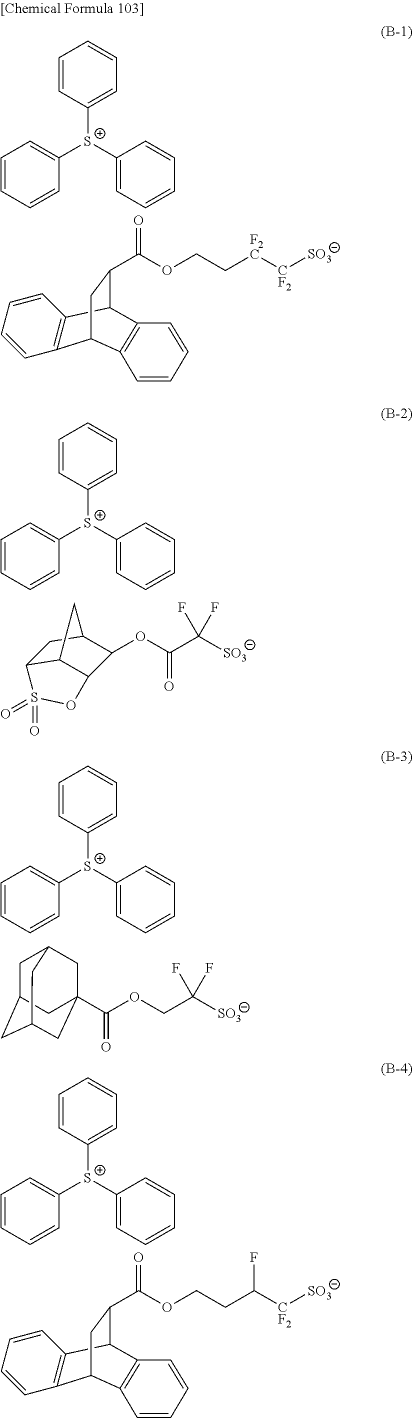

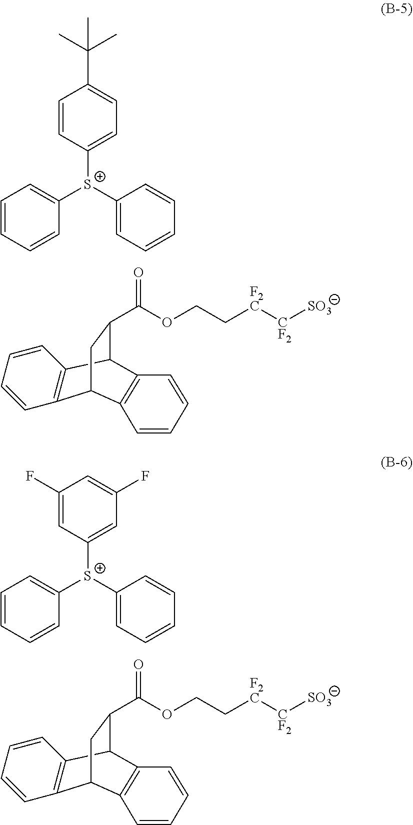

(D0)-1: a compound represented by chemical formula (D0-1) shown below

(D0)-2: a compound represented by chemical formula (D0-2) shown below

(D0)-3: a compound represented by chemical formula (D0-3) shown below

(D0)-4: a compound represented by chemical formula (D0-4) shown below

(D0)-5: a compound represented by chemical formula (D0-5) shown below

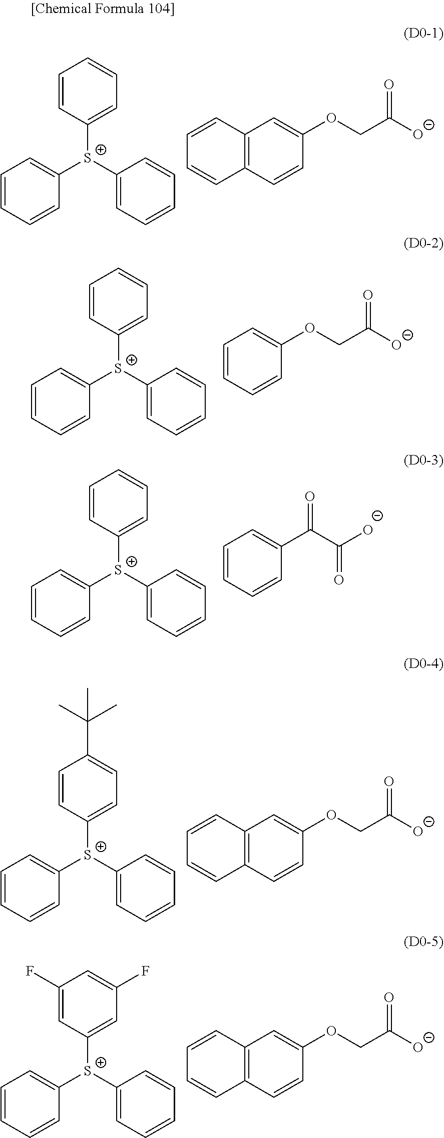

(D1)-1: Acid diffusion control agent represented by chemical formula (D1-1) shown below.

(D1)-2: Acid diffusion control agent represented by chemical formula (D1-2) shown below.

(D1)-3: Acid diffusion control agent represented by chemical formula (D1-3) shown below.

(S)-1: a mixed solvent of propylene glycol monomethyl ether acetate/propylene glycol monomethyl ether=60/40 (weight ratio).

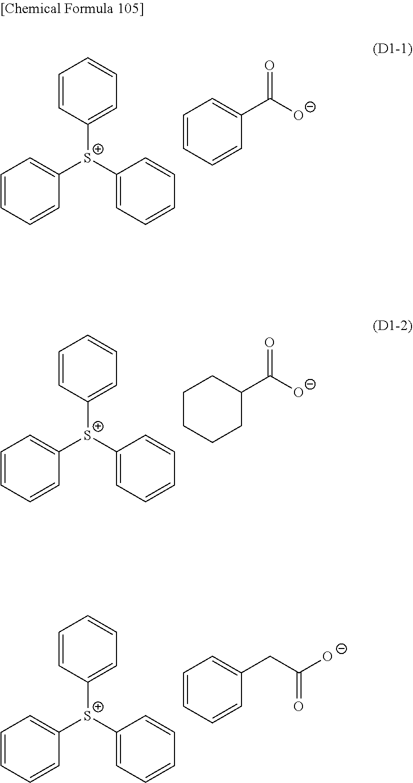 [SMILES: c1ccc([S+](c2ccccc2)c2ccccc2)cc1 ; O=C([O-])c1ccccc1 ; c1ccc([S+](c2ccccc2)c2ccccc2)cc1 ; O=C([O-])C1CCCCC1 ; c1ccc([S+](c2ccccc2)c2ccccc2)cc1 ; O=C([O-])Cc1ccccc1]

<Formation of Resist Pattern (1)>

Each of the resist compositions of examples and comparative examples was applied to an 8-inch silicon substrate which had been treated with hexamethyldisilazane (HMDS) using a spinner, and was then prebaked (PAB) on a hot plate at 110° C. for 60 seconds and dried, thereby forming a resist film having a film thickness of 50 nm.

A drawing (exposure) was carried out on the resist film using an electron beam lithography apparatus JEOL-JBX-9300FS (manufactured by JEOL Ltd.) with acceleration voltage of 100 kV and a target size of 1:1 line-and-space pattern (line width: 50 nm to 20 nm) (hereinafter referred to as an “LS pattern”). Then, a post exposure bake (PEB) treatment was conducted at 100° C. for 60 seconds. Thereafter, alkali developing was conducted for 60 seconds at 23° C. in a 2.38% by weight aqueous solution of tetramethylammonium hydroxide (TMAH) (product name: NMD-3; manufactured by Tokyo Ohka Kogyo Co., Ltd.). Then, water rinsing was conducted for 15 seconds using pure water.

As a result, a 1:1 LS pattern having a line width of 50 to 20 nm was formed.

[Evaluation of Optimum Exposure Dose (Eop)]

The optimum exposure dose Eop (μC/cm²) with which the LS pattern having a target size (line width: 50 nm) was formed in the above “Formation of resist pattern (1)” was determined. The results are indicated under “Eop (μC/cm²)” in Tables 4 and 5.

[Evaluation of Line Width Roughness (LWR)]

With respect to the LS pattern formed in the above “Formation of resist pattern (1)” with a target size of 50 nm, 3σ was determined as a yardstick for indicating LWR. The results are indicated under “LWR (nm)” in Tables 4 and 5.

“3σ” indicates a value of 3 times the standard deviation (σ) (i.e., 3σ) (unit: nm) determined by measuring the line positions at 400 points in the lengthwise direction of the line using a scanning electron microscope (product name: S-9380, manufactured by Hitachi High-Technologies Corporation; acceleration voltage: 800V).

The smaller this 3σ value is, the lower the level of roughness on the side walls of the line, indicating that an LS pattern with a uniform width was obtained.

[Evaluation of Film Thickness Loss]

The film thickness loss was evaluated as follows. The film thickness of the large area unexposed portion of the resist film after PAB in the above <Formation of resist pattern (1)> and the film thickness after rinsing were measured. With respect to the film thickness of the resist film after rinsing, the case where the change in the film thickness from the film thickness of the resist film after PAB was within 3% (film retention ratio of 97% or more) was evaluated “A”, more than 3% and no more than 5% (film retention ratio of 95% or more and less than 97%) was evaluated “B”, and more than 5% (film retention ratio of less than 95%) was evaluated “C”. The results are indicated under “Film thickness loss (nm)” in Tables 4 and 5.

TABLE 4

| | | | | | Film |
|---|---|---|---|---|---|
| | PAB | PEB | Eop | LWR | thickness |
| | (° C.) | (° C.) | [μC/cm²] | [nm] | loss |
| Example 1 | 110 | 100 | 135 | 4.9 | A |
| Example 2 | 110 | 100 | 130 | 4.5 | A |
| Example 3 | 110 | 100 | 120 | 4.1 | A |
| Example 4 | 110 | 100 | 130 | 4.5 | A |
| Example 5 | 110 | 100 | 130 | 4.6 | A |
| Example 6 | 110 | 100 | 135 | 4.7 | A |
| Example 7 | 110 | 100 | 135 | 4.8 | A |
| Example 8 | 110 | 100 | 130 | 4.6 | A |
| Example 9 | 110 | 100 | 140 | 4.8 | A |
| Example 10 | 110 | 100 | 125 | 4.7 | A |
| Example 11 | 110 | 100 | 135 | 4.8 | A |
| Example 12 | 110 | 100 | 130 | 4.7 | A |
| Example 13 | 110 | 100 | 140 | 5.2 | A |
| Example 14 | 110 | 100 | 115 | 4.1 | A |
| Example 15 | 110 | 100 | 110 | 4.0 | A |
| Example 16 | 110 | 100 | 80 | 4.3 | A |

TABLE 5

| | | | | | Film |
|---|---|---|---|---|---|
| | PAB | PEB | Eop | LWR | thickness |
| | (° C.) | (° C.) | [μC/cm²] | [nm] | loss |
| Comparative | 110 | 100 | 160 | 4.6 | B |
| Example 1 | | | | | |
| Comparative | 110 | 100 | 155 | 4.4 | C |
| Example 2 | | | | | |
| Comparative | 110 | 100 | 145 | 4.2 | C |
| Example 3 | | | | | |
| Comparative | 110 | 100 | 160 | 4.5 | C |
| Example 4 | | | | | |
| Comparative | 110 | 100 | 160 | 4.6 | C |
| Example 5 | | | | | |
| Comparative | 110 | 100 | 145 | 6.0 | A |
| Example 6 | | | | | |
| Comparative | 110 | 100 | 140 | 5.3 | A |
| Example 7 | | | | | |
| Comparative | 110 | 100 | 120 | 4.2 | C |
| Example 8 | | | | | |
| Comparative | 110 | 100 | 145 | 6.0 | A |
| Example 9 | | | | | |
| Comparative | 110 | 100 | 145 | 6.2 | A |
| Example 10 | | | | | |
| Comparative | 110 | 100 | 150 | 6.2 | A |
| Example 11 | | | | | |
| Comparative | 110 | 100 | 130 | 4.5 | C |
| Example 12 | | | | | |
| Comparative | 110 | 100 | 150 | 6.3 | A |
| Example 13 | | | | | |
| Comparative | 110 | 100 | 150 | 6.1 | A |
| Example 14 | | | | | |
| Comparative | 110 | 100 | 150 | 6.0 | A |
| Example 15 | | | | | |
| Comparative | 110 | 100 | 140 | 6.0 | A |
| Example 16 | | | | | |
| Comparative | 110 | 100 | 150 | 6.0 | A |
| Example 17 | | | | | |
| Comparative | 110 | 100 | 145 | 6.0 | A |
| Example 18 | | | | | |
| Comparative | 110 | 100 | 155 | 6.5 | A |
| Example 19 | | | | | |
| Comparative | 110 | 100 | 130 | 5.4 | A |
| Example 20 | | | | | |
| Comparative | 110 | 100 | 125 | 5.3 | A |
| Example 21 | | | | | |
| Comparative | 110 | 100 | 100 | 5.7 | A |
| Example 22 | | | | | |

From the results shown in Tables 4 and 5, according to the resist composition of the examples which applied the present invention, sensitivity could be enhanced in the formation of a resist pattern, and a resist pattern having a good shape could be formed with reduced roughness.

In addition, in the resist compositions of the examples which applied the present invention, it can be confirmed that, even when the total amount of the component (B) and the component (D) is increased, film thickness loss of the pattern is unlikely to occur.

<Formation of Resist Pattern (2)>

Using the resist compositions of Examples 1 to 3, Comparative Examples 1 to 3 and Comparative Examples 6 to 8, a 1:1 LS pattern having a line width of 50 nm was formed in the same manner as in the above “Formation of resist pattern (1)”.

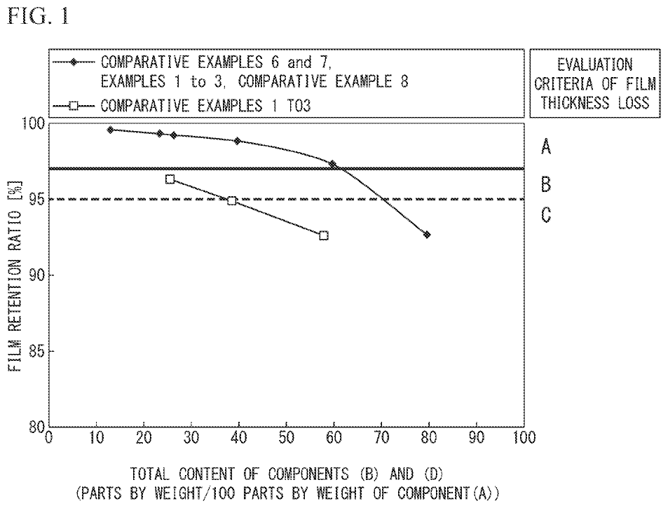

In the same manner as in the above “Evaluation of film thickness loss”, the change in the film thickness (film retention ratio) of the resist film after rinsing, with respect to the film thickness of the resist film after PAB was determined. The results are shown in FIG. 1.

FIG. 1 is a graph showing the change in the film retention ratio relative to the total amount of the components (B) and (D) in the resist composition.

In FIG. 1, “A” indicates that the change in the film thickness of the resist film with respect to the film thickness of the resist film after PAB was within 3% (film retention ratio of 97% or more). In FIG. 1, “B” indicates that the change in the film thickness was more than 3% and no more than 5% (film retention ratio of 95% or more and less than 97%).

In FIG. 1, “C” indicates that the change in the film thickness was more than 5% (film retention ratio of less than 95%).

As seen from the results shown in FIG. 1, it was confirmed that, in the case of a resist composition in which compound (D0-1) was used as the component (D), even when the total amount of the component (B) and the component (D) was increased to 60 parts by weight, the film retention ratio of the resist film was maintained at 97% or more. In addition, it was confirmed that, with respect to the resist compositions of Examples 1 to 3 in which the total amount of the component (B) and the component (D) was 25 to 60 parts by weight, sensitivity could be enhanced, and a resist pattern having a good shape and reduced roughness could be formed.

On the other hand, in the case of a resist composition in which compound (D1-1) was used as the component (D), when the total amount of the component (B) and the component (D) exceeded 25 parts by weight, the film retention ratio of the resist film could not maintain 97%, and the film retention ratio was markedly decreased as the total amount was increased.

<Production of Resist Composition (2)>

### Examples 2A, 5A to 8A, Comparative Examples 1A, 3A, 5A to 7A

The components shown in Tables 6 and 7 were mixed together and dissolved to obtain each resist composition.

TABLE 6

| | Component | Component | Component | Component |
|---|---|---|---|---|
| | (A) | (B) | (D) | (S) |
| Example | (A)-1a | (B0)-1 | (D0)-2a | (S)-1 |
| 2A | [100] | [21.0] | [4.1] | [6400] |
| Example | (A)-1a | (B0)-2 | (D0)-5a | (S)-1 |
| 5A | [100] | [24.2] | [4.1] | [6400] |
| Example | (A)-1a | (B0)-2 | (D0)-6a | (S)-1 |
| 6A | [100] | [24.2] | [4.0] | [6400] |
| Example | (A)-2a | (B0)-1 | (D0)-4a | (S)-1 |
| 7A | [100] | [21.0] | [5.8] | [6400] |
| Example | (A)-2a | (B0)-1 | (D0)-5a | (S)-1 |
| 8A | [100] | [21.0] | [4.1] | [6400] |

TABLE 7

| | Component | Component | Component | Component |
|---|---|---|---|---|
| | (A) | (B) | (D) | (S) |
| Comparative | (A)-1a | (B1)-1 | (D0)-1a | (S)-1 |
| Example 1A | [100] | [15.5] | [3.9] | [6400] |
| Comparative | (A)-1a | (B1)-2 | (D0)-2a | (S)-1 |
| Example 2A | [100] | [17.2] | [4.1] | [6400] |
| Comparative | (A)-1a | (B0)-1 | (D1)-1a | (S)-1 |
| Example 3A | [100] | [21.0] | [3.6] | [6400] |
| Comparative | (A)-1a | (B0)-3 | (D1)-3a | (S)-1 |
| Example 5A | [100] | [16.9] | [3.7] | [6400] |
| Comparative | (A)-2a | (B1)-3 | (D0)-4a | (S)-1 |
| Example 6A | [100] | [15.0] | [5.8] | [6400] |
| Comparative | (A)-2a | (B0)-1 | (D1)-4a | (S)-1 |
| Example 7A | [100] | [21.0] | [3.6] | [6400] |

In Tables 6 and 7, the reference characters indicate the following. The values in brackets [ ] indicate the amount (in terms of parts by weight) of the component added.

(A)-1a: polymeric compound represented by chemical formula (A-1a) shown below. The polymeric compound (A-1a) was obtained by a radical polymerization of monomers which derive the structural units constituting the polymeric compound, at a predetermined ratio. With respect to the polymeric compound (A-1a), the weight average molecular weight (Mw) and the polydispersity (Mw/Mn) were determined by the polystyrene equivalent value as measured by gel permeation chromatography (GPC). As a result, it was found that the weight average molecular weight was 7,100, and the polydispersity was 1.68. The composition of the copolymer (ratio (molar ratio) of the respective structural units within the structural formula) as determined by ¹³C-NMR was l/m=50/50.

(A)-2a: polymeric compound represented by chemical formula (A-2a) shown below. The polymeric compound (A-2a) was obtained by a radical polymerization of monomers which derive the structural units constituting the polymeric compound, at a predetermined ratio. With respect to the polymeric compound (A-2a), the weight average molecular weight (Mw) and the polydispersity (Mw/Mn) were determined by the polystyrene equivalent value as measured by gel permeation chromatography (GPC). As a result, it was found that the weight average molecular weight was 7,300, and the polydispersity was 1.75. The composition of the copolymer (ratio (molar ratio) of the respective structural units within the structural formula) as determined by ¹³C-NMR was l/m/n=30/60/10.

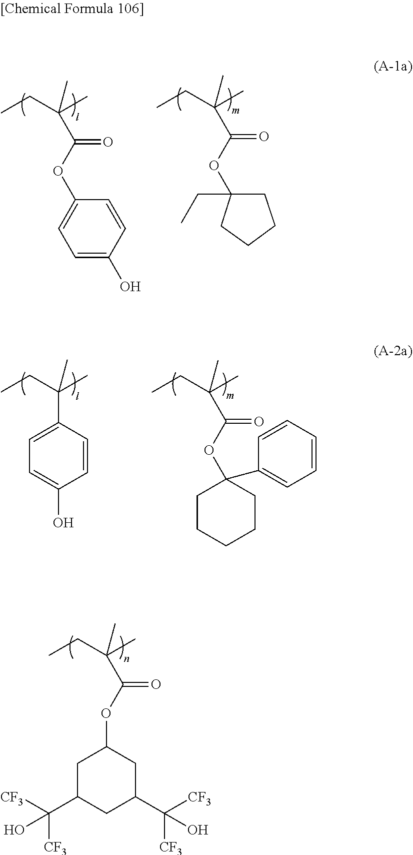

(B0)-1 to (B0)-3: acid generators represented by chemical formulae (B0-1) to (B0-3) shown below.

(B1)-1 to (B1)-3: acid generators represented by chemical formulae (B1-1) to (B1-3) shown below.

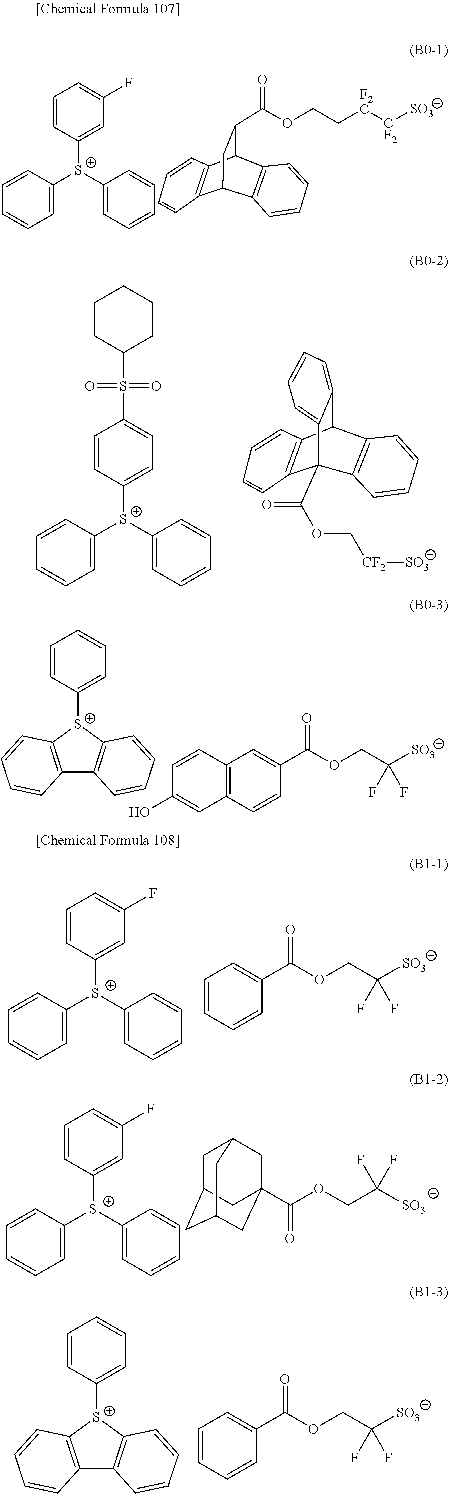

(D0)-1a to (D0)-6a: Acid diffusion control agents represented by the aforementioned chemical formulae (D0-1a) to (D0-6a).

(D1)-1a to (D1)-4a: Acid diffusion control agents represented by the aforementioned chemical formulae (D1-1a) to (D1-4a).

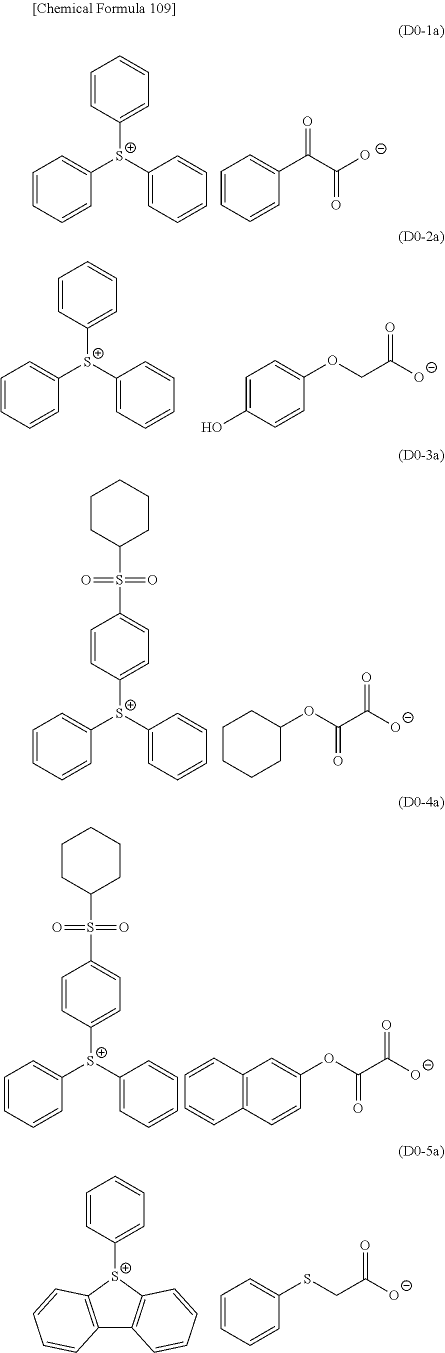

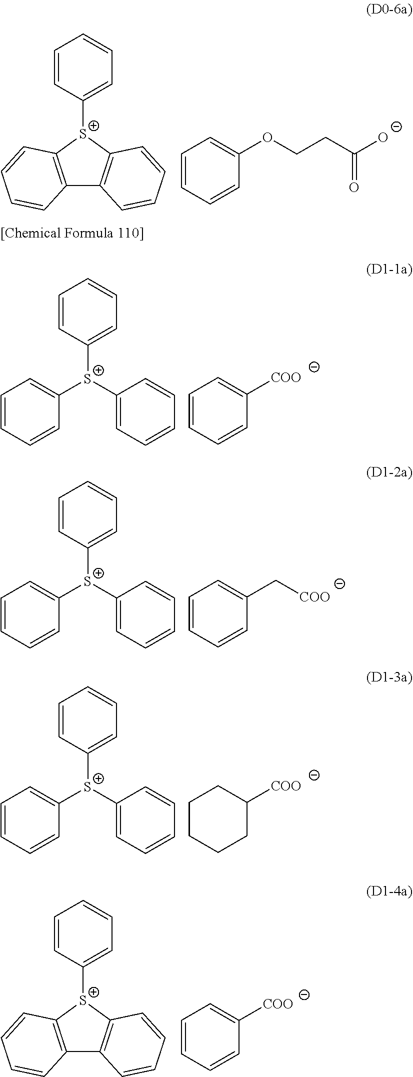

(S)-1: a mixed solvent of propylene glycol monomethyl ether acetate/propylene glycol monomethyl ether=60/40 (weight ratio).

<Formation of Resist Pattern (3)>

Each of the resist compositions of examples and comparative examples was applied to an 8-inch silicon substrate which had been treated with hexamethyldisilazane (HMDS) using a spinner, and was then prebaked (PAB) on a hot plate at 110° C. for 60 seconds and dried, thereby forming a resist film having a film thickness of 50 nm.

A drawing (exposure) was carried out on the resist film using an electron beam lithography apparatus JEOL-JBX-9300FS (manufactured by JEOL Ltd.) with acceleration voltage of 100 kV and a target size of a contact hole pattern in which holes having a diameter of 32 nm were arranged at equal intervals (pitch of 64 nm) (hereinafter referred to as a “CH pattern”). Then, a post exposure bake (PEB) treatment was conducted at 110° C. for 60 seconds.

Thereafter, alkali developing was conducted for 60 seconds at 23° C. in a 2.38% by weight aqueous solution of tetramethylammonium hydroxide (TMAH) (product name: NMD-3; manufactured by Tokyo Ohka Kogyo Co., Ltd.).

Then, water rinsing was conducted for 15 seconds using pure water.

As a result, a CH pattern in which holes having a diameter of 32 nm were arranged at equal intervals (pitch of 64 nm) was formed.

[Evaluation of in-Plane Uniformity (CDU) of Pattern Size]

With respect to each hole pattern obtained above, 400 holes in the CH pattern were observed from the upper side thereof using a lengthwise measuring scanning electron microscope (SEM) (product name: CG5000, manufactured by Hitachi High-Technologies Corporation; acceleration voltage: 500V), and the hole diameter (nm) of each hole was measured. From the results, the value of 3 times the standard deviation (σ) (3σ) was determined. The results are indicated under “CDU (nm)” in Tables 8 and 9.

The smaller the thus determined 3σ value is, the higher the level of the dimension uniformity (CD uniformity) of the holes formed in the resist film.

[Evaluation of Critical Resolution]

The critical resolution with the above Eop was determined using a scanning electron microscope (product name: S-9380, manufactured by Hitachi High-Technologies Corporation). Specifically, the exposure dose was gradually decreased from the optimum exposure dose Eop, and the hole diameter (nm) of the pattern which resolves was determined. The results are indicated under “Critical resolution (nm)” in Tables 8 and 9.

TABLE 8

| | | | | Critical |
|---|---|---|---|---|
| | PAB | PEB | CDU | resolution |
| | (° C.) | (° C.) | [nm] | [nm] |
| Example 2A | 110 | 110 | 4.8 | 24 |
| Example 5A | 110 | 110 | 4.9 | 24 |
| Example 6A | 110 | 110 | 4.7 | 24 |
| Example 7A | 110 | 110 | 4.3 | 24 |
| Example 8A | 110 | 110 | 4.3 | 24 |

TABLE 9

| | | | | Critical |
|---|---|---|---|---|
| | PAB | PEB | CDU | resolution |
| | (° C.) | (° C.) | [nm] | [nm] |
| Comparative | 110 | 110 | 5.8 | 24 |
| Example 1A | | | | |
| Comparative | 110 | 110 | 6.1 | 24 |
| Example 2A | | | | |
| Comparative | 110 | 110 | 5.1 | 32 |
| Example 3A | | | | |
| Comparative | 110 | 110 | 5.5 | 32 |
| Example 5A | | | | |
| Comparative | 110 | 110 | 5.7 | 24 |
| Example 6A | | | | |
| Comparative | 110 | 110 | 4.5 | 32 |
| Example 7A | | | | |

As seen from the results shown in Tables 8 and 9, the resist compositions of examples could form a resist pattern with improved CDU and resolution, as compared to the resist compositions of comparative examples.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A resist composition which generates acid upon exposure and exhibits changed solubility in a developing solution under action of acid, the resist composition comprising:
a base material component (A) which exhibits changed solubility in a developing solution under action of acid,
an acid-generator component (B) which generates acid upon exposure, and
a basic component (D) which controls diffusion of the acid generated from the acid-generator component (B) upon exposure,
the basic component (D) comprising a compound (D0) represented by general formula (d0) shown below, and
a total amount of the acid-generator component (B) and the basic component (D) being 25 to 60 parts by weight, relative to 100 parts by weight of the base material component (A):
Rd⁰-Xd⁰-Yd⁰-COO^{⊖}(M^{m⊕})_{1/m} (d0)
wherein Rd⁰ represents a monovalent organic group; Xd⁰ represents —O—, —C(═O)—, —O—C(═O)—, —C(═O)—O—, —S— or —SO₂—; Yd⁰ represents a single bond or a divalent hydrocarbon group which may have a substituent; M^{m+} represents a m-valent organic cation; and m represents an integer of 1 or more.

2. The resist composition according to claim 1, wherein Rd⁰ represents a cyclic hydrocarbon group which may have a substituent.

3. The resist composition according to claim 1, wherein the amount of the compound (D0) relative to 100 parts by weight of the base material component (A) is 4 parts by weight or more.

4. The resist composition according to claim 1, wherein the amount of the component (B) relative to 100 parts by weight of the base material component (A) is 20 parts by weight or more.

5. The resist composition according to claim 1, wherein the acid-generator component (B) comprises a compound (B0) represented by general formula (b0) shown below:
Rb⁰-Yb⁰-Vb⁰-SO₃^{⊖}(M^{m⊕})_{1/m} (b0)
wherein Rb⁰ represents a condensed cyclic group containing a condensed ring having at least one aromatic ring; Yb⁰ represents a divalent linking group or a single bond; Vb⁰ represents a single bond, an alkylene group or a fluorinated alkylene group; M^{m+} represents a m-valent organic cation; and m represents an integer of 1 or more.

6. The resist composition according to claim 5, wherein Rd⁰ in general formula (d0) represents a cyclic hydrocarbon group which may have a substituent.

7. The resist composition according to claim 5, wherein the compound (B0) comprises a compound represented by general formula (b0-1) shown below: 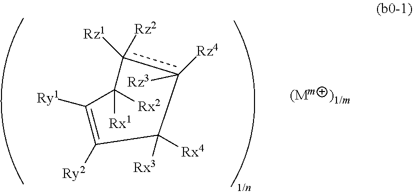
wherein Rx¹ to Rx⁴ each independently represents a hydrogen atom or a hydrocarbon group which may have a substituent, or two or more of Rx¹ to Rx⁴ may be mutually bonded to form a ring structure; Ry¹ and Ry² each independently represents a hydrogen atom or a hydrocarbon group which may have a substituent, or Ry¹ and Ry² may be mutually bonded to form a ring structure; [symbol]
represents a double bond or a single bond; Rz¹ to Rz⁴ each independently represents, where valence allows, a hydrogen atom or a hydrocarbon group which may have a substituent, or two or more of Rz¹ to Rz⁴ may be mutually bonded to form a ring structure; provided that 2 or more of Rx¹ to Rx⁴, Ry¹ and Ry², or 2 or more of Rz¹ to Rz⁴ are mutually bonded to form an aromatic ring; at least one of Rx¹ to Rx⁴, Ry¹, Ry² and Rz¹ to Rz⁴ has an anionic group represented by general formula (b0-r-an1) shown below, and the whole anion moiety is an n-valent anion; n represents an integer of 1 or more; m represents an integer of 1 or more; and M^{m+} represents an organic cation having a valency of m:
*—Yb⁰-Vb⁰-SO₃^{⊖} (b0-r-an1),
wherein Yb⁰ represents a divalent linking group or a single bond; Vb⁰ represents a single bond, an alkylene group or a fluorinated alkylene group; and * represents a bonding site.

8. The resist composition according to claim 1, wherein the compound (D0) comprises a compound (D0′) represented by general formula (d0′) shown below: 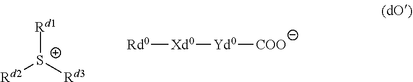
wherein Rd¹′ represents an aryl group having an electron-withdrawing group selected from a halogen atom, a halogenated alkyl group, a cyano group, a nitro group, an alkylsulfone group or an arylsufone group; the aryl group for Rd¹′ may have, as a substituent, an alkyl group, an alkoxy group, an oxycarbonyl group, a sulfenyl group or an aryl group; Rd²′ and Rd³′ each independently represents an aryl group, alkyl group or alkenyl group which may have a substituent; Rd²′ and Rd³′ may be mutually bonded to form a ring with the sulfur atom in the formula; provided that, in the case where Rd²′ and Rd³′ are mutually bonded to form a ring with the sulfur atom in the formula, a ring structure formed via —C(═O)— is excluded; Rd⁰ represents a monovalent organic group; Xd⁰ represents —O—, —C(═O)—, —O—C(═O)—, —C(═O)—O—, —S— or —SO₂—; and Yd⁰ represents a single bond or a divalent hydrocarbon group which may have a substituent.

9. The resist composition according to claim 8, wherein the compound (D0′) comprised a compound represented by general formula (d0′-1) shown below: 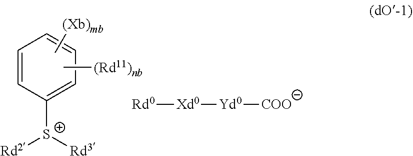
wherein Xb represents a halogen atom, a halogenated alkyl group, a cyano group, a nitro group, an alkylsulfone group or an arylsulfone group; Rd¹¹ represents an alkyl group, an alkoxy group, an oxycarbonyl group, a sulfenyl group or an aryl group; mb represents an integer of 1 to 5; nb represents an integer of 0 or more and (5-mb) or less; in the case where mb is 2 or more, the plurality of Xb may be the same or different from each other; in the case where nb is 2 or more, the plurality of Rd¹¹ may be the same or different from each other; Rd²′ and Rd³′ each independently represents an aryl group, alkyl group or alkenyl group which may have a substituent; Rd²′ and Rd³′ may be mutually bonded to form a ring with the sulfur atom in the formula; provided that, in the case where Rd² and Rd³ are mutually bonded to form a ring with the sulfur atom in the formula, a ring structure formed via —C(═O)— is excluded; Rd⁰ represents a monovalent organic group; Xd⁰ represents —O—, —C(═O)—, —O—C(═O)—, —C(═O)—O—, —S— or —SO₂—; and Yd⁰ represents a single bond or a divalent hydrocarbon group which may have a substituent.

10. The resist composition according to claim 8, wherein Rd⁰ in general formula (d0′) represents a cyclic hydrocarbon group which may have a substituent.

11. A method of forming a resist pattern, comprising:
forming a resist film using the resist composition according to claim 1;
exposing the resist film; and
developing the exposed resist film to form a resist pattern.

12. The method according to claim 5, wherein the resist film is exposed to extreme ultraviolet (EUV) or electron beam (EB).
